(19) United States
(12) Patent Application Publication
(10) Pub. No.: US 2026/0026259 A1
(43) Pub. Date: Jan. 22, 2026

(54) LIGHT-EMITTING DIODE, ELECTRONIC DEVICE INCLUDING THE LIGHT-EMITTING DIODE AND HETEROCYCLIC COMPOUND FOR THE LIGHT-EMITTING DIODE

(71) Applicant: Samsung Display Co., Ltd., Yongin-si (KR)

(72) Inventors: YESEUL LEE, Yongin-si (KR); YOUNGJIN PARK, Yongin-si (KR); HEECHOON AHN, Yongin-si (KR); JUHUI YUN, Yongin-si (KR); HYOYOUNG LEE, Yongin-si (KR); JUNGHOON HAN, Yongin-si (KR)

(21) Appl. No.: 19/084,440

(22) Filed: Mar. 19, 2025

(30) Foreign Application Priority Data
Jul. 18, 2024 (KR) 10-2024-0095336

(51) Int. Cl. H10K 85/60; C09K 11/02; C09K 11/06; H10K 50/12; H10K 85/30; H10K 85/40; H10K 101/00

(52) U.S. Cl. CPC H10K 85/6572; C09K 11/02; C09K 11/06; H10K 85/346; H10K 85/40; H10K 85/654; C09K 2211/1007; C09K 2211/1014; C09K 2211/1022; C09K 2211/1029; C09K 2211/1044; C09K 2211/185; H10K 50/12; H10K 2101/90

(57) ABSTRACT

A light-emitting diode including a first electrode, a second electrode opposite to the first electrode, and a light-emitting layer between the first electrode and the second electrode and including a first compound represented by Formula 1, an electronic device including the light-emitting diode, and a heterocyclic compound represented by Formula 1 are provided.

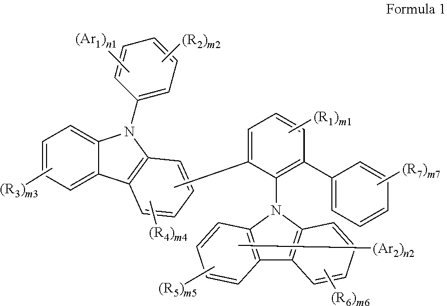

### CROSS-REFERENCE TO RELATED APPLICATION

The present application claims priority to and the benefit of Korean Patent Application No. 10-2024-0095336, filed on Jul. 18, 2024, in the Korean Intellectual Property Office, the entire content of which is incorporated herein by reference.

### BACKGROUND

### 1. Field

One or more embodiments of the present disclosure relate to a light-emitting diode, an electronic device including the light-emitting diode and a heterocyclic compound used in the light-emitting diode.

### 2 Description of the Related Art

Among light emitting diodes, an organic light-emitting diode is a self-emissive diode that has a relatively wider viewing angle, a higher contrast ratio, a shorter response time, and better characteristics in terms of luminance, driving voltage and response speed compared to the other kinds of light emitting diodes in the art.

For example, an organic light-emitting diode may have a structure in which a first electrode is arranged on a substrate, followed sequentially by a hole function layer, a light-emitting layer, an electron function layer, and a second electrode. Holes injected from the first electrode move to the light-emitting layer via the hole function layer, while electrons injected from the second electrode move to the light-emitting layer via the electron function layer. Carriers, such as the holes and the electrons, recombine in the light-emitting layer to produce excitons. The excitons may decay from an excited state to a ground state to generate light.

### SUMMARY

One or more aspects of embodiments of the present disclosure are directed toward a light-emitting diode, an electronic device including the light-emitting diode, and a heterocyclic compound for the light-emitting diode. Additional aspects will be set forth in part in the description which follows and, in part, will be apparent from the description, or may be learned by practice of the presented embodiments of the disclosure.

According to one or more embodiments of the present disclosure, a light-emitting diode may include a first electrode, a second electrode opposite to (e.g., facing) the first electrode, and a light-emitting layer between (e.g., interposed between) the first electrode and the second electrode, the light-emitting layer including a first compound represented by Formula 1:

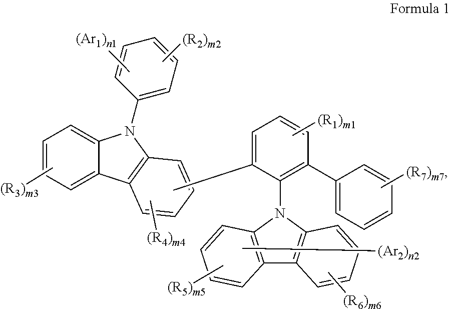

wherein in Formula 1, each of Ar₁ and Ar₂ may independently be represented by Formula 2 or Formula 3, each of n1 and n2 may independently be an integer between 0 and 2, inclusive, each of R₁ through R₇ may independently be hydrogen, deuterium, halogens, a substituted or unsubstituted alkyl group having 1 to 20 carbons, or a substituted or unsubstituted aryl group having 6 to 30 ring-forming carbons, each of m1 and m4 may independently be an integer between 0 and 3, inclusive, each of m2 and m7 may independently be an integer between 0 and 5, inclusive, and each of m3, m5, and m6 may independently be an integer between 0 and 4, inclusive.

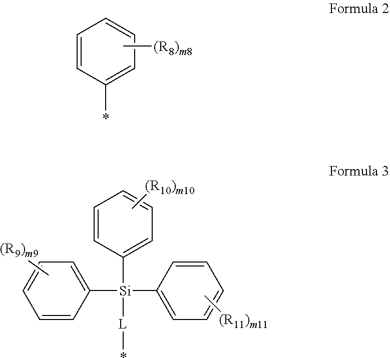

In Formula 2 and Formula 3, each of R₈ through R₁₁ may independently be hydrogen, deuterium, a substituted or unsubstituted silyl group, or a substituted or unsubstituted aryl group having 6 to 60 ring-forming carbons, each of m8 through m11 may independently be an integer between 0 and 5, inclusive, L may be a direct linkage or a substituted or unsubstituted arylene group having 6 to 30 ring-forming carbons, and [symbol] is a site of binding to Formula 1, e.g., a binding site to a corresponding moiety of Formula 1.

In one or more embodiments, the first compound represented by Formula 1 may be represented by any formula selected from among Formulae 1-1 through 1-4.

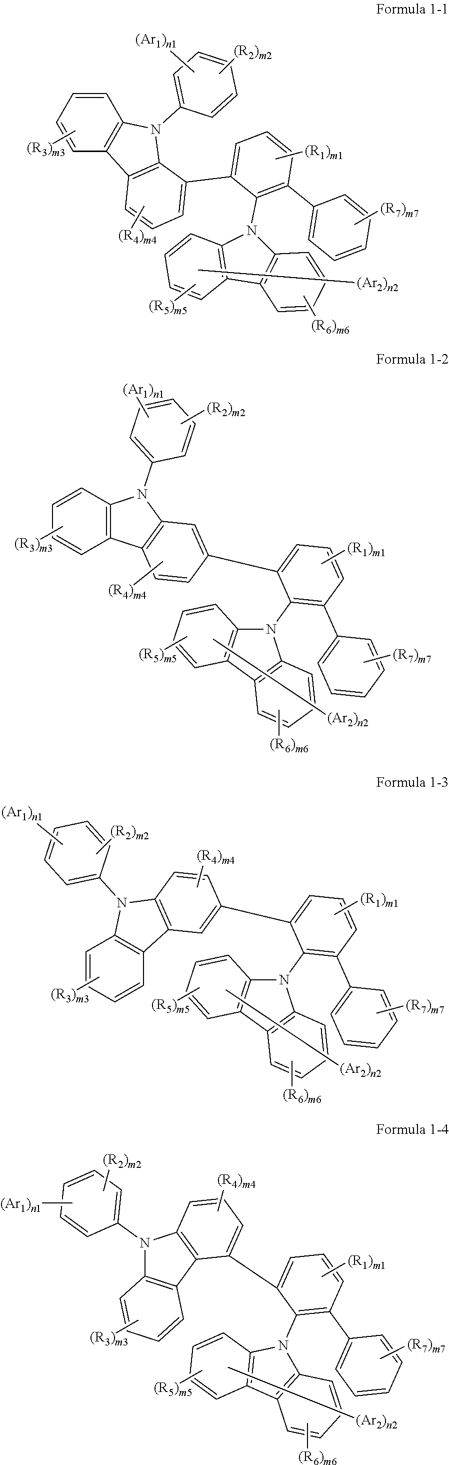

In Formulae 1-1 through 1-4, Ar₁, Ar₂, n1, n2, R₁ through R₇, and m1 through m7 may each independently be the same as defined in Formula 1.

In one or more embodiments, in Formula 1, R₇ may be hydrogen or deuterium, and m7 may be 5.

In one or more embodiments, in Formula 3, L may be a direct linkage, a substituted or unsubstituted phenylene group, or a phenylene group substituted with deuterium.

In one or more embodiments, the first compound represented by Formula 1 may be represented by any formula selected from among Formula 1-5 through Formula 1-15.

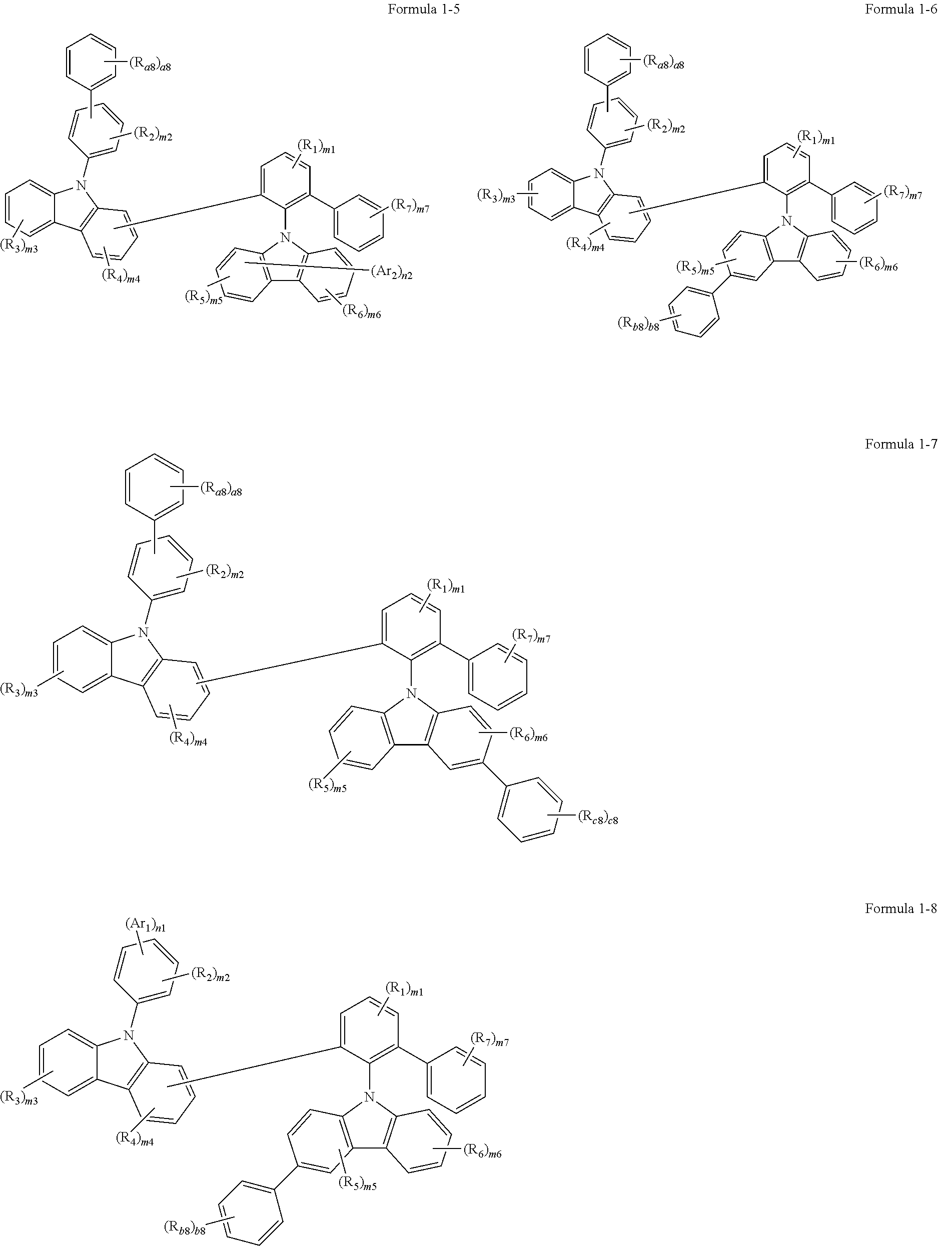

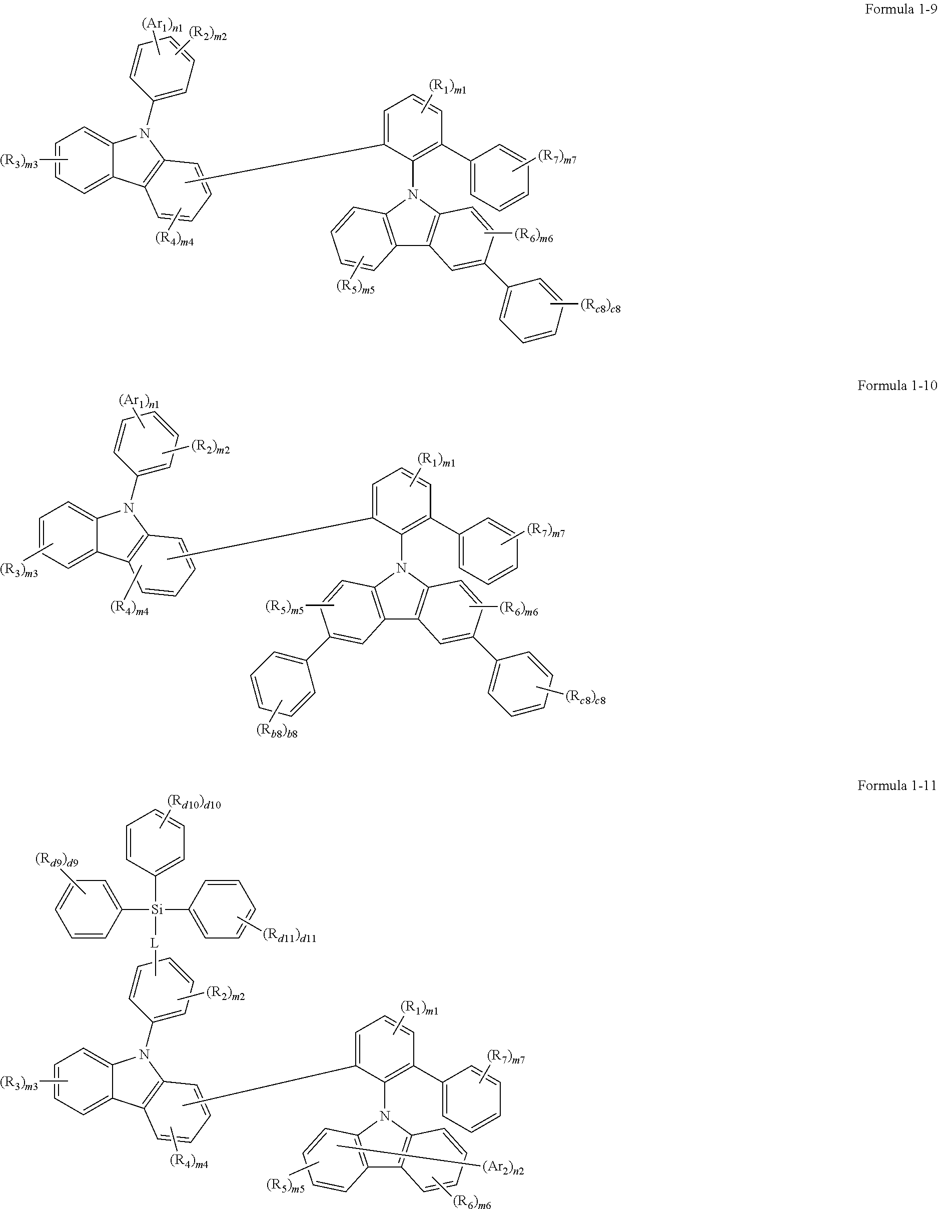

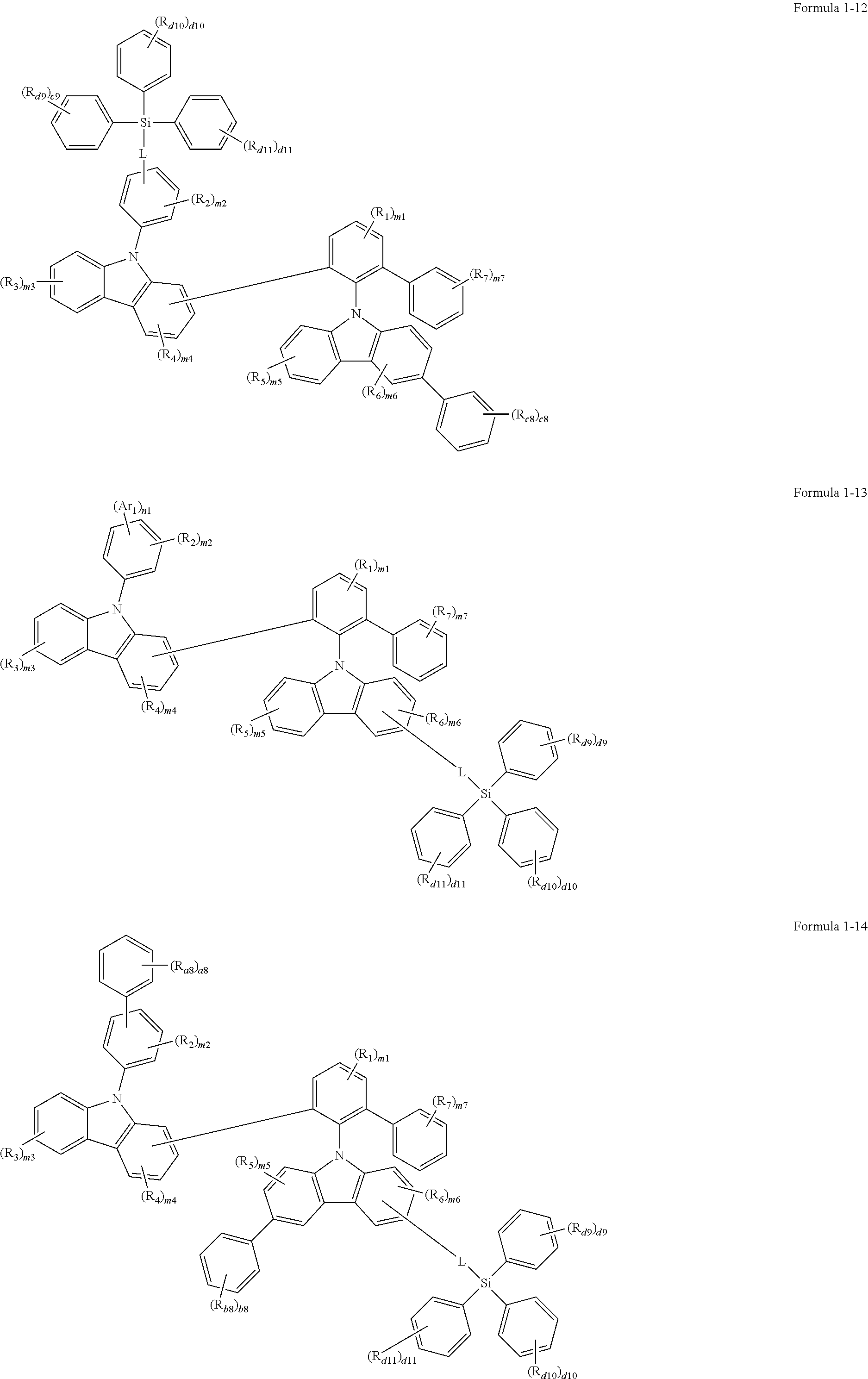

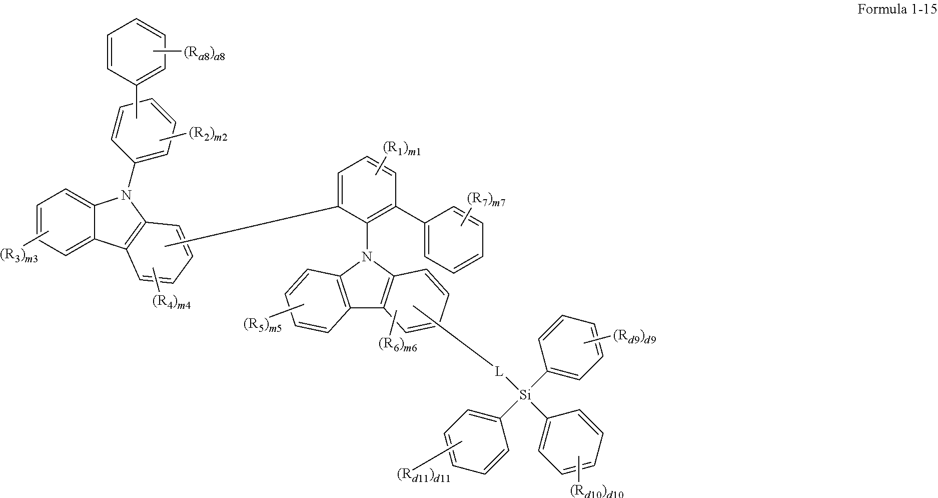

In Formulae 1-5 through 1-15, each of Res, Res, Res, Rue, Rono, and Ran may independently be hydrogen, deuterium, a substituted or unsubstituted silyl group, or a substituted or unsubstituted aryl group having 6 to 60 ring-forming carbons, each of a8, b8, c8, d9, d10 and d11 may independently be an integer between 0 and 5, inclusive, and Ar₁, Ar₂, n1, n2, R₁ through R₇, m1 through m7, and L may each independently be the same as defined in Formula 1.

The light-emitting layer may include the first compound represented by Formula 1.

In one or more embodiments, the light-emitting layer may include a host and a dopant, and the host may contain the first compound represented by Formula 1.

The light-emitting layer may be configured to emit light of phosphorescence or thermally activated delayed fluorescence.

In one or more embodiments, the light-emitting layer may further include a second compound represented by Formula ETH-1:

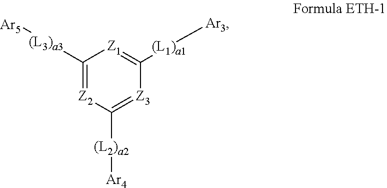

In Formula ETH-1, Z₁ may be N or CR₁₂, Z₂ may be N or CR₁₃, Z₃ may be N or CR₁₄, and at least one selected from among Z₁ through Z₃ may be N, Each of R₁₂ through R₁₄ may independently be hydrogen, deuterium, a substituted or unsubstituted alkyl group having 1 to 20 carbons, a substituted or unsubstituted aryl group having 6 to 50 ring-forming carbons, or a substituted or unsubstituted heteroaryl group having 2 to 50 ring-forming carbons; and each of L₁ through L₃ may independently be a direct linkage, a substituted or unsubstituted arylene group having 6 to 30 ring-forming carbons, or a substituted or unsubstituted heteroarylene group having 2 to 30 ring-forming carbons.

When each of a1 through a3 is an integer of at least 2, each of L₁ through L₃ may independently be a substituted or unsubstituted arylene group having 6 to 30 ring-forming carbons or a substituted or unsubstituted heteroarylene group having 2 to 30 ring-forming carbons, and each of a1 through a3 is independently an integer between 0 and 10, inclusive.

Each of Ar₃ through Ar₅ may independently be hydrogen, deuterium, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons.

In one or more embodiments, the light-emitting layer may further include a third compound represented by Formula M-a:

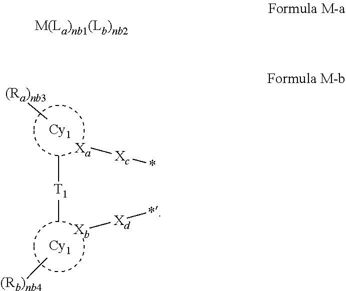

In Formula M-a and Formula M-b, M may be a transition metal, Lₐ may be a ligand represented by Formula M-b, nb1 may be 1, 2, or 3, and if (e.g., when) nb1 is two or greater, two or more Lₐ(s) may be identical to or different from each other, L_{b} may be an organic ligand, nb2 may be 0, 1, 2, 3, or 4, and if (e.g., when) nb2 is two or greater, two or more L_{b}(s) may be identical to or different from each other.

T₁ may be a direct linkage, *—O—*, *—S—*, *—N(Q₁)*—C(═O)—*, *C(Q₁)=C(Q₂)-*, *—C(Q₁)=*, *—C(Q₁)(Q₂)-*, or *═C(Q₁)-*; each of Xₐ and X_{b} may independently be C or N; each of X_{c} and X_{d} may independently be a chemical bond, O, S, N(Q₃), B(Q₃), P(Q₃), C(Q₃)(Q₄), or Si(Q₃)(Q₄); each of rings Cy₁ and Cy₂ may independently be a substituted or unsubstituted carbocyclic ring having 3 to 60 ring-forming carbons or a substituted or unsubstituted heterocyclic ring having 1 to 60 ring-forming carbons.

Each of Rₐ and R_{b} may independently be hydrogen, deuterium, halogens, a hydroxyl group, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbons, a substituted or unsubstituted alkenyl group having 2 to 20 carbons, a substituted or unsubstituted aryl group having 6 to 60 ring-forming carbons, or a substituted or unsubstituted heteroaryl group having 2 to 60 ring-forming carbons.

Each of Q₁ through Q₄ may independently be hydrogen, deuterium, halogens, a hydroxyl group, a cyano group, a nitro group, a substituted or unsubstituted alkyl group having 1 to 30 carbons, a substituted or unsubstituted alkenyl group having 1 to 30 carbons, a substituted or unsubstituted alkynyl group having 2 to 30 carbons, a substituted or unsubstituted alkoxy group having 1 to 30 carbons, a substituted or unsubstituted aryl group having 6 to 60 ring-forming carbons, or a substituted or unsubstituted heteroaryl group having 2 to 60 ring-forming carbons.

Each of nb3 and nb4 may independently be an integer between 0 and 10, inclusive.

In Formula M-b, each of * and *′ is a binding site with M of Formula M-a.

According to one or more embodiments of the present disclosure, an electronic device including the light-emitting diode is provided.

According to one or more embodiments of the present disclosure, a heterocyclic compound represented by Formula 1 is provided.

The light-emitting diode of one or more embodiments may include the heterocyclic compound of one or more embodiments to lower a driving voltage and improve a maximum quantum efficiency.

The heterocyclic compound of one or more embodiments may contribute to lowering a driving voltage and improving a maximum quantum efficiency of a light-emitting diode by including the heterocyclic compound. An electronic device may be manufactured by utilizing the light-emitting diode.

### BRIEF DESCRIPTION OF DRAWINGS

The accompanying drawings are included to provide a further understanding of the present disclosure and are incorporated in and constitute a part of this disclosure. The drawings illustrate embodiments of the present disclosure and, together with the description, serve to explain principles of the disclosure. These and/or other features will become apparent and more readily appreciated from the following description of one or more embodiments, taken in conjunction with the accompanying drawings, in which:

FIG. 1 is a plan view illustrating a display device in accordance with one or more embodiments of the present disclosure;

FIG. 2 is a cross-sectional view taken along the I-I′ line of FIG. 1;

FIGS. 3 through 6 are each a cross-sectional view illustrating a light-emitting diode in accordance with one or more embodiments of the present disclosure;

FIG. 7 is a cross-sectional view illustrating a portion of a display device in accordance with one or more embodiments of the present disclosure;

FIG. 8 is a cross-sectional view illustrating a portion of a display device in accordance with one or more embodiments of the present disclosure; and

FIG. 9 and FIG. 10 are each a drawing illustrating electronic devices applied with a display device according to one or more embodiments of the present disclosure.

### DETAILED DESCRIPTION

References will now be made in more detail to certain embodiments, of which examples are illustrated in the accompanying drawings, where like reference numerals refer to like elements throughout the disclosure, and duplicative descriptions thereof may not be provided for conciseness. The presented embodiments may have a variety of forms and permutations, but the present disclosure shall by no means be construed as being limited to the described embodiments. Rather, the present disclosure shall be construed to encompass all form, permutations, equivalents, and substitutes covered by the technical ideas and scope of the present disclosure. Accordingly, one or more embodiments are merely described, by referring to the drawings, to explain features of the present disclosure and to convey the scope of the disclosure to those skilled in the art.

Unless otherwise defined, all technical terms and scientific terms used herein have the same meaning as how they are generally understood by those of ordinary skill in the art to which the present disclosure pertains. However, if (e.g., when) the meanings do not match, a description, including a definition, of the present disclosure takes precedence.

Terms such as “first” and “second” may be used in describing one or more suitable elements, but the elements shall not be restricted to the terms. The terms may be used only to distinguish one element from the other. For instance, the first element may be named the second element, and vice versa, without departing the scope of the present disclosure. Unless clearly used otherwise, any expressions in a singular form may include a meaning of a plural form. For example, the singular forms “a,” “an,” “one,” and “the” are intended to include the plural forms as well, unless the context clearly indicates otherwise. The term “and/or” or “or” as used herein shall include the combination of a plurality of listed items or any of the plurality of listed items. Further, the utilization of “may” when describing embodiments of the present disclosure refers to “one or more embodiments of the present disclosure”.

When an element is described to be “on,” “placed on,” “arranged on,” “connected to,” or “coupled to” another element, it shall be construed as being on, placed on, arranged on, connected to, or coupled to the other element directly but also as possibly having another element arranged between the element and the other element. In contrast, if (e.g., when) one element is described to be “directly on,” “directly placed on,” “directly arranged on,” “directly connected to,” or “directly coupled to” another element, it shall be construed that there is no other element arranged between the element and the another element.

An expression such as “comprise(s)/comprising”, “include(s)/including”, or “has (have)/having” is intended to designate a characteristic, a number, a step (e.g., act or task), an operation, an element, a part, and/or one or more (e.g., any suitable) combinations thereof, and shall not be construed to preclude any possibility of presence or addition of one or more other characteristics, numbers, steps, operations, elements, parts, and/or one or more (e.g., any suitable) combinations thereof. Additionally, the terms “comprise(s)/comprising,” “include(s)/including,” “has (have)/having,” or other similar terms include or support the terms “consisting of” and “consisting essentially of,” indicating the presence of stated features, integers, steps, operations, elements, components, and/or groups, without or essentially without the presence of other features, integers, steps, operations, elements, components, and/or groups thereof.

When a component is described to be arranged “on (or below)” an element or “above (or below)” an element, it shall be construed not only as being arranged directly on (or below) the element but also as possibly having another element arranged between the component and the element.

Any reference to “and/or” shall be construed to include one or more combinations that can be defined by relevant elements. A size and a thickness of each configuration illustrated in a drawing is shown as an example for convenience, and embodiments of the present disclosure are not limited thereto.

As used herein,

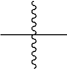

and [symbol] may each refer to a binding site.

As used herein, a direct linkage may refer to a chemical bond, such as a single bond.

As used herein, examples of halogens may include fluorine, chlorine, bromine, and iodine.

As used herein, a “substituted or unsubstituted” group may be a group unsubstituted or substituted with at least one substituent selected from among a group containing deuterium, halogens, a nitro group, an amine group, a cyano group, a silyl group, an oxy group, a thio group, a sulfinyl group, a sulfonyl group, a carbonyl group, a boron group, an alkyl group, an alkenyl group, an alkynyl group, an alkoxy group, a phosphine sulfide group, a phosphine oxide group, a hydrocarbon ring group, an aryl group, and a heterocyclic group. In addition, each of the substituents presented as examples above may be substituted or unsubstituted. For example, a biphenyl group may be interpreted as an aryl or as a phenyl group substituted with a phenyl group.

As used herein, the phrase “forming a ring by combining with an adjacent group” and/or the like may refer to forming a substituted or unsubstituted hydrocarbon ring or a substituted or unsubstituted heterocycle by combining with an adjacent group. The hydrocarbon ring includes an aliphatic hydrocarbon ring and/or an aromatic hydrocarbon ring. The heterocycle includes an aliphatic heterocycle and/or an aromatic heterocycle. The carbon ring and the heterocycle may each be a monocycle or a polycycle. In addition, the formed ring may be combined with another ring to form a spiro structure.

As used herein, a fluorenyl group may be substituted, and two substituents may be combined to form a spiro structure with the fluorenyl group.

As used herein, the phrase “an adjacent group” may refer to a substitute connected to an atom which is directly connected to another atom substituted with another substituent; a substituent connected to an atom which is substituted with another substituent; or a substituent sterically positioned at the nearest position to another substituent. For example, two methyl groups in 1,2-dimethylbenzene may be interpreted as an “adjacent group” to each other.

As used herein, an alkyl group may have a linear chain or a branched chain. The number of carbons in the alkyl group may be 1 to 30, 1 to 20, or 1 to 10. Non-limiting examples thereof may include methyl, ethyl, propyl, n-propyl, isopropyl, butyl, n-butyl, isobutyl, tert-butyl, sec-butyl, 1-methyl-butyl, 1-ethyl-butyl, pentyl, n-pentyl, isopentyl, neopentyl, tert-pentyl, hexyl, n-hexyl, 1-methylpentyl, 2-methylpentyl, 3,3-dimethylbutyl, 2-ethylbutyl, heptyl, n-heptyl, 1-methylhexyl, octyl, n-octyl, tert-octyl, 1-methylheptyl, 2-ethylhexyl, 2-propylpentyl, n-nonyl, 2,2-dimethylheptyl, 1-ethyl-propyl, 1,1-dimethyl-propyl, isohexyl, 2-methylpentyl, 4-methylhexyl, and 5-methylhexyl.

As used herein, a cycloalkyl group may refer to a cyclic alkyl group. The number of carbons in the cycloalkyl group may be 3 to 50, 3 to 30, or 3 to 10. Non-limiting examples of the cycloalkyl group may include cyclopropyl, cyclobutyl, cyclopentyl, cyclohexyl, 4-methylcyclohexyl, 4-t-butylcyclohexyl, cycloheptyl, cyclooctyl, cyclononyl, cyclodecyl, norbornyl, 1-adamantyl, 2-adamantyl, isobornyl, and bicycloheptyl.

As used herein, an alkenyl group may refer to a hydrocarbon group including one or more carbon-carbon double bonds in the middle and/or at the terminal of an alkyl group having 2 or more carbons. An alkenyl group may have a linear chain or a branched chain. The number of carbons in the alkenyl group may be, but not limited to, 2 to 30, 2 to 20 or 2 to 10. Non-limiting examples of the alkenyl group may include 1-butenyl, 1-pentenyl, 1,3-butadienyl aryl, and styrenyl.

As used herein, an alkynyl group may refer to a hydrocarbon group including one or more carbon-carbon triple bonds in the middle and/or at the terminal of an alkyl group having 2 or more carbons. The number of carbons in the alkynyl group may be, but not limited to, 2 to 30, 2 to 20 or 2 to 10. Non-limiting examples thereof may include ethynyl and propynyl.

As used herein, a carbocyclic ring refers to a monocyclic group or a polycyclic group having 3 to 60 ring-forming carbons including carbon only as a ring-forming atom. The carbocyclic ring having 3 to 60 carbons may include an aromatic carbocyclic group and/or a non-aromatic carbocyclic group, for example, a non-aromatic carbocyclic group.

In addition, as used herein, a heterocyclic ring is a cyclic group having 1 to 60 ring-forming carbons and further including a heteroatom as a ring-forming atom other than a carbon. The heteroatom may include at least one of B, O, N, P, Si, or S.

As used herein, a hydrocarbon ring group may be an any functional group or a substituent derived from an aliphatic hydrocarbon ring, or any functional group or a substituent derived from an aromatic hydrocarbon ring. The hydrocarbon ring group may at least one heteroatom selected from among B, O, N, P, Si, and S as a ring-forming atom. When two or more heteroatoms are included, the two or more heteroatoms may be identical to or different from each other.

As used herein, an aryl group refers to a functional group or a substituent derived from an aromatic hydrocarbon ring. The aryl group may be a monocyclic aryl or a polycyclic aryl. The aryl group may have 6 to 60, 6 to 30, 6 to 20, or 6 to 15 ring-forming carbons. Non-limiting examples of the aryl group may include a phenyl group, a fluorenyl group, an anthracenyl group, a naphthyl group, a terphenyl group, a biphenyl group, a sexiphenyl group, a triphenylenyl group, and a benzofluoranthenyl group.

As used herein, a heteroring group (i.e., a heterocyclic group) may refer to any functional group or substituent derived from a ring including at least one of B, O, N, P, Si, or S as a ring-forming heteroatom. The heteroring group may include an aliphatic heteroring group and/or an aromatic heteroring group. The aromatic heteroring group may be a heteroaryl group. The aliphatic heteroring and the aromatic heteroring may each be a monocyclic or a polycyclic.

As used herein, if (e.g., when) the heteroring group includes two or more heteroatoms, the two or more heteroatoms may be identical to or different from each other. The heteroring group may be a monocyclic heteroring or a polycyclic heteroring and interpreted as a concept including a heteroaryl group. The heteroring group may have 2 to 30, 2 to 20, or 2 to 10 ring-forming carbons.

As used herein, an aliphatic heteroring group may include at least one of B, O, N, P, Si, or S as a ring-forming heteroatom. The aliphatic heteroring group may have 2 to 30, 2 to 20, or 2 to 10 ring-forming carbons. Non-limiting examples of the aliphatic heteroring group may include a thiirane group, a pyrrolidine group, a piperidine group, a tetrahydrofuran group, and 1,4-dioxane group.

As used herein, a heteroaryl group may include at least one of B, O, N, P, Si, or S as a ring-forming atom. When the heteroaryl group includes two or more heteroatoms, the two or more heteroatoms may be identical to or different from each other. The heteroaryl group may be a monocyclic heteroring or a polycyclic heteroring. The heteroaryl group may have 2 to 60, 2 to 30, 2 to 20, or 2 to 10 ring-forming carbons. Non-limiting examples may include a furan group, a pyrrole group, an imidazole group, a pyridine group, a pyrimidine group, a triazine group, a pyridazine group, a quinoline group, an isoquinoline group, a pyridopyrimidine group, a benzocarbazole group, a benzofuran group, and an oxazole group.

As used herein, the above description of the aryl group may be applied to an arylene group, except that the arylene group is a polyvalent group (e.g., a divalent group). The above description of the heteroaryl may be applied to a heteroarylene group, except that the heteroarylene group is a polyvalent group (e.g., a divalent group).

As used herein, a silyl group may include an alkyl silyl group and/or an aryl silyl group. Non-limiting examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, and a phenylsilyl group.

As used herein, a boryl group may include an alkyl boryl and/or an aryl boryl group. Non-limiting examples of the boryl group may include a dimethylboryl group, a diethylboryl group, a t-butylmethylboryl group, a diphenylboryl group, and a phenylboryl group.

As used herein, a thio group may include an alkyl thio group and/or an aryl thio group. A thio group may indicate a group in which a sulfur atom is bonded to an alkyl or an aryl group defined above. Non-limiting examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthiol group, and a naphthylthio group.

As used herein, an oxy group may indicate a group in which an oxygen atom is bonded to an alkyl or an aryl group defined above. The oxy group may include an alkoxy group and/or an aryl oxy group. An alkoxy group may be linear, branched, or cyclic. The number of carbon atoms in the alkoxy group is not particularly limited, but may be, for example, 1 to 20, or 1 to 10. Non-limiting examples of the oxy group may include a methoxy, an ethoxy, a n-propoxy, an isopropoxy, a butoxy, a pentyloxy, a hexyloxy, an octyloxy, a nonyloxy, a decyloxy, and a benzyloxy.

As used herein, a boron group may refer to a group in which a boron atom is bonded to an alkyl or an aryl group defined above. The boron group may include an alkyl boron group and/or an aryl boron group. Non-limiting examples of the boron group may include a dimethyboron group, a diethylboron group, a t-butylmethylboron group, a diphenylboron group, and a phenylboron group.

As used herein, the number of carbon atoms in an amine group is not particularly limited, but may be 1 to 30. The amine group may include an alkyl amine group and/or an aryl amine group. Non-limiting examples of the amine group may include a methylamine group, a dimethylamine group, a phenylamine group, a diphenylamine group, a naphthylamine group, a 9-methyl-anthracenylamine group, and a triphenylamine group.

Hereinafter, certain example embodiments of the present disclosure will be described in more detail with reference to the accompanying drawings.

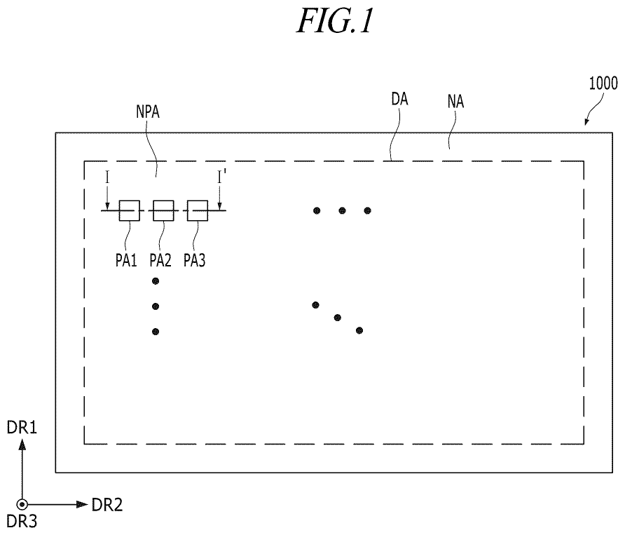

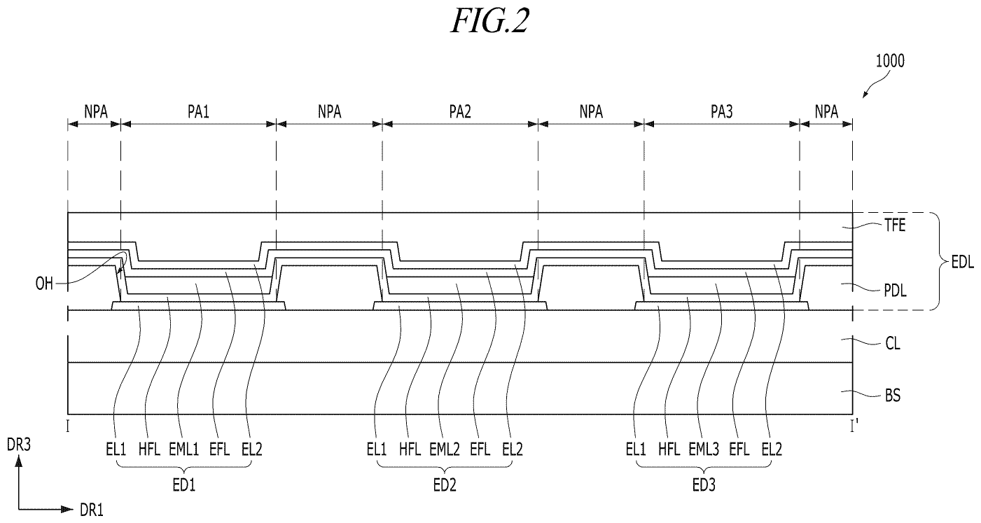

FIG. 1 is a plan view illustrating a display device in accordance with one or more embodiments of the present disclosure, and FIG. 2 is a cross-sectional view of the display device, taken along the I-I′ line of FIG. 1, in accordance with one or more embodiments of the present disclosure.

In one or more embodiments of the present disclosure, first to third directions DR1, DR2 and DR3 may be defined, in which a first direction DR1 and a second direction DR2 may intersect with each other in directions flush with a display device 1000 illustrated in FIG. 1. A third direction DR3 may be in a direction of thickness of the display device illustrated in FIG. 2, for example normal to a plane defined by the first direction DR1 and the second direction DR2.

The display device 1000 may include a substrate BS, a circuit layer CL and a display device layer EDL.

The circuit layer CL and the display device layer EDL may be arranged on the substrate BS.

The substrate BS may include, glass, ceramic, a metal, or a polymer resin such as a polyimide. Yet, embodiments of the present disclosure are not limited thereto, and the substrate BS may be an inorganic layer, an organic layer, or a composite material layer, and may be constituted with a single layer and a multilayer.

The circuit layer CL may be arranged on the substrate BS and include a plurality of wires and a plurality of transistors. In one or more embodiments, the circuit layer CL may include pixel transistors configured to drive light-emitting diodes ED1, ED2, and ED3 of the display device layer EDL. The circuit layer CL may include surrounding transistors arranged on a surrounding area NA and configured to output signals to control pixel transistors.

The display diode layer EDL may include a pixel defining film PDL, light-emitting diodes ED1, ED2, and ED3, and an encapsulation layer TFE.

The pixel defining film PDL may include at least one insulating material selected from the group consisted of a polyimide, a polyamide, an acryl resin, a benzocyclobutene-based resin, and a phenol resin.

Each of the light emitting diodes ED1, ED2, and ED3 may include a first electrode EL1, a hole functional layer HFL, a respective light-emitting layer EML1, EML2, or EML3, an electron functional layer EFL, and a second electrode EL2.

The hole functional layer HFL is configured to facilitate movement of a hole from the first electrode EL1 to the light-emitting layer EML1, EML2, and EML3, and the electron functional layer EFL is configured to facilitate movement of an electron from the second electrode EL2 to the light-emitting layer EML1, EML2, and EML3. FIG. 2 illustrates that the hole functional layer HFL is interposed between the first electrode EL1 and the light-emitting layer EML1, EML2, and EML3, and the electron functional layer EFL is interposed between the second electrode EL2 and the light-emitting layer EML1, EML2, and EML3. However, embodiments of the present disclosure are not limited thereto, and the positions of the hole functional layer HFL and the electron functional layer EFL may be exchanged based on whether each of the first electrode EL1 and the second electrode EL2 is positively charged or negatively charged.

FIG. 2 illustrates one or more embodiments in which the light-emitting layers EML1, EML2, and EML3 of the light-emitting diodes are arranged in an opening OH defined in the pixel defining film PDL, and the hole functional layer HFL, the electron functional layer EFL, and the second electrode EL2 are each provided as a common layer throughout the light-emitting diodes ED1, ED2, and ED3. However, embodiments of the present disclosure are not limited to what is illustrated in FIG. 2, for example, in one or more embodiments, at least one of the hole functional layer HFL or the electron functional layer EFL may be provided to be patterned inside the opening OH defined in the pixel defining film PDL.

In one or more embodiments, at least some of the light-emitting diodes ED1, ED2, and ED3 may be configured to emit light in a different wavelength range. For example, in one or more embodiments, a first light-emitting diode ED1 may be configured to emit red light, a second light-emitting diode ED2 may be configured to emit green light, and a third light-emitting diode ED3 may be configured to emit blue light. However, embodiments of the present disclosure are not limited to this configuration, for example, a first through a third light-emitting diodes may be configured to emit light in substantially the same wavelength range, such as blue light.

The structure of the light-emitting diodes ED1, ED2, and ED3 and materials of layers constituting each of the light-emitting diodes ED1, ED2, and ED3 will be described in more detail later.

The encapsulation layer TFE may be configured to seal off the light-emitting diodes ED1, ED2, and ED3 to protect the light-emitting diodes ED1, ED2, and ED3 from moisture, oxygen, and/or foreign substances. In one or more embodiments, the encapsulation layer TFE may be constituted with a single layer. In one or more embodiments, the encapsulation layer TFE may be constituted with multiple layers including an encapsulation organic film and an encapsulation inorganic film.

The encapsulation organic film may include one or more selected from among acrylic compounds, epoxy compounds, and/or the like. In one or more embodiments, the encapsulation organic film may contain, but may not be limited to, one or more of photo-polymerizable organic materials. The encapsulation inorganic film may include, but may not be limited to, silicon nitride, silicon oxynitride, silicon oxide, titanium oxide, and/or aluminum oxide.

Referring to FIG. 1 and FIG. 2, the display device 1000 may be defined with a display area DA and a surrounding area NA defined outside of the display area. The display area DA may be an area configured to display an image and the surrounding area NA may be an area not configured to display an image. In certain embodiments, the surrounding area NA may not be provided.

Pixel areas PA1, PA2, and PA3 and a non-pixel area NPA may be defined in the display area DA. As light-emitting diodes ED1, ED2, and ED3 may be arranged to correspond to the pixel areas PA1, PA2, and PA3, respectively, the pixel areas may be areas configured to display emitted light. The non-pixel area NPA may be an area defined among the pixel areas PA1, PA2, and PA3 and correspond to the pixel defining film PDL.

Although it is illustrated in FIG. 1 and FIG. 2 that the pixel areas PA1, PA2, and PA3 have the same area, embodiments of the present disclosure are not limited to what are illustrated in FIG. 1 and FIG. 2, for example, in one or more embodiments, some of the pixel areas PA1, PA2, and PA3 may have different areas.

In one or more embodiments, the display device 1000 according to one or more embodiments of the present disclosure may further include an optical layer arranged on the display device layer EDL. The optical layer may be configured to reduce reflected light of external light. The optical layer may include a polarizing layer or a color filter layer.

In one or more embodiments, the display device 1000 according to one or more embodiments of the present disclosure may further include a touch-sensor layer arranged on the display device layer EDL. The touch-sensor layer may detect a coordination of a touch where a touch occurs. The touch-sensor layer may be interposed between the display device layer EDL and the optical layer.

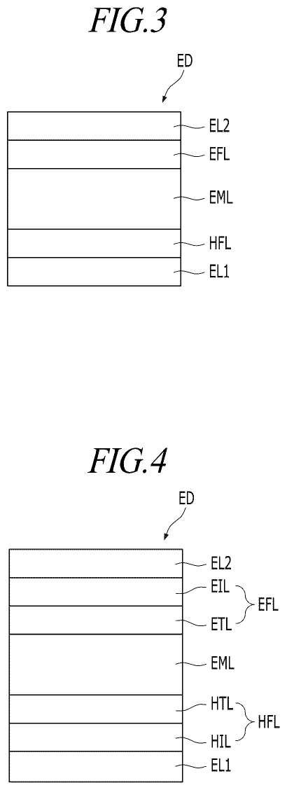

FIGS. 3 through 6 are each a cross-sectional view illustrating a light-emitting diode according to one or more embodiments of the present disclosure.

The light-emitting diode ED according to one or more embodiments of the present disclosure illustrated in FIG. 3 may include a first electrode EL1, a hole functional layer HFL, a light-emitting layer EML, an electron functional layer EFL, and a second electrode EL2 that are sequentially laminated (e.g., in the stated order).

In the light-emitting diode ED according to one or more embodiments of the present disclosure illustrated in FIG. 4, the hole functional layer HFL may include a hole injection layer HIL and a hole transport layer HTL, and an electron functional layer EFL may include an electron transport layer ETL and an electron injection layer EIL.

In the light-emitting diode ED according to one or more embodiments of the present disclosure illustrated in FIG. 5, the hole functional layer HFL may include a hole injection layer HIL, a hole transport layer HTL, and an electron blocking layer EBL, and the electron functional layer EFL may include a hole blocking layer HBL, an electron transport layer ETL, and an electron injection layer EIL.

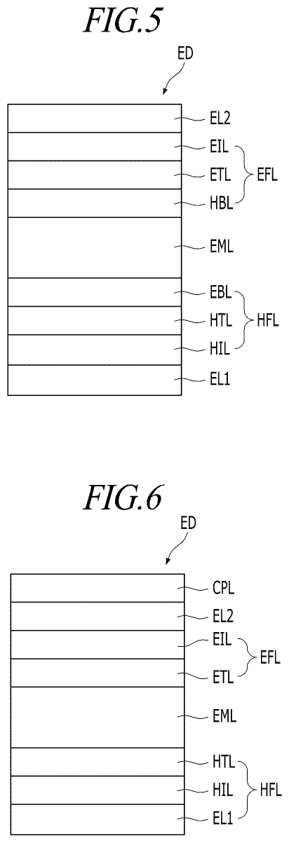

In one or more embodiments illustrated in FIG. 6, compared to the structure of the light-emitting diode ED in FIG. 4, the light-emitting diode ED may further include a capping layer CPL arranged on the second electrode EL2.

The first electrode EL1 is conductive (e.g., is a conductor). The first electrode EL1 may include a metal material, a metal alloy, or a conductive compound. The first electrode EL1 may be an anode or a cathode.

The first electrode EL1 may be a reflective electrode, a semi-transmissive electrode, or a transmissive electrode. If (e.g., when) the first electrode EL1 is a transmissive electrode, material(s) such as indium tin oxide (ITO), indium zinc oxide (IZO), zinc oxide (ZnO), indium tin zinc oxide (ITZO) may be included. If (e.g., when) the first electrode EL1 is a semi-transmissive electrode or a reflective electrode, the first electrode EL1 may include silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), LiF/Ca (lamination structure of lithium fluoride (LiF) and Ca), LiF/Al (lamination structure of LiF and Al), molybdenum (Mo), titanium (Ti), tungsten (W), and/or a (e.g., any suitable) combination and/or mixture thereof (e.g., a mixture of Ag and Mg)). In one or more embodiments, the first electrode EL1 may have a multilayer structure including a reflective film or a semi-transmissive film including one or more of the aforementioned materials and a transparent conductive film including ITO (indium tin oxide), IZO (indium zinc oxide), ZnO (zinc oxide), ITZO (indium tin zinc oxide), and/or the like. For example, in one or more embodiments, the first electrode EL1 may have a triple layer structure of ITO/Ag/ITO or a multiple layer structure of a triple layer structure of ITO/Ag/ITO, but embodiments of the present disclosure are not limited to this configuration.

The hole functional layer HFL may be provided on the first electrode EL1. The hole functional layer HFL may include at least one of a hole injection layer HIL, a hole transport layer HTL, a buffer layer, an emission auxiliary layer, or an electron blocking layer EBL.

The hole functional layer HFL may have a single layer structure including (e.g., consisted of) a single layer including (e.g., consisting of) a single material, a single layer structure including (e.g., consisted of) a single layer including a plurality of different materials, or a multi-layer structure including (e.g., consisted of) a plurality of layers including a plurality of different materials.

For example, in one or more embodiments, the hole functional layer HFL may have a structure in which a hole injection layer HIL/hole transport layer HTL, a hole injection layer HIL/hole transport layer HTL/buffer layer, a hole injection layer HIL/buffer layer, a hole transport layer HIL/buffer layer, or a hole injection layer HIL/hole transport layer HTL/electron blocking layer EBL are laminated in order (e.g., in the stated order) from the first electrode EL1. However, embodiments of the present disclosure are not limited thereto.

The hole functional layer HFL may be manufactured using one or more suitable methods, such as a vacuum deposition method, a spin coating method, a Langmuir-Blodgett (LB) method, an inkjet printing method, a casting method, a laser printing method, and/or a laser induced thermal imaging (LITI) method.

In one or more embodiments, the hole functional layer HFL may include a compound represented by Formula H-1, a compound represented by Formula H-2, and/or a (e.g., any suitable) combination thereof.

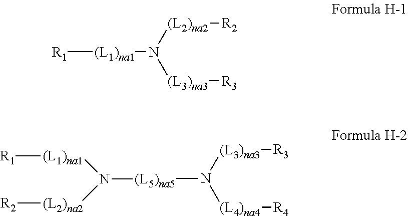

In Formula H-1 and Formula H-2, L₁ through L₅ may independently be a direct linkage, a substituted or unsubstituted arylene group having 6 to 30 ring-forming carbons, or a substituted or unsubstituted heteroarylene group having 2 to 30 ring-forming carbons.

na1 and na4 may independently be an integer between 0 and 5, inclusive.

na5 may be an integer between 1 and 10, inclusive.

In Formula H-1 and Formula H-2, R₁ through R₄ may independently be hydrogen, deuterium, halogens, a substituted or unsubstituted alkyl group having 1 to 20 carbons, a cycloalkyl group having 3 to 10 ring-forming carbons, a substituted or unsubstituted heterocycloalkyl group having 1 to 10 ring-forming carbons, a substituted or unsubstituted cycloalkenyl group having 3 to 10 ring-forming carbons, a substituted or unsubstituted heterocycloalkenyl group having 1 to 10 ring-forming carbons, a substituted or unsubstituted aryl group having 6 to 60 ring-forming carbons, a substituted or unsubstituted aryloxy group having 6 to 60 carbons, a substituted or unsubstituted arylthiol group having 6 to 60 carbons, or a substituted or unsubstituted heteroaryl group having 1 to 60 ring-forming carbons.

For example, in one or more embodiments, R₁ through R₄ may independently be, but not limited to, a phenyl group, a biphenyl group, a terphenyl group, a naphthyl group, a fluorenyl group, a spiro-bifluorenyl group, a benzofluorenyl group, a dibenzofluorenyl group, a phenanthrenyl group, a fluoranthenyl group, triphenylenyl group, a pyrenyl group, a perylenyl group, a pentaphenyl group, a thiophenyl group, a furanyl group, a carbazolyl group, an indolyl group, an isoindolyl group, a benzofuranyl group, a benzothiophenyl group, a dibenzofuranyl group, a dibenzothiophenyl group, a benzocarbazolyl group, a dibenzocarbazolyl group, a dibenzosilolyl group, or a pyridinyl group.

In one or more embodiments, R₁ and R₂ may be optionally bonded to each other via a single bond, and/or R₃ and R₄ may be optionally bonded to each other via a single bond.

In one or more embodiments of the present disclosure, compounds represented by Formula H-1 and Formula H-2 may be a carbazole-based compound including a substituted or unsubstituted carbazole group in at least one selected from among R₁ through R₄, or a compound including a substituted or unsubstituted fluorenyl group in at least one selected from among R₁ through R₄.

A compound represented by any formula selected from among Formula H-1 and Formula H-2 may be shown as N-([1,1′-biphenyl]-4-yl)-9,9-dimethyl-N-(4-(9-phenyl-9H-carbazol-3-yl)phenyl)-9H-fluoren-2-amine (BCFN) or 9-(3-(triphenylsilyl)phenyl)-9H-3,9′-bicarbazole (SiCzCz) presented in a device manufacture example of the present disclosure, however embodiments of the present disclosure are not limited thereto.

In one or more embodiments, the hole functional layer HFL may include at least of 4,4′,4″-tris{N,-(2-naphthyl)-N-phenylamino}-triphenylamine (2-TNATA), Poly(3,4-ethylenedioxythiophene)/Poly(4-styrenesulfonate) (PEDOT/PSS), 4,4′,4″-tris(3-methylphenylphenylamino) triphenylamine (m-MTDATA), 4,4′4″-Tris(N,N-diphenylamino)triphenylamine (TDATA), a phthalocyanine compound, such as copper phthalocyanine, N,N′-diphenyl-N,N′-bis-[4-(phenyl-m-tolyl-amino)-phenyl]-biphenyl-4,4′-diamine (DNTPD), Polyaniline/Dodecylbenzenesulfonic acid (PANI/DBSA), N,N′-di(naphthalen-1-yl)-N,N′-diphenyl-benzidine (NPB), triphenylamine-containing polyetherketone (TPAPEK), 4-Isopropyl-4′-methyldiphenyliodonium [Tetrakis(pentafluorophenyl)borate], or dipyrazino[2,3-f: 2′,3′-h] quinoxaline-2,3,6,7,10,11-hexacarbonitrile (HAT-CN).

In one or more embodiments, the hole functional layer HFL may include one or more selected from among a carbazole-based derivative, such as polyvinyl carbazole and/or N-phenyl carbazole, a fluorene-based derivative, a triphenylamine-based derivative, such as 4,4′4″-Tris-(carbazol-9-yl)-triphenylamine (TCTA), N,N′-bis(3-methylphenyl)-N,N′-diphenyl-[1,1′-biphenyl]-4,4′-diamine (TPD), N,N′-di(naphthalen-1-yl)-N,N′-diphenyl-benzidine (NPB), 4,4′-Cyclohexylidene bis[N,N-bis(4-methylphenyl)benzenamine] (TAPC), 4,4′-Bis[N,N′-(3-tolyl)amino]-3,3′-dimethylbiphenyl (HMTPD), and/or 1,3-Bis(N-carbazolyl)benzene (mCP).

In one or more embodiments, the hole functional layer HFL may include at least one of 1,3-bis(1,8-dimethyl-9H-carbazol-9-yl)benzene (mDCP), 9-(4-tert-Butylphenyl)-3,6-bis(triphenylsilyl)-9H-carbazole (CzSi), or 9-phenyl-9H-3,9′-bicarbazole (CCP).

The hole functional layer HFL may have a thickness of about 50 ångströms (Å) to about 10000 Å, e.g. about 100 Å to about 5000 Å. If (e.g., when) the hole functional layer HFL includes a hole injection layer HIL, a hole transport layer HTL, or any combination thereof, the hole injection layer HIL may have a thickness of about 100 Å to about 9000 Å, e.g., about 100 Å to about 1000 Å, and the hole transport layer may have a thickness of about 50 Å to about 2000 Å, e.g., about 100 Å to about 1500 Å. When the thicknesses of the hole functional layer HFL, the hole injection layer HIL, and the hole transport layer HTL satisfy their respective above-described ranges, satisfactory level of hole transport properties may be obtained without a substantial increase in driving voltage.

In one or more embodiments, the hole functional layer HFL may further include, in addition to one or more of the above-described materials, a charge-generation material to increase conductivity. The charge-generation material may be uniformly (e.g., substantially uniformly) or non-uniformly dispersed in the hole functional layer HFL.

The charge-generation material may be, for example, a p-dopant.

According to one or more embodiments of the present disclosure, the p-dopant may include at least one of a halogenated metal compound (e.g., a metal halide), a quinone derivative, a metal oxide, or a cyano group-containing compound, but embodiments of the present disclosure are not limited thereto.

For example, the p-dopant may include a halogenated metal compound, such as CuI and/or RbI, a quinone derivative, such as Tetracyanoquinodimethane (TCNQ) and/or 2,3,5,6-tetrafluoro-7,7,8,8-tetracyanoquinodimethane (F4-TCNQ), a cyano-group containing compound, such as dipyrazino[2,3-f: 2′3′-h] quinoxaline-2,3,6,7,10,11-hexacarbonitrile (HATCN) and/or 4-[2,3-bis[cyano-(4-cyano-2,3,5,6-tetrafluorophenyl)methylidene] cyclopropylidene]-cyanomethyl]-2,3,5,6-tetrafluorobenzonitrile (NDP9), and/or a metal oxide, such as a tungsten oxide and/or a molybdenum oxide, but embodiments of the present disclosure are not limited thereto.

As described above, in one or more embodiments, the hole functional layer HFL may further include at least one of a buffer layer or an electron blocking layer EBL in addition to the hole injection layer HIL and the hole transport layer HTL. The buffer layer may compensate for a resonance distance according to a wavelength of light emitted from the light-emitting layer EML to increase light-emitting efficiency. A material which may be included in the hole functional layer HFL may be used as a material included in the buffer layer. The electron blocking layer EBL is a layer that is configured to prevent or reduce the injection of electrons from the electron functional layer EFL to the hole functional layer HFL.

The emission auxiliary layer is a layer configured to compensate an optical resonance distance according to a wavelength of light emitted from the light-emitting layer to increase light-emitting efficiency, and the electron blocking layer EBL is a layer configured to prevent or reduce leakage of an electron from the light-emitting layer to the hole functional layer HFL. A material that may be included in the described hole functional layer HFL may be included in the emission auxiliary layer and the light blocking layer EBL.

The light-emitting layer EML may be provided on the hole functional layer HFL. The light-emitting layer EML may have a single layer including (e.g., consisting of) a single material, a single layer including (e.g., consisting of) a plurality of different materials, or a multilayer structure having a plurality of layers including (e.g., consisting of) a plurality of different materials.

In one or more embodiments of the present disclosure, the light-emitting layer EML of the light-emitting diode ED may include the heterocyclic compound of one or more embodiments. In one or more embodiments of the present disclosure, the light-emitting layer EML may include the heterocyclic compound of one or more embodiments as a host. The heterocyclic compound of one or more embodiments may be a host material of the light-emitting layer EML. The heterocyclic compound may be referred to as a first compound in one or more embodiments described hereinafter of the present disclosure.

The heterocyclic compound of one or more embodiments may include two carbazole groups substituted in ortho positions of a central phenylene group and a phenyl group substituted in an ortho position of the central phenylene group, and the phenyl group may include R₇ as a substituent. The central phenylene group may include R₁ of Formula 1 as a substituent. In one of the two carbazole groups (hereinafter, a first carbazole), a nitrogen atom, a ring-forming atom, may be coupled to the central phenylene group, one benzene ring of two benzene rings included in (e.g., composing) the first carbazole group may include R₅ of Formula 1 as a substituent, the other benzene ring may include R₆ of Formula 1 as a substituent, and the two benzene rings may include Ar₂. In the other carbazole group (hereinafter, a second carbazole group), one benzene ring of two benzene rings included in (e.g., composing) the second carbazole group may include R₃ of Formula 1 as a substituent, a benzene ring including R₄ of Formula 1 as a substituent may be coupled to the central phenylene group, a nitrogen atom, a ring-forming atom, may be coupled to a phenyl group, which may include R₂ of Formula 1 as a substituent and may include Ar₁.

In the present disclosure, a carbon atom of a basic structure of the carbazole group is numbered as follows:

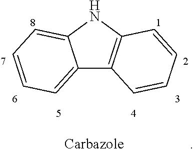 [SMILES: c1ccc2c(c1)[nH]c1ccccc12]

The numbering of the carbon of the carbazole group starts from a carbon atom at a position adjacent to a nitrogen atom clockwise. For the convenience of explanation, a substituent to be connected with the nitrogen atom is omitted in the above carbazole group.

The light-emitting diode ED of one or more embodiments may include the heterocyclic compound of one or more embodiments. The heterocyclic compound of one or more embodiments may be represented by Formula 1:

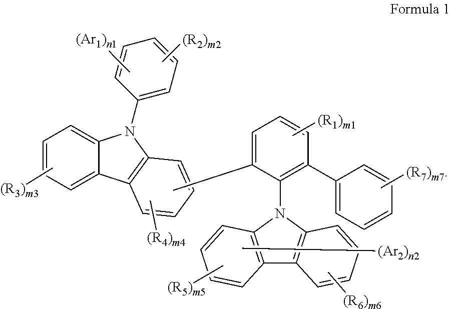

In Formula 1, each of R₁ to R₇ may independently be hydrogen, deuterium, halogens, a substituted or unsubstituted alkyl group of 1 to 20 carbons, or a substituted or unsubstituted aryl group of 6 to 30 ring-forming carbons. For example, in one or more embodiments, each of R₁ to R₇ may independently be hydrogen or deuterium.

Each of m1 and m4 may independently be an integer between 0 and 3, inclusive, each of m2 and m7 may independently be an integer between 0 and 5, inclusive, and each of m3, m5, and m6 may independently be an integer between 0 and 4, inclusive.

In Formula 1, if (e.g., when) each of m1 to m7 is independently 0, the heterocyclic compound of one or more embodiments may be unsubstituted with R₁ to R₇. An embodiment in which m1 and m4 are each 3, m2 and m7 are each 5, m3, m5, and m6 are each 4, and each of R₁ to R₇ is hydrogen may be the same as an embodiment in which m1 to m7 are each 0 in Formula 1. If (e.g., when) each of m1 to m7 is an integer of 2 or greater, each of R₁ to R₇ provided in a plurality may be all the same, or at least one selected from among R₁ to R₇ each in plurality may be different.

In Formula 1, a carbon atom numbered 1, a carbon atom numbered 2, a carbon atom numbered 3, or a carbon atom numbered 4 of the second carbazole group (i.e., the carbazole substituted with R₃ and R₄) may be substituted to a phenylene group.

n1 and n2 of Formula 1 may independently be an integer between 0 and 2, inclusive.

n1 and n2 of Formula 1 represent the number of Ar₁ and Ar₂, respectively. Ar₁ and Ar₂ may be represented by Formula 2 or Formula 3. For example, if (e.g., when) the n1 is an integer of 2, the two Ar₁ may be the same or different, and if (e.g., when) n2 is an integer of 2, the two Ar₂ may be the same or different. If (e.g., when) each of n1 and n2 is independently 0, it may not be substituted to Ar₁ and Ar₂.

For example, in one or more embodiments, the sum of n1 and n2 is 3.

Each of Ar₁ and Ar₂ in Formula 1 may independently be represented by Formula 2 or Formula 3:

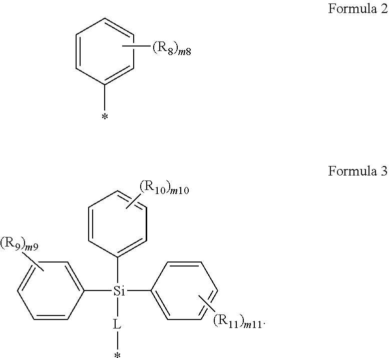

In Formula 2 and Formula 3, each of R₈ to R₁₁ may independently be hydrogen, deuterium, a substituted or unsubstituted silyl group, or a substituted or unsubstituted aryl group of 6 to 60 ring-forming carbons. For example, in one or more embodiments, each of R₈ to R₁₁ may independently be hydrogen, deuterium, a substituted or unsubstituted silyl group, or a substituted or unsubstituted phenyl group, or a phenyl group substituted with deuterium. L may be a direct linkage or a substituted or unsubstituted arylene group having 6 to 30 ring-forming carbons.

Each of m8 to m11 may independently be an integer between 0 and 5, inclusive.

In Formula 2 and Formula 3, if (e.g., when) each of m8 to m11 is independently 0, the heterocyclic compound of one or more embodiments may not involve substitution with R₈ to R₁₁ respectively. An embodiment in which m8 to m11 are each 5 and each of R₈ to R₁₁ is hydrogen may be the same as an embodiment in which m8 to m11 are 0 in Formula 2 and Formula 3. If (e.g., when) each of m8 to m11 is an integer of 2 or greater in Formula 2 and Formula 3, R₈ to R₁₁ each provided in a plurality may be all the same or at least one of the plurality of R₈(s) to R₁₁(s) may be different.

[symbol] is a binding site to Formula 1, e.g., a binding site to a corresponding moiety of Formula 1.

In one or more embodiments, the heterocyclic compound represented by Formula 1 may be represented by any one selected from among Formulae 1-1 through 1-4.

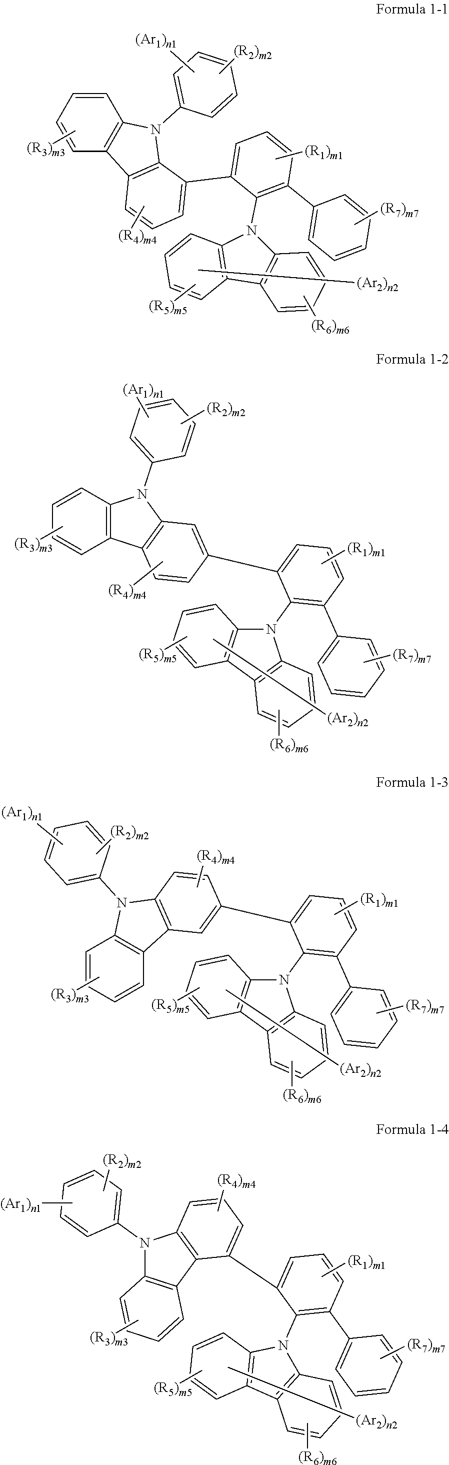

In Formulae 1-1 through 1-4, the same descriptions as for Formula 1 may be applied to Ar₁ to Ar₂, n1 to n2, R₁ to R₇, and m1 to m7. In other words, Ar₁ to Ar₂, n1 to n2, R₁ to R₇, and m1 to m7 may each independently be the same as defined in Formula 1.

According to one or more embodiments, R₇ in Formula 1 may be hydrogen or deuterium, and m7 may be 5.

According to one or more embodiments, L in Formula 3 may be a direct linkage, a substituted or unsubstituted phenylene group, or a phenylene group substituted with deuterium.

In one or more embodiments, the heterocyclic compound represented by Formula 1 may be represented by any one selected from among Formulae 1-5 through 1-15.

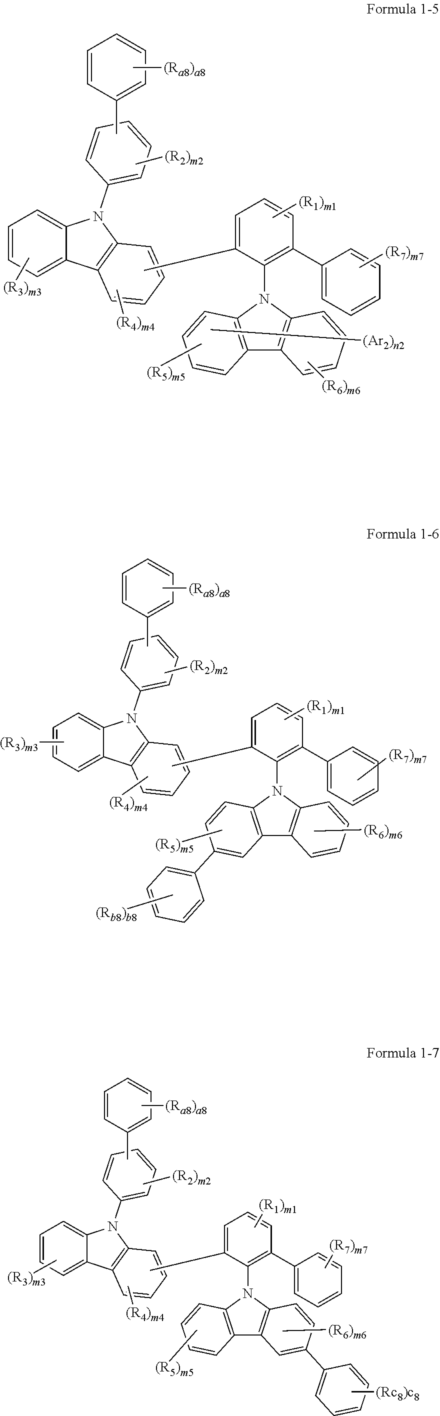

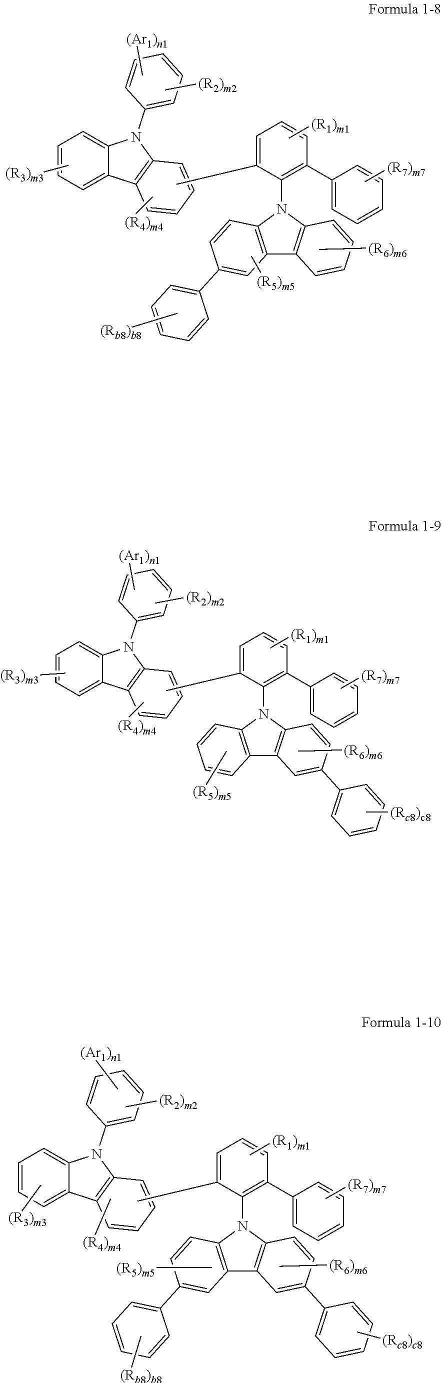

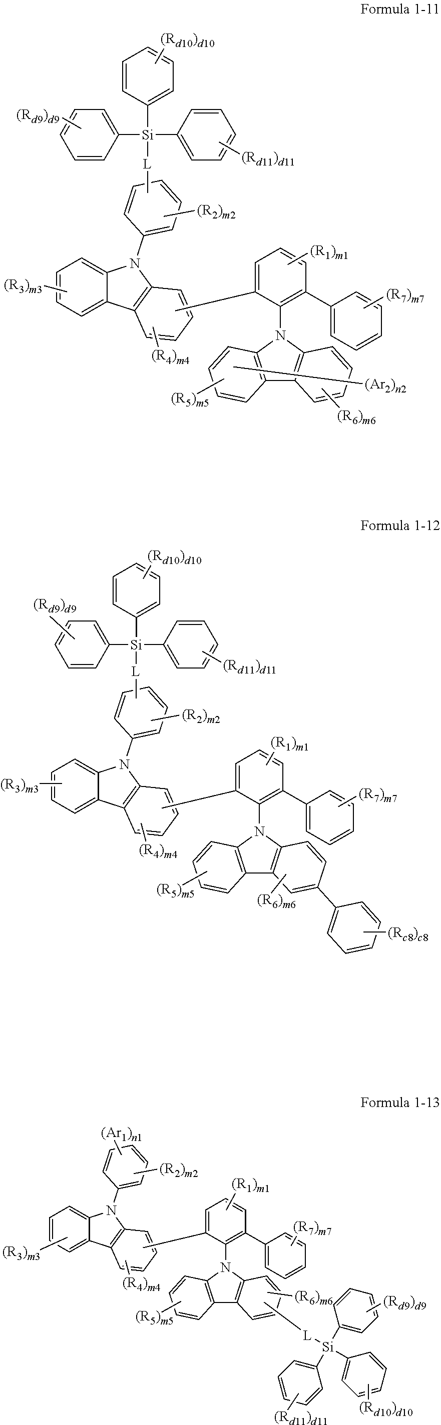

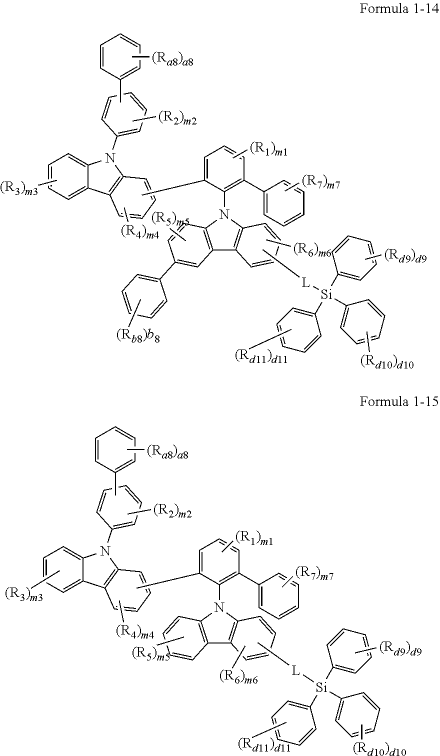

Formula 1-5 through Formula 1-10 specifically show Ar₁ and Ar₂ with substitution of the first carbazole group (i.e., the carbazole group substituted with R₅ and R₆) and the second carbazole group (i.e., the carbazole group substituted with R₃ and R₄) in Formula 1 with a group represented by Formula 2.

For example, Formula 1-5 shows an embodiment in which the phenyl group coupled to the nitrogen atom of the second carbazole group is substituted with a group represented by Formula 2, Formula 1-6 shows an embodiment in which the phenyl group coupled to the nitrogen atom of the second carbazole group is substituted with a group represented by Formula 2 and a carbon numbered 6 in a benzene ring including R₅ of Formula 1 as a substituent between the two benzene rings included in (e.g., composing) the first carbazole group is substituted with a group represented by Formula 2, Formula 1-7 is an embodiment in which the phenyl group coupled to the nitrogen atom of the second carbazole group is substituted with a group represented by Formula 2 and a carbon numbered 3 in a benzene ring including R₆ of Formula 1 as a substituent between the two benzene rings included in (e.g., composing) the first carbazole group is substituted with a group represented by Formula 2, Formula 1-8 is an embodiment in which a carbon numbered 6 in a benzene ring including R₅ of Formula 1 as a substituent between the two benzene rings included in (e.g., composing) the first carbazole group is substituted with a group represented by Formula 2, Formula 1-9 is an embodiment in which a carbon numbered 3 in a benzene ring including R₆ of Formula 1 as a substituent between the two benzene rings included in (e.g., composing) the first carbazole group is substituted with a group represented by Formula 2, and Formula 1-10 is an embodiment in which a carbon numbered 3 and a carbon numbered 6 in benzene rings including R₅ and R₆ of Formula 1 as substituents between the two benzene rings included in (e.g., composing) the first carbazole group are each substituted with a group represented by Formula 2.

In Formulae 1-5 through 1-10, each of Rₐ₈, R_{b8}, and R_{c8} may independently be hydrogen, deuterium, a substituted or unsubstituted silyl group, or a substituted or unsubstituted aryl group of 6 to 60 ring-forming carbons. For example, in one or more embodiments, each of Rₐ₈ to R_{c8} may independently be hydrogen, deuterium, a substituted or unsubstituted silyl group, or a phenyl group substituted with deuterium.

In Formulae 1-5 through 1-10, each of a8, b8, and c8 may independently be an integer between 0 and 5, inclusive. If (e.g., when) each of a8 through c8 in Formulae 1-5 through 1-10 is 0, the heterocyclic compound of one or more embodiments may be unsubstituted with Rₐ₈ to R_{c8}, respectively. An embodiment in which each of Rₐ₈ to R_{c8} is hydrogen may be the same as an embodiment in which a8 to c8 in Formulae 1-5 through 1-10 are each 0. If (e.g., when) each of a8 to c8 in Formulae 1-5 through 1-10 may be an integer of 2 or greater, each of Rₐ₈ to R_{c8} provided in a plurality may be the same, or at least one of Rₐ₈ to Rₐ₈ each in a plurality may be different.

In Formulae 1-5 through 1-10, the same descriptions as for Formula 1 may be applied to Ar₁ to Ar₂, n1 to n2, R₁ to R₇, and m1 to m7. In other words, Ar₁ to Ar₂, n1 to n2, R₁ to R₇, and m1 to m7 may each independently be the same as defined in Formula 1.

In Formulae 1-5 through 1-10, a carbon atom numbered 1, a carbon atom numbered 2, a carbon atom numbered 3, or a carbon numbered 4 in the second carbazole group may be substituted to the phenylene group.

Formula 1-11 through Formula 1-15 specifically show substitutions of Ar₁ and Ar₂ in the first carbazole group and the second carbazole group in Formula 1 with a group represented by Formula 2 and/or a group represented by Formula 3. Formula 1-11 shows an embodiment in which the phenyl group coupled to the nitrogen atom of the second carbazole group is substituted with a group represented by Formula 3, Formula 1-12 shows an embodiment in which the phenyl group coupled to the nitrogen atom of the second carbazole group is substituted with a group represented by Formula 3 and a carbon atom numbered 3 in a benzene ring including R₆ of Formula 1 as a substituent between the two benzene rings included in (e.g., composing) the first carbazole group is substituted with a group represented by Formula 2, Formula 1-13 shows an embodiment in which the benzene ring including R₆ of Formula 1 as a substituent between the two benzene rings included in (e.g., composing) the first carbazole group is substituted with a group represented by Formula 3, Formula 1-14 shows an embodiment in which the phenyl group coupled to the nitrogen atom of the second carbazole group is substituted with a group represented by Formula 2, a carbon numbered 6 in a benzene ring including R₅ of Formula 1 as a substituent between the two benzene rings included in (e.g., composing) the first carbazole group is substituted with a group represented by Formula 2, and the benzene ring including R₆ of Formula 1 as a substituent between the two benzene rings included in (e.g., composing) the first carbazole group is substituted with a group represented by Formula 3, and Formula 1-15 shows an embodiment in which the phenyl group coupled to the nitrogen atom of the second carbazole group is substituted with a group represented by Formula 2 and the benzene ring including R₆ of Formula 1 as a substituent between the two benzene rings included in (e.g., composing) the first carbazole group is substituted with a group represented by Formula 3.

In Formula 1-11 through Formula 1-15, each of R_{d9}, R_{d10}, and R_{d11} may independently be hydrogen, deuterium, a substituted or unsubstituted silyl group, or a substituted or unsubstituted aryl group of 6 to 60 ring-forming carbons. For example, in one or more embodiments, each of R_{d9}, R_{d10}, and R_{d11} may independently be hydrogen, deuterium, a substituted or unsubstituted silyl group, a substituted or unsubstituted phenyl group, or a phenyl group substituted with deuterium.

In Formulae 1-11 through 1-15, each of d9, d10, and d11 may independently be an integer between 0 and 5, inclusive. If (e.g., when) each of d9, d10, and d11 in Formulae 1-11 through 1-15 is 0, R_{d9}, R_{d10}, and R_{d11} of the heterocyclic compound of one or more embodiments may be unsubstituted. An embodiment in which each of R_{d9}, R_{d10}, and R_{d11} is hydrogen may be the same as an embodiment in which d9, d10, and d11 in Formulae 1-11 through 1-15 are each 0. If (e.g., when) each of d9, d10, and d11 in Formulae 1-11 through 1-15 is an integer of 2 or greater, each of R_{d9}, R_{d10}, and R_{d11} provided in a plurality may be all the same, or at least one of R_{d9}, R_{d10}, and R_{d11} each in a plurality may be different.

In Formula 1-11 through Formula 1-15, the same descriptions as for Formula 1 may be applied to Ar₁ to Ar₂, n1 to n2, R₁ to R₇, m1 to m7, and L. In other words, Ar₁ to Ar₂, n1 to n2, R₁ to R₇, m1 to m7, and L may each independently be the same as defined in Formula 1.

In Formula 1-11 through Formula 1-15, the same descriptions as for Formula 1-5 through Formula 1-10 may be applied to Rₐ₈, R_{b8}, R_{c8}, a8, b8, and c8. In other words, Rₐ₈, R_{b8}, R_{c8}, a8, b8, and c8 may each independently be the same as defined in Formula 1-5 through Formula 1-10.

In Formula 1-11 through Formula 1-15, a carbon numbered 1, a carbon numbered 2, a carbon numbered 3, and a carbon numbered 4 in the second carbazole group may be substituted to the phenylene group.

The heterocyclic compound of one or more embodiments may be any one of (e.g., any one selected from among) compounds represented in Compound Group 1. The light-emitting diode ED of one or more embodiments may include at least one heterocyclic compound selected from among the compounds listed in Compound Group 1 in the light-emitting layer EML.

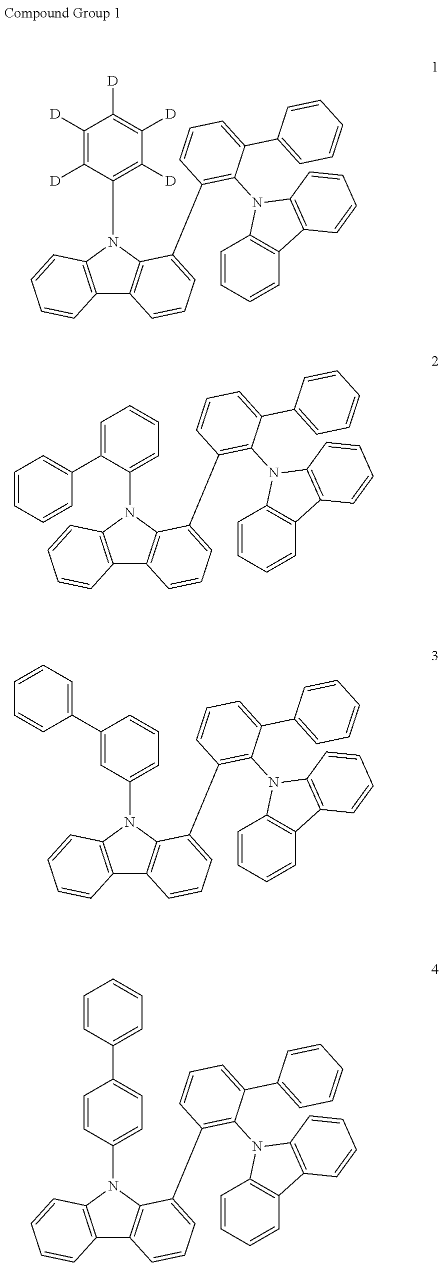 [SMILES: [2H]c1c([2H])c([2H])c(-n2c3ccccc3c3cccc(-c4cccc(-c5ccccc5)c4-n4c5ccccc5c5ccccc54)c32)c([2H])c1[2H] ; c1ccc(-c2ccccc2-n2c3ccccc3c3cccc(-c4cccc(-c5ccccc5)c4-n4c5ccccc5c5ccccc54)c32)cc1 ; c1ccc(-c2cccc(-n3c4ccccc4c4cccc(-c5cccc(-c6ccccc6)c5-n5c6ccccc6c6ccccc65)c43)c2)cc1 ; c1ccc(-c2ccc(-n3c4ccccc4c4cccc(-c5cccc(-c6ccccc6)c5-n5c6ccccc6c6ccccc65)c43)cc2)cc1]

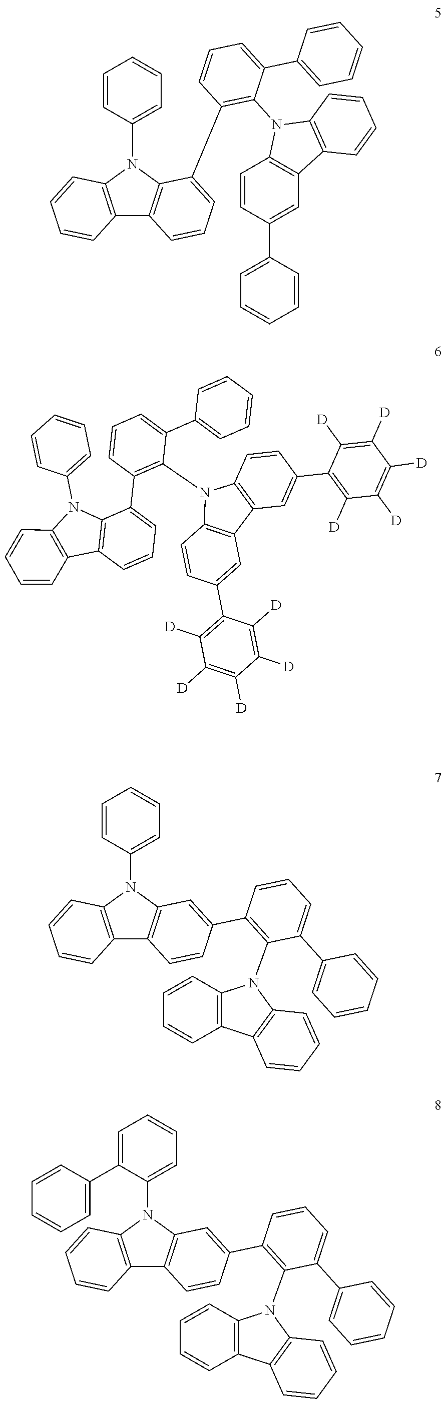 [SMILES: c1ccc(-c2ccc3c(c2)c2ccccc2n3-c2c(-c3ccccc3)cccc2-c2cccc3c4ccccc4n(-c4ccccc4)c23)cc1 ; [2H]c1c([2H])c([2H])c(-c2ccc3c(c2)c2cc(-c4c([2H])c([2H])c([2H])c([2H])c4[2H])ccc2n3-c2c(-c3ccccc3)cccc2-c2cccc3c4ccccc4n(-c4ccccc4)c23)c([2H])c1[2H] ; c1ccc(-c2cccc(-c3ccc4c5ccccc5n(-c5ccccc5)c4c3)c2-n2c3ccccc3c3ccccc32)cc1 ; c1ccc(-c2ccccc2-n2c3ccccc3c3ccc(-c4cccc(-c5ccccc5)c4-n4c5ccccc5c5ccccc54)cc32)cc1]

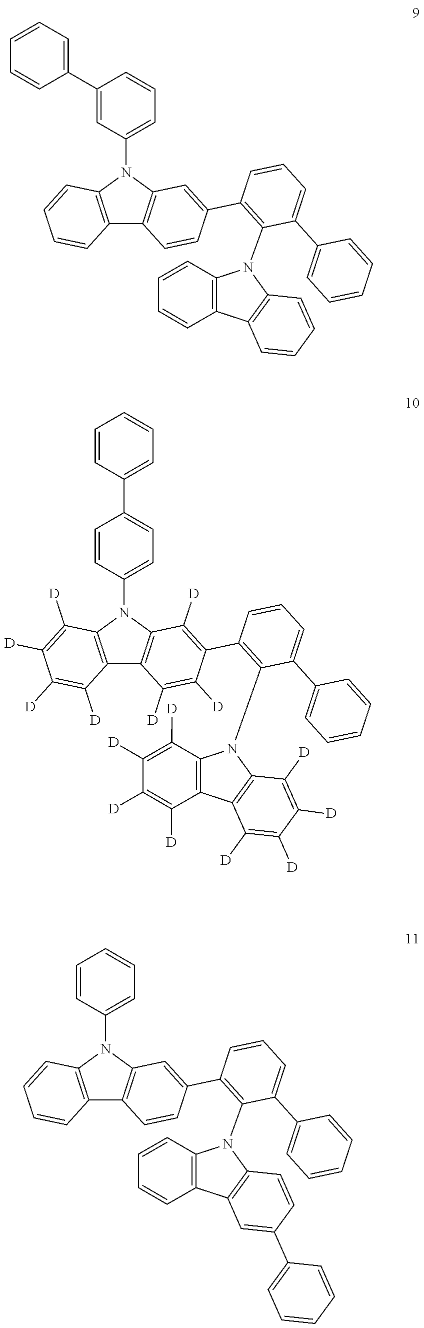 [SMILES: c1ccc(-c2cccc(-n3c4ccccc4c4ccc(-c5cccc(-c6ccccc6)c5-n5c6ccccc6c6ccccc65)cc43)c2)cc1 ; [2H]c1c([2H])c([2H])c2c(c1[2H])c1c([2H])c([2H])c(-c3cccc(-c4ccccc4)c3-n3c4c([2H])c([2H])c([2H])c([2H])c4c4c([2H])c([2H])c([2H])c([2H])c43)c([2H])c1n2-c1ccc(-c2ccccc2)cc1 ; c1ccc(-c2ccc3c(c2)c2ccccc2n3-c2c(-c3ccccc3)cccc2-c2ccc3c4ccccc4n(-c4ccccc4)c3c2)cc1]

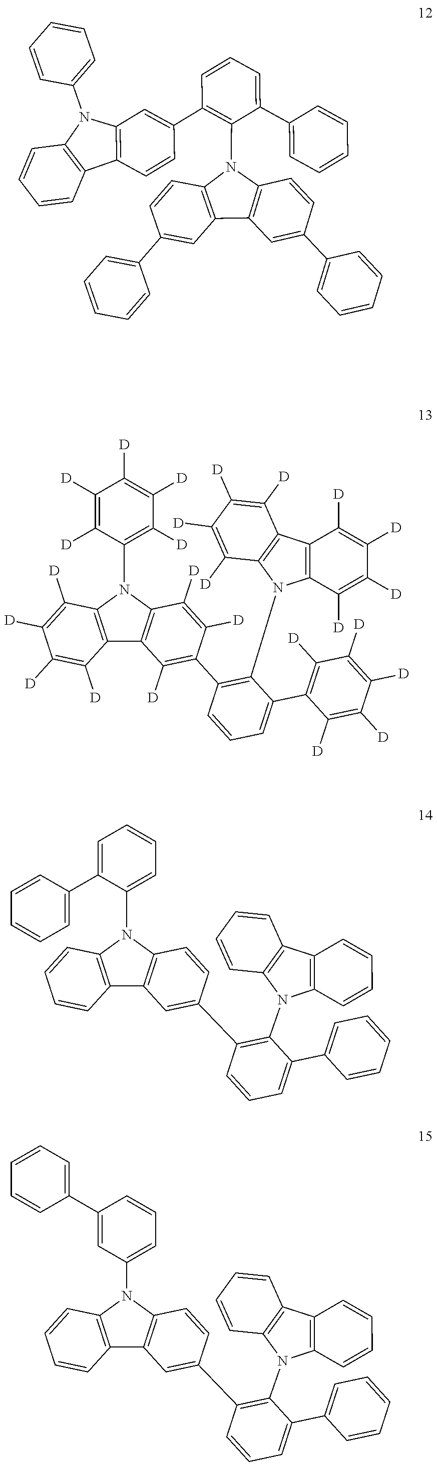 [SMILES: c1ccc(-c2ccc3c(c2)c2cc(-c4ccccc4)ccc2n3-c2c(-c3ccccc3)cccc2-c2ccc3c4ccccc4n(-c4ccccc4)c3c2)cc1 ; [2H]c1c([2H])c([2H])c(-c2cccc(-c3c([2H])c([2H])c4c(c3[2H])c3c([2H])c([2H])c([2H])c([2H])c3n4-c3c([2H])c([2H])c([2H])c([2H])c3[2H])c2-n2c3c([2H])c([2H])c([2H])c([2H])c3c3c([2H])c([2H])c([2H])c([2H])c32)c([2H])c1[2H] ; c1ccc(-c2ccccc2-n2c3ccccc3c3cc(-c4cccc(-c5ccccc5)c4-n4c5ccccc5c5ccccc54)ccc32)cc1 ; c1ccc(-c2cccc(-n3c4ccccc4c4cc(-c5cccc(-c6ccccc6)c5-n5c6ccccc6c6ccccc65)ccc43)c2)cc1]

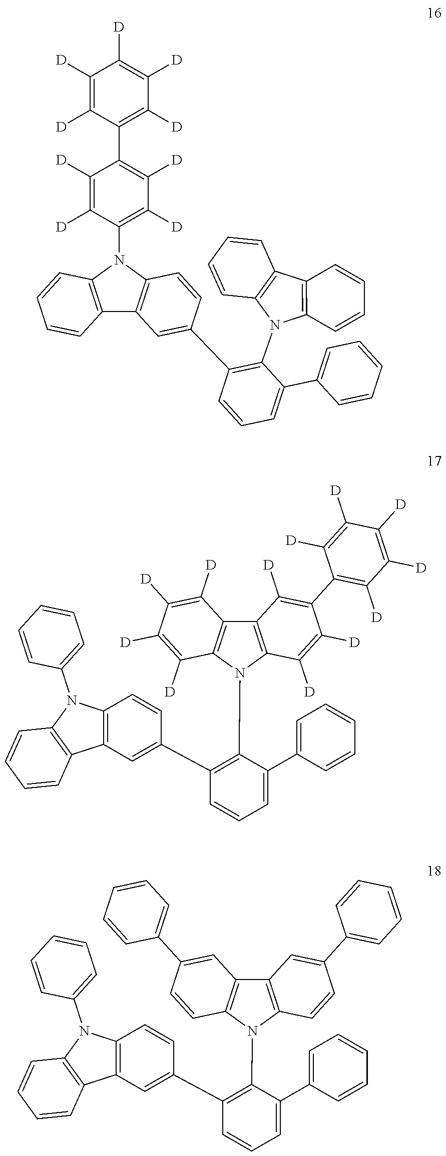 [SMILES: [2H]c1c([2H])c([2H])c(-c2c([2H])c([2H])c(-n3c4ccccc4c4cc(-c5cccc(-c6ccccc6)c5-n5c6ccccc6c6ccccc65)ccc43)c([2H])c2[2H])c([2H])c1[2H] ; [2H]c1c([2H])c([2H])c(-c2c([2H])c([2H])c3c(c2[2H])c2c([2H])c([2H])c([2H])c([2H])c2n3-c2c(-c3ccccc3)cccc2-c2ccc3c(c2)c2ccccc2n3-c2ccccc2)c([2H])c1[2H] ; c1ccc(-c2ccc3c(c2)c2cc(-c4ccccc4)ccc2n3-c2c(-c3ccccc3)cccc2-c2ccc3c(c2)c2ccccc2n3-c2ccccc2)cc1]

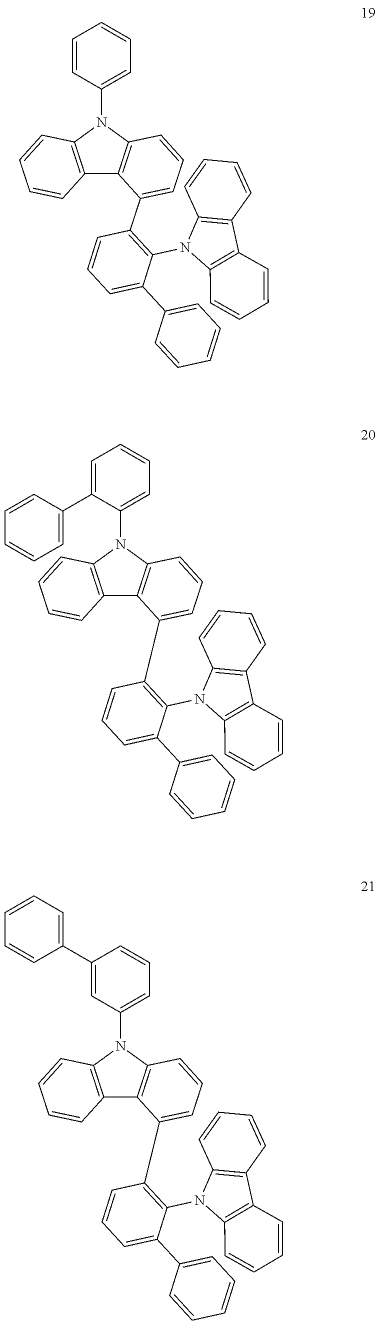 [SMILES: c1ccc(-c2cccc(-c3cccc4c3c3ccccc3n4-c3ccccc3)c2-n2c3ccccc3c3ccccc32)cc1 ; c1ccc(-c2ccccc2-n2c3ccccc3c3c(-c4cccc(-c5ccccc5)c4-n4c5ccccc5c5ccccc54)cccc32)cc1 ; c1ccc(-c2cccc(-n3c4ccccc4c4c(-c5cccc(-c6ccccc6)c5-n5c6ccccc6c6ccccc65)cccc43)c2)cc1]

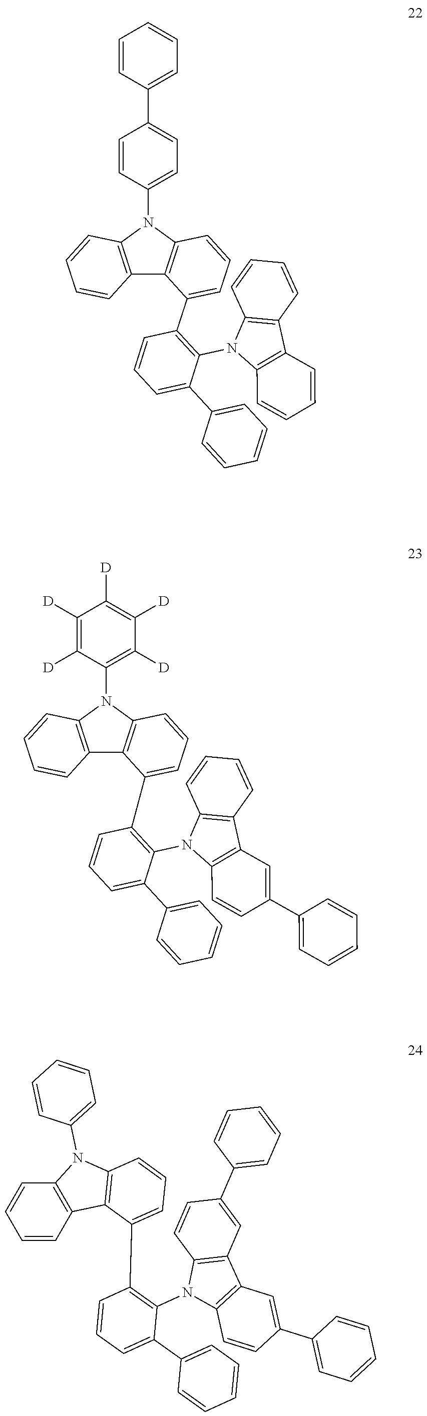 [SMILES: c1ccc(-c2ccc(-n3c4ccccc4c4c(-c5cccc(-c6ccccc6)c5-n5c6ccccc6c6ccccc65)cccc43)cc2)cc1 ; [2H]c1c([2H])c([2H])c(-n2c3ccccc3c3c(-c4cccc(-c5ccccc5)c4-n4c5ccccc5c5cc(-c6ccccc6)ccc54)cccc32)c([2H])c1[2H] ; c1ccc(-c2ccc3c(c2)c2cc(-c4ccccc4)ccc2n3-c2c(-c3ccccc3)cccc2-c2cccc3c2c2ccccc2n3-c2ccccc2)cc1]

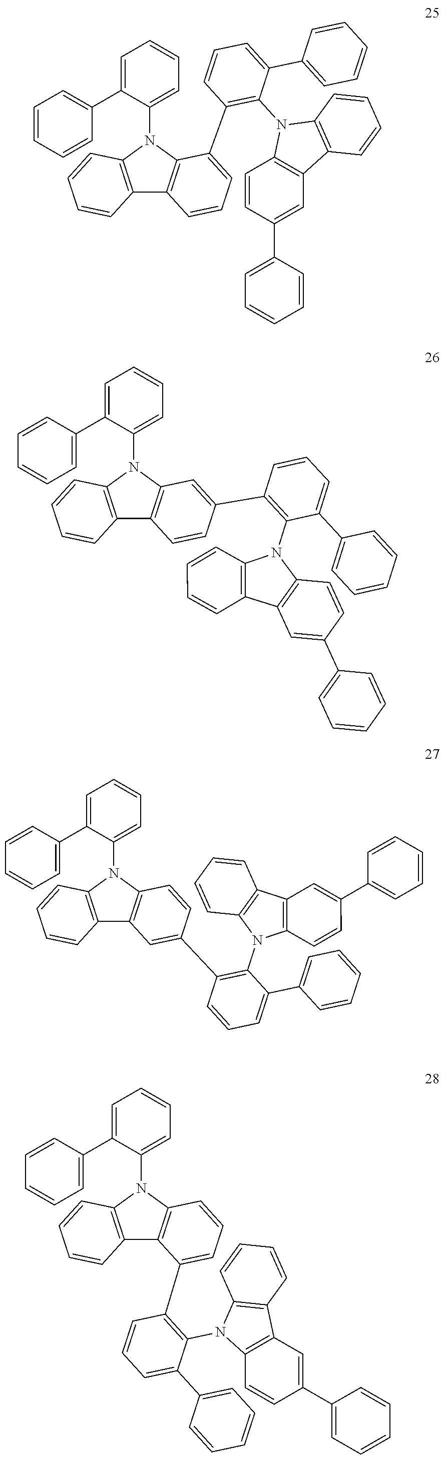 [SMILES: c1ccc(-c2ccc3c(c2)c2ccccc2n3-c2c(-c3ccccc3)cccc2-c2cccc3c4ccccc4n(-c4ccccc4-c4ccccc4)c23)cc1 ; c1ccc(-c2ccc3c(c2)c2ccccc2n3-c2c(-c3ccccc3)cccc2-c2ccc3c4ccccc4n(-c4ccccc4-c4ccccc4)c3c2)cc1 ; c1ccc(-c2ccc3c(c2)c2ccccc2n3-c2c(-c3ccccc3)cccc2-c2ccc3c(c2)c2ccccc2n3-c2ccccc2-c2ccccc2)cc1 ; c1ccc(-c2ccc3c(c2)c2ccccc2n3-c2c(-c3ccccc3)cccc2-c2cccc3c2c2ccccc2n3-c2ccccc2-c2ccccc2)cc1]

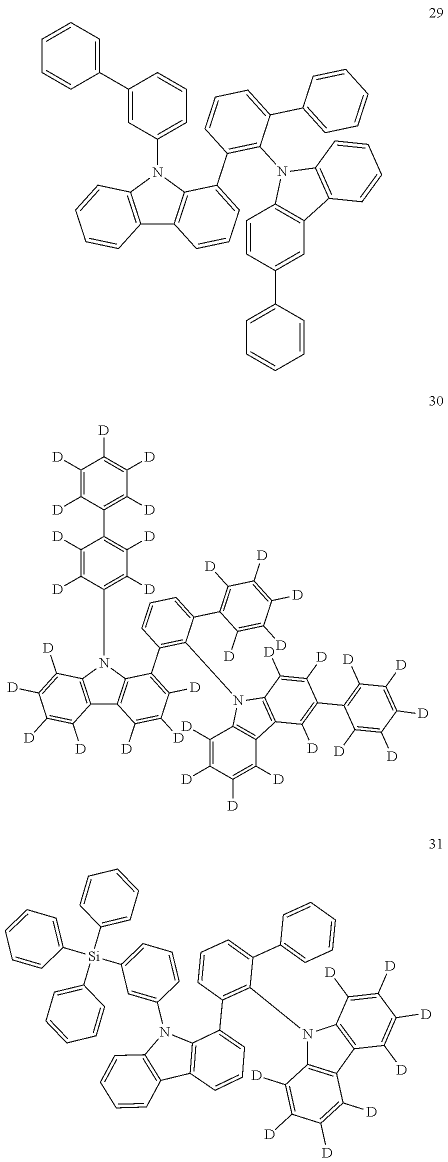

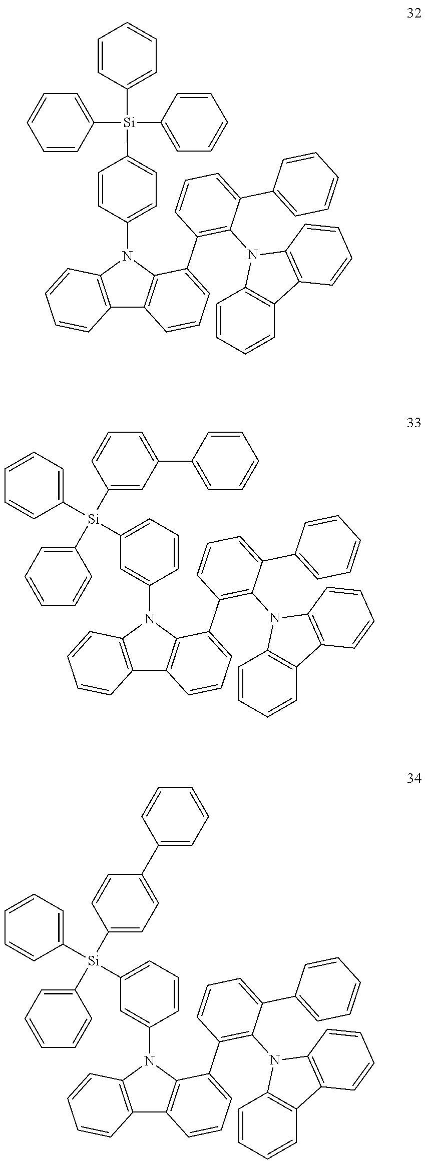 [SMILES: c1ccc(-c2cccc(-c3cccc4c5ccccc5n(-c5ccc([Si](c6ccccc6)(c6ccccc6)c6ccccc6)cc5)c34)c2-n2c3ccccc3c3ccccc32)cc1 ; c1ccc(-c2cccc([Si](c3ccccc3)(c3ccccc3)c3cccc(-n4c5ccccc5c5cccc(-c6cccc(-c7ccccc7)c6-n6c7ccccc7c7ccccc76)c54)c3)c2)cc1 ; c1ccc(-c2ccc([Si](c3ccccc3)(c3ccccc3)c3cccc(-n4c5ccccc5c5cccc(-c6cccc(-c7ccccc7)c6-n6c7ccccc7c7ccccc76)c54)c3)cc2)cc1]

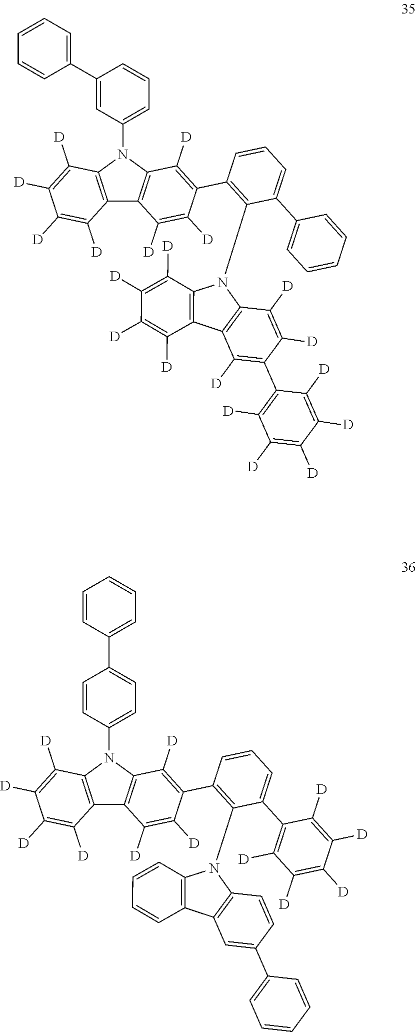 [SMILES: [2H]c1c([2H])c([2H])c(-c2c([2H])c([2H])c3c(c2[2H])c2c([2H])c([2H])c([2H])c([2H])c2n3-c2c(-c3ccccc3)cccc2-c2c([2H])c([2H])c3c4c([2H])c([2H])c([2H])c([2H])c4n(-c4cccc(-c5ccccc5)c4)c3c2[2H])c([2H])c1[2H] ; [2H]c1c([2H])c([2H])c(-c2cccc(-c3c([2H])c([2H])c4c5c([2H])c([2H])c([2H])c([2H])c5n(-c5ccc(-c6ccccc6)cc5)c4c3[2H])c2-n2c3ccccc3c3cc(-c4ccccc4)ccc32)c([2H])c1[2H]]

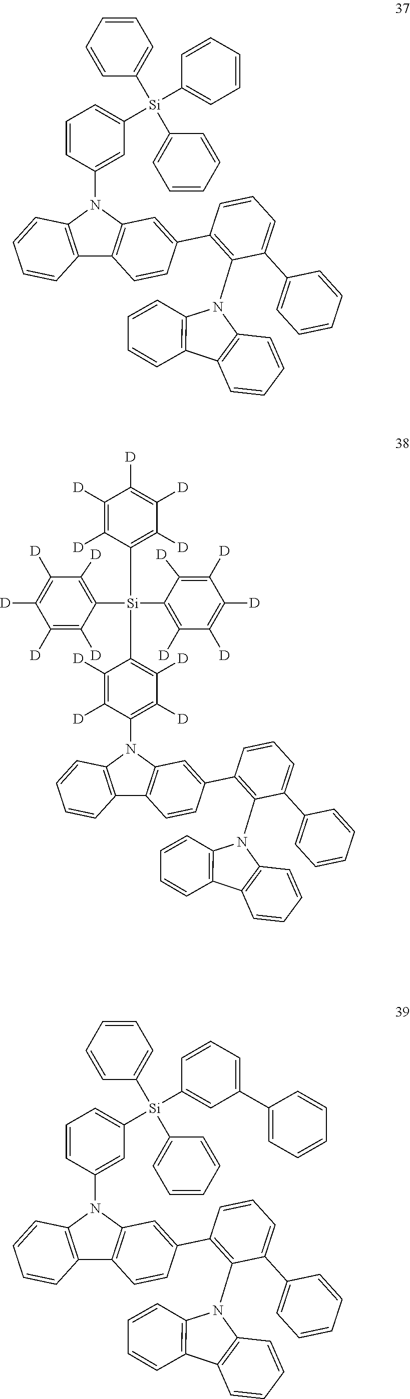 [SMILES: c1ccc(-c2cccc(-c3ccc4c5ccccc5n(-c5cccc([Si](c6ccccc6)(c6ccccc6)c6ccccc6)c5)c4c3)c2-n2c3ccccc3c3ccccc32)cc1 ; [2H]c1c([2H])c([2H])c([Si](c2c([2H])c([2H])c([2H])c([2H])c2[2H])(c2c([2H])c([2H])c([2H])c([2H])c2[2H])c2c([2H])c([2H])c(-n3c4ccccc4c4ccc(-c5cccc(-c6ccccc6)c5-n5c6ccccc6c6ccccc65)cc43)c([2H])c2[2H])c([2H])c1[2H] ; c1ccc(-c2cccc([Si](c3ccccc3)(c3ccccc3)c3cccc(-n4c5ccccc5c5ccc(-c6cccc(-c7ccccc7)c6-n6c7ccccc7c7ccccc76)cc54)c3)c2)cc1]

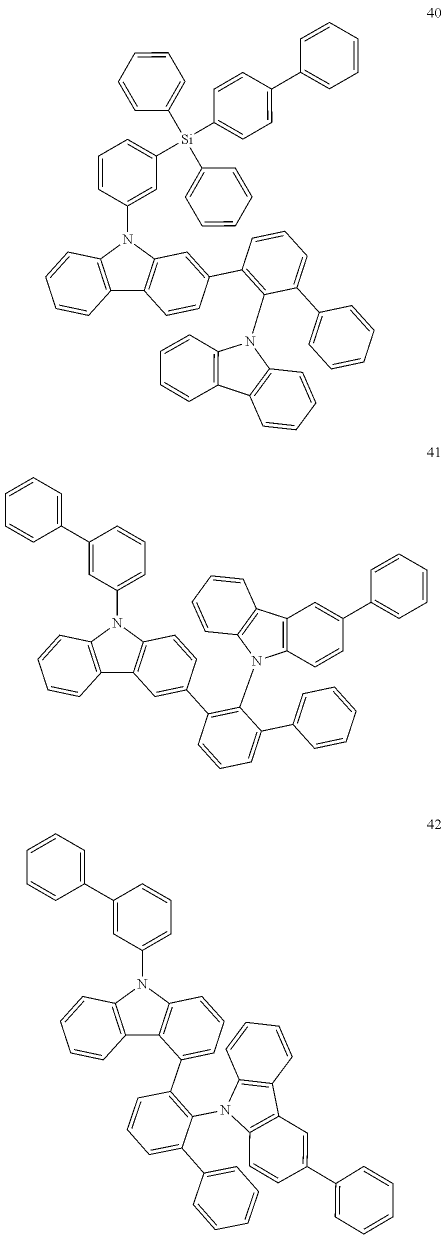 [SMILES: c1ccc(-c2ccc([Si](c3ccccc3)(c3ccccc3)c3cccc(-n4c5ccccc5c5ccc(-c6cccc(-c7ccccc7)c6-n6c7ccccc7c7ccccc76)cc54)c3)cc2)cc1 ; c1ccc(-c2cccc(-n3c4ccccc4c4cc(-c5cccc(-c6ccccc6)c5-n5c6ccccc6c6cc(-c7ccccc7)ccc65)ccc43)c2)cc1 ; c1ccc(-c2cccc(-n3c4ccccc4c4c(-c5cccc(-c6ccccc6)c5-n5c6ccccc6c6cc(-c7ccccc7)ccc65)cccc43)c2)cc1]

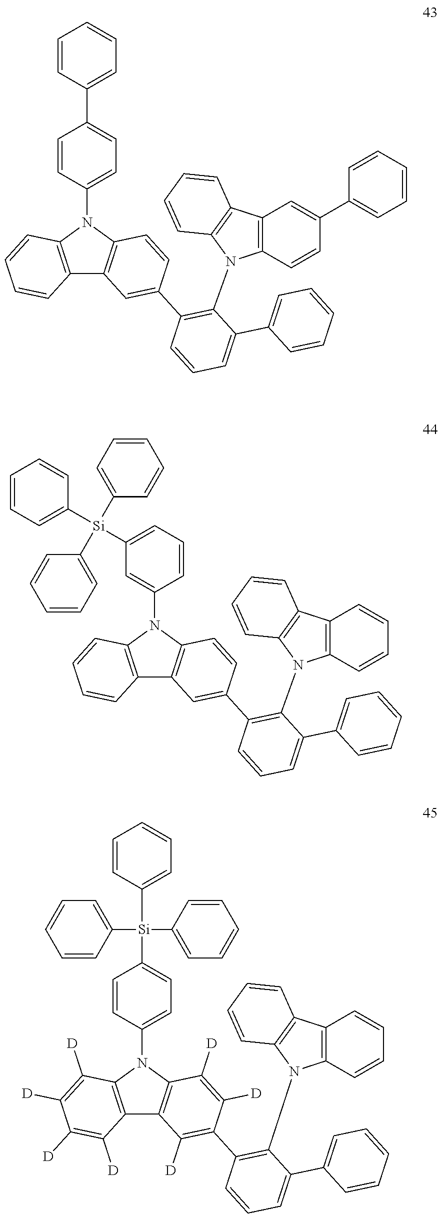 [SMILES: c1ccc(-c2ccc(-n3c4ccccc4c4cc(-c5cccc(-c6ccccc6)c5-n5c6ccccc6c6cc(-c7ccccc7)ccc65)ccc43)cc2)cc1 ; c1ccc(-c2cccc(-c3ccc4c(c3)c3ccccc3n4-c3cccc([Si](c4ccccc4)(c4ccccc4)c4ccccc4)c3)c2-n2c3ccccc3c3ccccc32)cc1 ; [2H]c1c([2H])c([2H])c2c(c1[2H])c1c([2H])c(-c3cccc(-c4ccccc4)c3-n3c4ccccc4c4ccccc43)c([2H])c([2H])c1n2-c1ccc([Si](c2ccccc2)(c2ccccc2)c2ccccc2)cc1]

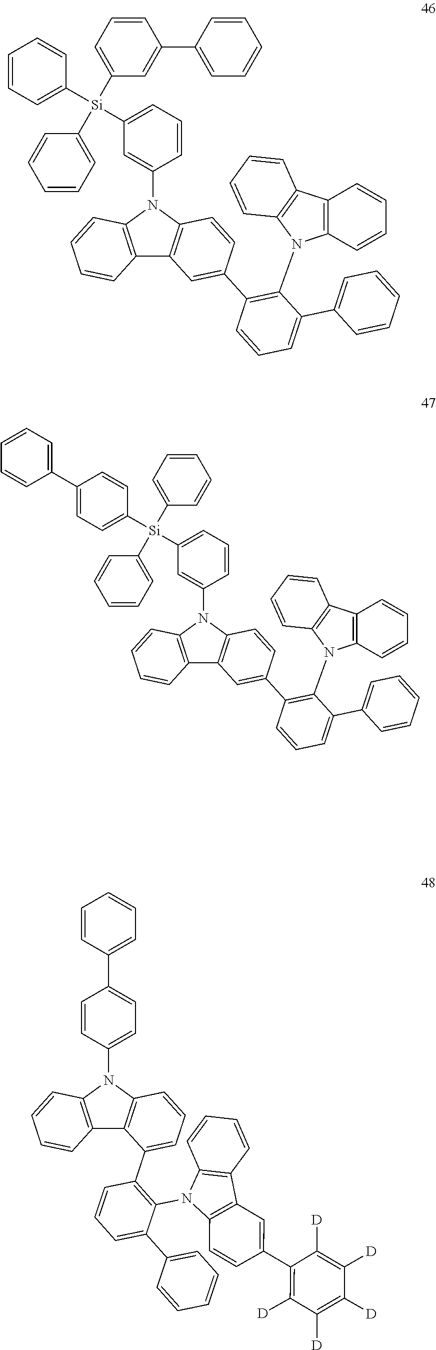 [SMILES: c1ccc(-c2cccc([Si](c3ccccc3)(c3ccccc3)c3cccc(-n4c5ccccc5c5cc(-c6cccc(-c7ccccc7)c6-n6c7ccccc7c7ccccc76)ccc54)c3)c2)cc1 ; c1ccc(-c2ccc([Si](c3ccccc3)(c3ccccc3)c3cccc(-n4c5ccccc5c5cc(-c6cccc(-c7ccccc7)c6-n6c7ccccc7c7ccccc76)ccc54)c3)cc2)cc1 ; [2H]c1c([2H])c([2H])c(-c2ccc3c(c2)c2ccccc2n3-c2c(-c3ccccc3)cccc2-c2cccc3c2c2ccccc2n3-c2ccc(-c3ccccc3)cc2)c([2H])c1[2H]]

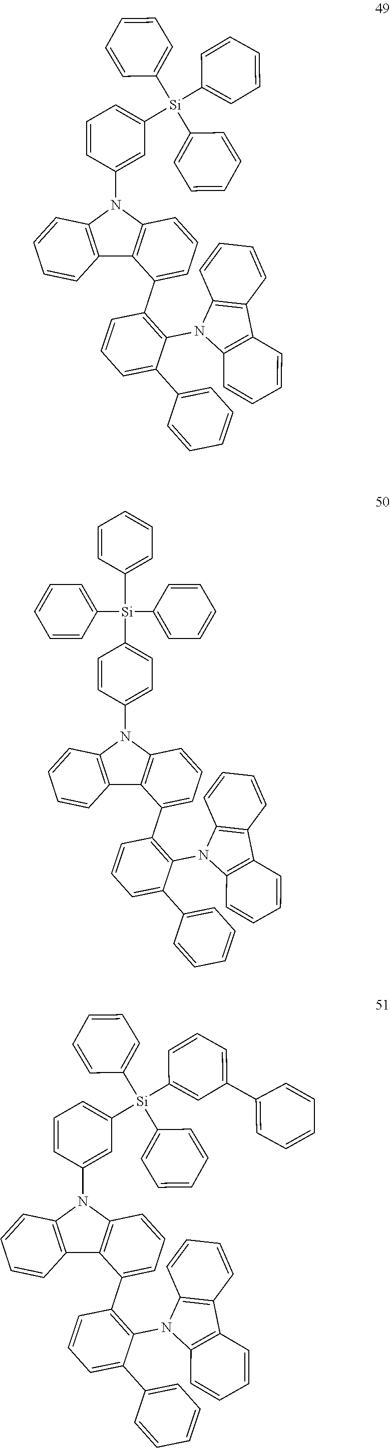 [SMILES: c1ccc(-c2cccc(-c3cccc4c3c3ccccc3n4-c3cccc([Si](c4ccccc4)(c4ccccc4)c4ccccc4)c3)c2-n2c3ccccc3c3ccccc32)cc1 ; c1ccc(-c2cccc(-c3cccc4c3c3ccccc3n4-c3ccc([Si](c4ccccc4)(c4ccccc4)c4ccccc4)cc3)c2-n2c3ccccc3c3ccccc32)cc1 ; c1ccc(-c2cccc([Si](c3ccccc3)(c3ccccc3)c3cccc(-n4c5ccccc5c5c(-c6cccc(-c7ccccc7)c6-n6c7ccccc7c7ccccc76)cccc54)c3)c2)cc1]

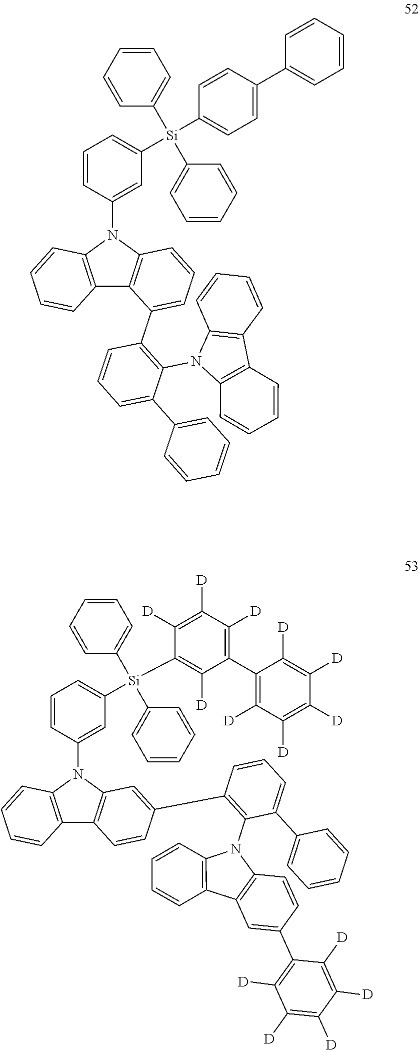 [SMILES: c1ccc(-c2ccc([Si](c3ccccc3)(c3ccccc3)c3cccc(-n4c5ccccc5c5c(-c6cccc(-c7ccccc7)c6-n6c7ccccc7c7ccccc76)cccc54)c3)cc2)cc1 ; [2H]c1c([2H])c([2H])c(-c2ccc3c(c2)c2ccccc2n3-c2c(-c3ccccc3)cccc2-c2ccc3c4ccccc4n(-c4cccc([Si](c5ccccc5)(c5ccccc5)c5c([2H])c([2H])c([2H])c(-c6c([2H])c([2H])c([2H])c([2H])c6[2H])c5[2H])c4)c3c2)c([2H])c1[2H]]

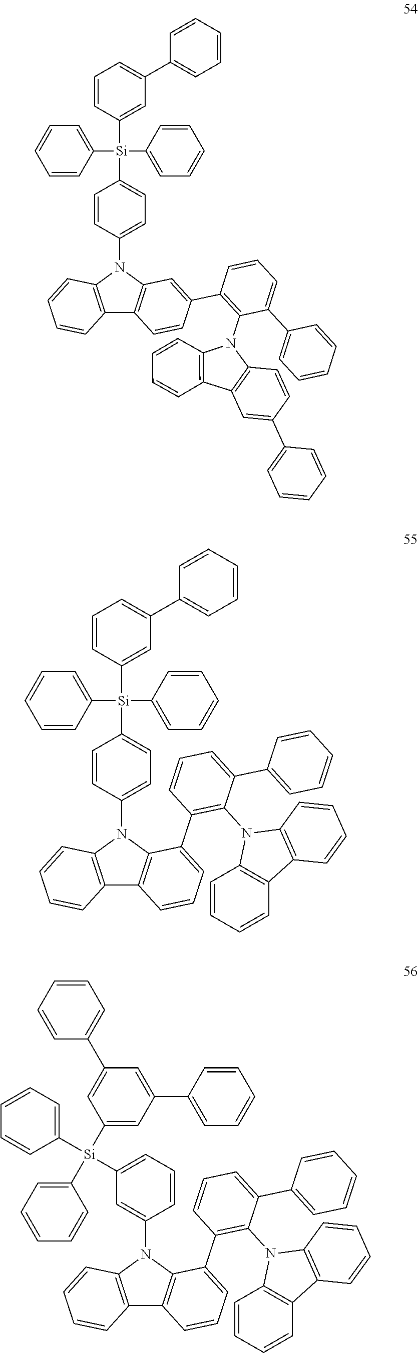 [SMILES: c1ccc(-c2cccc([Si](c3ccccc3)(c3ccccc3)c3ccc(-n4c5ccccc5c5ccc(-c6cccc(-c7ccccc7)c6-n6c7ccccc7c7cc(-c8ccccc8)ccc76)cc54)cc3)c2)cc1 ; c1ccc(-c2cccc([Si](c3ccccc3)(c3ccccc3)c3ccc(-n4c5ccccc5c5cccc(-c6cccc(-c7ccccc7)c6-n6c7ccccc7c7ccccc76)c54)cc3)c2)cc1 ; c1ccc(-c2cc(-c3ccccc3)cc([Si](c3ccccc3)(c3ccccc3)c3cccc(-n4c5ccccc5c5cccc(-c6cccc(-c7ccccc7)c6-n6c7ccccc7c7ccccc76)c54)c3)c2)cc1]

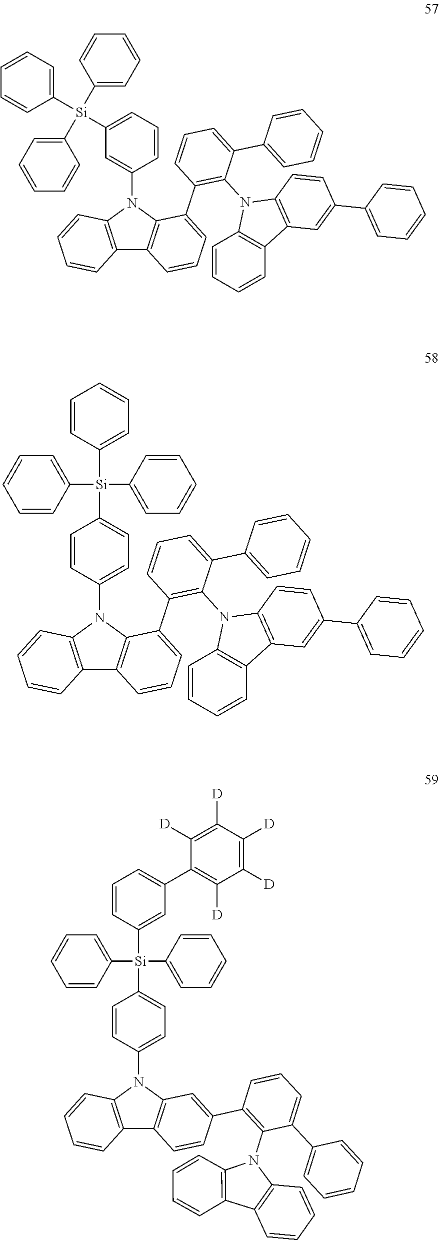 [SMILES: c1ccc(-c2ccc3c(c2)c2ccccc2n3-c2c(-c3ccccc3)cccc2-c2cccc3c4ccccc4n(-c4cccc([Si](c5ccccc5)(c5ccccc5)c5ccccc5)c4)c23)cc1 ; c1ccc(-c2ccc3c(c2)c2ccccc2n3-c2c(-c3ccccc3)cccc2-c2cccc3c4ccccc4n(-c4ccc([Si](c5ccccc5)(c5ccccc5)c5ccccc5)cc4)c23)cc1 ; [2H]c1c([2H])c([2H])c(-c2cccc([Si](c3ccccc3)(c3ccccc3)c3ccc(-n4c5ccccc5c5ccc(-c6cccc(-c7ccccc7)c6-n6c7ccccc7c7ccccc76)cc54)cc3)c2)c([2H])c1[2H]]

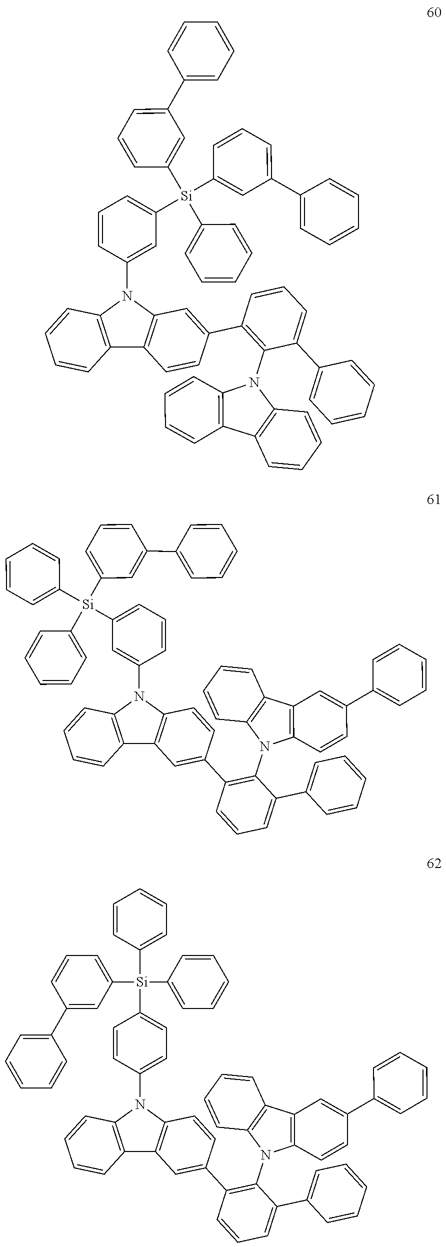 [SMILES: c1ccc(-c2cccc([Si](c3ccccc3)(c3cccc(-c4ccccc4)c3)c3cccc(-n4c5ccccc5c5ccc(-c6cccc(-c7ccccc7)c6-n6c7ccccc7c7ccccc76)cc54)c3)c2)cc1 ; c1ccc(-c2cccc([Si](c3ccccc3)(c3ccccc3)c3cccc(-n4c5ccccc5c5cc(-c6cccc(-c7ccccc7)c6-n6c7ccccc7c7cc(-c8ccccc8)ccc76)ccc54)c3)c2)cc1 ; c1ccc(-c2cccc([Si](c3ccccc3)(c3ccccc3)c3ccc(-n4c5ccccc5c5cc(-c6cccc(-c7ccccc7)c6-n6c7ccccc7c7cc(-c8ccccc8)ccc76)ccc54)cc3)c2)cc1]

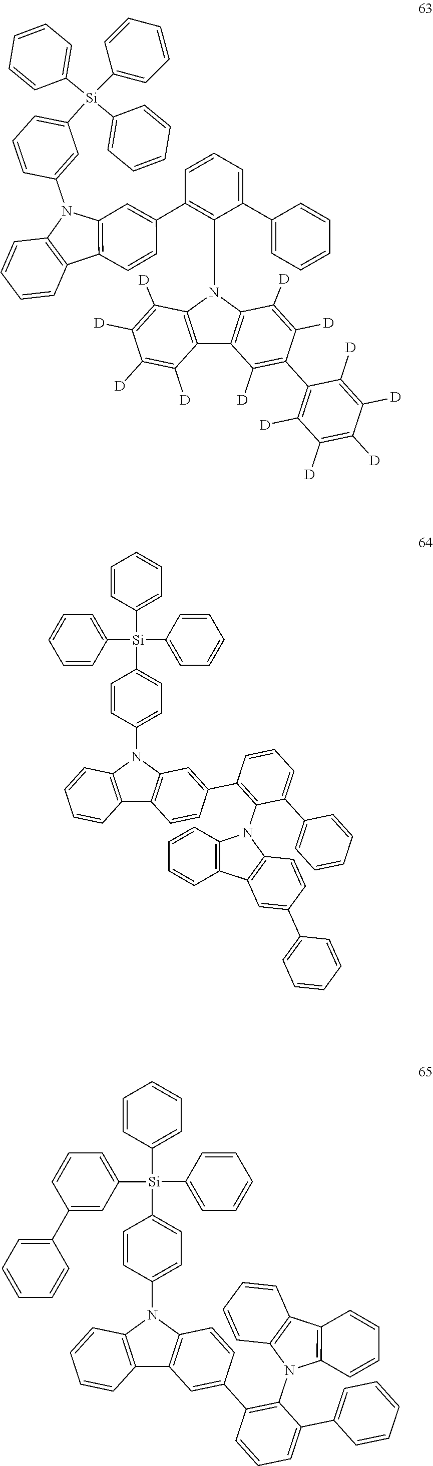 [SMILES: [2H]c1c([2H])c([2H])c(-c2c([2H])c([2H])c3c(c2[2H])c2c([2H])c([2H])c([2H])c([2H])c2n3-c2c(-c3ccccc3)cccc2-c2ccc3c4ccccc4n(-c4cccc([Si](c5ccccc5)(c5ccccc5)c5ccccc5)c4)c3c2)c([2H])c1[2H] ; c1ccc(-c2ccc3c(c2)c2ccccc2n3-c2c(-c3ccccc3)cccc2-c2ccc3c4ccccc4n(-c4ccc([Si](c5ccccc5)(c5ccccc5)c5ccccc5)cc4)c3c2)cc1 ; c1ccc(-c2cccc([Si](c3ccccc3)(c3ccccc3)c3ccc(-n4c5ccccc5c5cc(-c6cccc(-c7ccccc7)c6-n6c7ccccc7c7ccccc76)ccc54)cc3)c2)cc1]

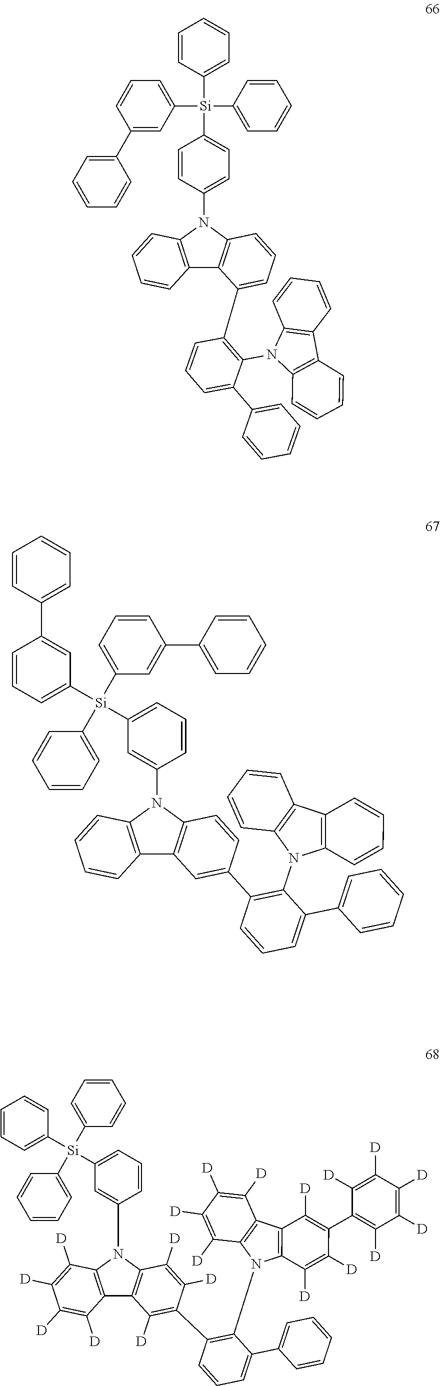 [SMILES: c1ccc(-c2cccc([Si](c3ccccc3)(c3ccccc3)c3ccc(-n4c5ccccc5c5c(-c6cccc(-c7ccccc7)c6-n6c7ccccc7c7ccccc76)cccc54)cc3)c2)cc1 ; c1ccc(-c2cccc([Si](c3ccccc3)(c3cccc(-c4ccccc4)c3)c3cccc(-n4c5ccccc5c5cc(-c6cccc(-c7ccccc7)c6-n6c7ccccc7c7ccccc76)ccc54)c3)c2)cc1 ; [2H]c1c([2H])c([2H])c(-c2c([2H])c([2H])c3c(c2[2H])c2c([2H])c([2H])c([2H])c([2H])c2n3-c2c(-c3ccccc3)cccc2-c2c([2H])c([2H])c3c(c2[2H])c2c([2H])c([2H])c([2H])c([2H])c2n3-c2cccc([Si](c3ccccc3)(c3ccccc3)c3ccccc3)c2)c([2H])c1[2H]]

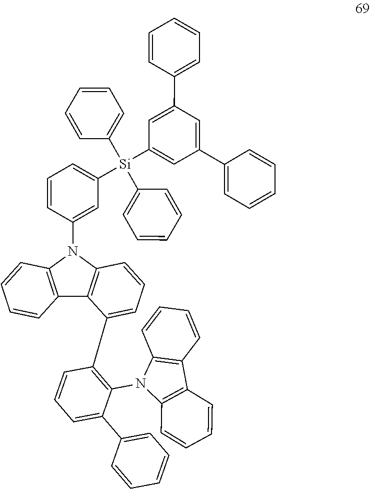 [SMILES: c1ccc(-c2cc(-c3ccccc3)cc([Si](c3ccccc3)(c3ccccc3)c3cccc(-n4c5ccccc5c5c(-c6cccc(-c7ccccc7)c6-n6c7ccccc7c7ccccc76)cccc54)c3)c2)cc1]

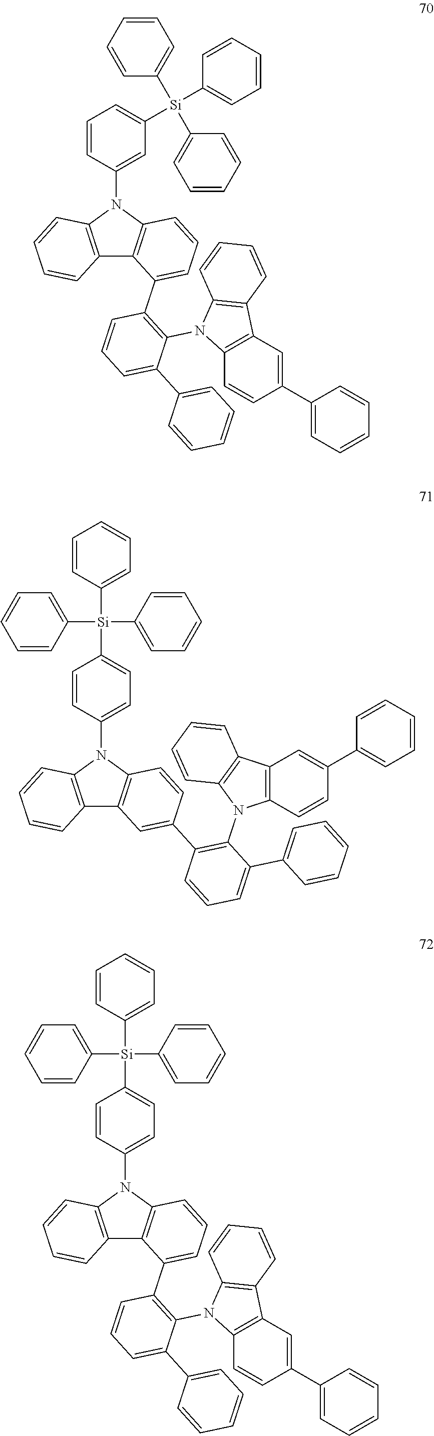 [SMILES: c1ccc(-c2ccc3c(c2)c2ccccc2n3-c2c(-c3ccccc3)cccc2-c2cccc3c2c2ccccc2n3-c2cccc([Si](c3ccccc3)(c3ccccc3)c3ccccc3)c2)cc1 ; c1ccc(-c2ccc3c(c2)c2ccccc2n3-c2c(-c3ccccc3)cccc2-c2ccc3c(c2)c2ccccc2n3-c2ccc([Si](c3ccccc3)(c3ccccc3)c3ccccc3)cc2)cc1 ; c1ccc(-c2ccc3c(c2)c2ccccc2n3-c2c(-c3ccccc3)cccc2-c2cccc3c2c2ccccc2n3-c2ccc([Si](c3ccccc3)(c3ccccc3)c3ccccc3)cc2)cc1]

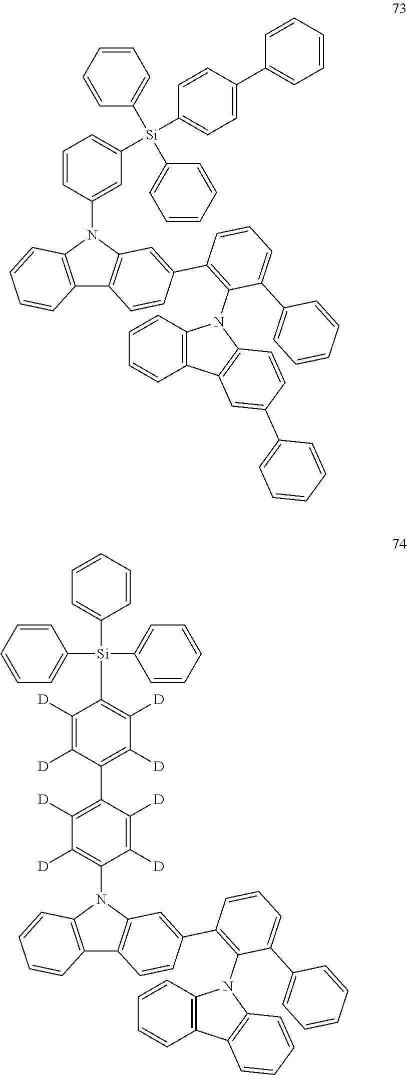 [SMILES: c1ccc(-c2ccc([Si](c3ccccc3)(c3ccccc3)c3cccc(-n4c5ccccc5c5ccc(-c6cccc(-c7ccccc7)c6-n6c7ccccc7c7cc(-c8ccccc8)ccc76)cc54)c3)cc2)cc1 ; [2H]c1c([2H])c(-n2c3ccccc3c3ccc(-c4cccc(-c5ccccc5)c4-n4c5ccccc5c5ccccc54)cc32)c([2H])c([2H])c1-c1c([2H])c([2H])c([Si](c2ccccc2)(c2ccccc2)c2ccccc2)c([2H])c1[2H]]

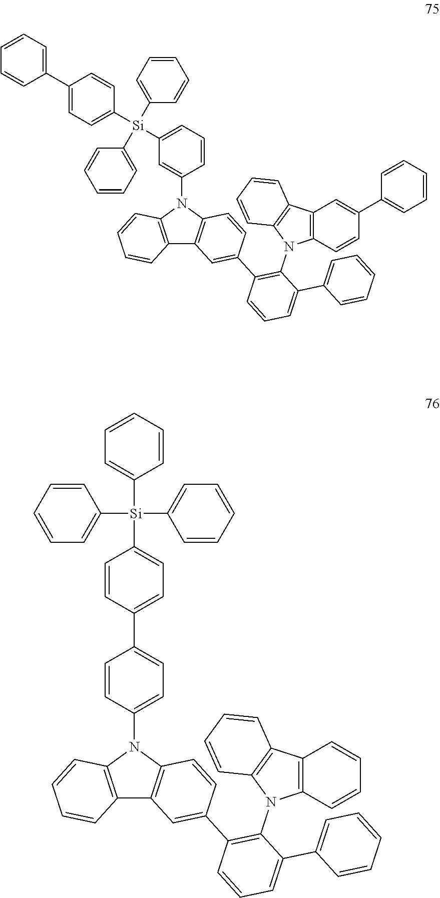 [SMILES: c1ccc(-c2ccc([Si](c3ccccc3)(c3ccccc3)c3cccc(-n4c5ccccc5c5cc(-c6cccc(-c7ccccc7)c6-n6c7ccccc7c7cc(-c8ccccc8)ccc76)ccc54)c3)cc2)cc1 ; c1ccc(-c2cccc(-c3ccc4c(c3)c3ccccc3n4-c3ccc(-c4ccc([Si](c5ccccc5)(c5ccccc5)c5ccccc5)cc4)cc3)c2-n2c3ccccc3c3ccccc32)cc1]

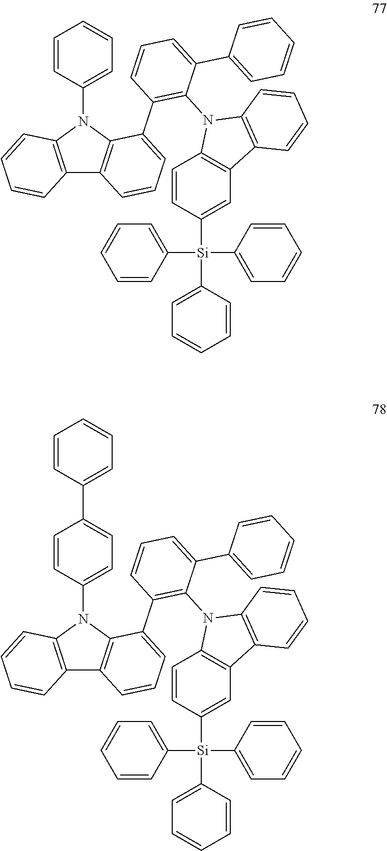 [SMILES: c1ccc(-c2cccc(-c3cccc4c5ccccc5n(-c5ccccc5)c34)c2-n2c3ccccc3c3cc([Si](c4ccccc4)(c4ccccc4)c4ccccc4)ccc32)cc1 ; c1ccc(-c2ccc(-n3c4ccccc4c4cccc(-c5cccc(-c6ccccc6)c5-n5c6ccccc6c6cc([Si](c7ccccc7)(c7ccccc7)c7ccccc7)ccc65)c43)cc2)cc1]

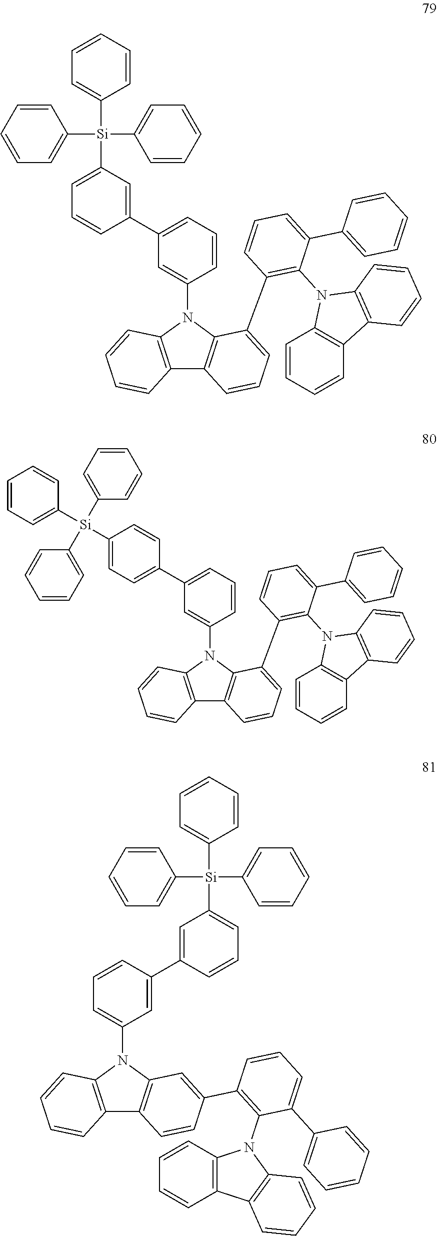 [SMILES: c1ccc(-c2cccc(-c3cccc4c5ccccc5n(-c5cccc(-c6cccc([Si](c7ccccc7)(c7ccccc7)c7ccccc7)c6)c5)c34)c2-n2c3ccccc3c3ccccc32)cc1 ; c1ccc(-c2cccc(-c3cccc4c5ccccc5n(-c5cccc(-c6ccc([Si](c7ccccc7)(c7ccccc7)c7ccccc7)cc6)c5)c34)c2-n2c3ccccc3c3ccccc32)cc1 ; c1ccc(-c2cccc(-c3ccc4c5ccccc5n(-c5cccc(-c6cccc([Si](c7ccccc7)(c7ccccc7)c7ccccc7)c6)c5)c4c3)c2-n2c3ccccc3c3ccccc32)cc1]

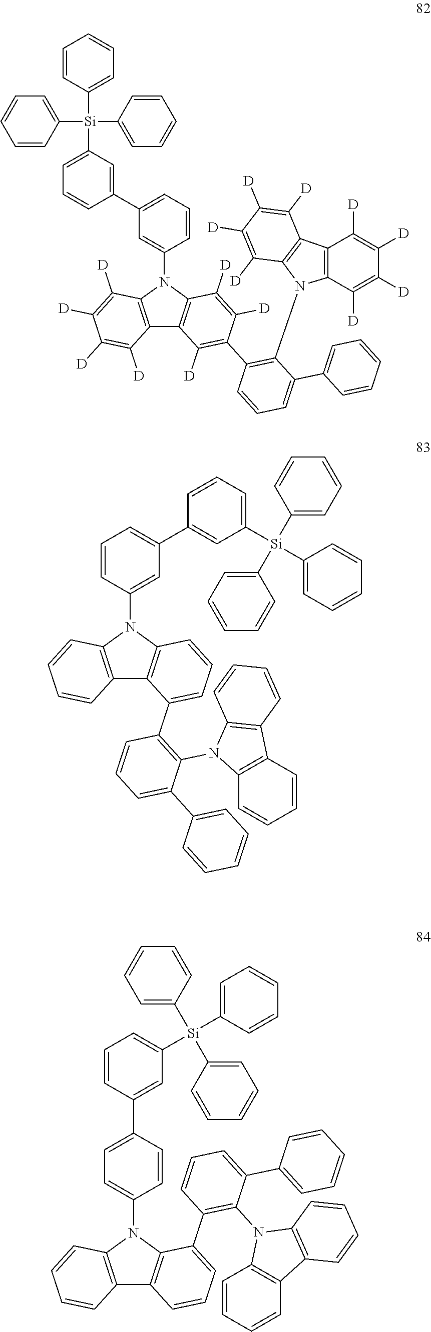 [SMILES: [2H]c1c([2H])c([2H])c2c(c1[2H])c1c([2H])c(-c3cccc(-c4ccccc4)c3-n3c4c([2H])c([2H])c([2H])c([2H])c4c4c([2H])c([2H])c([2H])c([2H])c43)c([2H])c([2H])c1n2-c1cccc(-c2cccc([Si](c3ccccc3)(c3ccccc3)c3ccccc3)c2)c1 ; c1ccc(-c2cccc(-c3cccc4c3c3ccccc3n4-c3cccc(-c4cccc([Si](c5ccccc5)(c5ccccc5)c5ccccc5)c4)c3)c2-n2c3ccccc3c3ccccc32)cc1 ; c1ccc(-c2cccc(-c3cccc4c5ccccc5n(-c5ccc(-c6cccc([Si](c7ccccc7)(c7ccccc7)c7ccccc7)c6)cc5)c34)c2-n2c3ccccc3c3ccccc32)cc1]

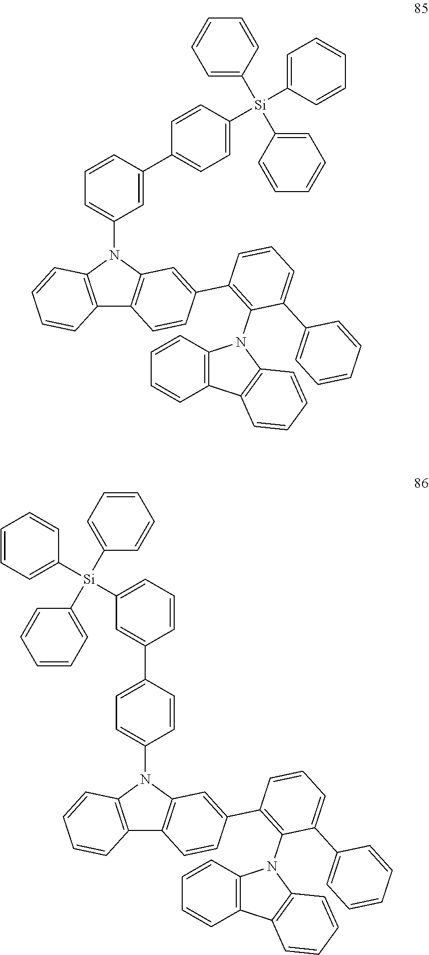 [SMILES: c1ccc(-c2cccc(-c3ccc4c5ccccc5n(-c5cccc(-c6ccc([Si](c7ccccc7)(c7ccccc7)c7ccccc7)cc6)c5)c4c3)c2-n2c3ccccc3c3ccccc32)cc1 ; c1ccc(-c2cccc(-c3ccc4c5ccccc5n(-c5ccc(-c6cccc([Si](c7ccccc7)(c7ccccc7)c7ccccc7)c6)cc5)c4c3)c2-n2c3ccccc3c3ccccc32)cc1]

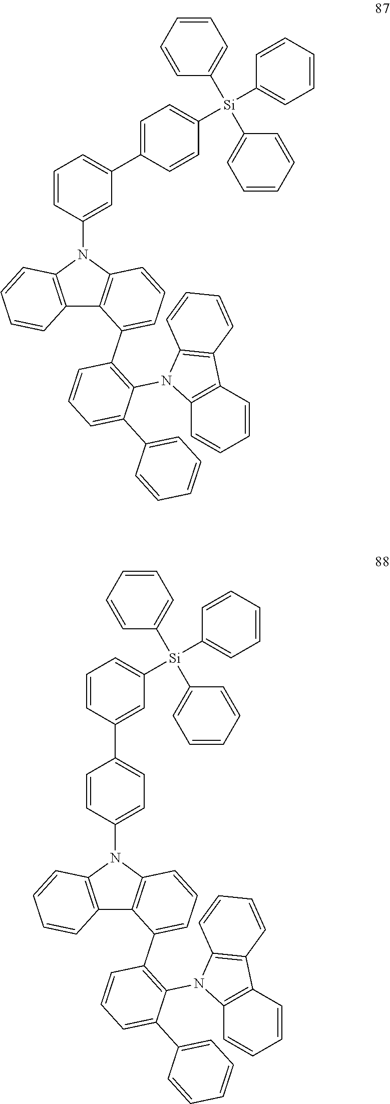 [SMILES: c1ccc(-c2cccc(-c3cccc4c3c3ccccc3n4-c3cccc(-c4ccc([Si](c5ccccc5)(c5ccccc5)c5ccccc5)cc4)c3)c2-n2c3ccccc3c3ccccc32)cc1 ; c1ccc(-c2cccc(-c3cccc4c3c3ccccc3n4-c3ccc(-c4cccc([Si](c5ccccc5)(c5ccccc5)c5ccccc5)c4)cc3)c2-n2c3ccccc3c3ccccc32)cc1]

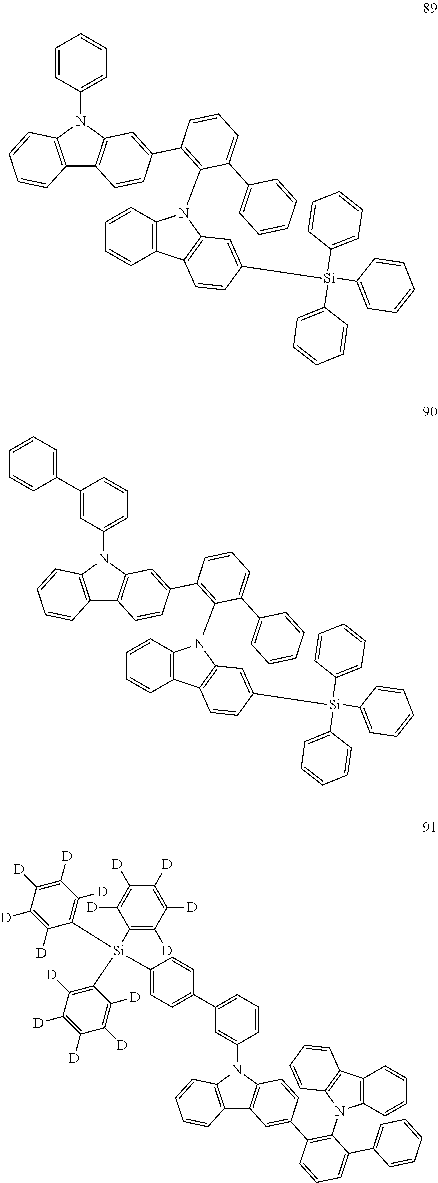 [SMILES: c1ccc(-c2cccc(-c3ccc4c5ccccc5n(-c5ccccc5)c4c3)c2-n2c3ccccc3c3ccc([Si](c4ccccc4)(c4ccccc4)c4ccccc4)cc32)cc1 ; c1ccc(-c2cccc(-n3c4ccccc4c4ccc(-c5cccc(-c6ccccc6)c5-n5c6ccccc6c6ccc([Si](c7ccccc7)(c7ccccc7)c7ccccc7)cc65)cc43)c2)cc1 ; [2H]c1c([2H])c([2H])c([Si](c2ccc(-c3cccc(-n4c5ccccc5c5cc(-c6cccc(-c7ccccc7)c6-n6c7ccccc7c7ccccc76)ccc54)c3)cc2)(c2c([2H])c([2H])c([2H])c([2H])c2[2H])c2c([2H])c([2H])c([2H])c([2H])c2[2H])c([2H])c1[2H]]

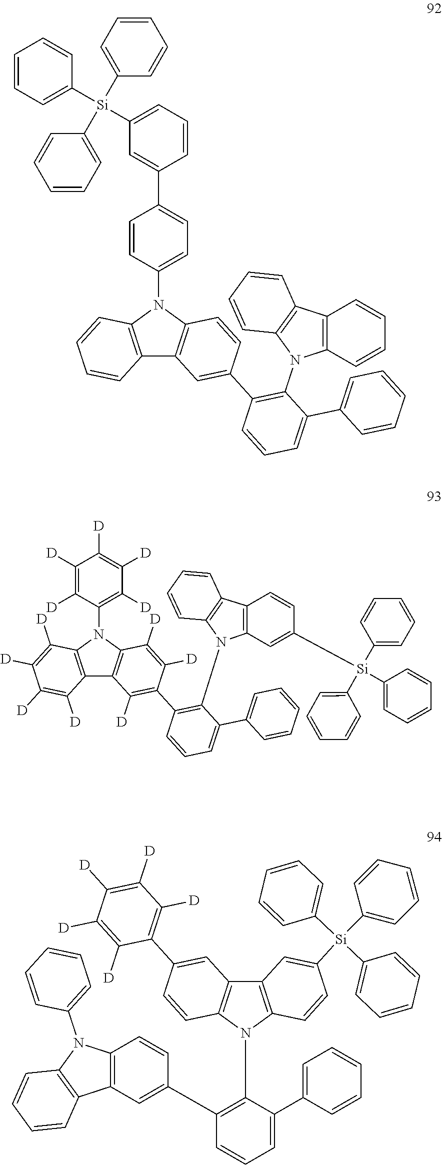 [SMILES: c1ccc(-c2cccc(-c3ccc4c(c3)c3ccccc3n4-c3ccc(-c4cccc([Si](c5ccccc5)(c5ccccc5)c5ccccc5)c4)cc3)c2-n2c3ccccc3c3ccccc32)cc1 ; [2H]c1c([2H])c([2H])c(-n2c3c([2H])c([2H])c([2H])c([2H])c3c3c([2H])c(-c4cccc(-c5ccccc5)c4-n4c5ccccc5c5ccc([Si](c6ccccc6)(c6ccccc6)c6ccccc6)cc54)c([2H])c([2H])c32)c([2H])c1[2H] ; [2H]c1c([2H])c([2H])c(-c2ccc3c(c2)c2cc([Si](c4ccccc4)(c4ccccc4)c4ccccc4)ccc2n3-c2c(-c3ccccc3)cccc2-c2ccc3c(c2)c2ccccc2n3-c2ccccc2)c([2H])c1[2H]]

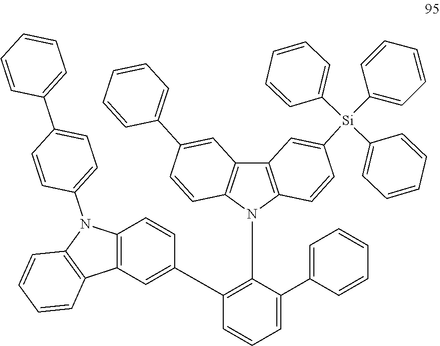 [SMILES: c1ccc(-c2ccc(-n3c4ccccc4c4cc(-c5cccc(-c6ccccc6)c5-n5c6ccc(-c7ccccc7)cc6c6cc([Si](c7ccccc7)(c7ccccc7)c7ccccc7)ccc65)ccc43)cc2)cc1]

In Compound Group 1, “D” refers to deuterium.

When the heterocyclic compound of one or more embodiments acts as the host of the light-emitting layer, a low driving voltage, a high emission efficiency, and blue light with high color purity may be accomplished. However, it is disclosed in a light-emitting diode in the art that two carbazoles are coupled in meta and para positions, when acting as a host, it results in lowering a Highest Occupied Molecular Orbital (HOMO) level and slowing injection of holes into a light-emitting layer, thereby being a main cause of increasing a driving voltage and reducing efficiency.

In one or more embodiments of the present disclosure, the heterocyclic compound has two carbazole groups (a first carbazole group and a second carbazole group) coupled in ortho positions around a central phenylene group. A steric hindrance is increased by additionally having a phenyl group in an ortho position as a substituent of the central phenylene group coupled with the two carbazoles. A conjugation length is decreased by further introduction of a phenyl group and/or a silyl group (Si) to the first carbazole group and the second carbazole group so that a relatively high triplet energy may be obtained to improve light-emitting efficiency of the light-emitting diode. In addition, having a high molecular weight may lead to high thermal stability.

For example, the heterocyclic compound of one or more embodiments may have a Highest Occupied Molecular Orbital (HOMO) level of −5.6 eV or higher and a triplet energy level of 2.8 eV or higher. According to one or more embodiments, the HOMO level and the triplet energy level may be a value calculated from the Density Functional Theory (DFT) calculation.

In addition, if (e.g., when) the heterocyclic compound of one or more embodiments includes deuterium, a heavy atom reduces a vibration mode, thereby decreasing the vibrational energy level. As a result, if (e.g., when) a hydrogen present in the heterocyclic compound is substituted with a deuterium, Van der Waals force between molecules may be decreased to prevent or reduce reduction of quantum efficiency that results from intermolecular vibration.

Therefore, the heterocyclic compound of one or more embodiments including the above structure and having a specific arrangement may suppress or reduce energy transfer with a dopant in the light-emitting layer. Accordingly, the interaction with the dopant is reduced so that blue emitting light with high color purity is provided while diffusion of a triplet exciton generated from the light-emitting layer to the hole transport region is suppressed or reduced, and the driving voltage and the light-emission efficiency of the light-emitting diode may be even further improved.

In one or more embodiments, the light-emitting layer EML may include a first compound represented by Formula 1. In one or more embodiments, the light-emitting layer EML may include a host and a dopant and include the first compound represented by Formula 1 as the host. The first compound represented by Formula 1 may be a host material of the light-emitting layer EML.

In one or more embodiments, the light-emitting layer may be to emit phosphorescence and/or a thermally activated delayed fluorescence.

In one or more embodiments, the light-emitting layer EML may include two or more hosts, a sensitizer, and a dopant. For example, the light-emitting layer EML may include a host for hole transport and a host for electron transport. The light-emitting layer EML may include a thermally activated delayed fluorescence (TADF) sensitizer or a phosphorescence sensitizer.

In one or more embodiments, the light-emitting layer EML may include a plurality of different hosts. In one or more embodiments, the host may include the first compound represented by Formula 1 and a second compound that is different from the first compound. In one or more embodiments, the host may include the first compound represented by Formula 1 and the second compound represented by Formula ETH-1. The first compound may be a host for hole transport and the second compound may be a host for electron transport. In one or more embodiments, the light-emitting layer EML may include the first compound and the second compound, and the first compound and the second compound may form an exciplex.

In the light-emitting layer EML of one or more embodiments, the host for hole transport and the host for electron transport may form an exciplex. Here, a triplet energy of the exciplex formed by the host for hole transport and the host for electron transport corresponds to a difference between a Lowest Unoccupied Molecular Orbital (LUMO) energy level of the host for electron transport and a Highest Occupied Molecular Orbital (HOMO) energy level of the host for hole transport.

In one or more embodiments, the light-emitting layer EML may include a host for hole transport represented by Formula HTH-1 in addition to the first compound.

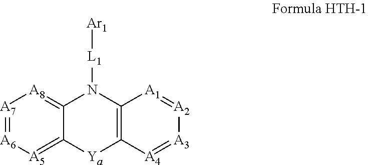

In Formula HTH-1, each of A₁ to A₈ may independently be N or CR₁.

For example, in one or more embodiments, all (e.g., each) of A₁ to A₈ may be CR₁, or at least one selected from among A₁ to A₈ may be N and the rest may be CR₁.

In Formula HTH-1, Yₐ may be a direct linkage, O, S, CR₂R₃, SiR₄R₅, NR₆, or BR₇. For example, it may refer to that two 6-membered rings (e.g., two benzene rings) coupled to the nitrogen atom of Formula HTH-1 may be connected via a direct linkage, O, S,

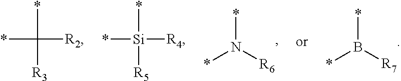

In Formula HTH-1, if (e.g., when) Yₐ is a direct linkage, the compound represented by Formula HTH-1 may include a carbazole moiety.

In Formula HTH-1, L₁ may be a direct linkage, a substituted or unsubstituted arylene group of 6 to 50 ring-forming carbons, or a substituted or unsubstituted heteroarylene group of 2 to 50 ring-forming carbons. For example, in one or more embodiments, L₁ may be a direct linkage, a substituted or unsubstituted phenylene group, a divalent carbazole group, or a divalent biphenyl group, but embodiments of the present disclosure are not limited thereto.

In Formula HTH-1, Ar₁ may be a substituted or unsubstituted aryl group of 6 to 30 ring-forming carbons or a substituted or unsubstituted heteroarylene group of 2 to 30 ring-forming carbons. For example, in one or more embodiments, Ar₁ may be a substituted or unsubstituted phenyl group, a biphenyl group, a carbazole group, a dibenzothiophene group, or a dibenzofuran group, but embodiments of the present disclosure are not limited thereto.

In Formula HTH-1, each of R₁ to R₇ may independently be hydrogen, deuterium, halogens, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbons, a substituted or unsubstituted alkenyl group of 2 to 20 carbons, a substituted or unsubstituted aryl group of 6 to 50 ring-forming carbons, or a substituted or unsubstituted heteroaryl group of 2 to 50 ring-forming carbons. In one or more embodiments, one or more selected from among R₁ to R₇ may bond to an adjacent group to form a ring. For example, in one or more embodiments, each of R₁ to R₇ may independently be hydrogen, deuterium, an unsubstituted methyl group, or an unsubstituted phenyl group.

In one or more embodiments, the light-emitting layer EML may include the second compound represented by Formula ETH-1. For example, the second compound may be used as a host for electron transport in the light-emitting layer EML.

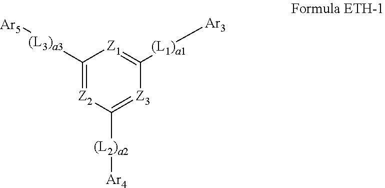

In Formula ETH-1, Z₁ may be N or CR₁₂, Z₂ may be N or CR₁₃, Z₃ may be N or CR₁₄, and at least one selected from among Z₁ to Z₃ may be N.

In Formula ETH-1, R₁₂ through R₁₄ may each independently be deuterium, hydrogen, halogens, a hydroxyl group, a cyano group, a nitro group, a substituted or unsubstituted alkyl group of 1 to 20 carbons, a substituted or unsubstituted alkenyl group of 2 to 20 carbons, a substituted or unsubstituted alkoxy group of 1 to 20 carbons, a substituted or unsubstituted alkynyl group of 2 to 20 carbons, a substituted or unsubstituted aryl group of 6 to 50 ring-forming carbons, or a substituted or unsubstituted heteroaryl group of 2 to 50 ring-forming carbons.

L₁ to L₃ may independently be a direct linkage, a substituted or unsubstituted arylene group of 6 to 30 ring-forming carbons, or a substituted or unsubstituted heteroarylene group of 2 to 30 ring-forming carbons. If (e.g., when) each of a1 to a3 may be an integer of 2 or greater, each of L₁ to L₃ may independently be a substituted or unsubstituted arylene group of 6 to 30 ring-forming carbons or a substituted or unsubstituted heteroarylene group of 2 to 30 ring-forming carbons.

Each of a1 to a3 may independently be an integer between 0 and 10, inclusive.

Each of Ar₃ to Ar₅ may independently be deuterium, hydrogen, a substituted or unsubstituted alkyl group of 1 to 20 carbons, a substituted or unsubstituted aryl group of 6 to 30 ring-forming carbons, or a substituted or unsubstituted heteroaryl group of 2 to 30 ring-forming carbons. For example, in one or more embodiments, Ar₃ to Ar₅ may be a substituted or unsubstituted phenyl group or a substituted or unsubstituted carbazole group.

In one or more embodiments, the host for electron transport represented by Formula ETH-1 in the light-emitting layer EML may be represented as 9,9′-(6-(3-(triphenylsilyl)phenyl)-1,3,5-triazine-2,4-diyl)bis(9H-carbazole) (SiTrzCz2) among the compounds shown in embodiments of manufactured light-emitting diodes of the present disclosure, but embodiments of the present disclosure are not limited thereto.

In one or more embodiments, the light-emitting layer EML may include a third compound in addition to the described first compound and second compound. The third compound may be a phosphorescence dopant. In one or more embodiments, the third compound may be a phosphorescence dopant configured to emit blue light, and the light-emitting layer EML may be to emit phosphoresce. For example, the light-emitting layer EML may be configured to emit phosphorescence. In one or more embodiments, the light-emitting layer EML may include an organic metal complex including a transition metal as a center atom and an organic ligand connected to the center transition metal atom, as the third compound.

In the light-emitting diode ED of one or more embodiments, the light-emitting layer EML may include a compound represented by Formula M-a as the third compound.

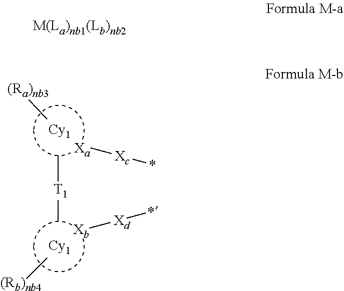

In Formula M-a and Formula M-b,
M may be a transition metal (e.g., Iridium (Ir), Platinum (Pt), Gold (Au), Titanium (Ti), Hafnium (Hf), Tantalum (Ta), Tungsten (W), Rhenium (Re), or Osmium (Os)),
Lₐ may be a ligand represented by Formula M-b,
nb1 may be 1, 2, or 3, and if (e.g., when) nb1 is 2 or greater, 2 or more Lₐ(s) may be the same or different, and
L_{b} may be an organic ligand such as halogens (e.g. Cl and/or F), a diketone ligand (e.g. acetylacetonate, 1,3-diphenyl-1,3-propanedionate, 2,2,6,6-tetramethyl-3,5-heptanedionate, and/or hexafluoroacetonate), or a carboxylic acid ligand (e.g. picolinate, dimethyl-3-pyrazolcarboxylate, and/or benzoate), but embodiments of the present disclosure are not limited thereto.
nb2 may be 0, 1, 2, 3, or 4,
if (e.g., when) nb2 is 2 or greater, 2 or more L_{b}(s) may be the same or different,
T₁ may be a direct linkage, *—O—*, *—S—*, *—N(Q₁)*—C(═O)—*, *C(Q₁)=C(Q₂)-*, *—C(Q₁)=*, *—C(Q₁)(Q₂)-*, or *—C(Q₁)-*,
each of Xₐ and X_{b} may independently be C or N,
each of X_{c} and X_{d} may independently be a chemical linkage (e.g. a coordination bond or a covalent bond), O, S, N(Q₃), B(Q₃), P(Q₃), C(Q₃)(Q₄), or Si(Q₃)(Q₄),
each of ring Cy₁ and ring Cy₂ may independently be selected from among a substituted or unsubstituted carbocyclic ring of 3 to 60 ring-forming carbons and a substituted or unsubstituted heterocyclic ring of 1 to 60 ring-forming carbons, and
each of Rₐ and R_{b} may independently be hydrogen, deuterium, halogens, a hydroxyl group, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbons, a substituted or substituted alkenyl group of 2 to 20 carbons, a substituted or unsubstituted aryl group of 6 to 60 ring-forming carbons, or a substituted or unsubstituted heteroaryl group of 2 to 60 ring-forming carbons.

Each of Q₁ to Q₄ may independently be hydrogen, deuterium, halogens, a hydroxyl group, a cyano group, a nitro group, a substituted or unsubstituted alkyl group of 1 to 30 carbons, a substituted or unsubstituted alkenyl group of 1 to 30 carbons, a substituted or unsubstituted alkynyl group of 2 to 30 carbons, a substituted or unsubstituted alkoxy group of 1 to 30 carbons, a substituted or unsubstituted aryl group of 6 to 60 ring-forming carbons, or a substituted or unsubstituted heteroaryl group of 2 to 60 ring-forming carbons.

Each of nb3 and nb4 may independently be an integer between 0 and 10, inclusive, and

in Formula M-b, if (e.g., when) nb1 is 2 or greater, 2 rings Cy among 2 or more Lₐ(s) may be optionally linked to each other via T₂, which is a linking group, and/or two rings Cy₂ may be optionally linked to each other via T₃, which is a linking group. T₂ and T₃ may each be the same as described with reference to T₁.

In Formula M-b, each of * and *′ may be a binding site to M of Formula M-a.

Compounds represented by Formula M-a and Formula M-b may be shown as PtON-TBBI among the compounds shown as an example of manufactured light-emitting diodes of the present disclosure, but embodiments of the present disclosure are not limited thereto. In one or more embodiments, the light-emitting layer EML may include a compound described below in addition to the compounds described above. In one or more embodiments, the light-emitting layer EML may include at least one of an anthracene derivative, a fluoranthene derivative, a chrysene derivative, a pyrene derivative, a dihydrobenzanthracene derivative, or a triphenylene derivative. For example, in one or more embodiments, the light-emitting layer EML may include an anthracene derivative and/or a pyrene derivative.

In one or more embodiments, the light-emitting layer EML may further include a compound represented by Formula EM-1.

The compound represented by Formula EM-1 may be used as a fluorescent host material.

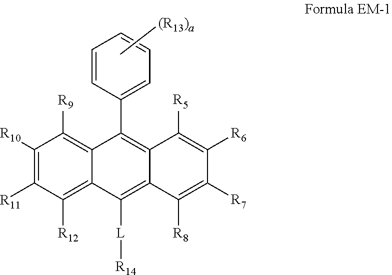

In Formula EM-1, L may be a direct linkage, a substituted or unsubstituted arylene group of 6 to 30 ring-forming carbons, or a substituted or unsubstituted heteroarylene group of 2 to 30 ring-forming carbons. Examples thereof may be a phenylene group, a biphenylene group, a terphenylene group, a naphthalene group, a phenanthrene group, a pyrene group, a spirofluorenylene group, a fluorenylene group, a dibenzofuranylene group, a dibenzothiophenylene group, or a carbazolylene group, but embodiments of the present disclosure may not be limited thereto.

In Formula EM-1, each of R₅ through R₁₄ may independently be hydrogen, deuterium, halogens, a substituted or unsubstituted oxy group, a substituted or unsubstituted thio group, a substituted or unsubstituted silyl group, a substituted or unsubstituted alkyl group of 1 to 30 carbons, a substituted or unsubstituted alkenyl group of 2 to 30 carbons, a substituted or unsubstituted aryl group of 6 to 30 ring-forming carbons, or a substituted or unsubstituted heteroaryl group of 2 to 30 ring-forming carbons, and/or bonded to an adjacent group to form a ring.

In Formula EM-1, a may be an integer between 0 and 5, inclusive.

The compound represented by Formula EM-1 may be any compound of (e.g., selected from among) Formulae E1 through E11, but embodiments of the present disclosure are not limited thereto.

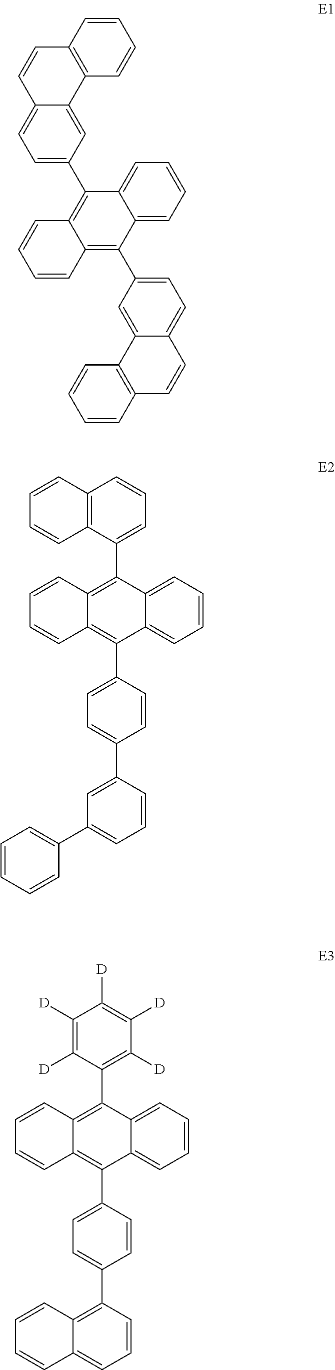

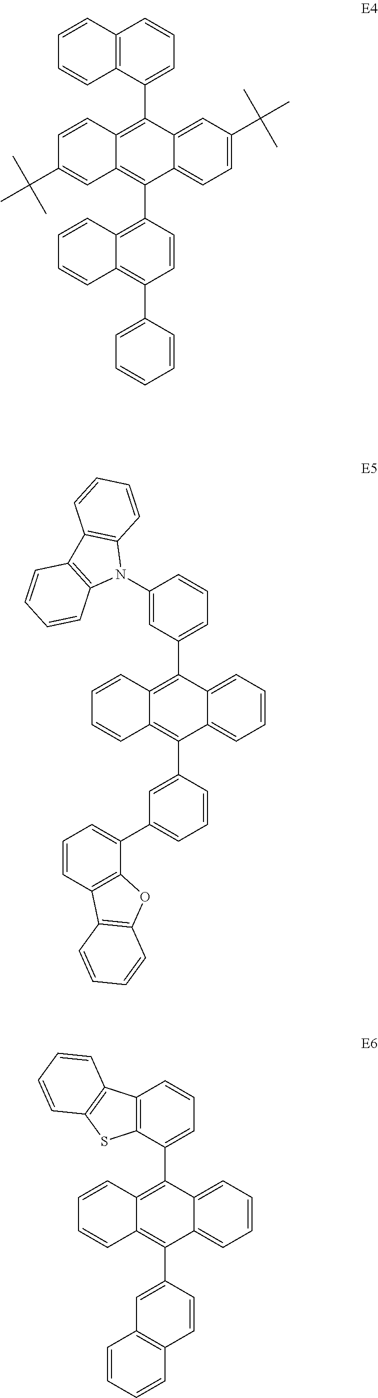

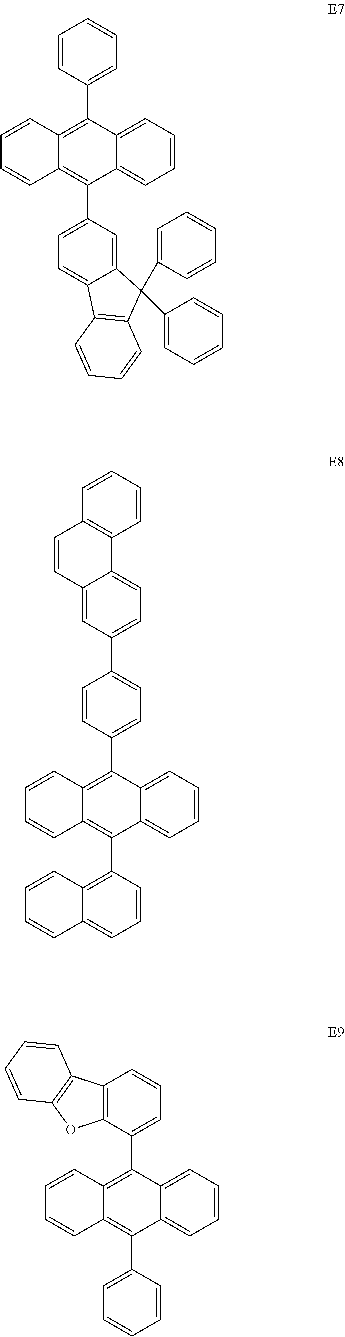

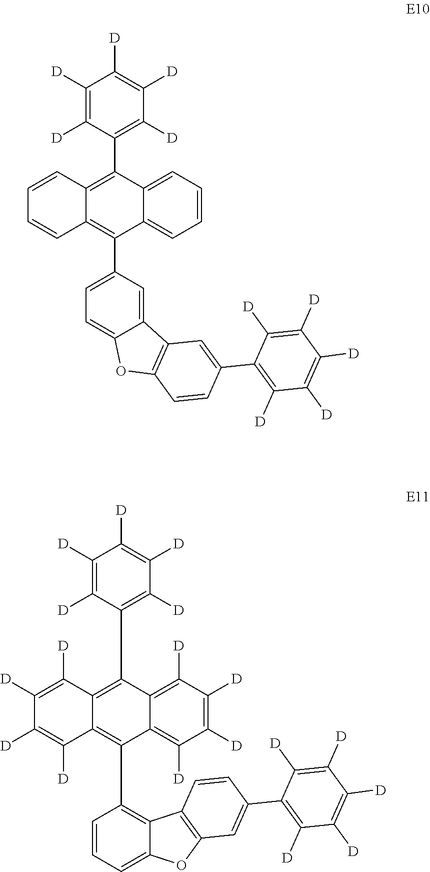 [SMILES: [2H]c1c([2H])c([2H])c(-c2ccc3oc4ccc(-c5c6ccccc6c(-c6c([2H])c([2H])c([2H])c([2H])c6[2H])c6ccccc56)cc4c3c2)c([2H])c1[2H] ; [2H]c1c([2H])c([2H])c(-c2ccc3c(c2)oc2cccc(-c4c5c([2H])c([2H])c([2H])c([2H])c5c(-c5c([2H])c([2H])c([2H])c([2H])c5[2H])c5c([2H])c([2H])c([2H])c([2H])c45)c23)c([2H])c1[2H]]

In one or more embodiments, the light emitting layer EML may further include a compound represented by Formula EM-2 or Formula EM-3. The compound represented by any formula selected from among Formula EM-2 and Formula EM-3 may be used as a phosphorescence host material.

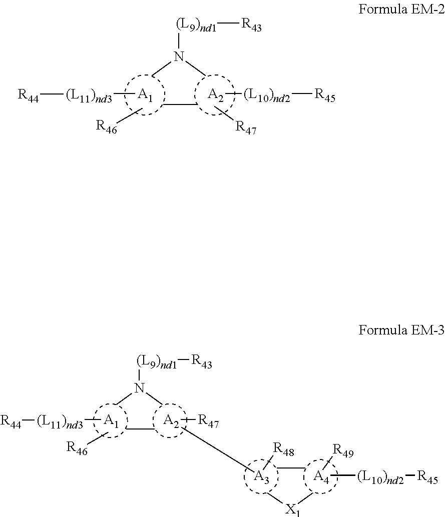

In Formula EM-2 and Formula EM-3, each of rings A₁ through A₄ may independently be a substituted or unsubstituted aryl group of 6 to 30 ring-forming carbons or a substituted or unsubstituted heteroaryl group of 2 to 30 ring-forming carbons. Non-limiting examples thereof may include a benzene group, a naphthalene group, a phenanthrene group, a fluoranthene group, a triphenylene group, a pyrene group, a pyridine group, a pyrimidine group, an indene group, a fluorene group, a spiro-bifluorene group, a benzofluorene group, a dibenzofluorene group, an indole group, a carbazole group, a benzocarbazole group, a dibenzocarbazole group, a furan group, a benzofuran group, a dibenzofuran group, a benzonaphthofuran group, a benzothiophene group, a dibenzothiophene group, a benzonaphthothiophene group, and a dinaphthothiophene group.

In Formula EM-2 and Formula EM-3, nd1 to nd3 may independently be 0, 1, or 2.

In Formula EM-2 and Formula EM-3, X₁ may be O, S, N-L₁₂-R₅₀, CR₅₁R₅₂, or SiR₅₃R₅₄.

In Formula EM-2 and Formula EM-3, each of L₉ through L₁₂ may independently be a direct linkage, a substituted or unsubstituted arylene group of 6 to 30 ring-forming carbons, or a substituted or unsubstituted heteroarylene group of 2 to 30 ring-forming carbons.

In Formula EM-2 and Formula EM-3, each of R₄₃ to R₄₉ and R₅₀ to R₅₄ may independently be hydrogen, deuterium, halogens, a substituted or unsubstituted amine group, a substituted or unsubstituted thio group, a substituted or unsubstituted oxy group, a substituted or unsubstituted alkyl group of 1 to 20 carbons, a substituted or unsubstituted alkenyl group of 2 to 20 carbons, a substituted or unsubstituted aryl group of 6 to 30 ring-forming carbons, or substituted or unsubstituted heteroaryl group of 2 to 30 ring-forming carbons.

In one or more embodiments, the light-emitting layer EML may further include a material generally suitable in the field as a host material.

For example, in one or more embodiments, the light emitting layer EML may include at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), Bis[2-(diphenylphosphino)phenyl]ether oxide (DPEPO), 4,4′-bis(N-carbazolyl)-1,1′-biphenyl), mCP (1,3-Bis(carbazol-9-yl)benzene (CBP), 2,8-Bis(diphenylphosphoryl)dibenzo[b,d]furan (PPF), 4,4′,4″-Tris(carbazol-9-yl)-triphenylamine (TCTA), or 1,3,5-tris(1-phenyl-1H-benzo[d]imidazol-2-yl)benzene (TPBi) as a host material. However, embodiments of the present disclosure are not limited thereto, for example, a host material, such as tris(8-hydroxyquinolinato)aluminum (Alq₃), 9,10-di(naphthalen-2-yl)anthracene (AND), 2-tert-butyl-9,10-di(naphth-2-yl)anthracene (TBADN), distyrylarylene (DSA), 4,4′-bis(9-carbazolyl)-2,2′-dimethylbiphenyl (CDBP), 2-Methyl-9,10-bis(naphthalen-2-yl)anthracene (MADN), Hexaphenyl cyclotriphosphazene (CP1), 1,4-Bis(triphenylsilyl)benzene (UGH2), Hexaphenylcyclotrisiloxane (DPSiO3), and/or Octaphenylcyclotetrasiloxane (DPSiO4), may be used.

In one or more embodiments, the light-emitting layer EML may include a compound represented by Formula F-a. The compound represented by Formula F-a may be a fluorescent dopant material or a delayed fluorescent material.

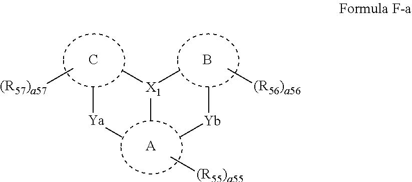

In Formula F-a, each of rings A through C may independently be a substituted or unsubstituted aromatic cyclic hydrocarbon of 6 to 60 ring-forming carbons or a substituted or unsubstituted aromatic heterocycle of 2 to 60 ring-forming carbons.

In Formula F-a, each of Yₐ and Y_{b} may independently be selected from among O, S, Se, CR₅₈R₅₉, NR₆₀, and SiR₆₁R₆₂.

In Formula F-a, X₁ may be any one selected from among B, P, and P═O. In one or more embodiments, in Formula F-a, X₁ may be a boron (B).

In Formula F-a, R₅₅ through R₆₂ may be the same or different, and each may independently be any one selected from among hydrogen, deuterium, a substituted or unsubstituted alkyl group of 1 to 30 carbons, a substituted or unsubstituted aryl group of 6 to 60 ring-forming carbons, a substituted or unsubstituted cycloalkyl group of 3 to 30 ring-forming carbons, a substituted or unsubstituted heteroaryl group of 2 to 60 ring-forming carbons, a substituted or unsubstituted alkoxy group of 1 to 30 carbons, a substituted or unsubstituted aryloxy group of 6 to 30 carbons, a substituted or unsubstituted arylthiol group of 6 to 30 carbons, a substituted or unsubstituted arylamine group of 5 to 30 carbons, a substituted or unsubstituted alkylsilyl group of 1 to 30 carbons, a substituted or unsubstituted arylsilyl group of 5 to 30 carbons, a nitro group, a cyano group, and halogens.

In Formula F-a, a55 through a57 may independently be an integer between 0 and 20, inclusive.

In one or more embodiments, the light-emitting layer EML may include one or more selected from among perylene and derivatives thereof (e.g., 2,5,8,11-Tetra-t-butylperylene (TBP)), pyrene and derivatives thereof (e.g., 1,1-dipyrene, 1,4-dipyrenylbenzene, and 1,4-Bis(N, N-Diphenylamino)pyrene), styryl derivatives (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (NBDAVBi)), and/or 4′-bis[2-(4-(N,N-diphenylamino)phenyl)vinyl]biphenyl (DPAVBi) as a dopant material.

In one or more embodiments, the light-emitting layer EML may further include a suitable phosphorescence dopant material. For example, a metal complex including iridium (Ir), platinum (Pt), osmium (Os), gold (Au), titanium (Ti), zirconium (Zr), hafnium (Hf), europium (Eu), terbium (Tb), or thulium (Tm) may be used. For example, iridium(III) bis(4,6-difluorophenylpyridinato-N,C2′)picolinate (FIrpic), Bis(2,4-difluorophenylpyridinato)-tetrakis(1-pyrazolyl)borate iridium(III) (Fir6), or platinum octaethyl porphyrin (PtOEP) may be used as a phosphorescence dopant. Nonetheless, embodiments of the present disclosure are not limited thereto.

In one or more embodiments, the light-emitting layer EML may be a quantum dot.

In one or more embodiments, a quantum dot may refer to a crystal of a semiconductor compound and may have selected color of emitted light based on the size of the crystal. Accordingly, the quantum dot may have one or more suitable colors of emitted light, such as blue, red, or green.

A diameter of the quantum dot may be, for example, in a range of 1 nanometer (nm) to 10 nm. In the present disclosure, when quantum dots or quantum dot particles are spherical, “diameter” indicates a particle diameter or an average particle diameter, and when the particles are non-spherical, the “diameter” indicates a major axis length or an average major axis length. The diameter of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter is referred to as D50. D50 refers to the average diameter of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

In addition, the quantum dot may be spherical nanoparticles, pyramidal nanoparticles, multi-arm nanoparticles, cubic nanoparticles, nanotubes, nanowires, nanofibers, nanoplates, and/or the like.

The quantum dot may be selected from among a Group III-VI compound, a Group II-VI compound, a Group III-V compound, a Group I-III-VI compound, a Group IV-VI compound, a Group IV element, a Group IV compound, and/or a (e.g., any suitable) combination thereof.

In the light-emitting diode ED of one or more embodiments illustrated in FIGS. 3 through 6, the electron functional layer may be provided on the light-emitting layer. The electron functional layer may include at least one of a hole blocking layer, an electron transport layer, or an electron injection layer, but embodiments of the present disclosure are not limited to what is illustrated in the drawings.

In the light-emitting diode ED of one or more embodiments illustrated in FIGS. 3 through 6, the electron functional layer EFL is provided on the light-emitting layer EML.

The electron functional layer EFL may include at least one of a hole blocking layer HBL, an electron transport layer ETL, or an electron injection layer EIL, but embodiments of the present disclosure are not limited to what is illustrated in the drawings. The electron functional layer EFL may have a single layer including (e.g., consisting of) a single material, a single layer including (e.g., consisting of) a plurality of different materials, or a multilayer structure having a plurality of layers including (e.g., consisting of) a plurality of different materials.

For example, in one or more embodiments, the electron functional layer EFL may have a single layer structure of an electron injection layer EIL or an electron transport layer ETL, or a single layer structure including (e.g., consisting of) an electron injection material and/or an electron transport material. In one or more embodiments, the electron functional layer EFL may have a single layer structure including (e.g., consisting of) a plurality of different materials, or a structure, in which constituting layers are sequentially stacked from the light-emitting layer EML, of an electron transport layer ETL/electron injection layer EIL or a hole blocking layer HBL/electron transport layer ETL/electron injection layer EIL, but embodiments of the present disclosure are not limited thereto. A thickness of the electron functional layer EFL may be, for example, from about 1000 Å to 1500 Å.

The electron functional layer EFL may be manufactured by utilizing a method selected from among vacuum deposition, spin coating, Langmuir-Blodgett (LB) casting, ink-jet printing, laser induced thermal imaging (LITI), and the like.

In one or more embodiments, the electron functional layer EFL may include a compound represented by Formula ET-1.

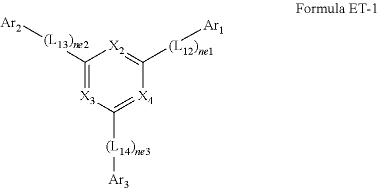

In Formula ET-1, each of Ar₁ to Ar₃ may independently be hydrogen, deuterium, a substituted or unsubstituted alkyl group of 1 to 20 carbons, a substituted or unsubstituted aryl group of 6 to 60 ring-forming carbons, or a substituted or unsubstituted heteroaryl group of 2 to 60 ring-forming carbons. Examples thereof may be a phenyl group, a naphthyl group, a biphenyl group, a phenanthrene group, a fluorene group, a spirofluorene group, a terphenyl group, a pyridine group, a carbazole group, and an isoquinoline group, but embodiments of the present disclosure are not limited thereto.

In Formula ET-1, at least one of X₂, X₃, or X₄ is N, and the rest are CR_{c}.

In Formula ET-1, R_{c} may be hydrogen, deuterium, halogens, a substituted or unsubstituted alkyl group of 1 to 20 carbons, a substituted or unsubstituted aryl group of 6 to 30 ring-forming carbons, or a substituted or unsubstituted heteroaryl group of 2 to 30 ring-forming carbons.

In Formula ET-1, each of ne1 to ne3 may independently be an integer between 0 and 5, inclusive. In Formula ET-1, each of L₁₂ to L₁₄ may independently be a direct linkage, a substituted or unsubstituted arylene group of 6 to 30 ring-forming carbons, or a substituted or unsubstituted heteroarylene group of 2 to 30 ring-forming carbons.

The compound represented by Formula ET-1 in the electron functional layer EFL and/or the light-emitting layer EML may be represented by 2-phenyl-4,6-bis(3-(triphenylsilyl)phenyl)-1,3,5-triazine (mSiTrz) among the compounds suggested in the device manufacturing embodiments of the present disclosure, but embodiments of the present disclosure are not limited thereto.

In one or more embodiments, the electron functional layer EFL may include an anthracene-based compound. However, embodiments of the present disclosure are not limited thereto, and the electron functional layer EFL may include, for example, 2,9-Dimethyl-4,7-diphenyl-1,10-phenanthroline (BCP), Tris(8-hydroxyquinolinato)aluminum (Alq₃), Bis(2-methyl-8-quinolinolato-N1,O8)-(1,1′-Biphenyl-4-olato)aluminum (BAlq), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzimidazol-1-yl)phenyl)-9,10-dinaphthylanthracene, 1,3,5-Tri(1-phenyl-1H-benzo[d]imidazol-2-yl)benzene (TPBi), 4,7-Diphenyl-1,10-phenanthroline (Bphen), 3-(Biphenyl-4-yl)-4-phenyl-5-tert-butylphenyl-1,2,4-triazole (TAZ), 4-(Naphthalen-1-yl)-3,5-diphenyl-4H-1,2,4-triazole (NTAZ), 2-(Biphenyl-4-yl)-5-(4-tert-butylphenyl)-1,3,4-oxadiazole (tBu-PBD), berylliumbis(benzoquinolin-10-olate) (Bebq2), 9,10-di(naphthalen-2-yl)anthracene (AND), 1,3-Bis[3,5-di(pyridin-3-yl)phenyl]benzene (BmPyPhB), or any combination thereof.

In one or more embodiments, the electron functional layer EFL (e.g. the electron transport layer ETL in the electron functional layer EFL) may include a metal-containing material in addition to one or more of the afore-described materials. For example, the metal-containing material may include a Li complex. The Li complex may include, for example, a compound ET-D1 (LiQ) or ET-D2.

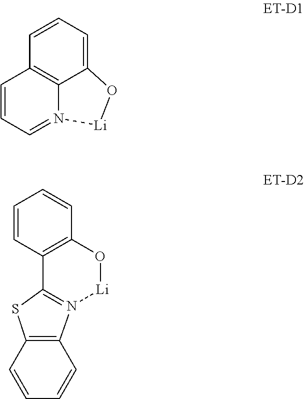

In one or more embodiments, the electron functional layer EFL may include an electron injection layer EIL configured to allow easy injection of an electron from the second electrode EL2. The electron injection layer may make direct contact with the second electrode.

The electron injection layer EIL may have a single layer including (e.g., consisting of) a single material, a single layer including (e.g., consisting of) a plurality of different materials, or a multilayer structure having a plurality of layers including (e.g., consisting of) a plurality of different materials.

The electron functional layer EFL (e.g., electron injection layer EIL) may include an alkaline earth metal, a rare earth metal, an alkali metal, an alkaline earth metal-containing compound, a rare earth metal-containing compound, an alkali metal-containing compound, an alkaline earth metal complex, a rare earth metal complex, an alkali metal complex, or any combination thereof, or further include an organic material (e.g. a compound represented by Formula EM-2 or Formula EM-3).

In one or more embodiments, the electron functional layer EFL may include a halogenated metal, such as LiF, NaCl, CsF, RbCl, RbI, CuI, and KI, a lanthanide metal such as Yb, or a co-deposition material of a halogenated metal and a lanthanide metal. For example, the co-deposition material of a halogenated metal and a lanthanide metal may include KI:Yb, RbI:Yb, and/or LiF:Yb. In one or more embodiments, a metal oxide, such as Li₂O and/or BaO, 8-hydroxyl-Lithium quinolate (Liq), and/or the like may be used for the electron functional layer EFL, but embodiments of the present disclosure are not limited thereto. In one or more embodiments, the electron functional layer EFL may also be consisting of a mixture material of an electron transport material and an insulating organo-metal salt. The insulating organo-metal salt may be a material having an energy band gap of about 4 eV or greater. For example, the insulating organo-metal salt may include, for example, a metal acetate, a metal benzoate, a metal acetoacetate, a metal acetylacetonate, and/or a metal stearate.

In one or more embodiments, the electron functional layer EFL may include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to one or more of the materials described above, but embodiments of the present disclosure are not limited thereto.

The electron functional layer EFL may include one or more of the compounds of the electron functional layer EFL described above in at least one of an electron injection layer EIL, an electron transport layer ETL, or a hole blocking layer HBL.

If (e.g., when) the electron functional layer EFL may include an electron transport layer ETL, the electron transport layer ETL may have a thickness of about 100 Å to about 1000 Å, such as about 150 Å to 500 Å. If (e.g., when) the thickness of the electron transport layer ETL satisfies the range described above, satisfactory level of electron transport properties may be obtained without a substantial increase in a driving voltage. If (e.g., when) the electron functional layer EFL includes an electron injection layer EIL, the electron injection layer EIL may have a thickness of about 1 Å to about 100 Å, such as about 3 Å to about 90 Å. If (e.g., when) the thickness of the electron injection layer EIL satisfies the range described above, satisfactory level of electron injection properties may be obtained without a substantial increase in a driving voltage.

The second electrode EL2 may be provided on the electron functional layer EFL. In one or more embodiments, the second electrode EL2 may be a common electrode. The second electrode EL2 may be a cathode or an anode, but embodiments of the present disclosure are not limited thereto. For example, if (e.g., when) the first electrode EL1 is an anode, the second electrode EL2 may be a cathode, and if (e.g., when) the first electrode EL1 is a cathode, the second electrode EL2 may be an anode. Here, at least one of an alloy, a metal, an electrically conductive compound, or any combination thereof, each having a low-work function, may be utilized as a material for the second electrode EL2.

The second electrode EL2 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode EL2 may be a transmissive electrode, a semi-transmissive electrode, or a reflective electrode.

In one or more embodiments, the second electrode EL2 may be connected with an auxiliary electrode. If (e.g., when) the second electrode EL2 is connected with the auxiliary electrode, a resistance of the second electrode EL2 may decrease.

In one or more embodiments, the second electrode EL2 may have a single layer structure of a single layer or a multiple layer structure of a plurality of layers.

In one or more embodiments, a first capping layer may be arranged outside of (e.g., on) the first electrode EL1, and/or a second capping layer may be arranged outside of (e.g., on) the second electrode EL2.

In one or more embodiments, light generated from the light-emitting layer of the light-emitting diode ED may be extracted toward the outside through the first electrode EL1, which is a semi-transmissive electrode or a transmissive electrode, and the first capping layer; in one or more embodiments, light generated from the light-emitting layer of the light-emitting diode ED may be extracted toward the outside through the second electrode EL2, which is a semi-transmissive electrode or a transmissive electrode, and the second capping layer.

In one or more embodiments, the capping layer CPL may independently be an organic capping layer including an organic material, an inorganic capping layer including an inorganic material, or a composite capping layer including an organic material and an inorganic material.

In one or more embodiments, the capping layer CPL may be an organic layer or an inorganic layer. For example, if (e.g., when) the capping layer CPL includes an inorganic material, the inorganic material may include an alkali metal compound, such as LiF, an alkaline earth metal compound, such as MgF₂, SiON, SiNₓ, SiO_{y}, and/or the like.

For example, if (e.g., when) the capping layer CPL includes an organic material, the organic material may include an amine compound, such as a monoamine and/or a diamine. For example, in one or more embodiments, the organic material may include TPD, α-NPD, β-NPB, m-MTDATA, N4, N4, N4′, N4′-tetra (biphenyl-4-yl)biphenyl-4,4′-diamine (TPD15), 4,4′4″-Tris(carbazol-9-yl)triphenylamine (TCTA), and/or the like. However, embodiments of the present disclosure are not limited thereto, for example, in one or more embodiments, the capping layer CPL may include Alq₃, CuPc, an epoxy resin, or an acrylate, such as a methacrylate. In one or more embodiments, the capping layer CPL may include at least one of (e.g., selected from among) Compounds CP1 through CP4, but embodiments of the present disclosure are not limited thereto. In a manufacturing embodiment of the device of the present disclosure, the capping layer includes the compound CP4.

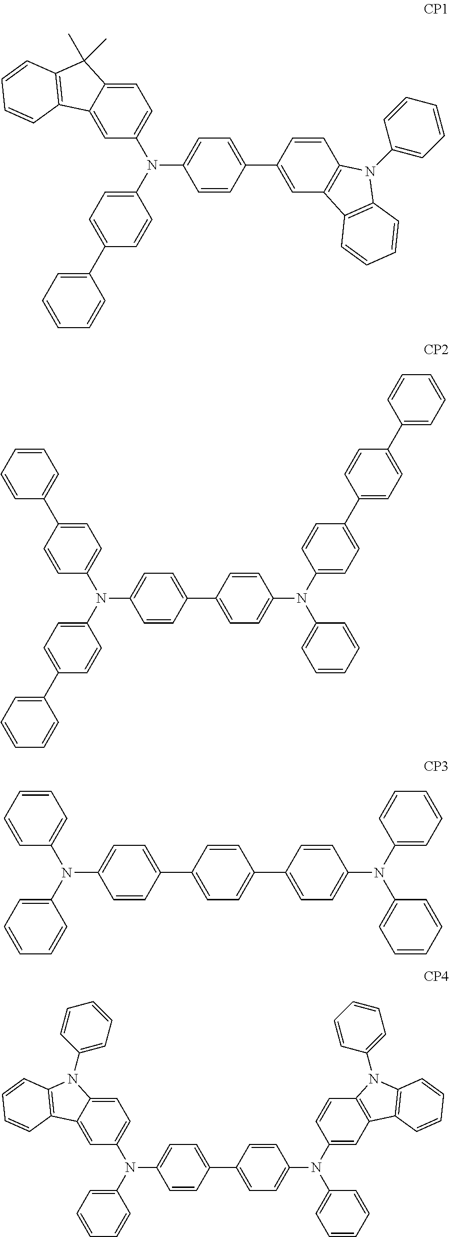 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccccc2)c2ccc(-c3ccc(-c4ccc(N(c5ccccc5)c5ccccc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

In one or more embodiments, the capping layer CPL may have a refractive index of 1.6 or more. For example, the refractive index of the capping layer CPL with respect to light in a wavelength range of 550 nm to 660 nm may be 1.6 or more, 1.8 or more, or 2.0 or more.

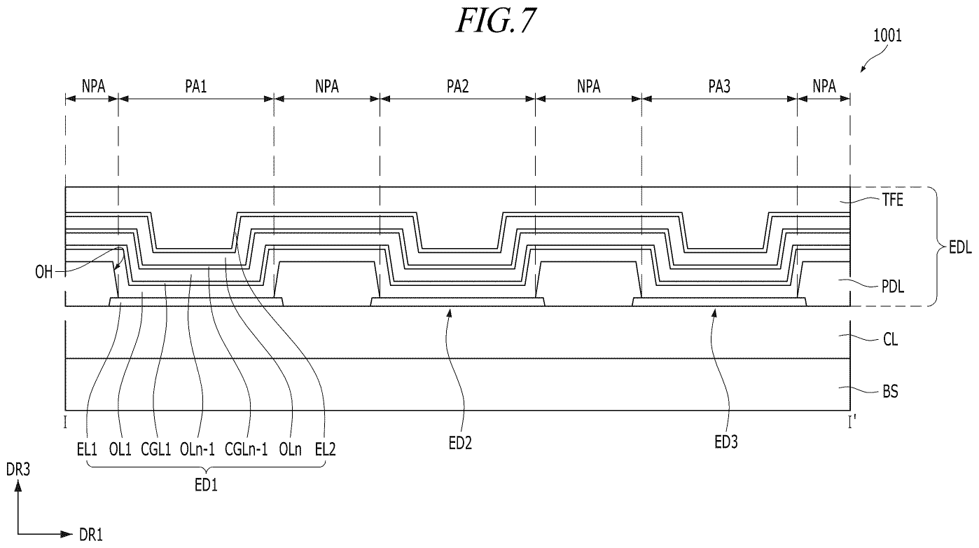

FIG. 7 is a cross-sectional view illustrating a portion of a display device in accordance with one or more embodiments of the present disclosure.

A display device 1001 will be described with reference to a first light-emitting diode ED1 among a plurality of light-emitting diodes ED1, ED2, and ED3. The first light-emitting diode ED1 may include n light-emitting structures (OL1, . . . , OLn−1, and OLn) laminated between a first electrode EL1 and a second electrode EL2, and n−1 charge generating layers (CGL1, . . . , and CGLn−1). Here, n may be a natural number.

Each of the light-emitting structures OL1, . . . , OLn−1, and OLn may include a hole functional layer HFL and an electron functional layer EFL. Light-emitting layer EML1 (in FIG. 2) may be arranged between the hole functional layer HFL and the electron functional layer EFL.

For example, the first light-emitting diode ED1 included in the display device 1001 of one or more embodiments may be a light-emitting diode having a tandem structure including a plurality of light-emitting layers.

The charge generation layers CGL1, . . . , and CGLn−1 may be each respectively interposed between neighboring light-emitting structures OL1, . . . , OLn−1, and OLn. The charge generation layers CGL1, . . . , and CGLn−1 may each include a p-type (kind) charge generation layer and/or an n-type (kind) charge generation layer.

At least one selected from among the light-emitting structures OL1, . . . , OLn−1, and OLn included in the display device 1001 of one or more embodiments may include the described heterocyclic compound of one or more embodiments. For example, at least one of the plurality of light-emitting layers included in the light-emitting diode ED1 may include the heterocyclic compound of one or more embodiments.

FIG. 7 illustrates the display device 1001 including three light-emitting structures OL1, OLn−1, and OLn and two charge generation layers CGL1 and CGLn−1 if (e.g., when) n is 2. Unlike what is illustrated in FIG. 7, in one or more embodiments, if (e.g., when) n is 1, the n−1-th light-emitting structure OLn−1 and n−1-th charge generation layer CGLn−1 may not be provided, and n-th light-emitting structure OLn may make direct contact with the first charge generation layer CGL1. In addition, unlike what is illustrated in FIG. 7, in one or more embodiments, if (e.g., when) n is 3, a light-emitting structure and a charge generation layer may be sequentially added between the first charge generation layer CGL1 and n−1-th light-emitting structure OLn−1.

In one or more embodiments, the light-emitting structures OL1, . . . , OLn−1, and OLn included in the first light-emitting diode ED1 may be to emit light in substantially the same wavelength range. However, embodiments of the present disclosure are not limited thereto, and at least some selected from among the light-emitting structures OL1, . . . , OLn−1, and OLn included in the first light-emitting diode ED1 may be to emit light with a different wavelength from the others.

In one or more embodiments, each of the light-emitting structures OL1, . . . , OLn−1, and OLn may allow each of the light-emitting diodes ED1, ED2, and ED3 including the light-emitting structures OL1, . . . , OLn−1, and OLn, respectively, to emit light in different ranges of wavelength. For example, the first light-emitting structure OL1 included in the first light-emitting diode ED1 and the first light-emitting structure OL1 included in the second light-emitting diode ED2 may be to emit light in different ranges of wavelength. However, embodiments of the present disclosure are not limited thereto, for example, each of the light-emitting structures OL1, . . . , OLn−1, and OLn may allow each of the light-emitting diodes ED1, ED2, and ED3 including the light-emitting structures OL1, . . . , OLn−1, and OLn, respectively, to emit light in substantially the same wavelength range.

Although it is illustrated in FIG. 7 that all (e.g., each) of the light-emitting diodes ED1, ED2, and ED3 have the same structure, embodiments of the present disclosure are not limited to what is illustrated in the drawing. In one or more embodiments, some of the light-emitting diodes ED1, ED2, and ED3 may include k light-emitting structures (k is a natural number), and the others may include m light-emitting structures (m is a natural number different from k).

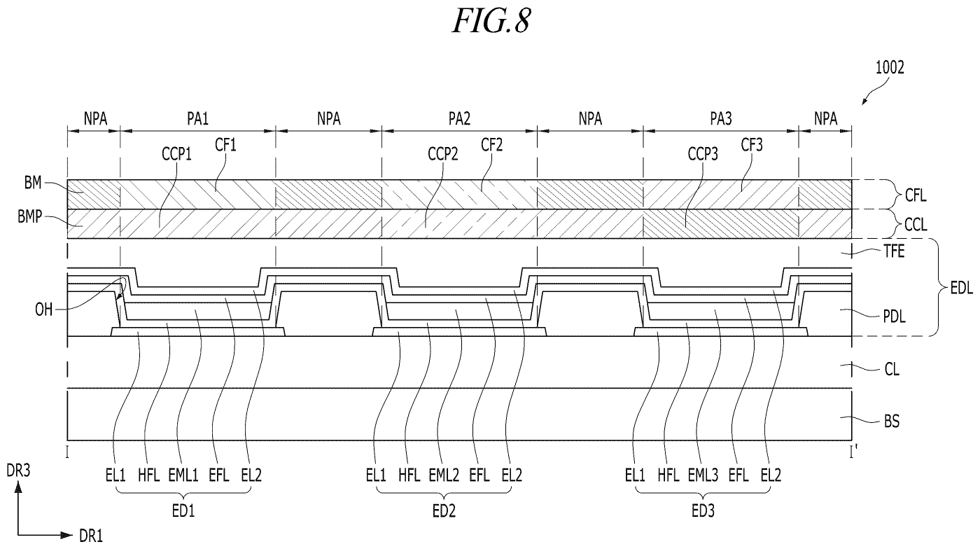

FIG. 8 is a cross-sectional view illustrating a portion of a display device in accordance with one or more embodiments of the present disclosure.

A display device 1002 according to one or more embodiments in FIG. 8 will be described based on a difference from the display device 1000 described with reference to FIG. 2. An undescribed configuration follows the descriptions of FIG. 2.

The display device 1002 may further include a light controlling layer CCL and a color filter layer CFL arranged on the display device layer EDL.

The light controlling layer CCL may include a plurality of light controlling parts CCP1, CCP2, and CCP3. FIG. 8 illustrates that the light controlling parts CCP1, CCP2, and CCP3 may be separated from one another and a partition pattern BMP may be arranged between the light controlling parts. Nonetheless, embodiments of the present disclosure are not limited to what is illustrated in FIG. 8, for example, in one or more embodiments, edges of the light controlling parts may overlap with one another or edges of the light controlling parts may overlap with the partition pattern.

The light controlling layer CCL may include a first through a third light controlling parts CCP1 through CCP3 overlapping with the first through the third light-emitting diodes ED1 through ED3, respectively.

At least one selected from among the first through the third light controlling parts CCP1 through CCP3 may transform a wavelength of incident light (e.g. blue light) and then emit light of different color (e.g. red light or green light). In addition, at least one selected from among the first through the third light controlling parts CCP1 through CCP3 may be to transmit incident light (e.g. blue light) without transforming its wavelength.

In one or more embodiments, at least one selected from among the first through the third light controlling parts CCP1 through CCP3 may include a light converter, such as a quantum dot or a phosphor. The light converter may transform the wavelength of light provided and then emit the transformed (converted) light. The first through the third light controlling parts CCP1 through CCP3 may each further include a scatter and a base resin configured to disperse the scatter.

In one or more embodiments, the light controlling layer CCL may further include a barrier layer configured to prevent or reduce penetration of moisture and/or oxygen.

The color filter layer CFL may be arranged on the light controlling layer CCL.

The color filter layer CFL may include a plurality of color filters CF1, CF2, and CF3. FIG. 8 illustrates that the color filters CF1, CF2, and CF3 are spaced and/or apart (e.g., spaced apart or separated) and have a blocking part BM arranged between the color filters. However, embodiments of the present disclosure are not limited to what is illustrated in FIG. 8, and in one or more embodiments, edges of the color filters may overlap with one another, and edges of the color filters may overlap with the blocking part.

The color filter layer CFL may include a first through a third color filters CF1 through CF3 overlapping with the first through the third light-emitting diodes ED1 through ED3, respectively.

The first through the third color filters CF1 through CF3 may selectively pass light with a selected color. However, embodiments of the present disclosure are not limited thereto, and at least one selected from among the first through the third color filters CF1 through CF3 may be provided as transparent or translucent.

At least one selected from among the light-emitting diodes ED1 through ED3 included in the display device 1002 of one or more embodiments may include the described heterocyclic compound of one or more embodiments.

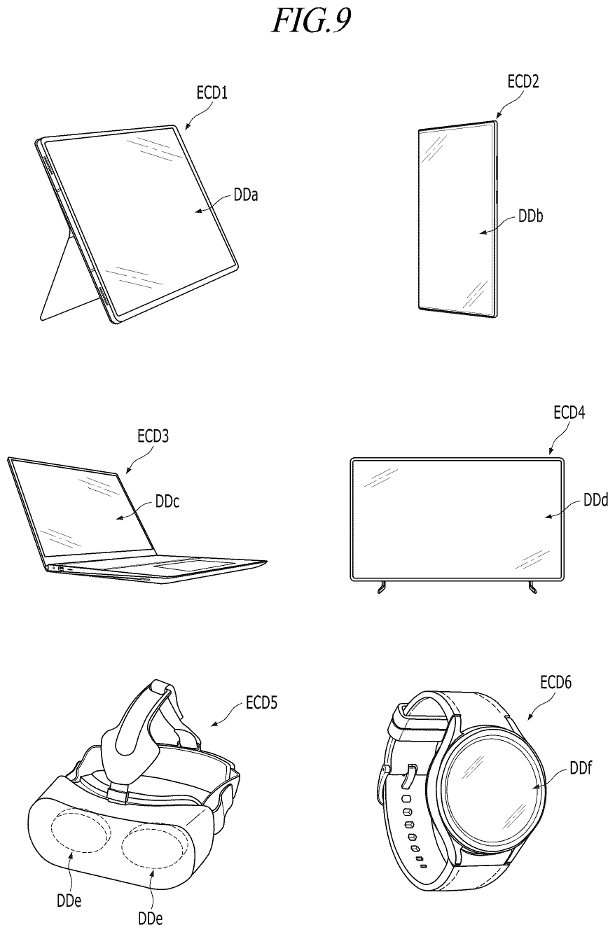

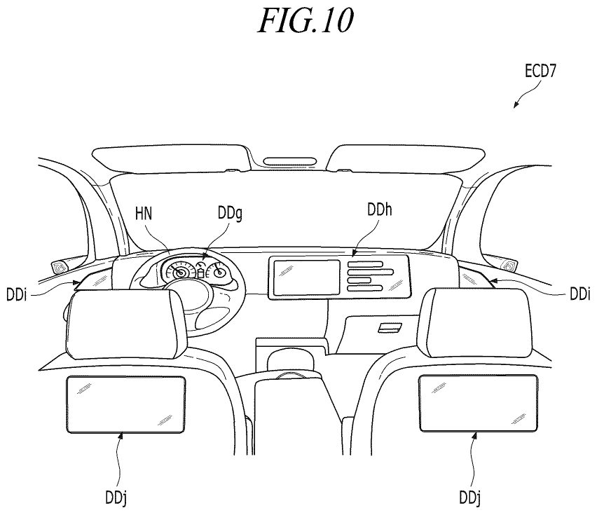

FIG. 9 and FIG. 10 are each a drawing illustrating electronic devices applied with the display device according to one or more embodiments of the present disclosure.

Referring to FIG. 9, a first electronic device ECD1 is illustrated as a tablet PC including a first display device DDa. A second electronic device ECD2 is illustrated as a portable terminal including a second display device DDb. A third electronic device ECD3 is illustrated as a laptop including a third display device DDc. A fourth electronic device ECD4 is illustrated as a TV including a fourth display device DDd.

A fifth electronic device ECD5 is illustrated as a head mounted display device including a fifth display device DDe. A sixth electronic device ECD6 is illustrated as a digital watch including a sixth display device DDf. Referring to FIG. 10, a seventh electronic device ECD7 is illustrated as a transportation vehicle including a seventh through a tenth display device DDg through DDj. The seventh electronic device ECD7 is illustrated as an automobile. However, embodiments of the present disclosure are not limited thereto, and the transportation vehicle may include a bicycle, a motorcycle, a train, a ship, a plane, and/or the like.

The seventh display device DDg may be arranged in front of a steering wheel HN in a driver's sight for utilization in showing instrument panel information such as a driving speed of the vehicle. The eighth display device DDh may be arranged on a dashboard of the vehicle, apart from the seventh display device DDg, and utilized in showing information about a vehicle control interface, audio, temperature, road condition, and/or video. The nineth display device DDi may be arranged on a side mirror of a driver seat or a passenger seat and utilized as a digital side mirror. The nineth display device DDi may display an image of filming outside of the vehicle. The tenth display device DDi may be arranged behind a driver seat or a passenger seat and utilized in displaying, for example, an image, which is recognized by a passenger in a rear seat.

At least one selected from among the first through the tenth display devices DDa through DDj may include the light-emitting diode ED described with reference to FIGS. 3 through 6.

The display device according to one or more embodiments is not limited to the example electronic devices and may be applicable to one or more suitable electronic devices, such as a plane panel display, a curved display, a television, a billboard, a computer monitor, a medical monitor, a head mounted display (HMD), an indoor light, an outdoor light, a signal light, a wearable device, a foldable device, a rollable device, a bendable device, a flexible device, a curved device, an electronic organizer, an electronic book, a portable multimedia player (PMP), a personal digital assistance (PDA), a laser printer, a telephone, a portable phone, a tablet PC, a portable terminal, a laptop computer, a digital camera, a viewfinder, a camcorder, a 3D display, a virtual reality display, an augmented reality display, a video wall including multiple displays tiled together, a vehicle, an outdoor display device, a theater screen, a stadium screen, a screen, and/or a signboard.

Hereinafter, Examples and Comparative Examples will be described in more detail. The heterocyclic compound according to one or more embodiments and the light-emitting diode of one or more embodiments will be specifically described. However, Examples shown below are shown to assist the understanding of the present disclosure, and the scope of the present disclosure is not limited thereto.

### EXAMPLES

### 1. Synthesis of Heterocyclic Compound of Embodiment

A process of synthesizing the heterocyclic compound according to one or more embodiments of the present disclosure will be particularly described with reference to examples of processes of synthesizing Compounds 10, 17, 41, 45, 68, 72, 81, and 95. However, a process of synthesizing the heterocyclic compound, which will be described hereinafter, is provided merely as an example, and the present disclosure is not limited to Examples.

### Synthesis Example 1: Synthesis of Compound 10

Compound 10 according to one or more embodiments may be synthesized according to, for example, a process of Reaction Scheme 1.

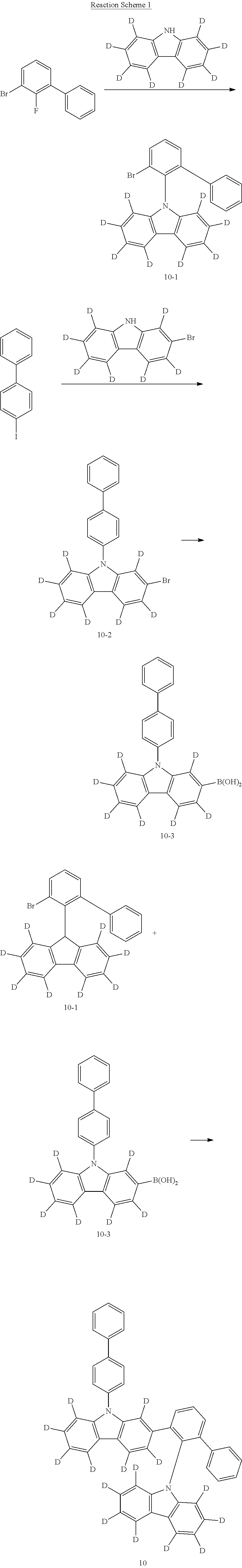

### Synthesis of Intermediate 10-1

3-bromo-2-fluoro-1,1′-biphenyl (CAS No.=1515573-52-0) and 9H-carbazole-1,2,3,4,5,6,7,8-d₈ (CAS No.=38537-24-5) were reacted in dimethylformamide solvent to obtain Intermediate 10-1. The M+1 peak value of Intermediate 10-1 was obtained utilizing liquid chromatography-mass spectrometry (LC-MS).

C₂₄H₈D₈BrN: M+1 406.12

### Synthesis of Intermediate 10-2

4-iodo-biphenyl (CAS No.=1591-31-7) and 7-bromo-9H-carbazole-1,2,3,4,5,6,8-d₇ (CAS No.=2650519-97-2) were reacted under a Cu catalyst to obtain Intermediate 10-2. The M+1 peak value of Intermediate 10-2 was obtained utilizing liquid chromatography-mass spectrometry (LC-MS).

C₂₄H₉D₇BrN: M+1 405.10

### Synthesis of Intermediate 10-3

Intermediate 10-2 was reacted with n-BuLi and then reacted with trimethyl borate (CAS No.=121-43-7) to obtain Intermediate 10-3. The M+1 peak value of Intermediate 10-3 was obtained utilizing liquid chromatography-mass spectrometry (LC-MS).

C₂₄H₁₁D₇BNO₂: M+1 371.20

### Synthesis of Compound 10

5 g of Intermediate 10-1, 4.6 g of Intermediate 10-3, 0.71 g of tetrakis(triphenylphosphine)palladium, and 4.3 g of potassium carbonate were placed in a reaction vessel and dissolved in 60 mL of 1,4-dioxane and 15 mL of distilled water, followed by refluxing for 24 hours. After completion of the reaction, the reaction solution was extracted with acetylacetate, and a collected organic layer was dried over anhydrous magnesium sulfate. The residue obtained by evaporating the solvent was separated and purified by silica gel column chromatography to obtain 5.1 g (yield: 64%) of Compound 10. Compound 10 was identified by LC-MS and proton nuclear magnetic resonance spectroscopy (¹H-NMR).

### Synthesis Example 2: Synthesis of Compound 17

Compound 17 according to one or more embodiments may be synthesized according to, for example, a process of Reaction Scheme 2.

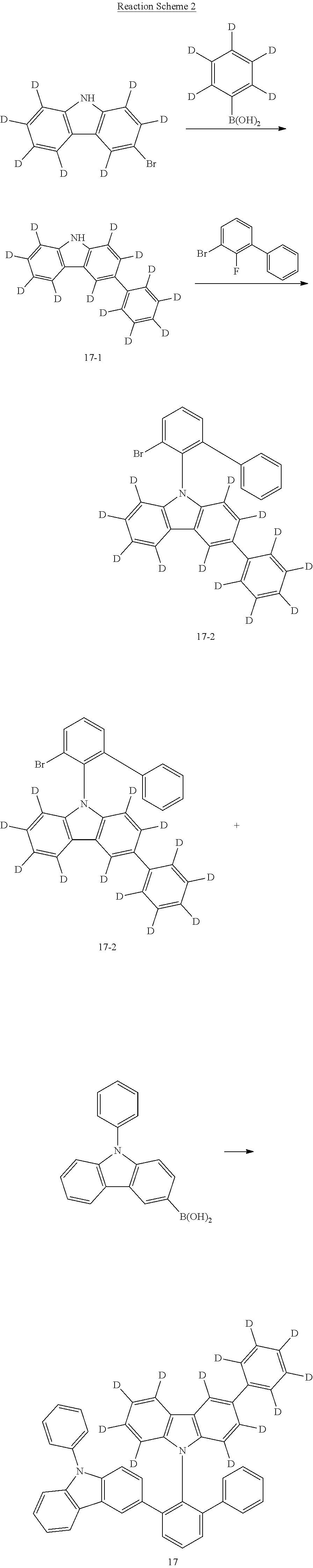

### Synthesis of Intermediate 17-1

6-bromo-9H-carbazole-1,2,3,4,5,7,8-d₇ (CAS No.=2764814-81-3) and (phenyl-d₅)boronic acid (CAS No.=215527-70-1) were reacted under a Pd catalyst to obtain Intermediate 17-1. The M+1 peak value of Intermediate 17-1 was obtained utilizing liquid chromatography-mass spectrometry (LC-MS).

C₁₈HD₁₂N: M+1 256.20

### Synthesis of Intermediate 17-2

Intermediate 17-1 and 3-bromo-2-fluoro-1,1′-biphenyl (CAS No.=1515573-52-0) were reacted in a dimethylformamide solvent to obtain Intermediate 17-2. The M+1 peak value of Intermediate 17-2 was obtained utilizing liquid chromatography-mass spectrometry (LC-MS).

C₃₀H₈D₁₂BrN: M+1 486.16

### Synthesis of Compound 17

Substantially the same process as the synthesis process of Compound 10 was performed except for utilizing Intermediate 17-2 and (9-phenyl-9H-carbazol-3-yl)boronic acid (CAS No.=854952-58-2) instead of Intermediate 10-1 and Intermediate 10-3. 3.9 g (yield: 66%) of Compound 17 was obtained. Compound 17 was identified by LC-MS and ¹H-NMR.

### Synthesis Example 3: Synthesis of Compound 41

Compound 41 according to one or more embodiments may be synthesized according to, for example, a process of Reaction Scheme 3.

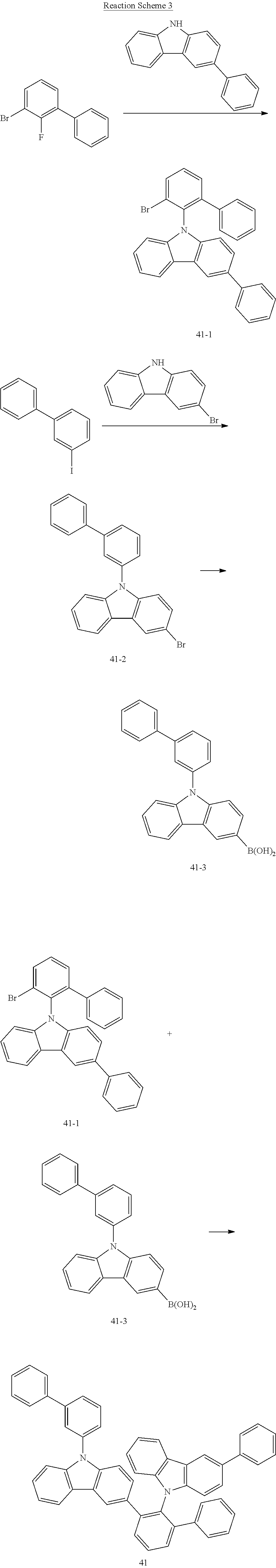

### Synthesis of Intermediate 41-1

3-bromo-2-fluoro-1,1′-biphenyl (CAS No.=1515573-52-0) and 3-phenyl-9H-carbazole (CAS No.=103012-26-6) were reacted in a dimethylformamide solvent to obtain Intermediate 41-1. The M+1 peak value of Intermediate 41-1 was obtained utilizing liquid chromatography-mass spectrometry (LC-MS).

C₃₀H₂₀BrN: M+1 474.10

### Synthesis of Intermediate 41-2

3-iodobiphenyl (CAS No.=20442-79-9) and 3-bromocarbazole (CAS No.=1592-95-6) were reacted under a Cu catalyst to obtain Intermediate 41-2. The M+1 peak value of Intermediate 41-2 was obtained utilizing liquid chromatography-mass spectrometry (LC-MS).

C₂₄H₁₆BrN: M+1 398.05

### Synthesis of Intermediate 41-3

Intermediate 41-2 was reacted with n-BuLi and then, reacted with trimethyl borate (CAS No.=121-43-7) to obtain Intermediate 41-3. The M+1 peak value of Intermediate 41-3 was obtained utilizing liquid chromatography-mass spectrometry (LC-MS).

C₂₄H₁₈BNO₂: M+1 364.15

### Synthesis of Compound 41

Substantially the same process as the synthesis process of Compound 10 was performed except for utilizing Intermediate 41-1 and Intermediate 41-3 instead of Intermediate 10-1 and Intermediate 10-3. 4.2 g (yield: 70%) of Compound 41 was obtained. Compound 41 was identified by LC-MS and ¹H-NMR.

### Synthesis Example 4: Synthesis of Compound 45

Compound 45 according to one or more embodiments may be synthesized according to, for example, a process of Reaction Scheme 4.

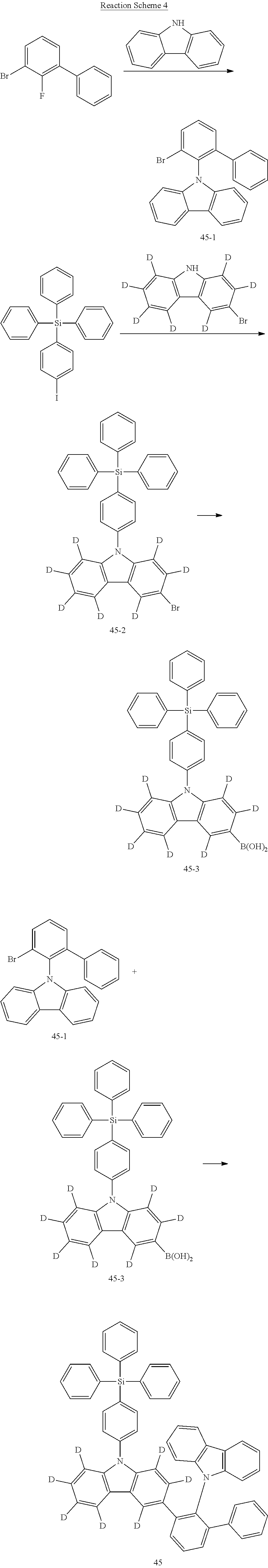

### Synthesis of Intermediate 45-1

3-bromo-2-fluoro-1,1′-biphenyl (CAS No.=1515573-52-0) and 9H-carbazole (CAS No.=86-74-8) were reacted in a dimethylformamide solvent to obtain Intermediate 45-1. The M+1 peak value of Intermediate 45-1 was obtained utilizing liquid chromatography-mass spectrometry (LC-MS).

C₂₄H₁₆BrN: M+1 398.05

### Synthesis of Intermediate 45-2

1-iodo-4-(triphenylsilyl)benzene (CAS No.=956776-56-0) and 6-bromo-9H-carbazole-1,2,3,4,5,7,8-d₇ (CAS No.=2764814-81-3) were reacted under a Cu catalyst to obtain Intermediate 45-2. The M+1 peak value of Intermediate 45-2 was obtained utilizing liquid chromatography-mass spectrometry (LC-MS).

C₃₆H₁₉D₇BrNSi: M+1 587.15

### Synthesis of Intermediate 45-3

Intermediate 45-2 was reacted with n-BuLi and then, reacted with trimethyl borate (CAS No.=121-43-7) to obtain Intermediate 45-3. The M+1 peak value of Intermediate 45-3 was obtained utilizing liquid chromatography-mass spectrometry (LC-MS).

C₃₆H₂₁D₇BNO₂Si: M+1 553.20

### Synthesis of Compound 45

Substantially the same process as the synthesis process of Compound 10 was performed except for utilizing Intermediate 45-1 and Intermediate 45-3 instead of Intermediate 10-1 and Intermediate 10-3. 4.4 g (yield: 72%) of Compound 45 was obtained. Compound 45 was identified by LC-MS and ¹H-NMR.

### Synthesis Example 5: Synthesis of Compound 68

Compound 68 according to one or more embodiments may be synthesized according to, for example, a process of Reaction Scheme 5.

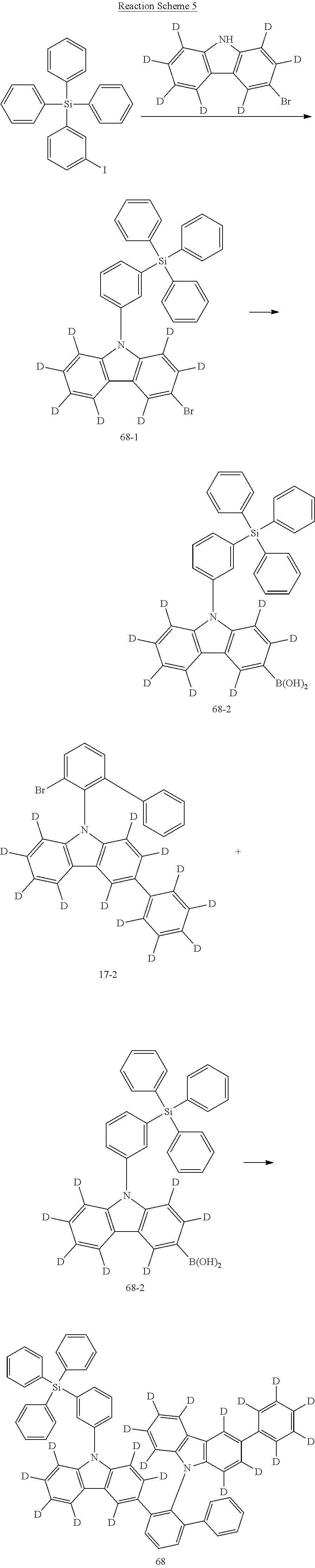

### Synthesis of Intermediate 68-1

1-iodo-3-(triphenylsilyl)benzene (CAS No.=1314221-75-4) and 6-bromo-9H-carbazole-1,2,3,4,5,7,8-d₇ (CAS No.=2764814-81-3) were reacted under a Cu catalyst to obtain Intermediate 68-1. The M+1 peak value of Intermediate 68-1 was obtained utilizing liquid chromatography-mass spectrometry (LC-MS).

C₃₆H₁₉D₇BrNSi: M+1 587.10

### Synthesis of Intermediate 68-2

Intermediate 68-1 was reacted with n-BuLi and then, reacted with trimethyl borate (CAS No.=121-43-7) to obtain Intermediate 68-2. The M+1 peak value of Intermediate 68-2 was obtained utilizing liquid chromatography-mass spectrometry (LC-MS).

C₃₆H₂₁D₇BNO₂Si: M+1 553.20

### Synthesis of Compound 68

Substantially the same process as the synthesis process of Compound 10 was performed except for utilizing Intermediate 17-2 and Intermediate 68-2 instead of Intermediate 10-1 and Intermediate 10-3. 5.9 g (yield: 63%) of Compound 68 was obtained. Compound 68 was identified by LC-MS and ¹H-NMR.

### Synthesis Example 6: Synthesis of Compound 72

Compound 72 according to one or more embodiments may be synthesized according to, for example, a process of Reaction Scheme 6.

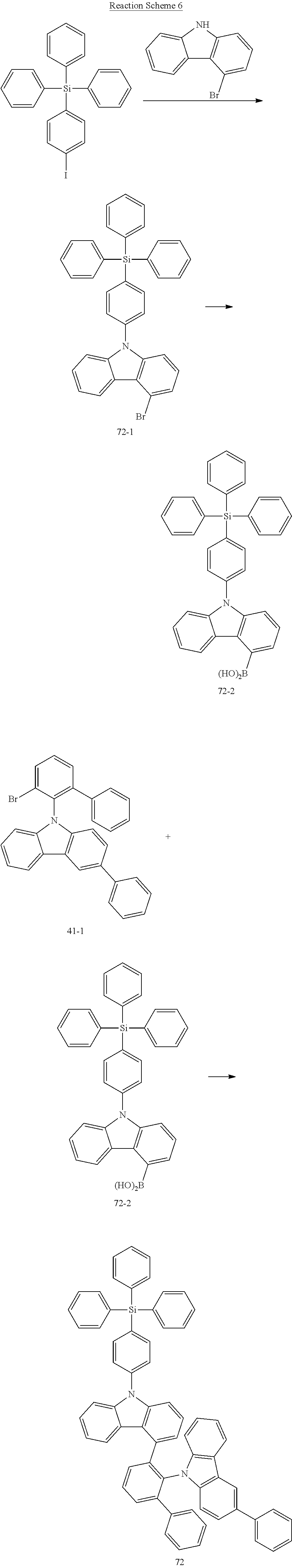

### Synthesis of Intermediate 72-1

1-iodo-4-(triphenylsilyl)benzene (CAS No.=956776-56-0) and 4-bromo-9H-carbazole (CAS No.=3652-89-9) were reacted under a Cu catalyst to obtain Intermediate 72-1. The M+1 peak value of Intermediate 72-1 was obtained utilizing liquid chromatography-mass spectrometry (LC-MS).

C₃₆H₂₆BrNSi: M+1 580.10

### Synthesis of Intermediate 72-2

Intermediate 72-1 was reacted with n-BuLi and then, reacted with trimethyl borate (CAS No.=121-43-7) to obtain Intermediate 72-2. The M+1 peak value of Intermediate 72-2 was obtained utilizing liquid chromatography-mass spectrometry (LC-MS).

C₃₆H₂₈BNO₂Si: M+1 546.20

### Synthesis of Compound 72

Substantially the same process as the synthesis process of Compound 10 was performed except for utilizing Intermediate 41-1 and Intermediate 72-2 instead of Intermediate 10-1 and Intermediate 10-3. 5.8 g (yield: 77%) of Compound 72 was obtained. Compound 72 was identified by LC-MS and ¹H-NMR.

### Synthesis Example 7: Synthesis of Compound 81

Compound 81 according to one or more embodiments may be synthesized according to, for example, a process of Reaction Scheme 7.

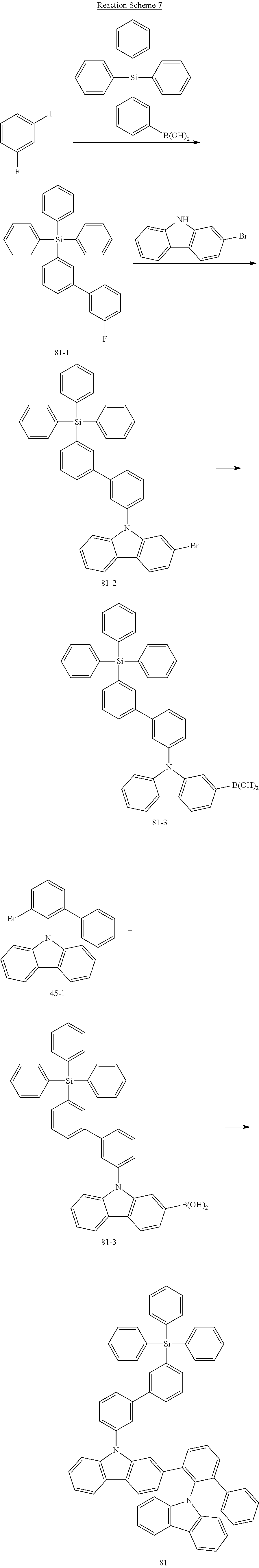

### Synthesis of Intermediate 81-1

1-fluoro-3-iodobenzene (CAS No.=1121-86-4) and [3-(triphenylsilyl)phenyl]boronic acid (CAS No.=1253912-58-1) were reacted under a Pd catalyst to obtain Intermediate 81-1. The M+1 peak value of Intermediate 81-1 was obtained utilizing liquid chromatography-mass spectrometry (LC-MS).

C₃₀H₂₃FSi: M+1 431.20

### Synthesis of Intermediate 81-2

Intermediate 81-1 and 2-bromo-9H-carbazole (CAS No.=3652-90-2) were reacted in a dimethylformamide solvent to obtain Intermediate 81-2. The M+1 peak value of Intermediate 81-2 was obtained utilizing liquid chromatography-mass spectrometry (LC-MS).

C₄₂H₃₀BrNSi: M+1 656.14

### Synthesis of Intermediate 81-3

Intermediate 81-2 was reacted with n-BuLi and then, reacted with trimethyl borate (CAS No.=121-43-7) to obtain Intermediate 81-3. The M+1 peak value of Intermediate 81-3 was obtained utilizing liquid chromatography-mass spectrometry (LC-MS).

C₄₂H₃₂BNO₂Si: M+1 622.25

### Synthesis of Compound 81

Substantially the same process as the synthesis process of Compound 10 was performed except for utilizing Intermediate 45-1 and Intermediate 81-3 instead of Intermediate 10-1 and Intermediate 10-3. 4.6 g (yield: 59%) of Compound 81 was obtained. Compound 81 was identified by LC-MS and ¹H-NMR.

### Synthesis Example 8: Synthesis of Compound 95

Compound 95 according to one or more embodiments may be synthesized according to, for example, a process of Reaction Scheme 8.

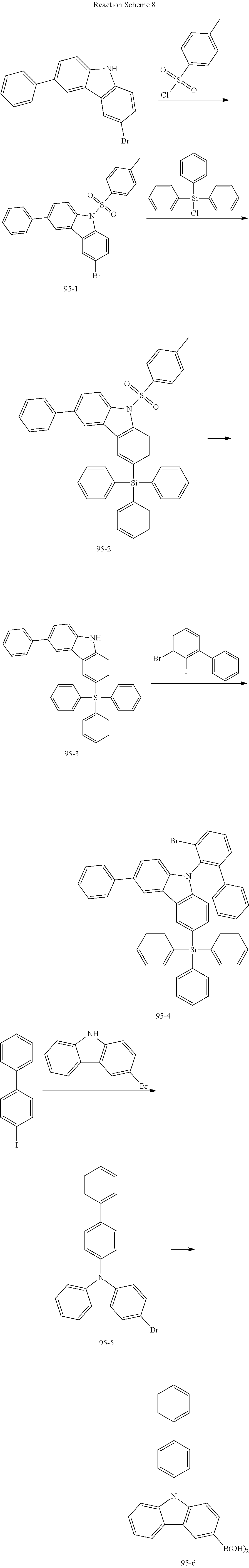

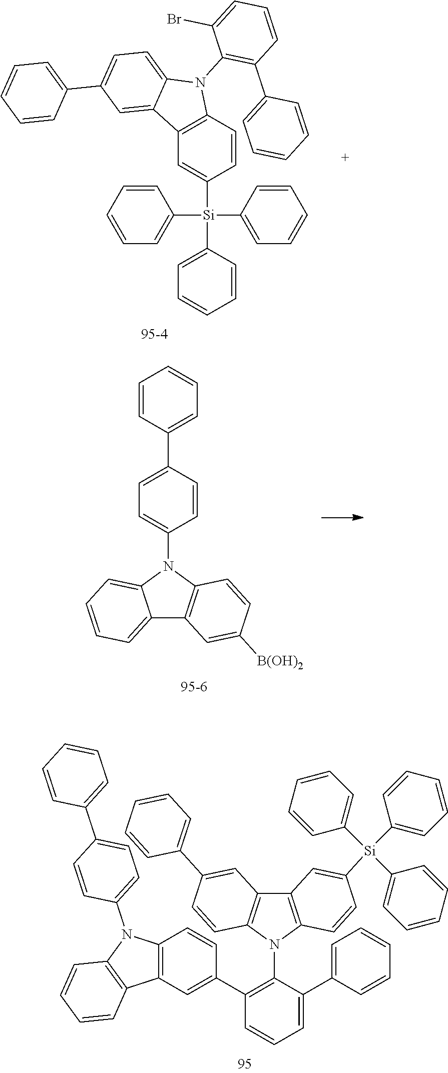 [SMILES: Brc1cccc(-c2ccccc2)c1-n1c2ccc(-c3ccccc3)cc2c2cc([Si](c3ccccc3)(c3ccccc3)c3ccccc3)ccc21 ; OB(O)c1ccc2c(c1)c1ccccc1n2-c1ccc(-c2ccccc2)cc1 ; c1ccc(-c2ccc(-n3c4ccccc4c4cc(-c5cccc(-c6ccccc6)c5-n5c6ccc(-c7ccccc7)cc6c6cc([Si](c7ccccc7)(c7ccccc7)c7ccccc7)ccc65)ccc43)cc2)cc1]

### Synthesis of Intermediate 95-1

3-bromo-6-phenyl-9H-carbazole (CAS No.=1303472-72-1), potassium hydroxide, and 4-toluenesulfonyl chloride (CAS No.=98-59-9) were reacted to obtain Intermediate 95-1. The M+1 peak value of Intermediate 95-1 was obtained utilizing liquid chromatography-mass spectrometry (LC-MS).

C₂₅H₁₈BrNO₂S: M+1 476.00

### Synthesis of Intermediate 95-2

Intermediate 95-1 was reacted with n-BuLi and then, reacted with chlorotriphenylsilane (CAS No.=76-86-8) to obtain Intermediate 95-2. The M+1 peak value of Intermediate 95-2 was obtained utilizing liquid chromatography-mass spectrometry (LC-MS).

C₄₃H₃₃NO₂SSi: M+1 656.20

### Synthesis of Intermediate 95-3

Intermediate 95-2 and sodium hydroxide were reacted to obtain Intermediate 95-3. The M+1 peak value of Intermediate 95-3 was obtained utilizing liquid chromatography-mass spectrometry (LC-MS).

C₃₆H₂₇NSi: M+1 502.20

### Synthesis of Intermediate 95-4

3-bromo-2-fluoro-1,1′-biphenyl (CAS No.=1515573-52-0) and Intermediate 95-3 were reacted in a dimethylformamide solvent to obtain Intermediate 95-4. The M+1 peak value of Intermediate 95-4 was obtained utilizing liquid chromatography-mass spectrometry (LC-MS).

C₄₈H₃₄BrNSi: M+1 732.20

### Synthesis of Intermediate 95-5

4-iodobiphenyl (CAS No.=1591-31-7) and 3-bromo-9H-carbazole (CAS No.=1592-95-6) were reacted under a Cu catalyst to obtain Intermediate 95-5. The M+1 peak value of Intermediate 95-5 was obtained utilizing liquid chromatography-mass spectrometry (LC-MS).

C₂₄H₁₆BrN: M+1 398.05

### Synthesis of Intermediate 95-6

Intermediate 95-5 was reacted with n-BuLi and then, reacted with trimethyl borate (CAS No.=121-43-7) to obtain Intermediate 95-6. The M+1 peak value of Intermediate 95-6 was obtained utilizing liquid chromatography-mass spectrometry (LC-MS).

C₂₄H₁₈BNO₂: M+1 364.15

### Synthesis of Compound 95

Substantially the same process as the synthesis process of Compound 10 was performed except for utilizing Intermediate 95-4 and Intermediate 95-6 instead of Intermediate 10-1 and Intermediate 10-3. 3.4 g (yield: 65%) of Compound 95 was obtained. Compound 95 was identified by LC-MS and ¹H-NMR.

The ¹H NMR and mass spectroscopy/fast atom bombardment (MS/FAB) of the compounds synthesized in Synthesis Examples 1 through 8 are shown in Table 1. Synthesis methods of other compounds can be easily recognized by a person skilled in the art by referring to the synthesis processes and raw materials above.

TABLE 1

| | | MS/FAB | |
|---|---|---|---|
| Compound | | Found | |
| No. | ¹H NMR (CDCl₃, 500 MHz) | [M + 1] | calc. |
| 10 | 8.01 (d, 2H), 7.91 (d, 4H), 7.75-7.68 (m, 3H), | 652.30 | 651.35 |
| | 7.50-7.41 (m, 4H), 7.19 (d, 4H) | | |
| 17 | 8.55 (d, 1H), 8.01-7.88 (m, 5H), 7.78-7.35 (m, | 649.30 | 648.33 |
| | 9H), 7.20-7.15 (m, 5H) | | |
| 41 | 8.55 (d, 2H), 8.21 (s, 1H), 8.01-7.88 (m, 8H), | 713.29 | 712.29 |
| | 7.75-7.60 (m, 9H), 7.50-7.35 (m, 10H), 7.20-7.16 | | |
| | (m, 6H) | | |
| 45 | 8.55 (d, 1H), 8.19 (d, 1H), 8.01 (d, 2H), 7.94 (d, | 826.30 | 825.36 |
| | 1H), 7.83 (d, 2H), 7.69 (t, 1H), 7.60-7.36 (m, | | |
| | 21H), 7.20-7.16 (m, 6H) | | |
| 68 | 8.01 (d, 2H), 7.69-7.60 (m, 4H), 7.46-7.35 (m, | 914.40 | 913.46 |
| | 17H), 7.19 (d, 4H) | | |
| 72 | 8.55 (d, 2H), 8.01-7.67 (m, 14H), 7.50-7.35 (m, | 895.34 | 894.34 |
| | 24H), 7.20-7.16 (m, 6H) | | |
| 81 | 8.55 (d, 2H), 8.31 (d, 1H), 8.21 (s, 1H), 8.19 (d, | 895.34 | 894.34 |
| | 1H), 8.01-7.94 (m, 6H), 7.68-7.35 (m, 28H), 7.20- | | |
| | 7.15 (m, 7H) | | |
| 95 | 8.55 (d, 1H), 8.30 (d, 1H), 8.13 (d, 1H), 8.01-7.88 | 971.37 | 970.37 |
| | (m, 10H), 7.78-7.68 (m, 8H), 7.50-7.35 (m, 24H), | | |
| | 7.19-7.15 (m, 5H) | | |

### 2. Manufacture and Evaluation of Light Emitting Diode

The light emitting diode of one or more embodiments including the heterocyclic compound of one or more embodiments in the light-emitting layer was manufactured by a method described herein. Light emitting diodes of Example 1 to Example 8 were manufactured by utilizing the heterocyclic compounds of Example Compounds 10, 17, 41, 45, 68, 72, 81, and 95, respectively, as a host material of the light-emitting layer. Comparative Example 1 to Comparative Example 5 correspond to light-emitting diodes manufactured utilizing Comparative Compound C1 to Comparative Compound C5, respectively, as a host material of the light-emitting layer.

### Example Compound

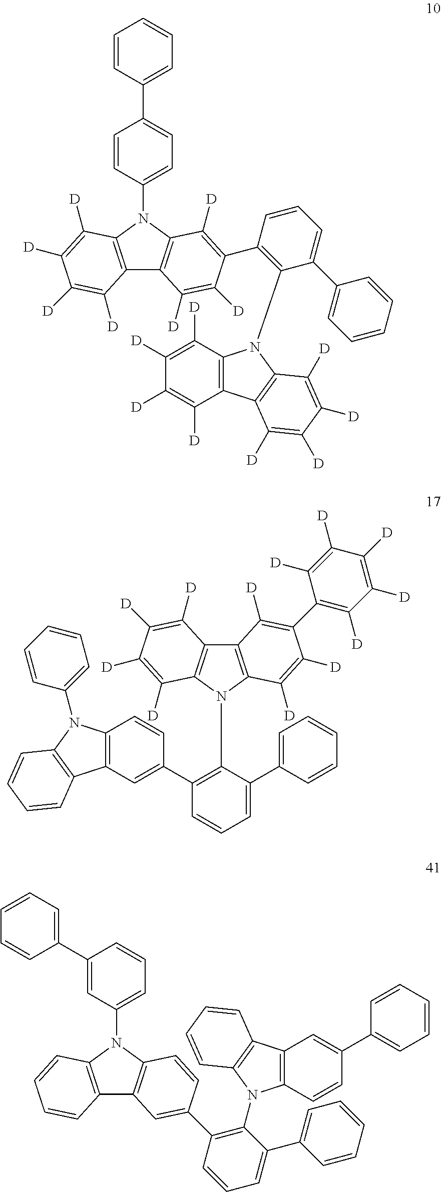 [SMILES: [2H]c1c([2H])c([2H])c2c(c1[2H])c1c([2H])c([2H])c(-c3cccc(-c4ccccc4)c3-n3c4c([2H])c([2H])c([2H])c([2H])c4c4c([2H])c([2H])c([2H])c([2H])c43)c([2H])c1n2-c1ccc(-c2ccccc2)cc1 ; [2H]c1c([2H])c([2H])c(-c2c([2H])c([2H])c3c(c2[2H])c2c([2H])c([2H])c([2H])c([2H])c2n3-c2c(-c3ccccc3)cccc2-c2ccc3c(c2)c2ccccc2n3-c2ccccc2)c([2H])c1[2H] ; c1ccc(-c2cccc(-n3c4ccccc4c4cc(-c5cccc(-c6ccccc6)c5-n5c6ccccc6c6cc(-c7ccccc7)ccc65)ccc43)c2)cc1]

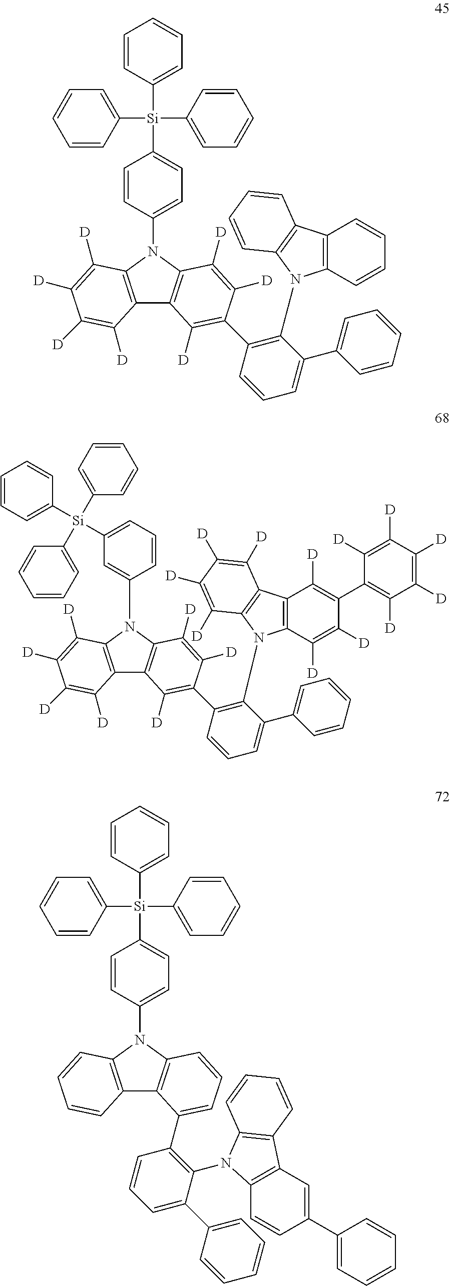 [SMILES: [2H]c1c([2H])c([2H])c2c(c1[2H])c1c([2H])c(-c3cccc(-c4ccccc4)c3-n3c4ccccc4c4ccccc43)c([2H])c([2H])c1n2-c1ccc([Si](c2ccccc2)(c2ccccc2)c2ccccc2)cc1 ; [2H]c1c([2H])c([2H])c(-c2c([2H])c([2H])c3c(c2[2H])c2c([2H])c([2H])c([2H])c([2H])c2n3-c2c(-c3ccccc3)cccc2-c2c([2H])c([2H])c3c(c2[2H])c2c([2H])c([2H])c([2H])c([2H])c2n3-c2cccc([Si](c3ccccc3)(c3ccccc3)c3ccccc3)c2)c([2H])c1[2H] ; c1ccc(-c2ccc3c(c2)c2ccccc2n3-c2c(-c3ccccc3)cccc2-c2cccc3c2c2ccccc2n3-c2ccc([Si](c3ccccc3)(c3ccccc3)c3ccccc3)cc2)cc1]

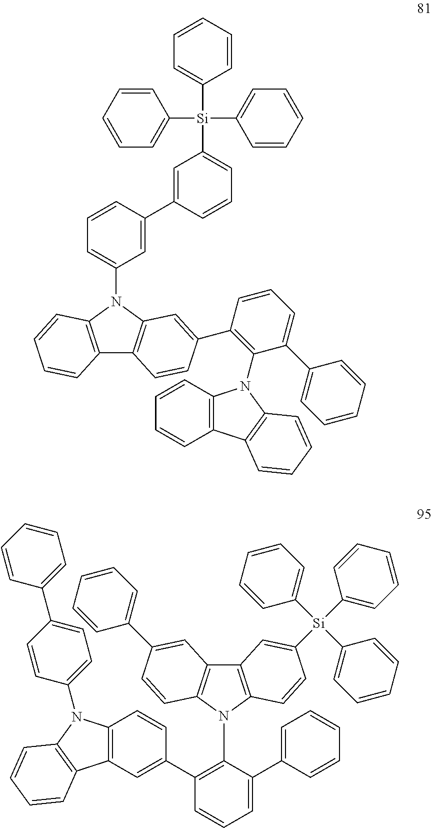 [SMILES: c1ccc(-c2cccc(-c3ccc4c5ccccc5n(-c5cccc(-c6cccc([Si](c7ccccc7)(c7ccccc7)c7ccccc7)c6)c5)c4c3)c2-n2c3ccccc3c3ccccc32)cc1 ; c1ccc(-c2ccc(-n3c4ccccc4c4cc(-c5cccc(-c6ccccc6)c5-n5c6ccc(-c7ccccc7)cc6c6cc([Si](c7ccccc7)(c7ccccc7)c7ccccc7)ccc65)ccc43)cc2)cc1]

### Comparative Compound

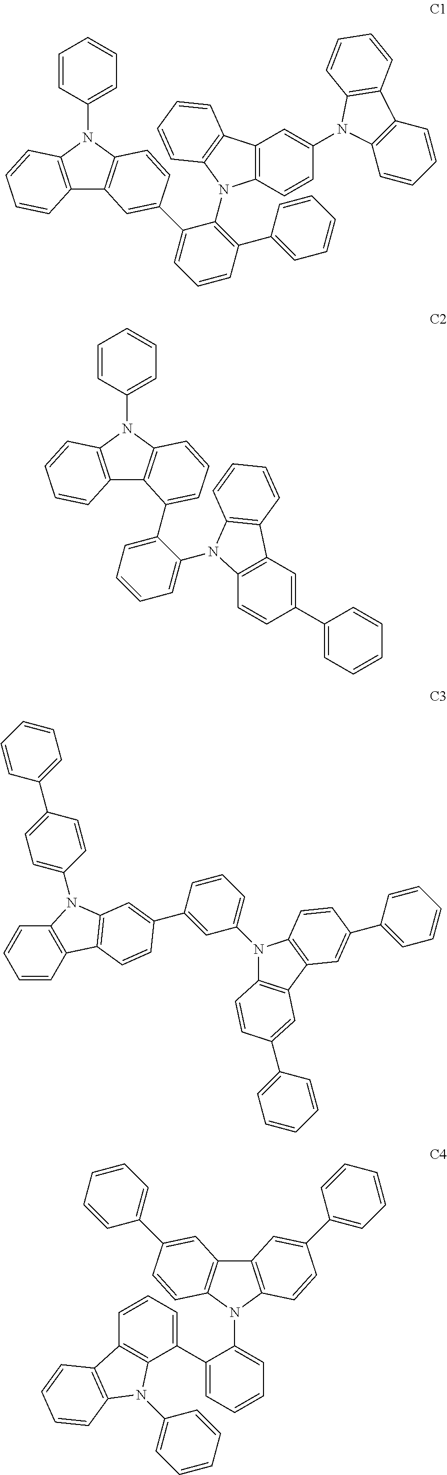 [SMILES: c1ccc(-c2cccc(-c3ccc4c(c3)c3ccccc3n4-c3ccccc3)c2-n2c3ccccc3c3cc(-n4c5ccccc5c5ccccc54)ccc32)cc1 ; c1ccc(-c2ccc3c(c2)c2ccccc2n3-c2ccccc2-c2cccc3c2c2ccccc2n3-c2ccccc2)cc1 ; c1ccc(-c2ccc(-n3c4ccccc4c4ccc(-c5cccc(-n6c7ccc(-c8ccccc8)cc7c7cc(-c8ccccc8)ccc76)c5)cc43)cc2)cc1 ; c1ccc(-c2ccc3c(c2)c2cc(-c4ccccc4)ccc2n3-c2ccccc2-c2cccc3c4ccccc4n(-c4ccccc4)c23)cc1]

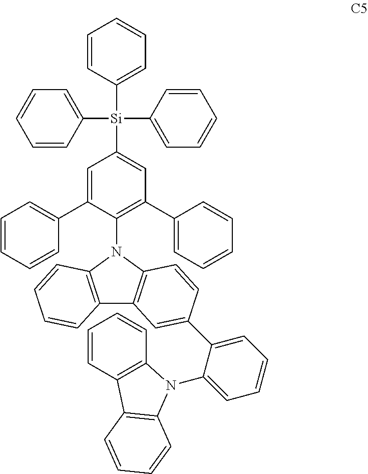 [SMILES: c1ccc(-c2cc([Si](c3ccccc3)(c3ccccc3)c3ccccc3)cc(-c3ccccc3)c2-n2c3ccccc3c3cc(-c4ccccc4-n4c5ccccc5c5ccccc54)ccc32)cc1]

### Manufacture of Light-Emitting Diode

For manufacturing each of the light-emitting diodes of Examples and Comparative Examples, an ITO glass substrate (product of Corning Inc.) as an anode having an ITO electrode with 15 Ω/cm² (1200 Å) was cut into a size of 50 mm×50 mm×0.5 mm, washed by ultrasonic waves with isopropyl alcohol and then distilled water for 5 minutes each, and cleaned by irradiating ultraviolet rays for 30 minutes and then, ozone. Then, the ITO glass substrate was installed in a vacuum deposition apparatus.

On the anode, a hole injection layer with a thickness of 100 Å was manufactured by depositing HATCN, and on the hole injection layer, a first hole transport layer with a thickness of 600 Å was manufactured by vacuum depositing BCFN. On the first hole transport layer, a second hole transport layer with a thickness of 50 Å was manufactured by depositing SiCzCz, to form a hole transport layer.

Then, the Example Compound according to one or more embodiments or Comparative Compound as a first compound, SiTrzCz2 as a second compound, and PtON-TBBI as a third compound were co-deposited in a weight ratio of 60:27:13 to form a light-emitting layer with a thickness of 350 Å. Then, mSiTrz was deposited on the light-emitting layer to form a first electron transport layer with a thickness of 50 Å. Subsequently, mSiTrz and LiQ were concurrently (e.g., simultaneously) deposited in a weight ratio of 1:1 on the first electron transport layer to form a second electron transport layer of 350 Å. On the second electron transport layer, halogenated alkali metal LiF was deposited with a thickness of 15 Å to form an electron injection layer, and Al was vacuum-deposited with a thickness of 80 Å to form a LiF/Al electrode. Then, the light-emitting diode was manufactured by having a capping layer having a thickness of 600 Å with CP4 on the Al electrode. In one or more embodiments, all layers were manufactured by a vacuum deposition method.

The compounds utilized for the manufacture of the light-emitting diodes of Examples and Comparative Examples are shown below. The materials below were utilized after performing sublimation purification on their commercial products.

### Materials Utilized for Manufacture of Light-Emitting Diode

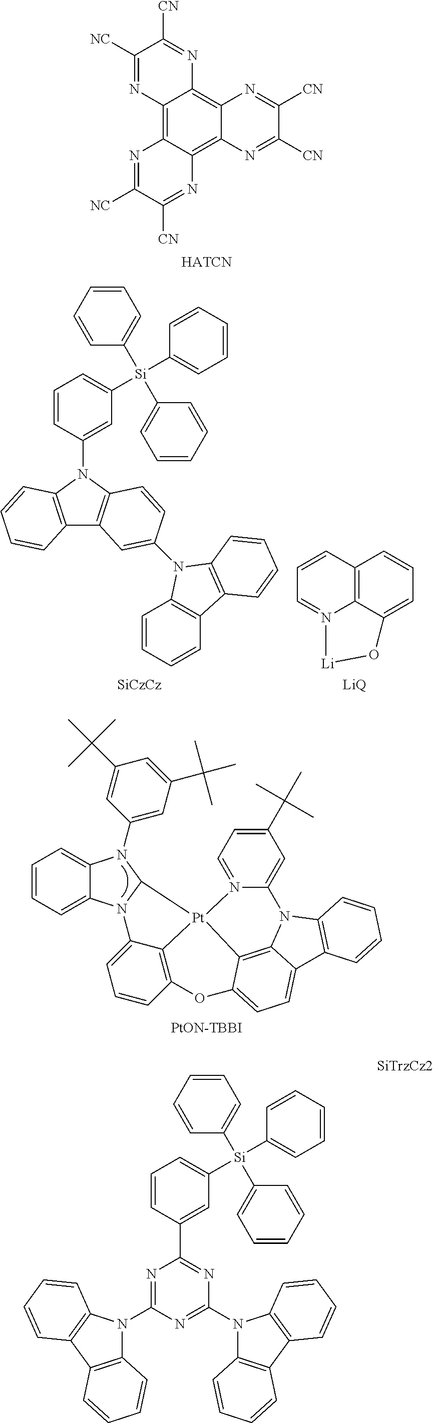

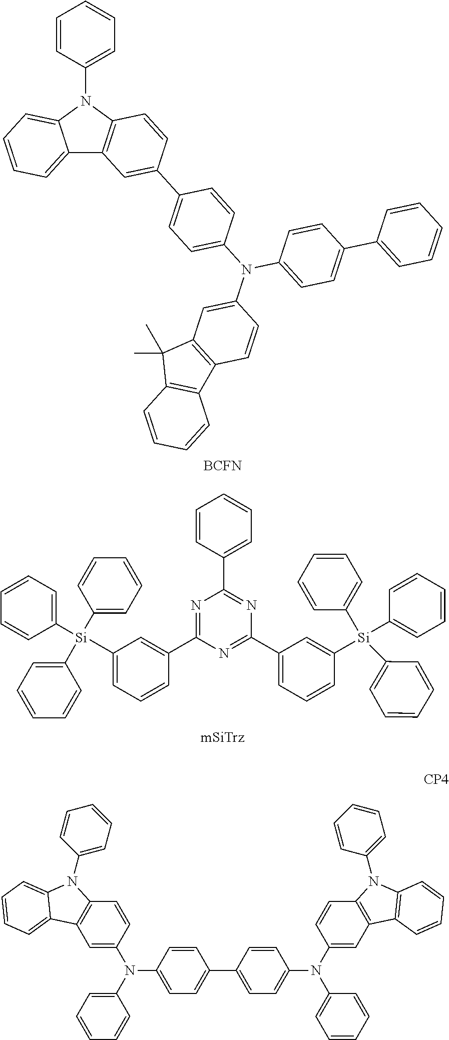

### Evaluation of Properties of Light-Emitting Diodes

The device efficiency of each of the light-emitting diodes manufactured utilizing Example Compounds 10, 17, 41, 45, 68, 72, 81, and 95, and Comparative Compounds C1 to C5, respectively, was evaluated. In Table 2, the evaluation results for each of the light-emitting diodes of Examples 1 to 8, and Comparative Examples 1 to 5 are shown. In order to evaluate the properties of the light emitting diodes manufactured in Examples 1 to 8 and Comparative Examples 1 to 5, a driving voltage (V) at a current density of about 10 mA/cm², and maximum quantum efficiency (%) were measured utilizing a source meter (Keithley, 2400 series) and an external quantum efficiency measurement apparatus (Hamamatsu Photonics, 09920-2-12). In the evaluation of the maximum quantum efficiency (%), luminance/current density was measured, and the maximum quantum efficiency (%) was converted supposing angular luminance distribution introducing Lambertian surface.

TABLE 2

| | | | | Maximum | |
|---|---|---|---|---|---|
| | | Driving | Current | quantum | Emis- |
| | Host | voltage | density | efficiency | sion |
| Category | material | (V) | (mA/cm²) | (%) | color |
| Example 1 | Compound 10 | 4.6 | 10 | 24.4 | Blue |
| Example 2 | Compound 17 | 4.4 | 10 | 27.3 | Blue |
| Example 3 | Compound 41 | 4.5 | 10 | 27.1 | Blue |
| Example 4 | Compound 45 | 4.6 | 10 | 26.2 | Blue |
| Example 5 | Compound 68 | 4.5 | 10 | 26.5 | Blue |
| Example 6 | Compound 72 | 4.8 | 10 | 25.9 | Blue |
| Example 7 | Compound 81 | 4.7 | 10 | 24.1 | Blue |
| Example 8 | Compound 95 | 4.7 | 10 | 25.3 | Blue |
| Comparative | Comparative | 4.9 | 10 | 22.7 | Blue |
| Example 1 | Compound C1 | | | | |
| Comparative | Comparative | 5.3 | 10 | 22.2 | Blue |
| Example 2 | Compound C2 | | | | |
| Comparative | Comparative | 5.1 | 10 | 21.6 | Blue |
| Example 3 | Compound C3 | | | | |
| Comparative | Comparative | 5.2 | 10 | 22.5 | Blue |
| Example 4 | Compound C4 | | | | |
| Comparative | Comparative | 5.2 | 10 | 23.1 | Blue |
| Example 5 | Compound C5 | | | | |

From Table 2, it was confirmed that the light-emitting diode according to Examples 1 through 8 each had low driving voltage and high efficiency properties, compared to the light-emitting diodes according to Comparative Examples 1 through 5.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

In the context of the present application and unless otherwise defined, the terms “use,” “using,” and “used” may be considered synonymous with the terms “utilize,” “utilizing,” and “utilized,” respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this disclosure, including the claims, to expressly recite any sub-range subsumed within the ranges expressly recited herein.

The light emitting element, the display apparatus/device, the electronic apparatus, a device for manufacturing the same, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

In the present disclosure, each suitable feature of the various embodiments of the disclosure may be combined or combined with each other, partially or entirely, and may be technically interlocked and operated in various suitable ways, and each embodiment may be implemented independently of each other or in conjunction with each other in any suitable manner unless otherwise stated or implied.

While certain embodiments of the present disclosure have been described above, anyone ordinarily skilled in the art to which the present disclosure pertains shall appreciate that there may be a variety of modifications and permutations of the present disclosure without departing from the technical ideas and scopes of the present disclosure that are defined in the appended claims. Therefore, the technical scope of the present disclosure should be interpreted by the scope of the claims and equivalents thereof, instead of being restricted the disclosed description in Detailed Description.

What is claimed is:

1. A light-emitting diode, comprising:
a first electrode;
a second electrode opposite to the first electrode; and
a light-emitting layer between the first electrode and the second electrode,
wherein the light-emitting layer comprises a first compound represented by Formula 1: 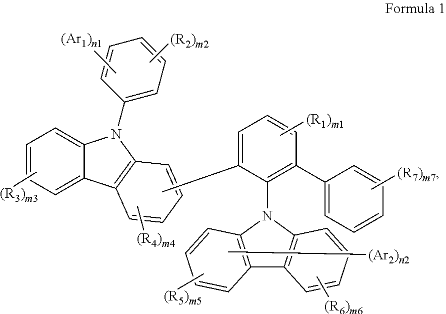
wherein in Formula 1:
each of Ar₁ and Ar₂ is independently represented by Formula 2 or Formula 3;
each of n1 and n2 is independently an integer between 0 and 2, inclusive;
each of R₁ through R₇ is independently hydrogen, deuterium, halogens, a substituted or unsubstituted alkyl group having 1 to 20 carbons, or a substituted or unsubstituted aryl group having 6 to 30 ring-forming carbons;
each of m1 and m4 is independently an integer between 0 and 3, inclusive;
each of m2 and m7 is independently an integer between 0 and 5, inclusive; and
each of m3, m5, and m6 is independently an integer between 0 and 4, inclusive, and 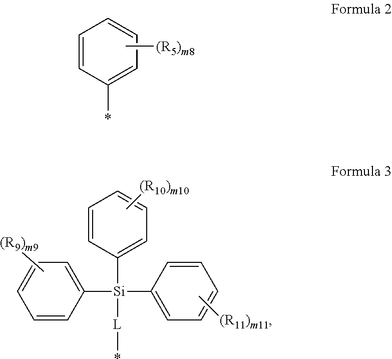
and
wherein in Formula 2 and Formula 3:
each of R₈ through R₁₁ is independently hydrogen, deuterium, a substituted or unsubstituted silyl group, or a substituted or unsubstituted aryl group having 6 to 60 ring-forming carbons;
each of m8 through m11 is independently an integer between 0 and 5, inclusive;
L is a direct linkage or a substituted or unsubstituted arylene group having 6 to 30 ring-forming carbons; and [symbol]
is a site of binding to a corresponding moiety of Formula 1.

2. The light-emitting diode of claim 1, wherein the first compound represented by Formula 1 is represented by any formula selected from among Formula 1-1 through Formula 1-4: 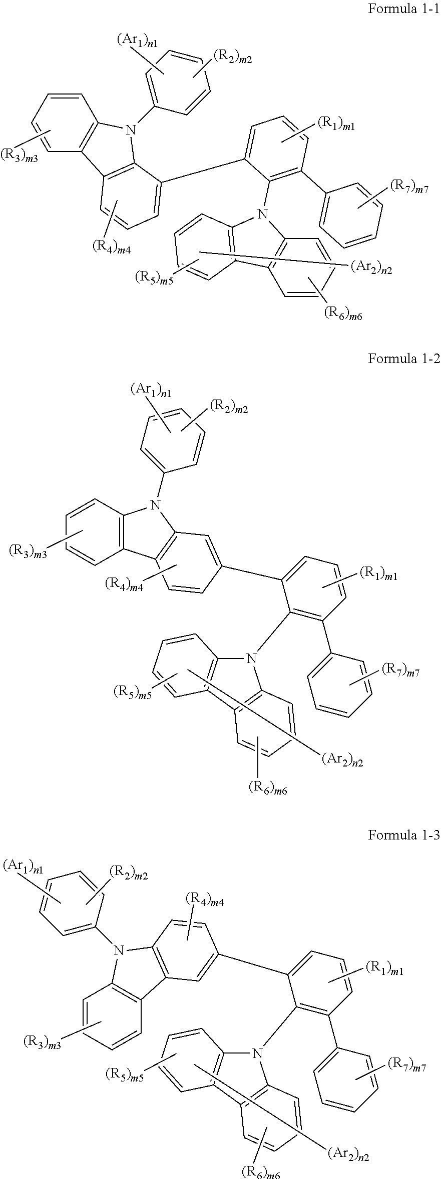 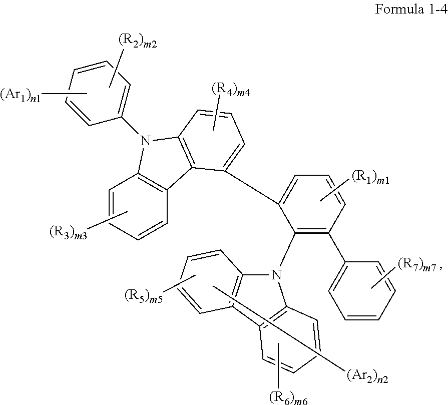
in Formulae 1-1 through 1-4, Ar₁, Ar₂, n1, n2, R₁ through R₇, and m1 through m7 being each the same as defined in Formula 1.

3. The light-emitting diode of claim 1,
wherein R₇ is hydrogen or deuterium, and m7 is 5.

4. The light-emitting diode of claim 1,
wherein L is a direct linkage, a substituted or unsubstituted phenylene group, or a phenylene group substituted with deuterium.

5. The light-emitting diode of claim 1,
wherein the first compound represented by Formula 1 is represented by any formula selected from among Formula 1-5 through Formula 1-15: 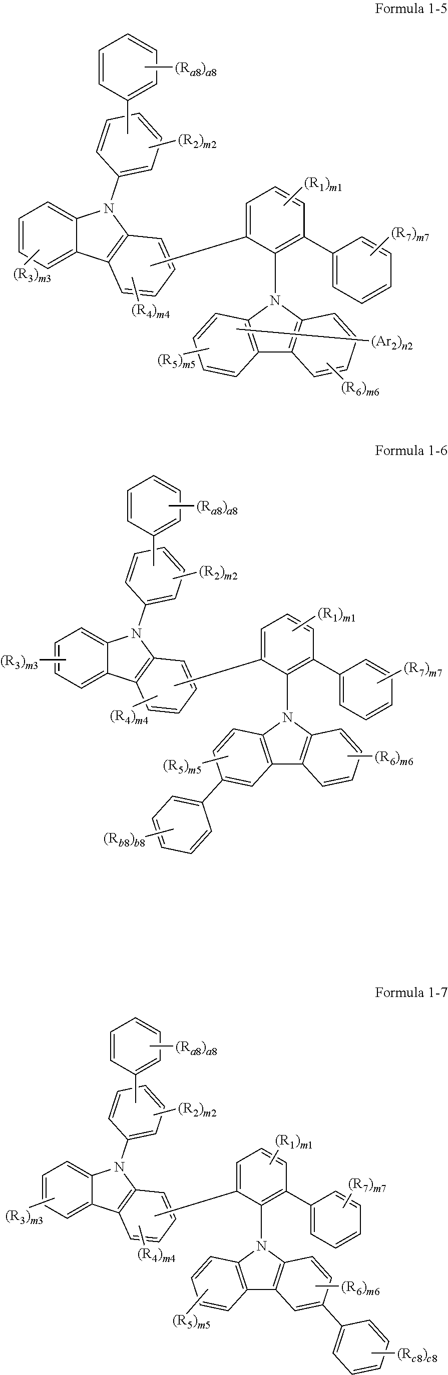 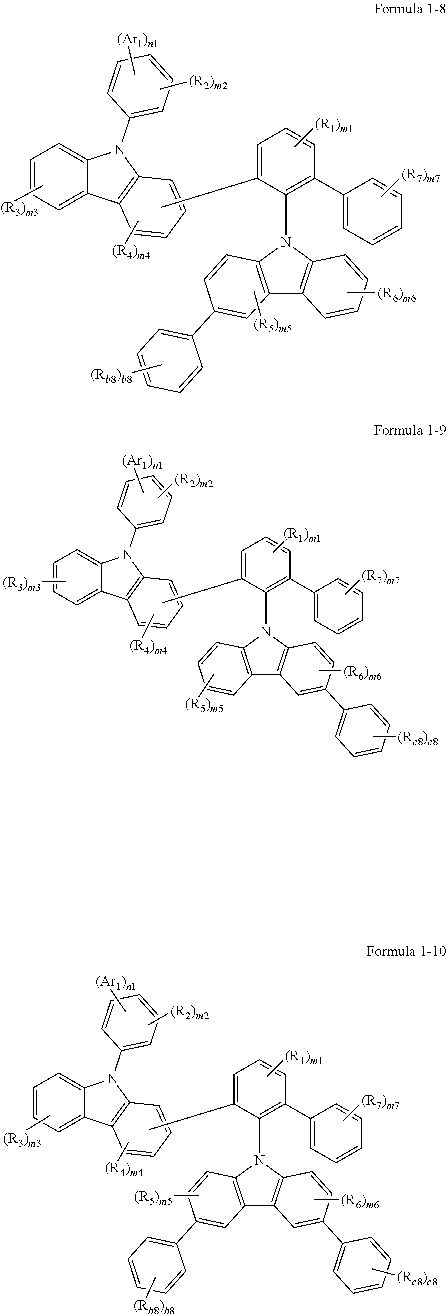 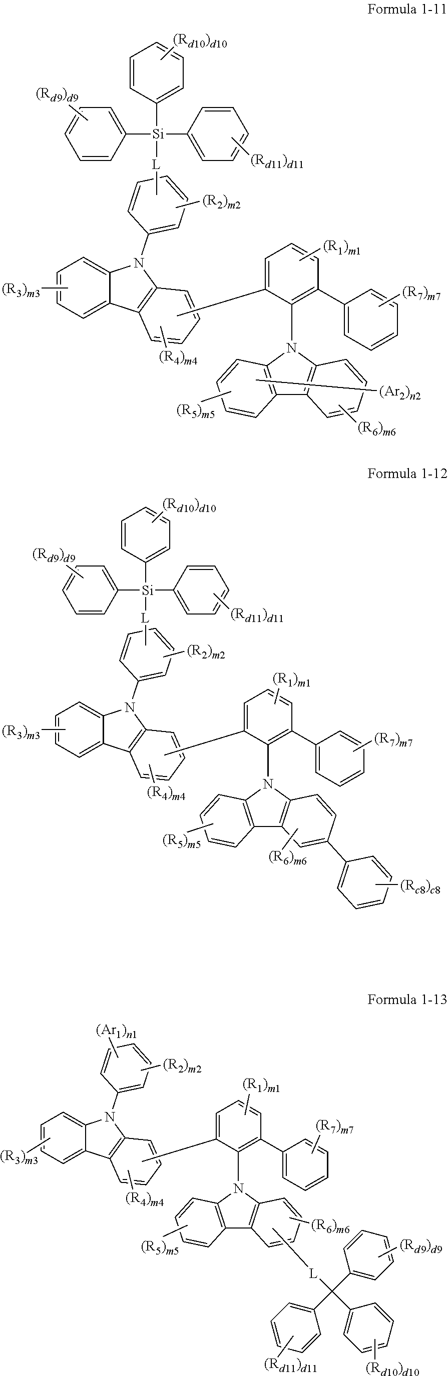 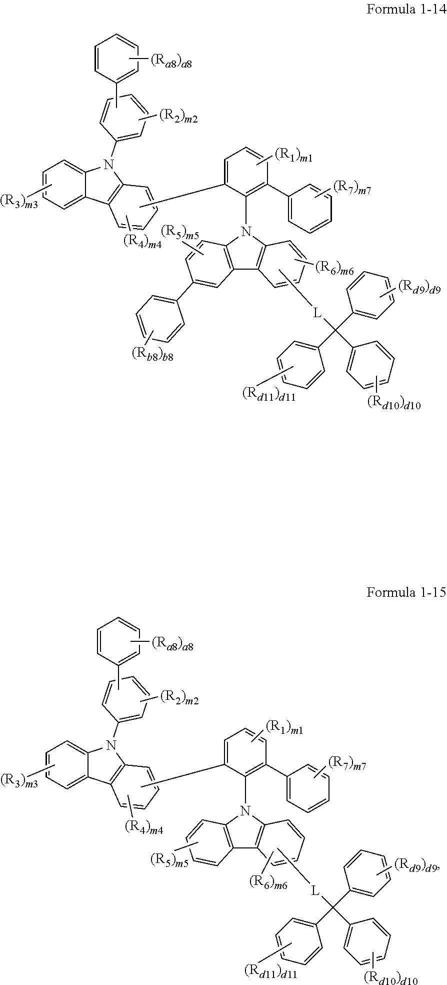
and
wherein in Formula 1-5 through Formula 1-15,
each of Rₐ₈, R_{b8}, R_{c8}, R_{d9}, R_{d10}, and R_{d11} is independently hydrogen, deuterium, a substituted or unsubstituted silyl group, or a substituted or unsubstituted aryl group having 6 to 60 ring-forming carbons,
each of a8, b8, c8, d9, d10, and d11 is independently an integer between 0 and 5, inclusive, and
Ar₁, Ar₂, n1, n2, R₁ through R₇, m1 through m7, and L are each the same as defined in Formula 1.

6. The light-emitting diode of claim 1,
wherein the first compound represented by Formula 1 comprises at least one selected from among compounds of Compound Group 1: 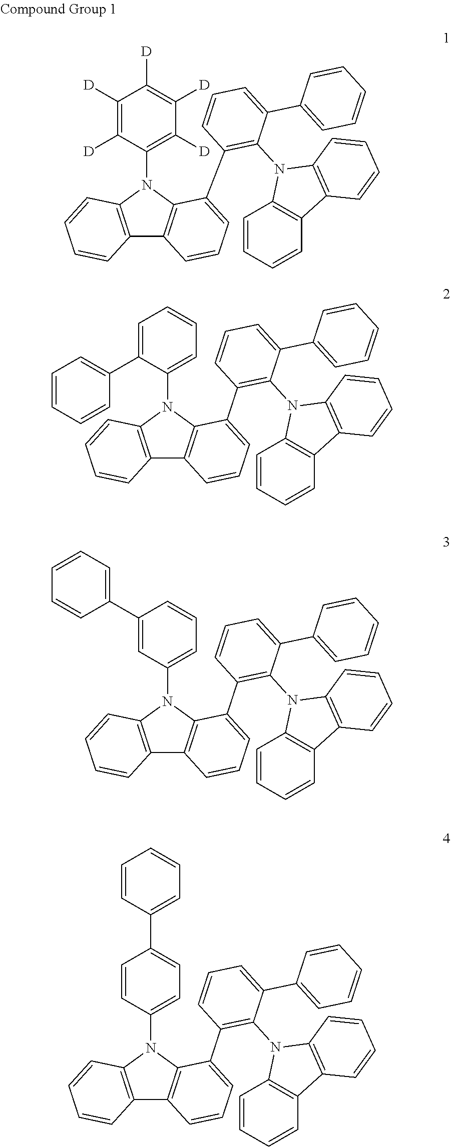 [SMILES: [2H]c1c([2H])c([2H])c(-n2c3ccccc3c3cccc(-c4cccc(-c5ccccc5)c4-n4c5ccccc5c5ccccc54)c32)c([2H])c1[2H] ; c1ccc(-c2ccccc2-n2c3ccccc3c3cccc(-c4cccc(-c5ccccc5)c4-n4c5ccccc5c5ccccc54)c32)cc1 ; c1ccc(-c2cccc(-n3c4ccccc4c4cccc(-c5cccc(-c6ccccc6)c5-n5c6ccccc6c6ccccc65)c43)c2)cc1 ; c1ccc(-c2ccc(-n3c4ccccc4c4cccc(-c5cccc(-c6ccccc6)c5-n5c6ccccc6c6ccccc65)c43)cc2)cc1] 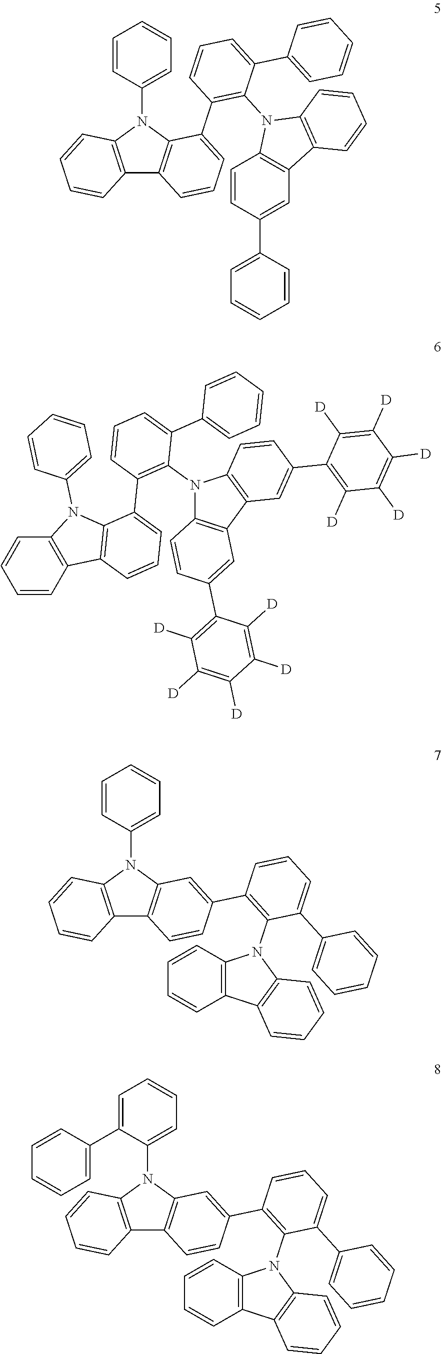 [SMILES: c1ccc(-c2ccc3c(c2)c2ccccc2n3-c2c(-c3ccccc3)cccc2-c2cccc3c4ccccc4n(-c4ccccc4)c23)cc1 ; [2H]c1c([2H])c([2H])c(-c2ccc3c(c2)c2cc(-c4c([2H])c([2H])c([2H])c([2H])c4[2H])ccc2n3-c2c(-c3ccccc3)cccc2-c2cccc3c4ccccc4n(-c4ccccc4)c23)c([2H])c1[2H] ; c1ccc(-c2cccc(-c3ccc4c5ccccc5n(-c5ccccc5)c4c3)c2-n2c3ccccc3c3ccccc32)cc1 ; c1ccc(-c2ccccc2-n2c3ccccc3c3ccc(-c4cccc(-c5ccccc5)c4-n4c5ccccc5c5ccccc54)cc32)cc1] 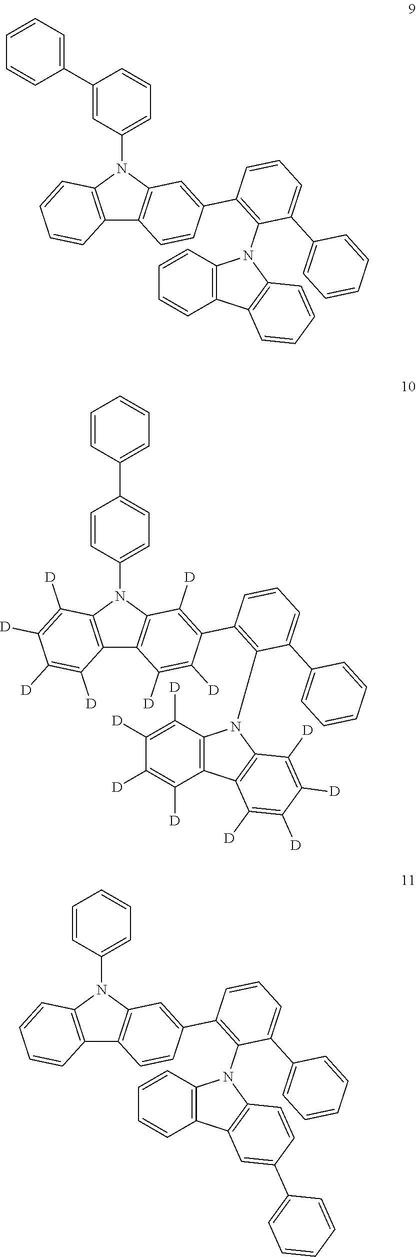 [SMILES: c1ccc(-c2cccc(-n3c4ccccc4c4ccc(-c5cccc(-c6ccccc6)c5-n5c6ccccc6c6ccccc65)cc43)c2)cc1 ; [2H]c1c([2H])c([2H])c2c(c1[2H])c1c([2H])c([2H])c(-c3cccc(-c4ccccc4)c3-n3c4c([2H])c([2H])c([2H])c([2H])c4c4c([2H])c([2H])c([2H])c([2H])c43)c([2H])c1n2-c1ccc(-c2ccccc2)cc1 ; c1ccc(-c2ccc3c(c2)c2ccccc2n3-c2c(-c3ccccc3)cccc2-c2ccc3c4ccccc4n(-c4ccccc4)c3c2)cc1] 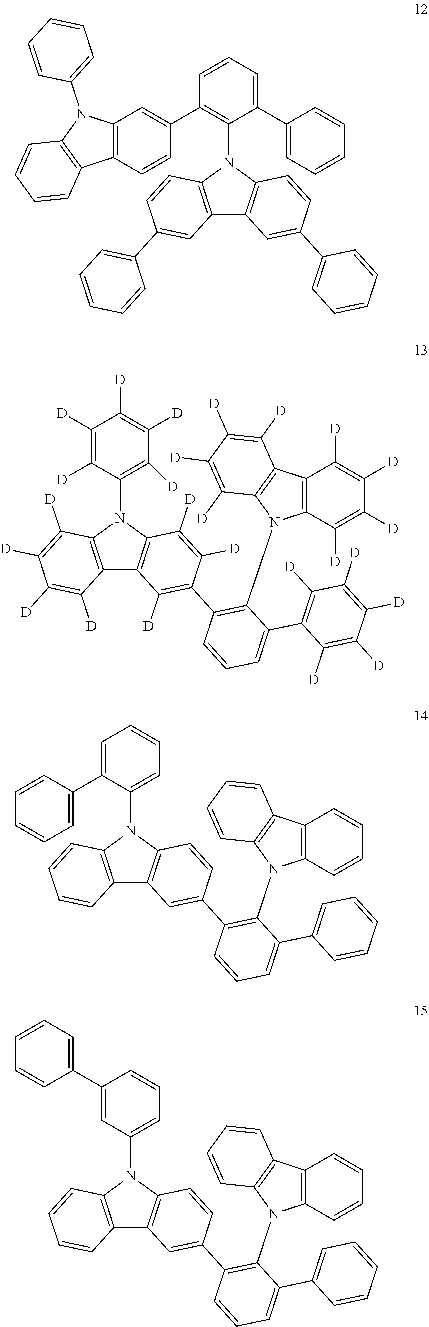 [SMILES: c1ccc(-c2ccc3c(c2)c2cc(-c4ccccc4)ccc2n3-c2c(-c3ccccc3)cccc2-c2ccc3c4ccccc4n(-c4ccccc4)c3c2)cc1 ; [2H]c1c([2H])c([2H])c(-c2cccc(-c3c([2H])c([2H])c4c(c3[2H])c3c([2H])c([2H])c([2H])c([2H])c3n4-c3c([2H])c([2H])c([2H])c([2H])c3[2H])c2-n2c3c([2H])c([2H])c([2H])c([2H])c3c3c([2H])c([2H])c([2H])c([2H])c32)c([2H])c1[2H] ; c1ccc(-c2ccccc2-n2c3ccccc3c3cc(-c4cccc(-c5ccccc5)c4-n4c5ccccc5c5ccccc54)ccc32)cc1 ; c1ccc(-c2cccc(-n3c4ccccc4c4cc(-c5cccc(-c6ccccc6)c5-n5c6ccccc6c6ccccc65)ccc43)c2)cc1] 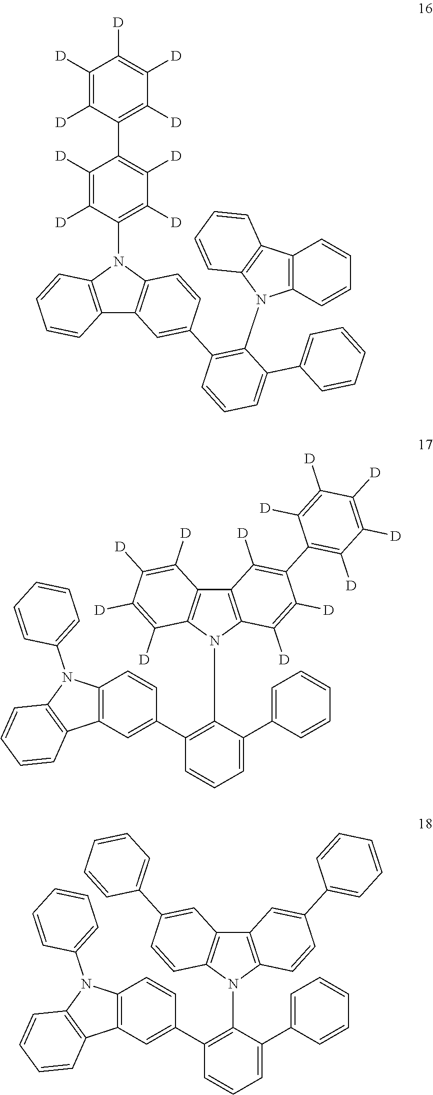 [SMILES: [2H]c1c([2H])c([2H])c(-c2c([2H])c([2H])c(-n3c4ccccc4c4cc(-c5cccc(-c6ccccc6)c5-n5c6ccccc6c6ccccc65)ccc43)c([2H])c2[2H])c([2H])c1[2H] ; [2H]c1c([2H])c([2H])c(-c2c([2H])c([2H])c3c(c2[2H])c2c([2H])c([2H])c([2H])c([2H])c2n3-c2c(-c3ccccc3)cccc2-c2ccc3c(c2)c2ccccc2n3-c2ccccc2)c([2H])c1[2H] ; c1ccc(-c2ccc3c(c2)c2cc(-c4ccccc4)ccc2n3-c2c(-c3ccccc3)cccc2-c2ccc3c(c2)c2ccccc2n3-c2ccccc2)cc1] 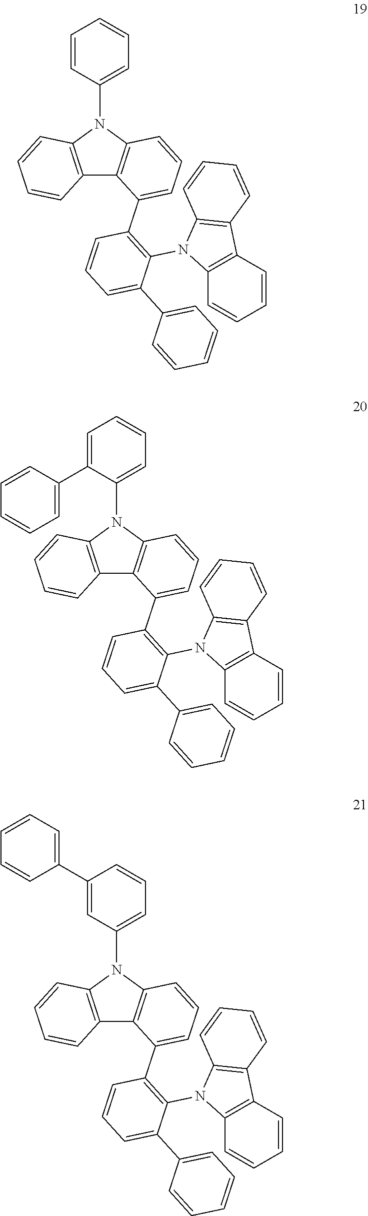 [SMILES: c1ccc(-c2cccc(-c3cccc4c3c3ccccc3n4-c3ccccc3)c2-n2c3ccccc3c3ccccc32)cc1 ; c1ccc(-c2ccccc2-n2c3ccccc3c3c(-c4cccc(-c5ccccc5)c4-n4c5ccccc5c5ccccc54)cccc32)cc1 ; c1ccc(-c2cccc(-n3c4ccccc4c4c(-c5cccc(-c6ccccc6)c5-n5c6ccccc6c6ccccc65)cccc43)c2)cc1] 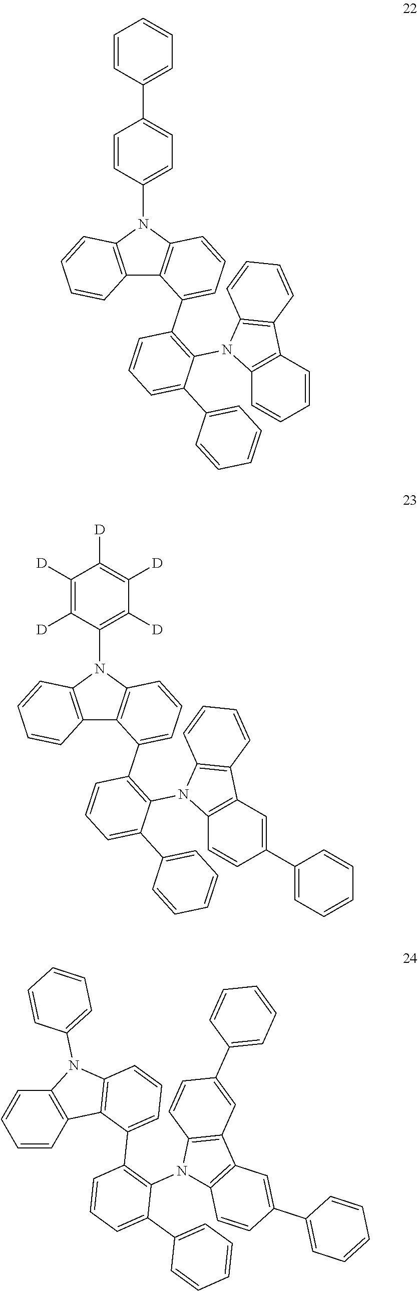 [SMILES: c1ccc(-c2ccc(-n3c4ccccc4c4c(-c5cccc(-c6ccccc6)c5-n5c6ccccc6c6ccccc65)cccc43)cc2)cc1 ; [2H]c1c([2H])c([2H])c(-n2c3ccccc3c3c(-c4cccc(-c5ccccc5)c4-n4c5ccccc5c5cc(-c6ccccc6)ccc54)cccc32)c([2H])c1[2H] ; c1ccc(-c2ccc3c(c2)c2cc(-c4ccccc4)ccc2n3-c2c(-c3ccccc3)cccc2-c2cccc3c2c2ccccc2n3-c2ccccc2)cc1] 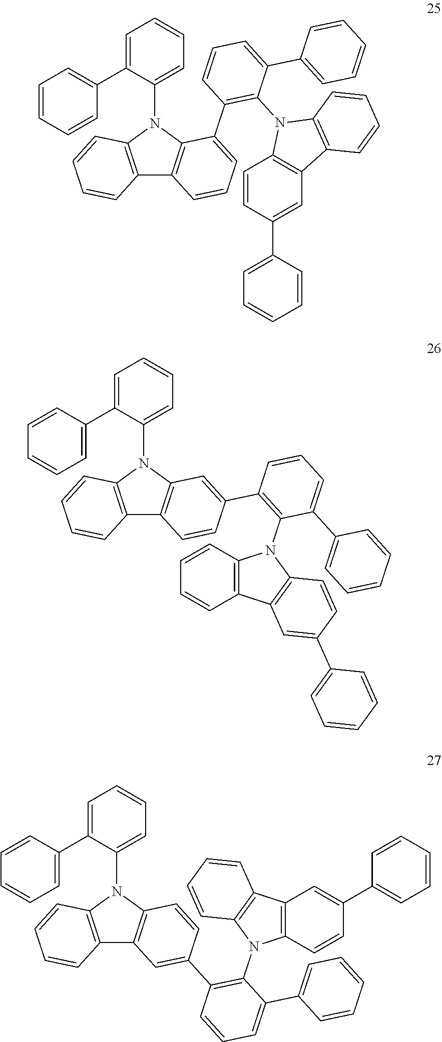 [SMILES: c1ccc(-c2ccc3c(c2)c2ccccc2n3-c2c(-c3ccccc3)cccc2-c2cccc3c4ccccc4n(-c4ccccc4-c4ccccc4)c23)cc1 ; c1ccc(-c2ccc3c(c2)c2ccccc2n3-c2c(-c3ccccc3)cccc2-c2ccc3c4ccccc4n(-c4ccccc4-c4ccccc4)c3c2)cc1 ; c1ccc(-c2ccc3c(c2)c2ccccc2n3-c2c(-c3ccccc3)cccc2-c2ccc3c(c2)c2ccccc2n3-c2ccccc2-c2ccccc2)cc1] 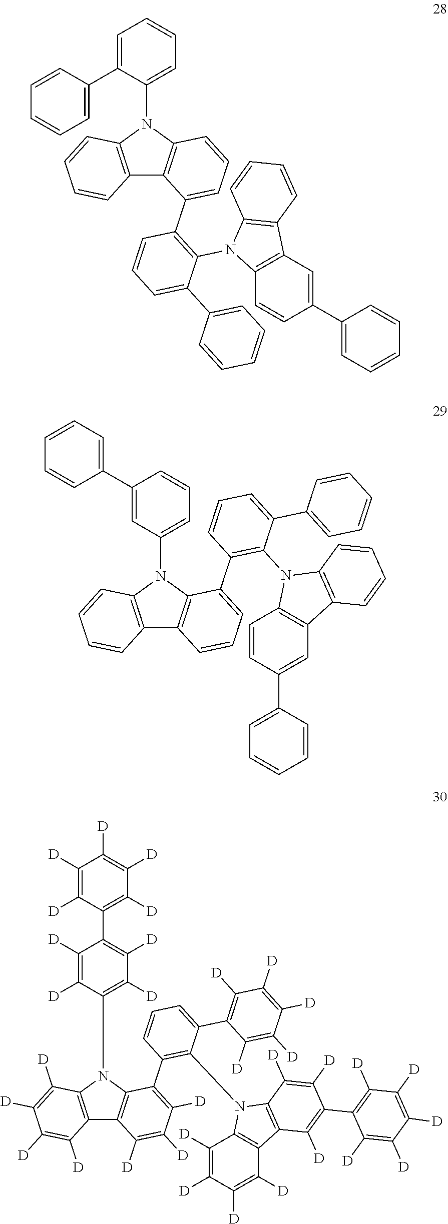 [SMILES: c1ccc(-c2ccc3c(c2)c2ccccc2n3-c2c(-c3ccccc3)cccc2-c2cccc3c2c2ccccc2n3-c2ccccc2-c2ccccc2)cc1 ; c1ccc(-c2cccc(-n3c4ccccc4c4cccc(-c5cccc(-c6ccccc6)c5-n5c6ccccc6c6cc(-c7ccccc7)ccc65)c43)c2)cc1 ; [2H]c1c([2H])c([2H])c(-c2cccc(-c3c([2H])c([2H])c([2H])c4c5c([2H])c([2H])c([2H])c([2H])c5n(-c5c([2H])c([2H])c(-c6c([2H])c([2H])c([2H])c([2H])c6[2H])c([2H])c5[2H])c34)c2-n2c3c([2H])c([2H])c([2H])c([2H])c3c3c([2H])c(-c4c([2H])c([2H])c([2H])c([2H])c4[2H])c([2H])c([2H])c32)c([2H])c1[2H]] 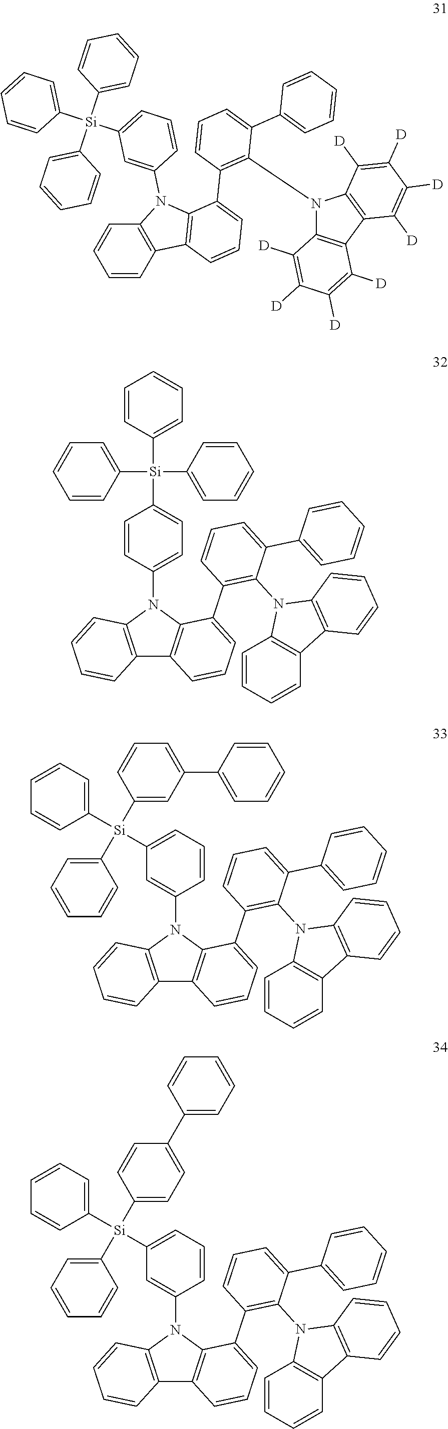 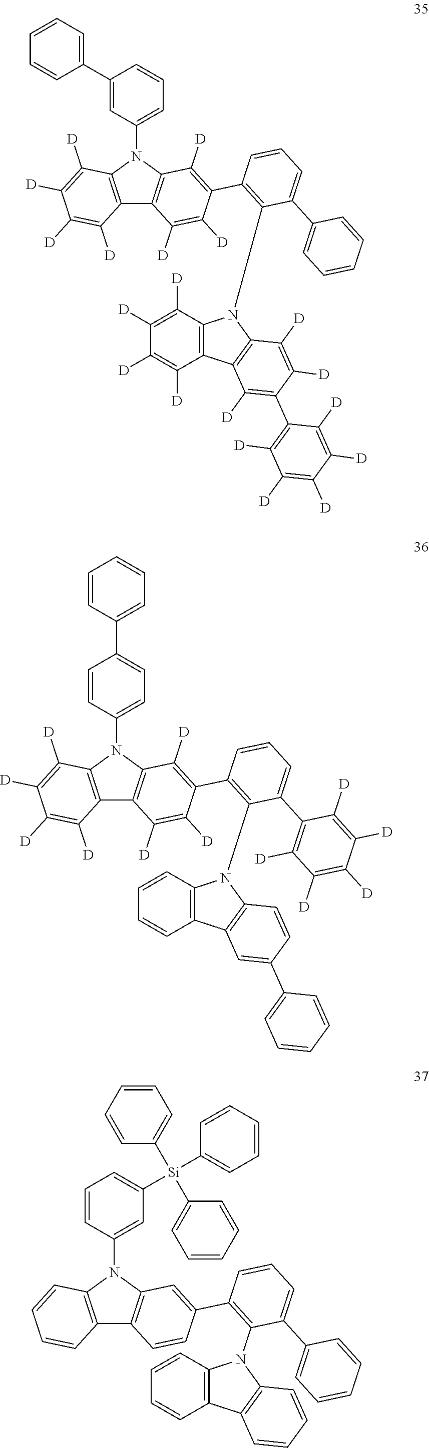 [SMILES: [2H]c1c([2H])c([2H])c(-c2c([2H])c([2H])c3c(c2[2H])c2c([2H])c([2H])c([2H])c([2H])c2n3-c2c(-c3ccccc3)cccc2-c2c([2H])c([2H])c3c4c([2H])c([2H])c([2H])c([2H])c4n(-c4cccc(-c5ccccc5)c4)c3c2[2H])c([2H])c1[2H] ; [2H]c1c([2H])c([2H])c(-c2cccc(-c3c([2H])c([2H])c4c5c([2H])c([2H])c([2H])c([2H])c5n(-c5ccc(-c6ccccc6)cc5)c4c3[2H])c2-n2c3ccccc3c3cc(-c4ccccc4)ccc32)c([2H])c1[2H] ; c1ccc(-c2cccc(-c3ccc4c5ccccc5n(-c5cccc([Si](c6ccccc6)(c6ccccc6)c6ccccc6)c5)c4c3)c2-n2c3ccccc3c3ccccc32)cc1] 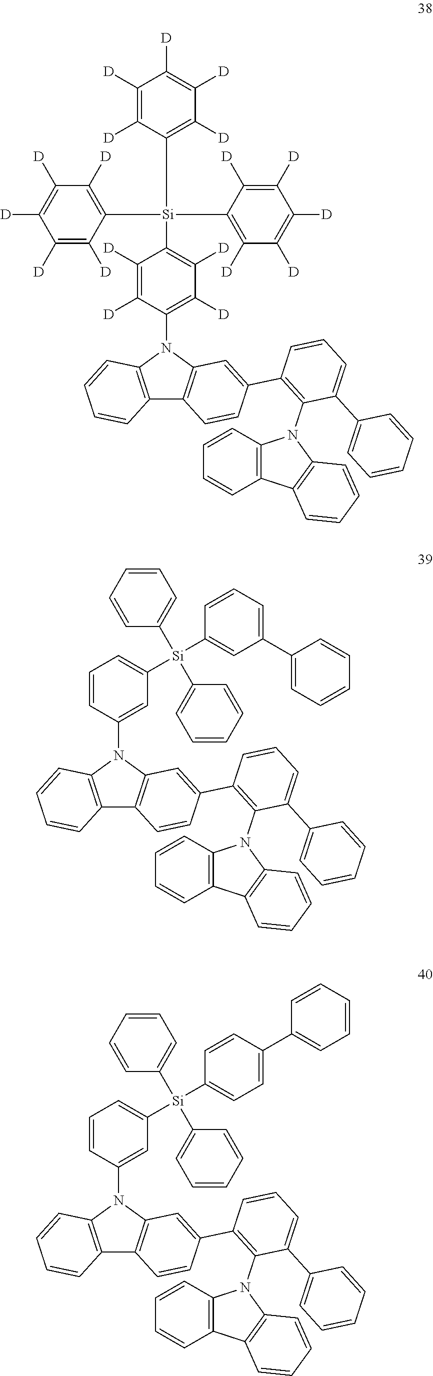 [SMILES: [2H]c1c([2H])c([2H])c([Si](c2c([2H])c([2H])c([2H])c([2H])c2[2H])(c2c([2H])c([2H])c([2H])c([2H])c2[2H])c2c([2H])c([2H])c(-n3c4ccccc4c4ccc(-c5cccc(-c6ccccc6)c5-n5c6ccccc6c6ccccc65)cc43)c([2H])c2[2H])c([2H])c1[2H] ; c1ccc(-c2cccc([Si](c3ccccc3)(c3ccccc3)c3cccc(-n4c5ccccc5c5ccc(-c6cccc(-c7ccccc7)c6-n6c7ccccc7c7ccccc76)cc54)c3)c2)cc1 ; c1ccc(-c2ccc([Si](c3ccccc3)(c3ccccc3)c3cccc(-n4c5ccccc5c5ccc(-c6cccc(-c7ccccc7)c6-n6c7ccccc7c7ccccc76)cc54)c3)cc2)cc1] 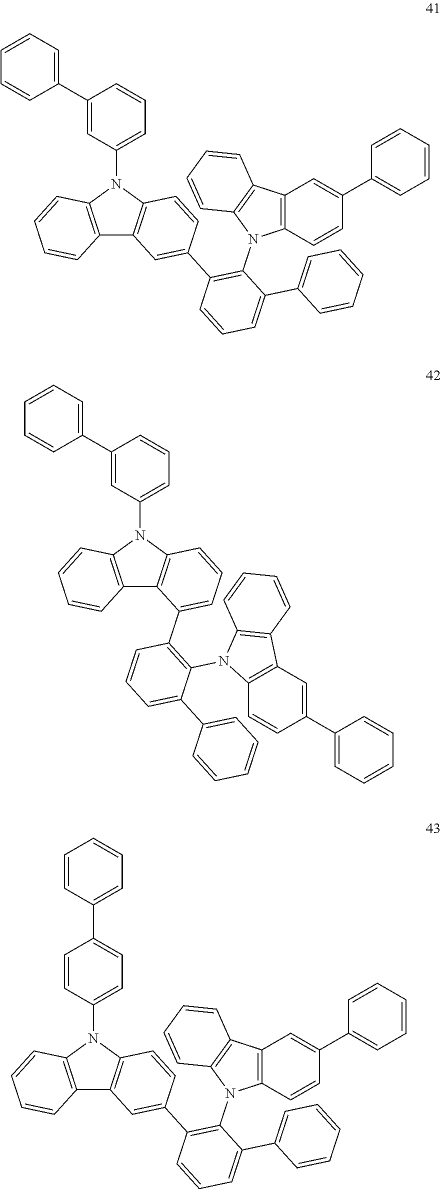 [SMILES: c1ccc(-c2cccc(-n3c4ccccc4c4cc(-c5cccc(-c6ccccc6)c5-n5c6ccccc6c6cc(-c7ccccc7)ccc65)ccc43)c2)cc1 ; c1ccc(-c2cccc(-n3c4ccccc4c4c(-c5cccc(-c6ccccc6)c5-n5c6ccccc6c6cc(-c7ccccc7)ccc65)cccc43)c2)cc1 ; c1ccc(-c2ccc(-n3c4ccccc4c4cc(-c5cccc(-c6ccccc6)c5-n5c6ccccc6c6cc(-c7ccccc7)ccc65)ccc43)cc2)cc1] 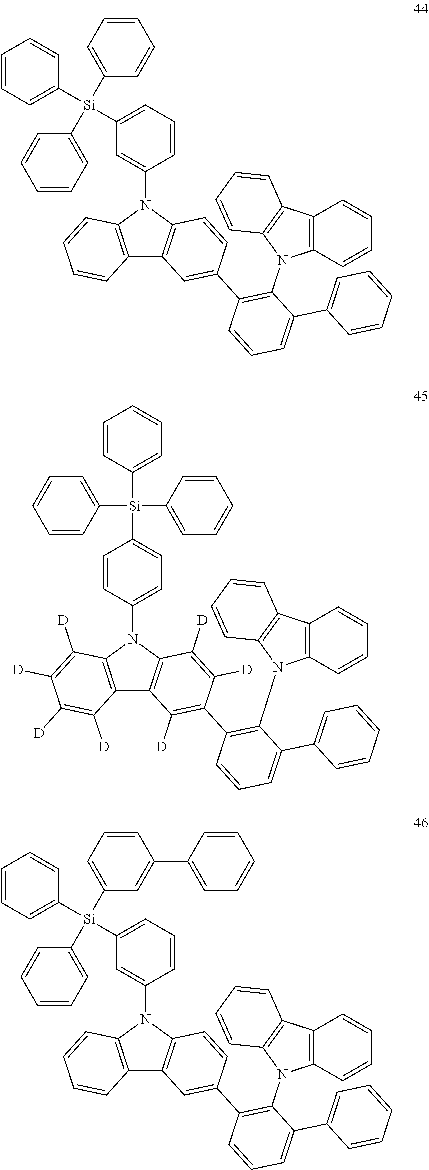 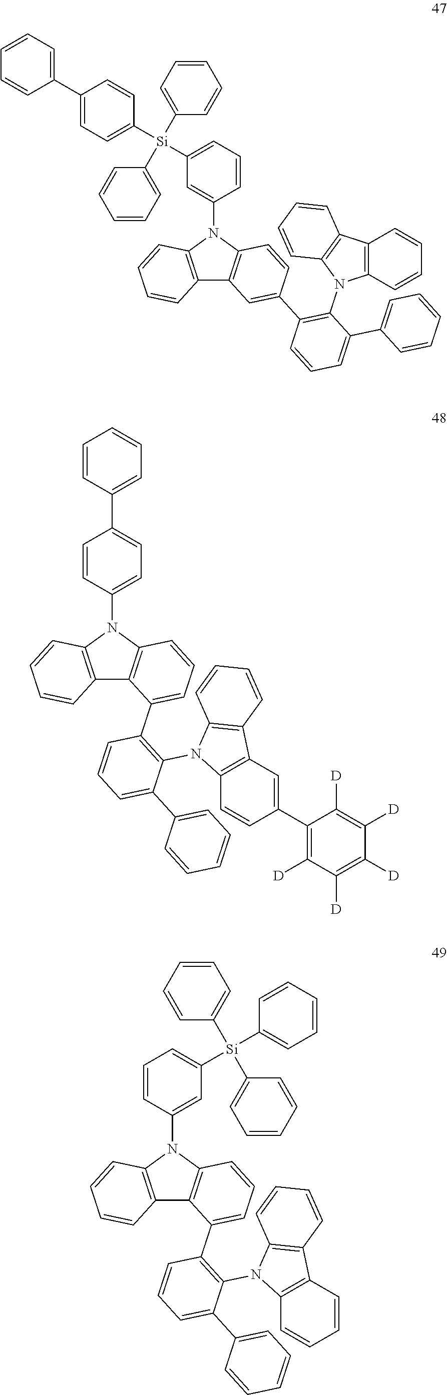 [SMILES: c1ccc(-c2ccc([Si](c3ccccc3)(c3ccccc3)c3cccc(-n4c5ccccc5c5cc(-c6cccc(-c7ccccc7)c6-n6c7ccccc7c7ccccc76)ccc54)c3)cc2)cc1 ; [2H]c1c([2H])c([2H])c(-c2ccc3c(c2)c2ccccc2n3-c2c(-c3ccccc3)cccc2-c2cccc3c2c2ccccc2n3-c2ccc(-c3ccccc3)cc2)c([2H])c1[2H] ; c1ccc(-c2cccc(-c3cccc4c3c3ccccc3n4-c3cccc([Si](c4ccccc4)(c4ccccc4)c4ccccc4)c3)c2-n2c3ccccc3c3ccccc32)cc1] 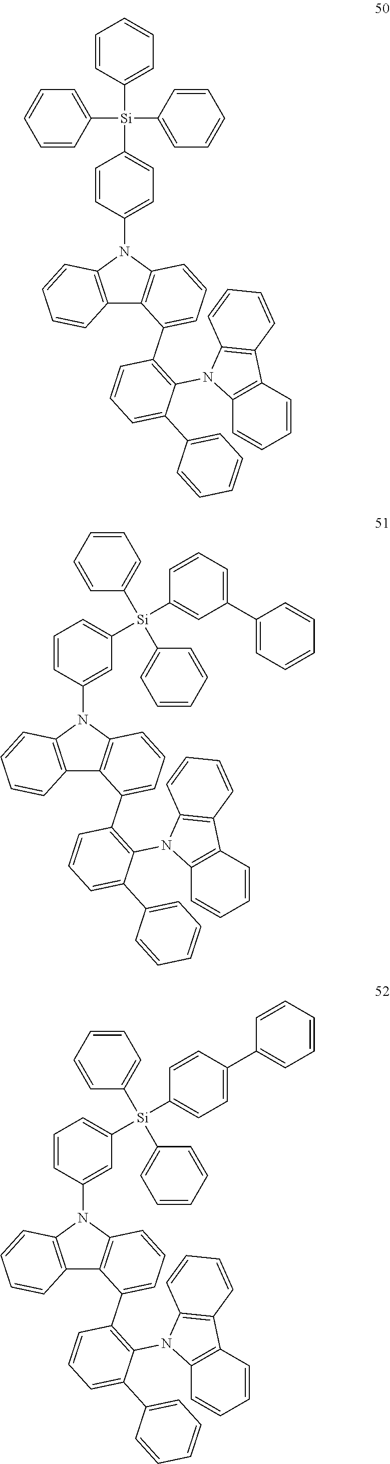 [SMILES: c1ccc(-c2cccc(-c3cccc4c3c3ccccc3n4-c3ccc([Si](c4ccccc4)(c4ccccc4)c4ccccc4)cc3)c2-n2c3ccccc3c3ccccc32)cc1 ; c1ccc(-c2cccc([Si](c3ccccc3)(c3ccccc3)c3cccc(-n4c5ccccc5c5c(-c6cccc(-c7ccccc7)c6-n6c7ccccc7c7ccccc76)cccc54)c3)c2)cc1 ; c1ccc(-c2ccc([Si](c3ccccc3)(c3ccccc3)c3cccc(-n4c5ccccc5c5c(-c6cccc(-c7ccccc7)c6-n6c7ccccc7c7ccccc76)cccc54)c3)cc2)cc1] 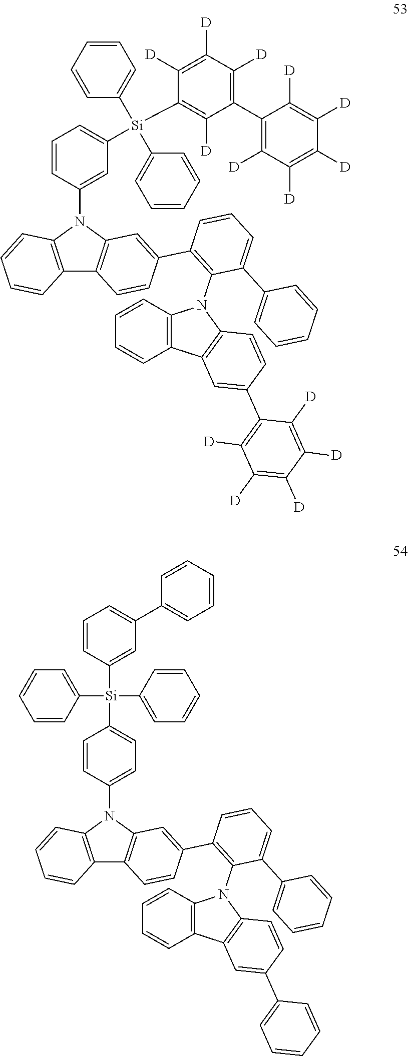 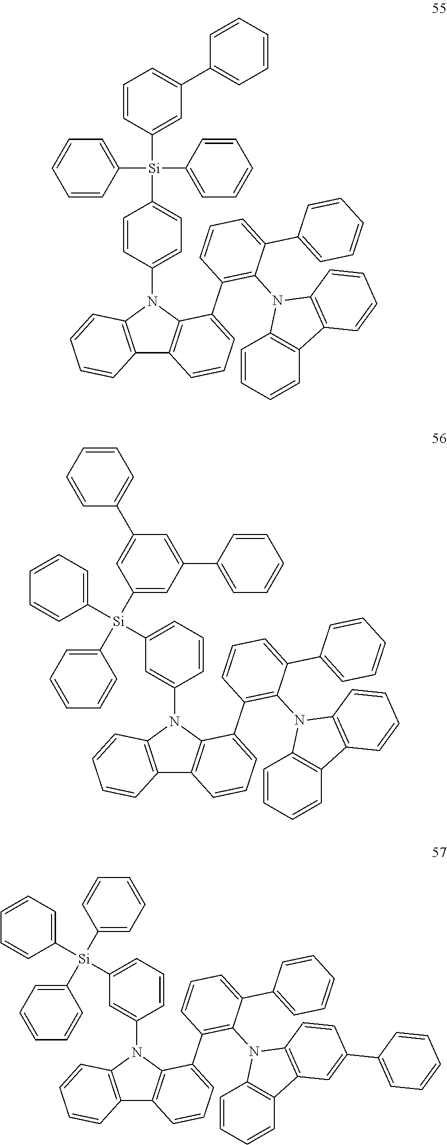 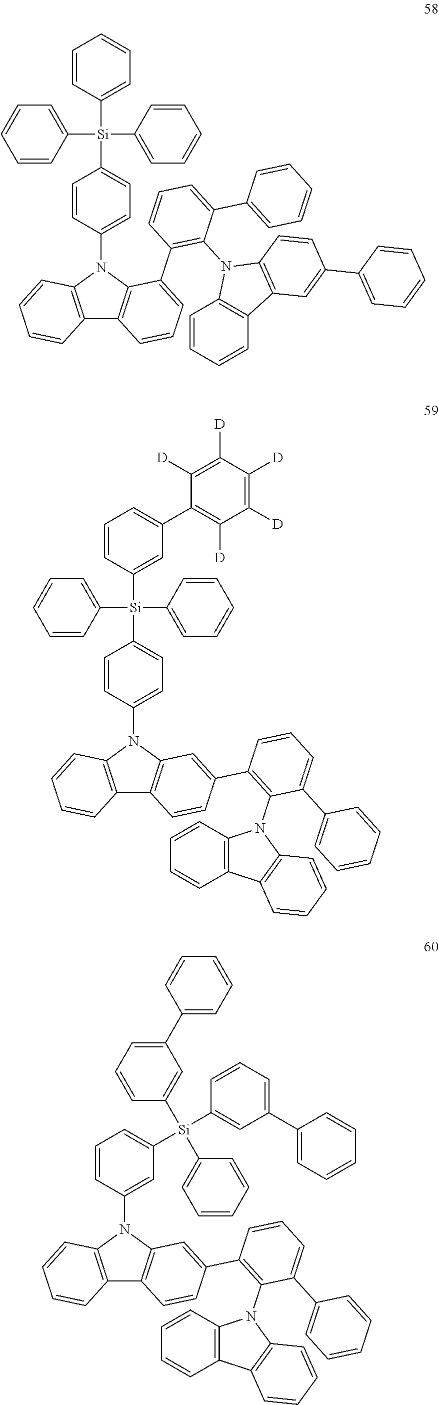 [SMILES: c1ccc(-c2ccc3c(c2)c2ccccc2n3-c2c(-c3ccccc3)cccc2-c2cccc3c4ccccc4n(-c4ccc([Si](c5ccccc5)(c5ccccc5)c5ccccc5)cc4)c23)cc1 ; [2H]c1c([2H])c([2H])c(-c2cccc([Si](c3ccccc3)(c3ccccc3)c3ccc(-n4c5ccccc5c5ccc(-c6cccc(-c7ccccc7)c6-n6c7ccccc7c7ccccc76)cc54)cc3)c2)c([2H])c1[2H] ; c1ccc(-c2cccc([Si](c3ccccc3)(c3cccc(-c4ccccc4)c3)c3cccc(-n4c5ccccc5c5ccc(-c6cccc(-c7ccccc7)c6-n6c7ccccc7c7ccccc76)cc54)c3)c2)cc1] 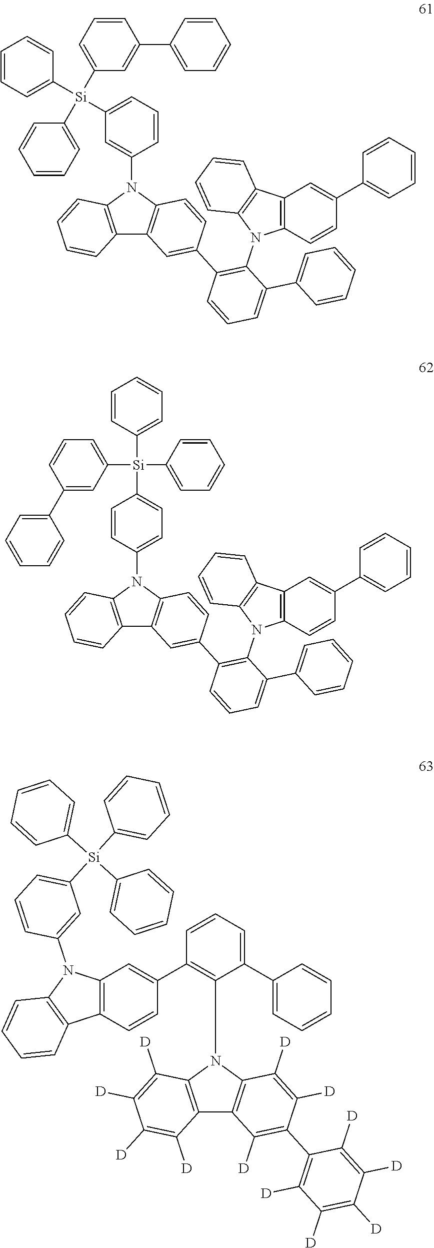 [SMILES: c1ccc(-c2cccc([Si](c3ccccc3)(c3ccccc3)c3cccc(-n4c5ccccc5c5cc(-c6cccc(-c7ccccc7)c6-n6c7ccccc7c7cc(-c8ccccc8)ccc76)ccc54)c3)c2)cc1 ; c1ccc(-c2cccc([Si](c3ccccc3)(c3ccccc3)c3ccc(-n4c5ccccc5c5cc(-c6cccc(-c7ccccc7)c6-n6c7ccccc7c7cc(-c8ccccc8)ccc76)ccc54)cc3)c2)cc1 ; [2H]c1c([2H])c([2H])c(-c2c([2H])c([2H])c3c(c2[2H])c2c([2H])c([2H])c([2H])c([2H])c2n3-c2c(-c3ccccc3)cccc2-c2ccc3c4ccccc4n(-c4cccc([Si](c5ccccc5)(c5ccccc5)c5ccccc5)c4)c3c2)c([2H])c1[2H]] 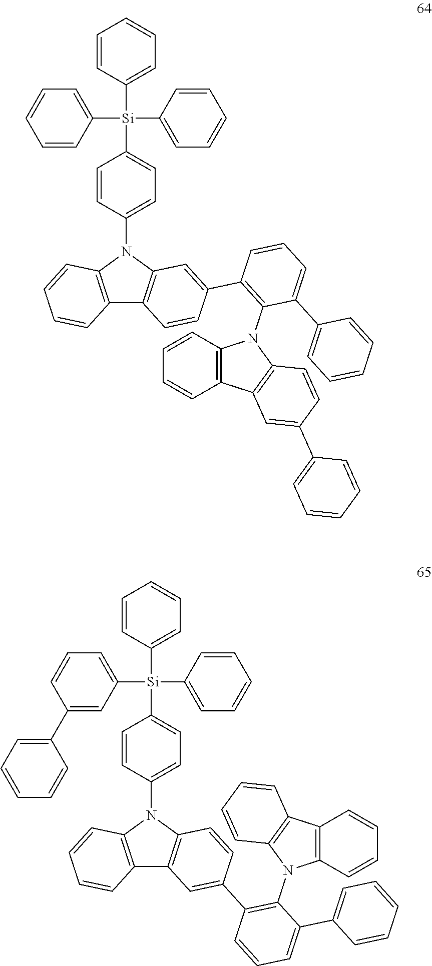 [SMILES: c1ccc(-c2ccc3c(c2)c2ccccc2n3-c2c(-c3ccccc3)cccc2-c2ccc3c4ccccc4n(-c4ccc([Si](c5ccccc5)(c5ccccc5)c5ccccc5)cc4)c3c2)cc1 ; c1ccc(-c2cccc([Si](c3ccccc3)(c3ccccc3)c3ccc(-n4c5ccccc5c5cc(-c6cccc(-c7ccccc7)c6-n6c7ccccc7c7ccccc76)ccc54)cc3)c2)cc1] 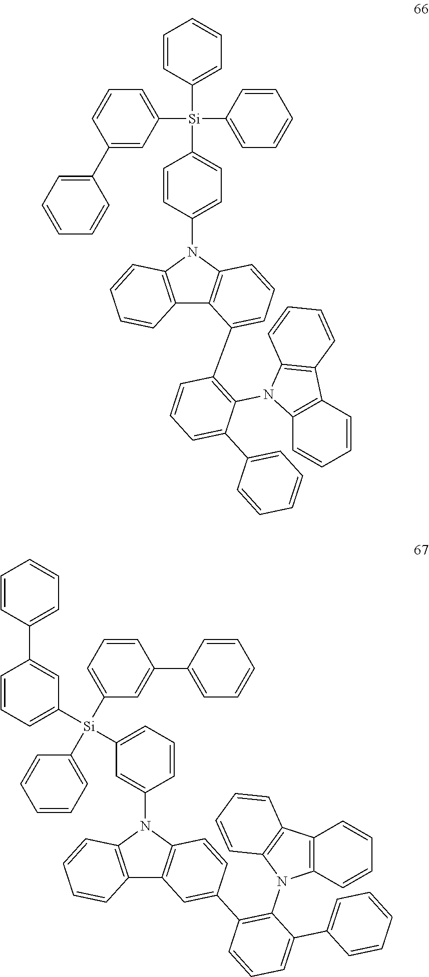 [SMILES: c1ccc(-c2cccc([Si](c3ccccc3)(c3ccccc3)c3ccc(-n4c5ccccc5c5c(-c6cccc(-c7ccccc7)c6-n6c7ccccc7c7ccccc76)cccc54)cc3)c2)cc1 ; c1ccc(-c2cccc([Si](c3ccccc3)(c3cccc(-c4ccccc4)c3)c3cccc(-n4c5ccccc5c5cc(-c6cccc(-c7ccccc7)c6-n6c7ccccc7c7ccccc76)ccc54)c3)c2)cc1] 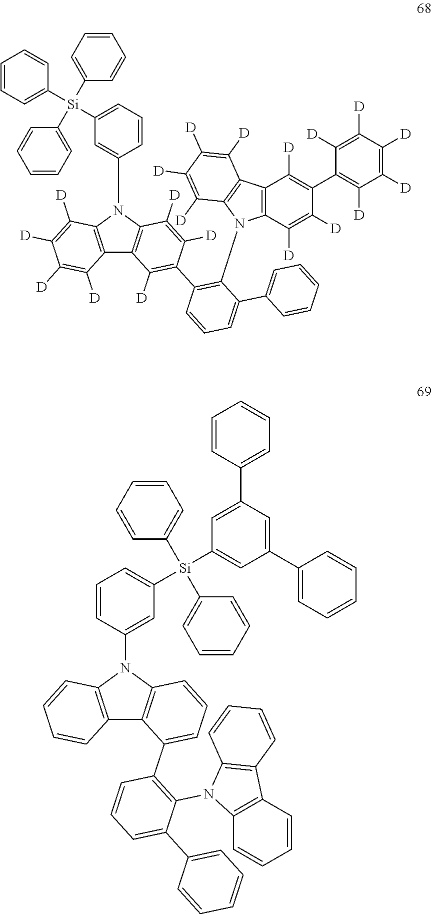 [SMILES: [2H]c1c([2H])c([2H])c(-c2c([2H])c([2H])c3c(c2[2H])c2c([2H])c([2H])c([2H])c([2H])c2n3-c2c(-c3ccccc3)cccc2-c2c([2H])c([2H])c3c(c2[2H])c2c([2H])c([2H])c([2H])c([2H])c2n3-c2cccc([Si](c3ccccc3)(c3ccccc3)c3ccccc3)c2)c([2H])c1[2H] ; c1ccc(-c2cc(-c3ccccc3)cc([Si](c3ccccc3)(c3ccccc3)c3cccc(-n4c5ccccc5c5c(-c6cccc(-c7ccccc7)c6-n6c7ccccc7c7ccccc76)cccc54)c3)c2)cc1] 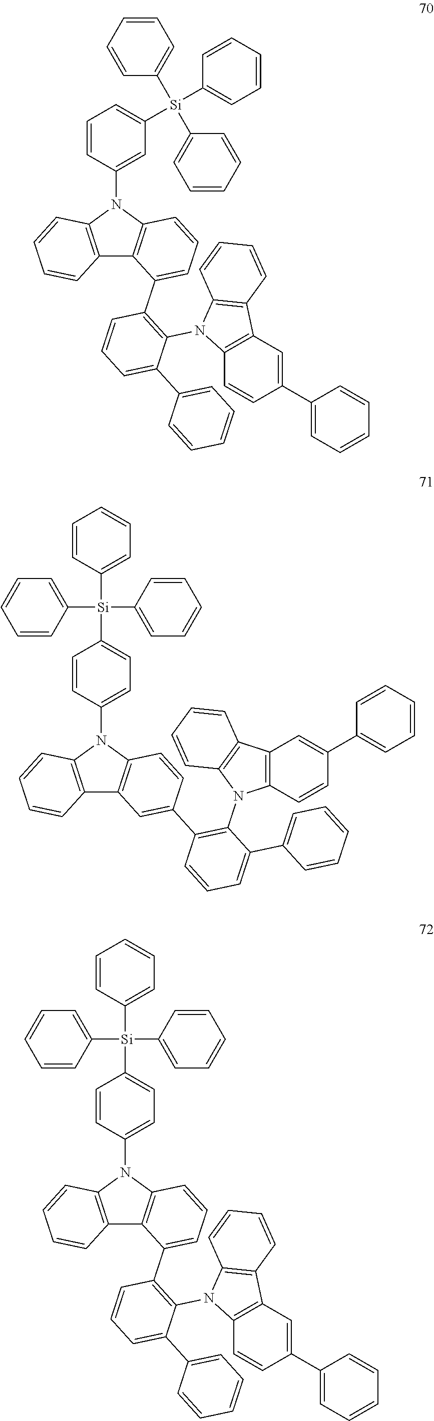 [SMILES: c1ccc(-c2ccc3c(c2)c2ccccc2n3-c2c(-c3ccccc3)cccc2-c2cccc3c2c2ccccc2n3-c2cccc([Si](c3ccccc3)(c3ccccc3)c3ccccc3)c2)cc1 ; c1ccc(-c2ccc3c(c2)c2ccccc2n3-c2c(-c3ccccc3)cccc2-c2ccc3c(c2)c2ccccc2n3-c2ccc([Si](c3ccccc3)(c3ccccc3)c3ccccc3)cc2)cc1 ; c1ccc(-c2ccc3c(c2)c2ccccc2n3-c2c(-c3ccccc3)cccc2-c2cccc3c2c2ccccc2n3-c2ccc([Si](c3ccccc3)(c3ccccc3)c3ccccc3)cc2)cc1] 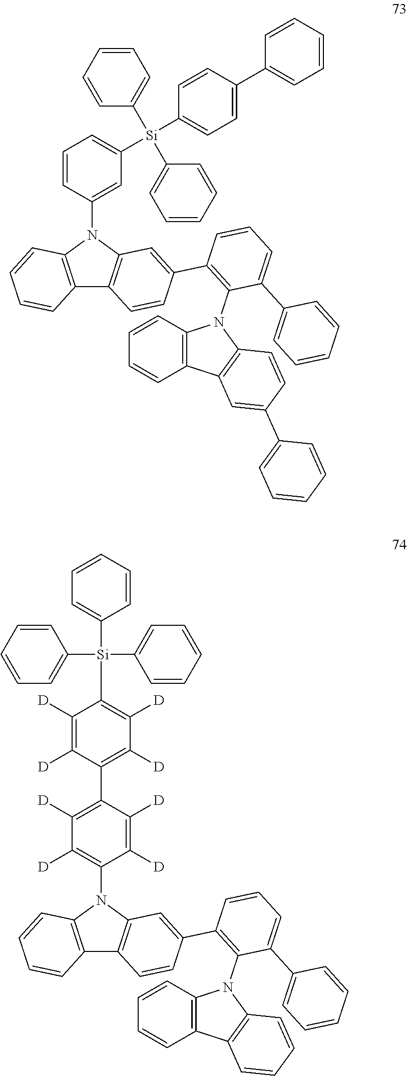 [SMILES: c1ccc(-c2ccc([Si](c3ccccc3)(c3ccccc3)c3cccc(-n4c5ccccc5c5ccc(-c6cccc(-c7ccccc7)c6-n6c7ccccc7c7cc(-c8ccccc8)ccc76)cc54)c3)cc2)cc1 ; [2H]c1c([2H])c(-n2c3ccccc3c3ccc(-c4cccc(-c5ccccc5)c4-n4c5ccccc5c5ccccc54)cc32)c([2H])c([2H])c1-c1c([2H])c([2H])c([Si](c2ccccc2)(c2ccccc2)c2ccccc2)c([2H])c1[2H]] 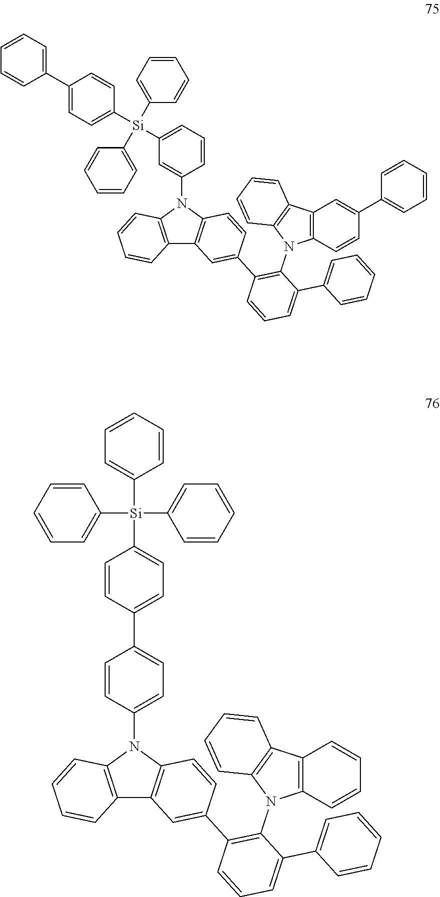 [SMILES: c1ccc(-c2ccc([Si](c3ccccc3)(c3ccccc3)c3cccc(-n4c5ccccc5c5cc(-c6cccc(-c7ccccc7)c6-n6c7ccccc7c7cc(-c8ccccc8)ccc76)ccc54)c3)cc2)cc1 ; c1ccc(-c2cccc(-c3ccc4c(c3)c3ccccc3n4-c3ccc(-c4ccc([Si](c5ccccc5)(c5ccccc5)c5ccccc5)cc4)cc3)c2-n2c3ccccc3c3ccccc32)cc1] 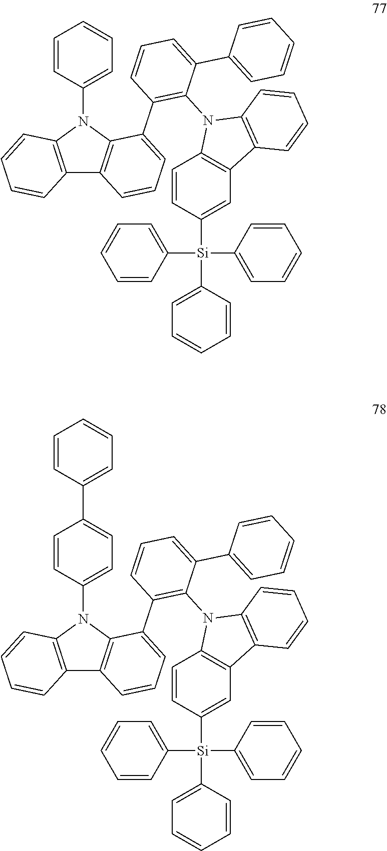 [SMILES: c1ccc(-c2cccc(-c3cccc4c5ccccc5n(-c5ccccc5)c34)c2-n2c3ccccc3c3cc([Si](c4ccccc4)(c4ccccc4)c4ccccc4)ccc32)cc1 ; c1ccc(-c2ccc(-n3c4ccccc4c4cccc(-c5cccc(-c6ccccc6)c5-n5c6ccccc6c6cc([Si](c7ccccc7)(c7ccccc7)c7ccccc7)ccc65)c43)cc2)cc1] 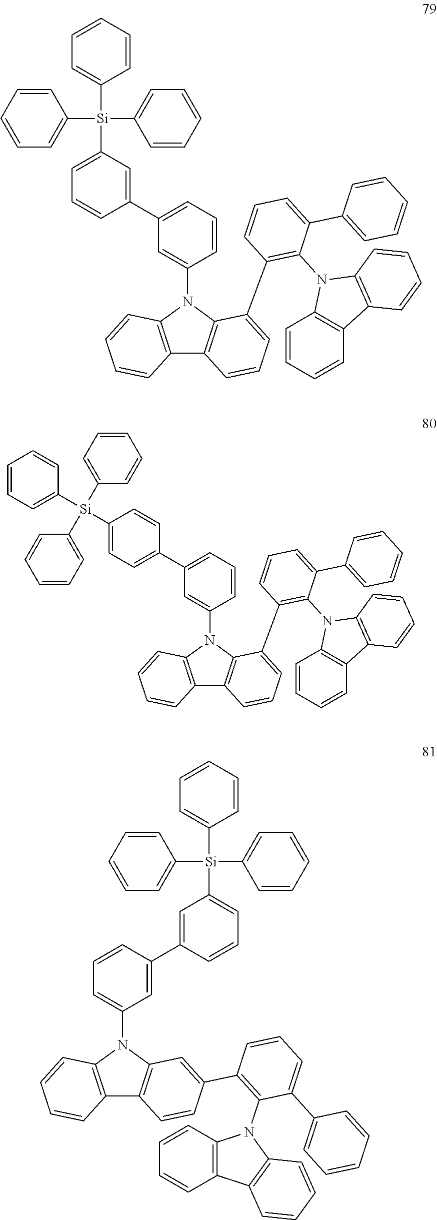 [SMILES: c1ccc(-c2cccc(-c3cccc4c5ccccc5n(-c5cccc(-c6cccc([Si](c7ccccc7)(c7ccccc7)c7ccccc7)c6)c5)c34)c2-n2c3ccccc3c3ccccc32)cc1 ; c1ccc(-c2cccc(-c3cccc4c5ccccc5n(-c5cccc(-c6ccc([Si](c7ccccc7)(c7ccccc7)c7ccccc7)cc6)c5)c34)c2-n2c3ccccc3c3ccccc32)cc1 ; c1ccc(-c2cccc(-c3ccc4c5ccccc5n(-c5cccc(-c6cccc([Si](c7ccccc7)(c7ccccc7)c7ccccc7)c6)c5)c4c3)c2-n2c3ccccc3c3ccccc32)cc1] 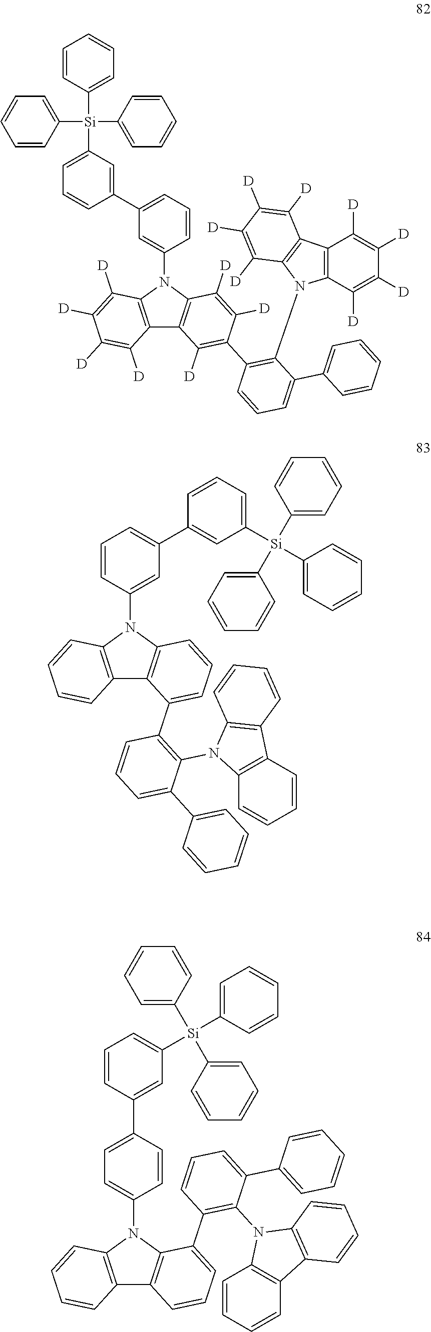 [SMILES: [2H]c1c([2H])c([2H])c2c(c1[2H])c1c([2H])c(-c3cccc(-c4ccccc4)c3-n3c4c([2H])c([2H])c([2H])c([2H])c4c4c([2H])c([2H])c([2H])c([2H])c43)c([2H])c([2H])c1n2-c1cccc(-c2cccc([Si](c3ccccc3)(c3ccccc3)c3ccccc3)c2)c1 ; c1ccc(-c2cccc(-c3cccc4c3c3ccccc3n4-c3cccc(-c4cccc([Si](c5ccccc5)(c5ccccc5)c5ccccc5)c4)c3)c2-n2c3ccccc3c3ccccc32)cc1 ; c1ccc(-c2cccc(-c3cccc4c5ccccc5n(-c5ccc(-c6cccc([Si](c7ccccc7)(c7ccccc7)c7ccccc7)c6)cc5)c34)c2-n2c3ccccc3c3ccccc32)cc1] 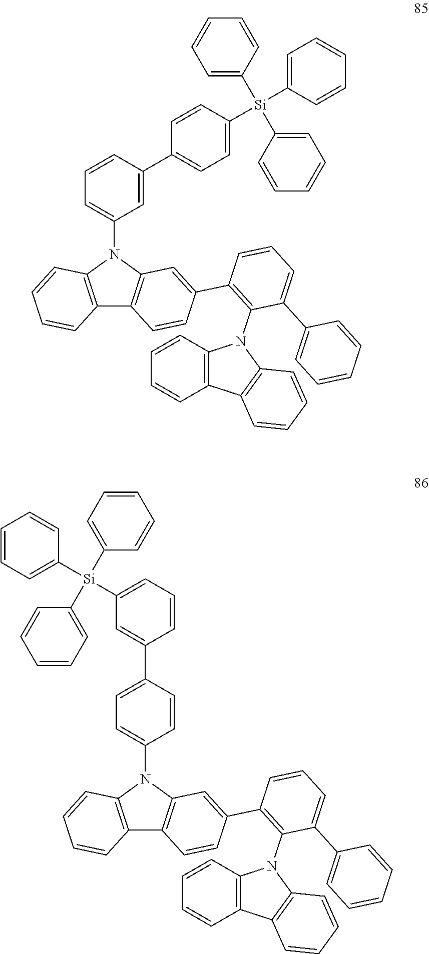 [SMILES: c1ccc(-c2cccc(-c3ccc4c5ccccc5n(-c5cccc(-c6ccc([Si](c7ccccc7)(c7ccccc7)c7ccccc7)cc6)c5)c4c3)c2-n2c3ccccc3c3ccccc32)cc1 ; c1ccc(-c2cccc(-c3ccc4c5ccccc5n(-c5ccc(-c6cccc([Si](c7ccccc7)(c7ccccc7)c7ccccc7)c6)cc5)c4c3)c2-n2c3ccccc3c3ccccc32)cc1] 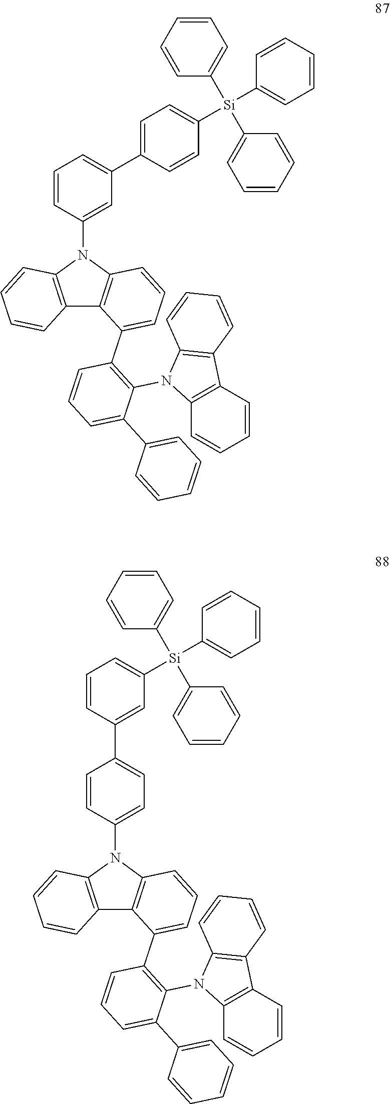 [SMILES: c1ccc(-c2cccc(-c3cccc4c3c3ccccc3n4-c3cccc(-c4ccc([Si](c5ccccc5)(c5ccccc5)c5ccccc5)cc4)c3)c2-n2c3ccccc3c3ccccc32)cc1 ; c1ccc(-c2cccc(-c3cccc4c3c3ccccc3n4-c3ccc(-c4cccc([Si](c5ccccc5)(c5ccccc5)c5ccccc5)c4)cc3)c2-n2c3ccccc3c3ccccc32)cc1] 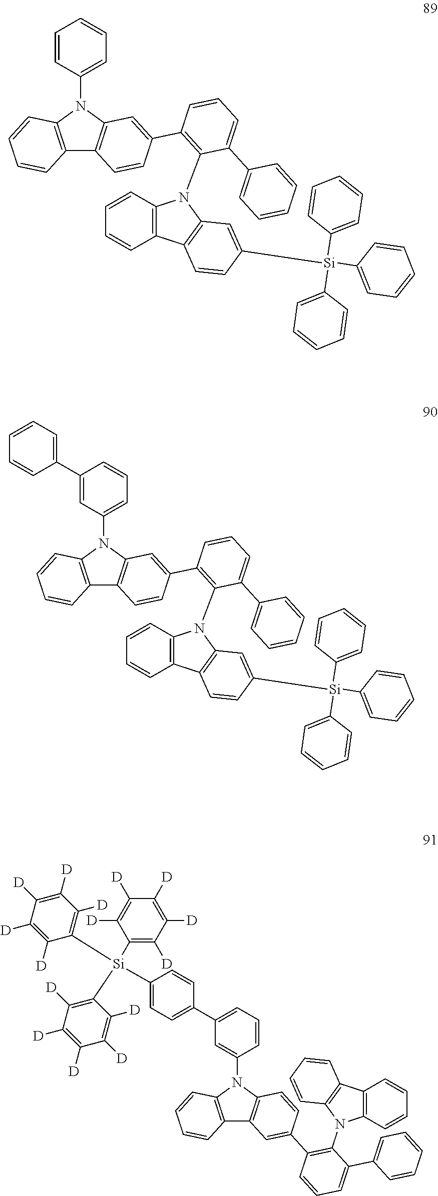 [SMILES: c1ccc(-c2cccc(-c3ccc4c5ccccc5n(-c5ccccc5)c4c3)c2-n2c3ccccc3c3ccc([Si](c4ccccc4)(c4ccccc4)c4ccccc4)cc32)cc1 ; c1ccc(-c2cccc(-n3c4ccccc4c4ccc(-c5cccc(-c6ccccc6)c5-n5c6ccccc6c6ccc([Si](c7ccccc7)(c7ccccc7)c7ccccc7)cc65)cc43)c2)cc1 ; [2H]c1c([2H])c([2H])c([Si](c2ccc(-c3cccc(-n4c5ccccc5c5cc(-c6cccc(-c7ccccc7)c6-n6c7ccccc7c7ccccc76)ccc54)c3)cc2)(c2c([2H])c([2H])c([2H])c([2H])c2[2H])c2c([2H])c([2H])c([2H])c([2H])c2[2H])c([2H])c1[2H]] 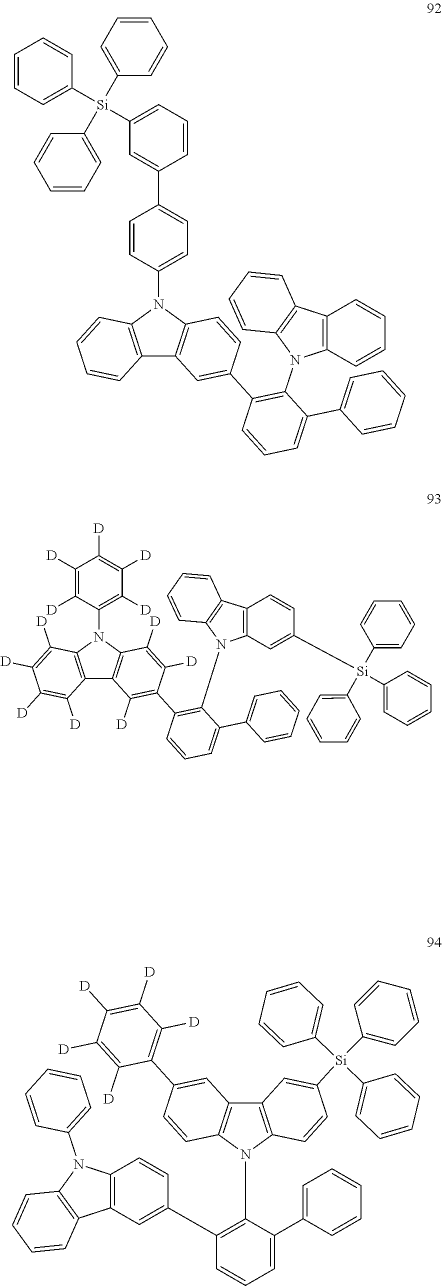 [SMILES: c1ccc(-c2cccc(-c3ccc4c(c3)c3ccccc3n4-c3ccc(-c4cccc([Si](c5ccccc5)(c5ccccc5)c5ccccc5)c4)cc3)c2-n2c3ccccc3c3ccccc32)cc1 ; [2H]c1c([2H])c([2H])c(-n2c3c([2H])c([2H])c([2H])c([2H])c3c3c([2H])c(-c4cccc(-c5ccccc5)c4-n4c5ccccc5c5ccc([Si](c6ccccc6)(c6ccccc6)c6ccccc6)cc54)c([2H])c([2H])c32)c([2H])c1[2H] ; [2H]c1c([2H])c([2H])c(-c2ccc3c(c2)c2cc([Si](c4ccccc4)(c4ccccc4)c4ccccc4)ccc2n3-c2c(-c3ccccc3)cccc2-c2ccc3c(c2)c2ccccc2n3-c2ccccc2)c([2H])c1[2H]] 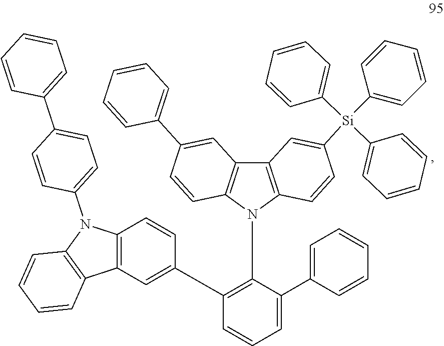 [SMILES: c1ccc(-c2ccc(-n3c4ccccc4c4cc(-c5cccc(-c6ccccc6)c5-n5c6ccc(-c7ccccc7)cc6c6cc([Si](c7ccccc7)(c7ccccc7)c7ccccc7)ccc65)ccc43)cc2)cc1]
in Compound Group 1, “D” being deuterium.

7. The light-emitting diode of claim 1,
wherein the light-emitting layer comprises a host and a dopant, and
the host comprises the first compound represented by Formula 1.

8. The light-emitting diode of claim 1,
wherein the light-emitting layer is to emit phosphorescence and/or a thermally activated delayed fluorescence.

9. The light-emitting diode of claim 1,
wherein the light-emitting layer further comprises a second compound represented by Formula ETH-1:
Formula ETH-1 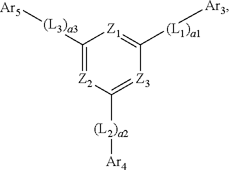
and
wherein in Formula ETH-1,
Z₁ is N or CR₁₂, Z₂ is N or CR₁₃, Z₃ is N or CR₁₄, and at least one selected from among Z₁ through Z₃ is N,
R₁₂ through R₁₄ are each independently hydrogen, deuterium, a substituted or unsubstituted alkyl group having 1 to 20 carbons, a substituted or unsubstituted aryl group having 6 to 50 ring-forming carbons, or a substituted or unsubstituted heteroaryl group having 2 to 50 ring-forming carbons, and
each of L₁ through L₃ is independently a direct linkage, a substituted or unsubstituted arylene group having 6 to 30 ring-forming carbons, or a substituted or unsubstituted heteroarylene group having 2 to 30 ring-forming carbons, provided that when each a1 through a3 is an integer of 2 or greater, then each of L₁ through L₃ is independently a substituted or unsubstituted arylene group having 6 to 30 ring-forming carbons or a substituted or unsubstituted heteroarylene group having 2 to 30 ring-forming carbons,
each of a1 through a3 is independently an integer between 0 and 10, inclusive, and
each of Ar₃ through Ar₅ is independently hydrogen, deuterium, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons.

10. The light-emitting diode of claim 1,
wherein the light-emitting layer further comprises a third compound represented by Formula M-a: 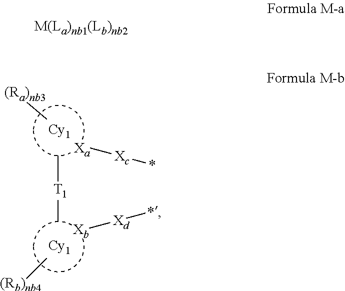
wherein in Formulae M-a and M-b,
M is a transition metal,
Lₐ is a ligand represented by Formula M-b,
nb1 is 1, 2, or 3, and when nb1 is two or greater, the two or more Lₐ(s) are identical to or different from each other,
L_{b} is an organic ligand,
nb2 is 0, 1, 2, 3, or 4, and when nb2 is two or greater, then the two or more L_{b}(s) are identical to or different from each other,
T₁ is a direct linkage, *—O—*, *—S—*, *—N(Q₁)*—C(═O)—*, *C(Q₁)=C(Q₂)-*, *—C(Q₁)=*, *—C(Q₁)(Q₂)-*, or *═C(Q₁)-*,
each of Xₐ and X_{b} is independently C or N,
each of X_{c} and X_{d} is independently a chemical bond, O, S, N(Q₃), B(Q₃), P(Q₃), C(Q₃)(Q₄), or Si(Q₃)(Q₄),
each of ring Cy₁ and ring Cy₂ is independently a substituted or unsubstituted carbocyclic ring having 3 to 60 ring-forming carbons or a substituted or unsubstituted heterocyclic ring having 1 to 60 ring-forming carbons,
each of Rₐ and R_{b} is independently hydrogen, deuterium, halogens, a hydroxyl group, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbons, a substituted or unsubstituted alkenyl group having 2 to 20 carbons, a substituted or unsubstituted aryl group having 6 to 60 ring-forming carbons, or a substituted or unsubstituted heteroaryl group having 2 to 60 ring-forming carbons,
each of Q₁ through Q₄ is independently hydrogen, deuterium, halogens, a hydroxyl group, a cyano group, a nitro group, a substituted or unsubstituted alkyl group having 1 to 30 carbons, a substituted or unsubstituted alkenyl group having 1 to 30 carbons, a substituted or unsubstituted alkynyl group having 2 to 30 carbons, a substituted or unsubstituted alkoxy group having 1 to 30 carbons, a substituted or unsubstituted aryl group having 6 to 60 ring-forming carbons, or a substituted or unsubstituted heteroaryl group having 2 to 60 ring-forming carbons,
each of nb3 and nb4 is independently an integer between 0 and 10, inclusive, and
wherein in Formula M-b, each * and *′ is a binding site with M of Formula M-a.

11. An electronic device comprising:
a substrate;
a circuit layer on the substrate and comprising a transistor; and
a light-emitting diode electrically connected to the transistor,
wherein the light-emitting diode comprises:
a first electrode;
a second electrode opposite to the first electrode; and
a light-emitting layer between the first electrode and the second electrode,
wherein the light-emitting layer comprises a first compound represented by Formula 1: 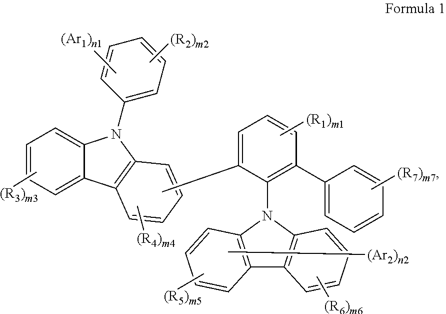
wherein in Formula 1,
each of Ar₁ and Ar₂ is independently represented by Formula 2 or Formula 3,
each of n1 and n2 is independently an integer between 0 and 2, inclusive,
each of R₁ through R₇ is independently hydrogen, deuterium, halogens, a substituted or unsubstituted alkyl group having 1 to 20 carbons, or a substituted or unsubstituted aryl group having 6 to 30 ring-forming carbons,
each of m1 and m4 is independently an integer between 0 and 3, inclusive,
each of m2 and m7 is independently an integer between 0 and 5, inclusive, and
each of m3, m5 and m6 is independently an integer between 0 and 4, inclusive, and 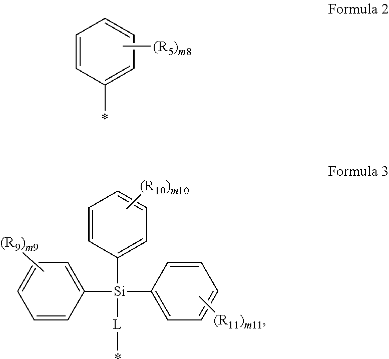
and
wherein in Formula 2 and Formula 3,
each of R₈ through R₁₁ is independently hydrogen, deuterium, a substituted or unsubstituted silyl group, or a substituted or unsubstituted aryl group having 6 to 60 ring-forming carbons,
each of m8 through m11 is independently an integer between 0 and 5, inclusive,
L is a direct linkage or a substituted or unsubstituted arylene group having 6 to 30 ring-forming carbons, and [symbol]
is a site of binding to a corresponding moiety of Formula 1.

12. The electronic device of claim 11,
wherein the electronic device is at least one of a plane panel display, a curved display, a television, a billboard, a computer monitor, a medical monitor, a head mounted display, an indoor light, an outdoor light, a signal light, a wearable device, a foldable device, a rollable device, a bendable device, a flexible device, a curved device, an electronic organizer, an electronic book, a portable multimedia player, a personal digital assistance, a laser printer, a telephone, a portable phone, a tablet PC, a portable terminal, a laptop computer, a digital camera, a viewfinder, a camcorder, a 3D display, a virtual reality display, an augmented reality display, a video wall comprising multiple displays tiled together, a vehicle, an outdoor display device, a theater screen, a stadium screen, or a signboard.

13. The electronic device of claim 11,
wherein the light-emitting diode further comprises at least one of a color filter layer, a color conversion layer, a touch-sensor layer, or an optical layer.

14. A heterocyclic compound represented by Formula 1: 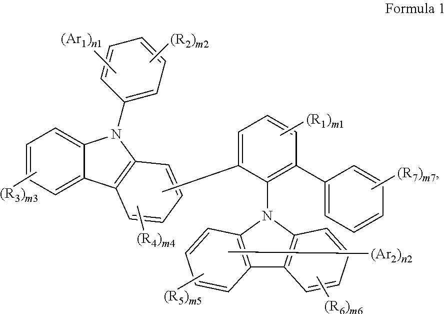
wherein in Formula 1,
each of Ar₁ and Ar₂ is independently represented by Formula 2 or Formula 3,
each of n1 and n2 is independently an integer between 0 and 2, inclusive,
each of R₁ through R₇ is independently hydrogen, deuterium, halogens, a substituted or unsubstituted alkyl group having 1 to 20 carbons, or a substituted or unsubstituted aryl group having 6 to 30 ring-forming carbons,
each of m1 and m4 is independently an integer between 0 and 3, inclusive,
each of m2 and m7 is independently an integer between 0 and 5, inclusive, and
each of m3, m5, and m6 is independently an integer between 0 and 4, inclusive, and 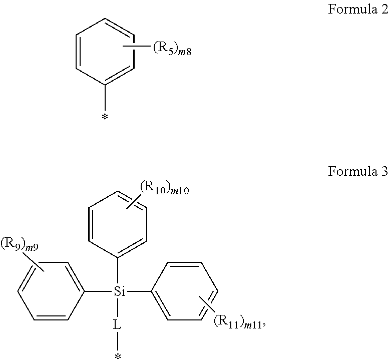
and
wherein in Formula 2 and Formula 3,
each of R₈ through R₁₁ is independently hydrogen, deuterium, a substituted or unsubstituted silyl group, or a substituted or unsubstituted aryl group having 6 to 60 ring-forming carbons,
each of m8 through m11 is independently an integer between 0 and 5, inclusive,
L is a direct linkage or a substituted or unsubstituted arylene group having 6 to 30 ring-forming carbons, and [symbol]
is a site of binding to a corresponding moiety of Formula 1.

15. The heterocyclic compound of claim 14,
wherein the heterocyclic compound represented by Formula 1 is represented by any formula selected from among Formula 1-1 through Formula 1-4: 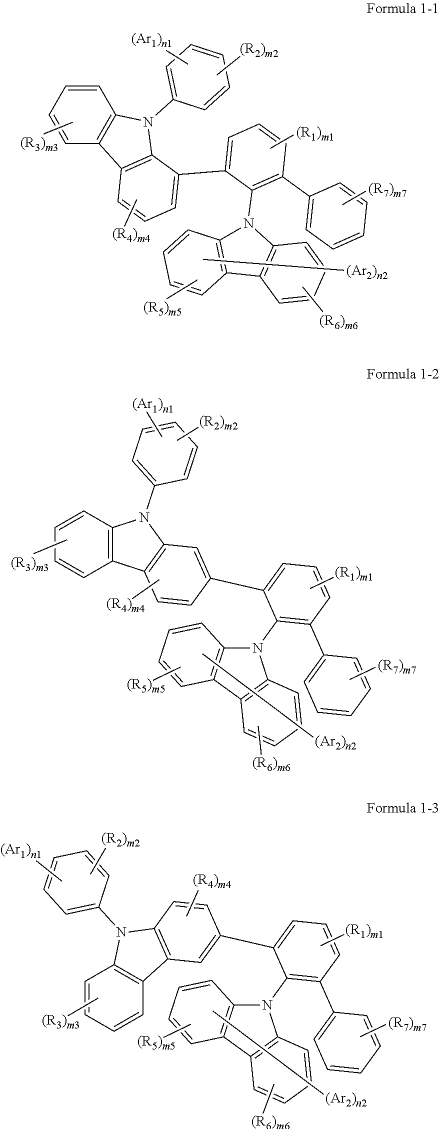 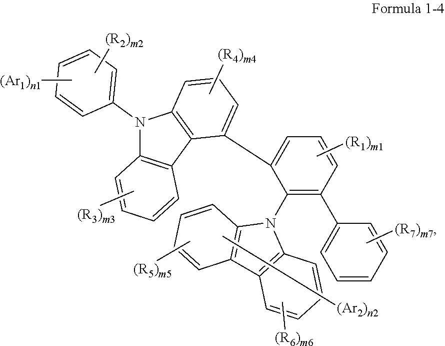
in Formulae 1-1 through 1-4, Ar₁, Ar₂, n1, n2, R₁ through R₇, and m1 through m7 being each the same as defined in Formula 1.

16. The heterocyclic compound of claim 14,
wherein R₇ is hydrogen or deuterium, and m7 is 5.

17. The heterocyclic compound of claim 14,
wherein L is a direct linkage, a substituted or unsubstituted phenylene group, or a phenylene group substituted with deuterium.

18. The heterocyclic compound of claim 14,
wherein the heterocyclic compound represented by Formula 1 is represented by any formula selected from among Formulae 1-5 through 1-15: 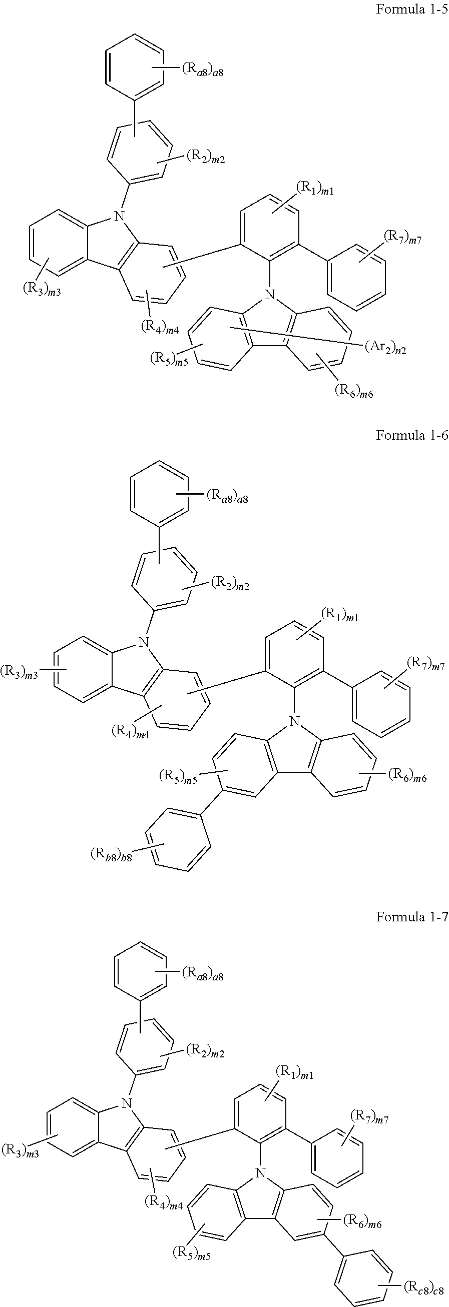 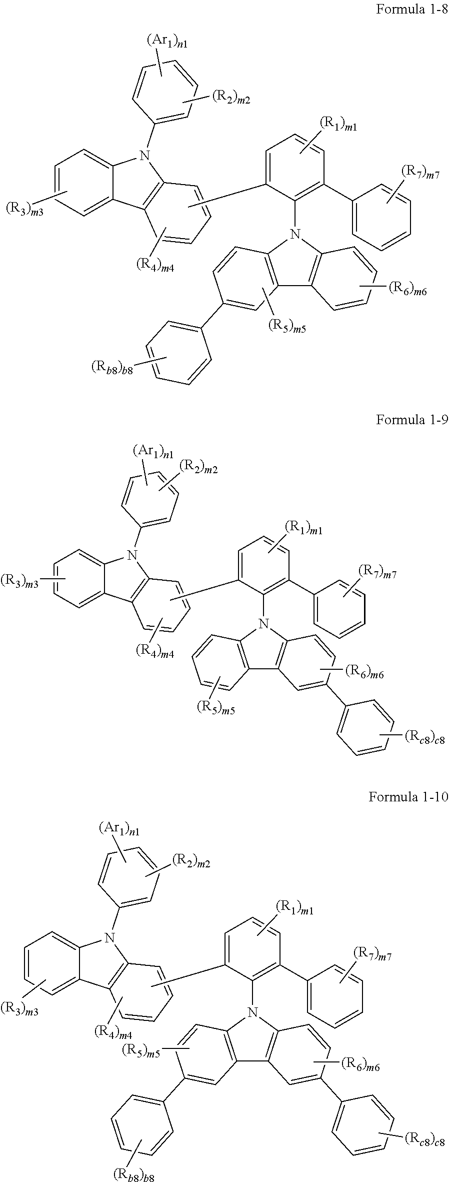 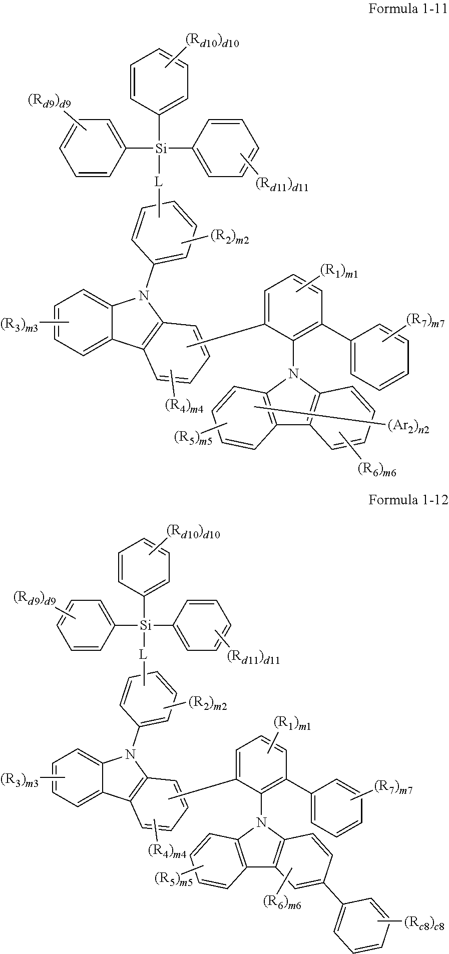 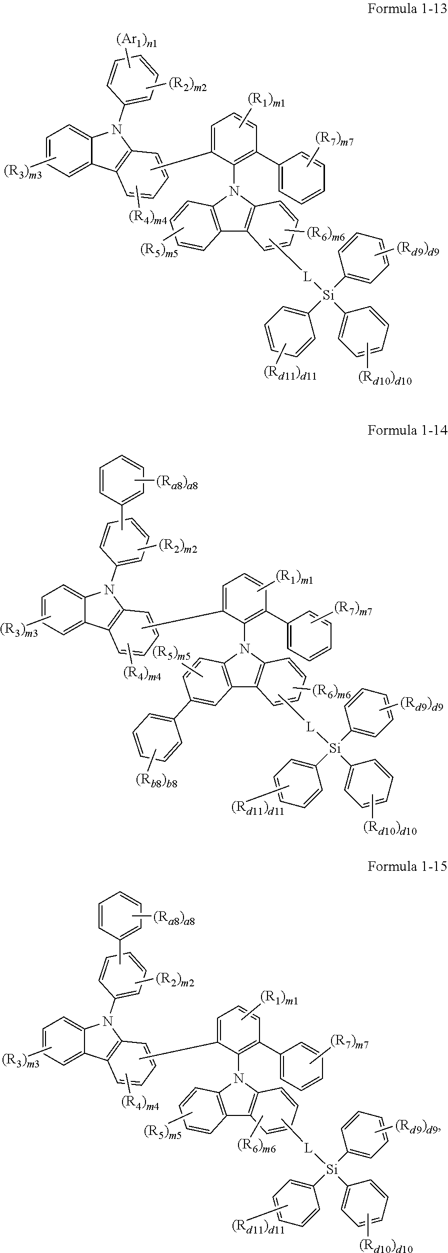
and
wherein in Formula 1-5 through Formula 1-15,
each of Rₐ₈, R_{b8}, R_{c8}, R_{d9}, R_{d10}, and R_{d11} is independently hydrogen, deuterium, a substituted or unsubstituted silyl group, or a substituted or unsubstituted aryl group having 6 to 60 ring-forming carbons,
each of a8, b8, c8, d9, d10, and d11 is independently an integer between 0 and 5, inclusive, and
Ar₁, Ar₂, n1, n2, R₁ through R₇, m1 through m7, and L are each the same as defined in Formula 1.

19. The heterocyclic compound of claim 14,
wherein the heterocyclic compound represented by Formula 1 is any one selected from among compounds of Compound Group 1: 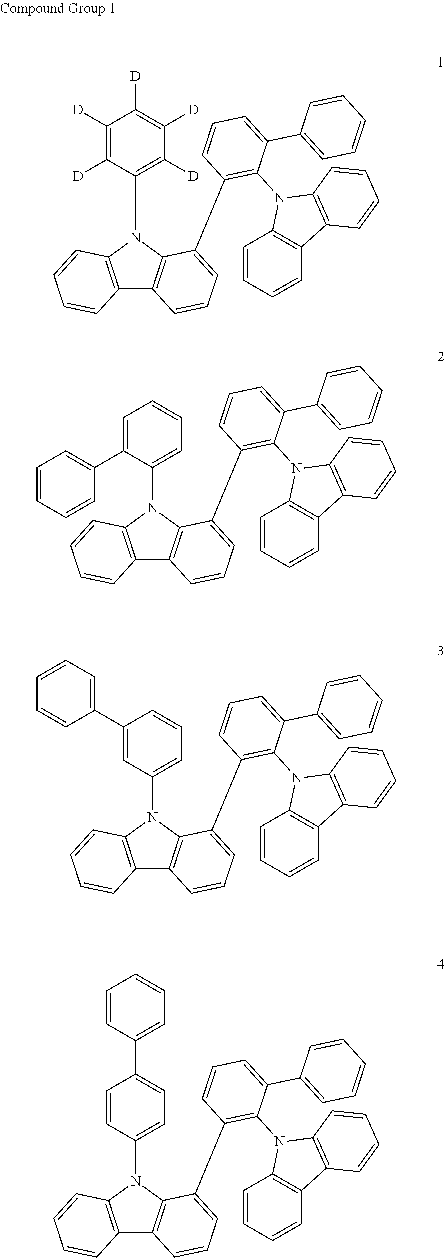 [SMILES: [2H]c1c([2H])c([2H])c(-n2c3ccccc3c3cccc(-c4cccc(-c5ccccc5)c4-n4c5ccccc5c5ccccc54)c32)c([2H])c1[2H] ; c1ccc(-c2ccccc2-n2c3ccccc3c3cccc(-c4cccc(-c5ccccc5)c4-n4c5ccccc5c5ccccc54)c32)cc1 ; c1ccc(-c2cccc(-n3c4ccccc4c4cccc(-c5cccc(-c6ccccc6)c5-n5c6ccccc6c6ccccc65)c43)c2)cc1 ; c1ccc(-c2ccc(-n3c4ccccc4c4cccc(-c5cccc(-c6ccccc6)c5-n5c6ccccc6c6ccccc65)c43)cc2)cc1] 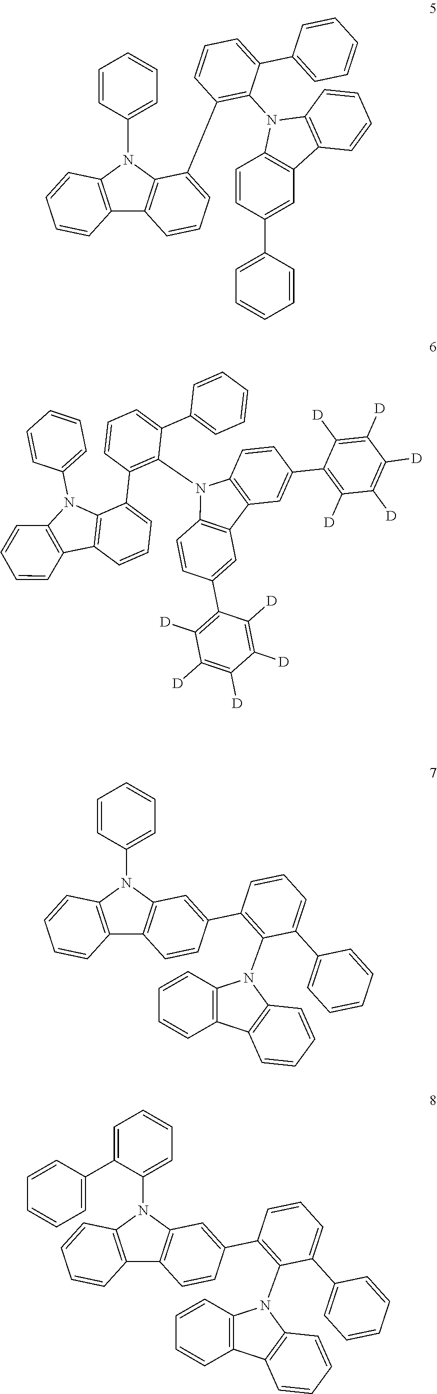 [SMILES: c1ccc(-c2ccc3c(c2)c2ccccc2n3-c2c(-c3ccccc3)cccc2-c2cccc3c4ccccc4n(-c4ccccc4)c23)cc1 ; [2H]c1c([2H])c([2H])c(-c2ccc3c(c2)c2cc(-c4c([2H])c([2H])c([2H])c([2H])c4[2H])ccc2n3-c2c(-c3ccccc3)cccc2-c2cccc3c4ccccc4n(-c4ccccc4)c23)c([2H])c1[2H] ; c1ccc(-c2cccc(-c3ccc4c5ccccc5n(-c5ccccc5)c4c3)c2-n2c3ccccc3c3ccccc32)cc1 ; c1ccc(-c2ccccc2-n2c3ccccc3c3ccc(-c4cccc(-c5ccccc5)c4-n4c5ccccc5c5ccccc54)cc32)cc1] 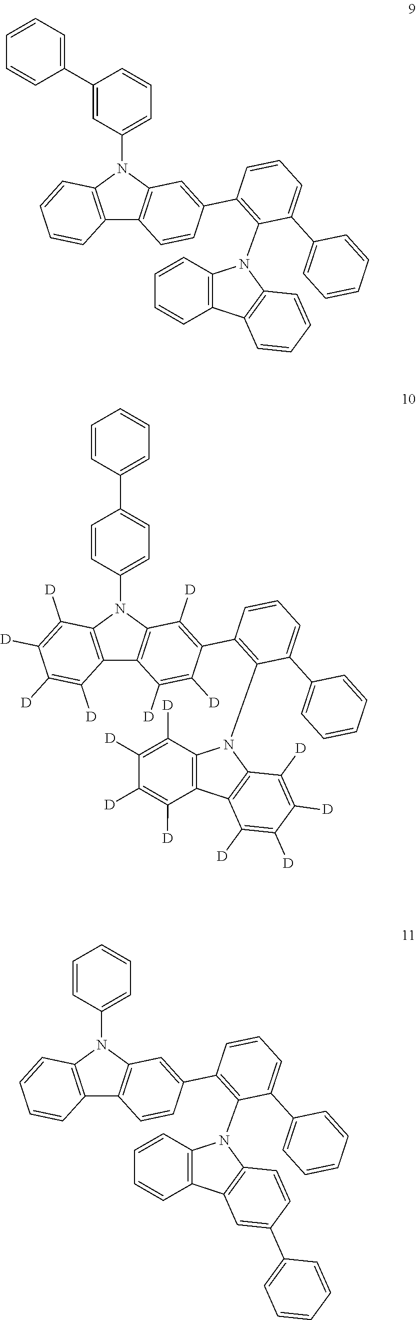 [SMILES: c1ccc(-c2cccc(-n3c4ccccc4c4ccc(-c5cccc(-c6ccccc6)c5-n5c6ccccc6c6ccccc65)cc43)c2)cc1 ; [2H]c1c([2H])c([2H])c2c(c1[2H])c1c([2H])c([2H])c(-c3cccc(-c4ccccc4)c3-n3c4c([2H])c([2H])c([2H])c([2H])c4c4c([2H])c([2H])c([2H])c([2H])c43)c([2H])c1n2-c1ccc(-c2ccccc2)cc1 ; c1ccc(-c2ccc3c(c2)c2ccccc2n3-c2c(-c3ccccc3)cccc2-c2ccc3c4ccccc4n(-c4ccccc4)c3c2)cc1] 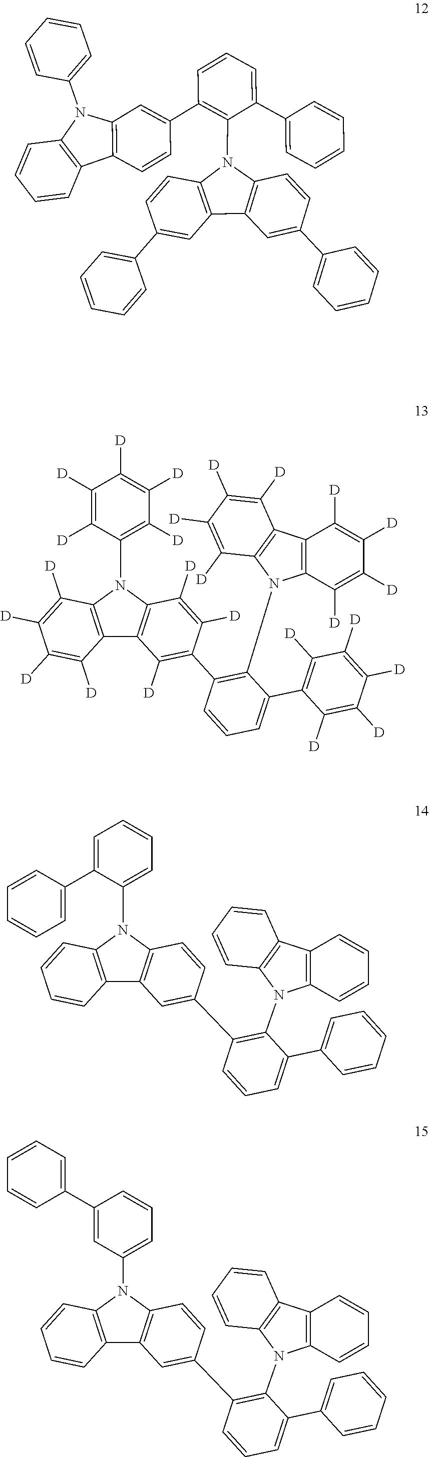 [SMILES: c1ccc(-c2ccc3c(c2)c2cc(-c4ccccc4)ccc2n3-c2c(-c3ccccc3)cccc2-c2ccc3c4ccccc4n(-c4ccccc4)c3c2)cc1 ; [2H]c1c([2H])c([2H])c(-c2cccc(-c3c([2H])c([2H])c4c(c3[2H])c3c([2H])c([2H])c([2H])c([2H])c3n4-c3c([2H])c([2H])c([2H])c([2H])c3[2H])c2-n2c3c([2H])c([2H])c([2H])c([2H])c3c3c([2H])c([2H])c([2H])c([2H])c32)c([2H])c1[2H] ; c1ccc(-c2ccccc2-n2c3ccccc3c3cc(-c4cccc(-c5ccccc5)c4-n4c5ccccc5c5ccccc54)ccc32)cc1 ; c1ccc(-c2cccc(-n3c4ccccc4c4cc(-c5cccc(-c6ccccc6)c5-n5c6ccccc6c6ccccc65)ccc43)c2)cc1] 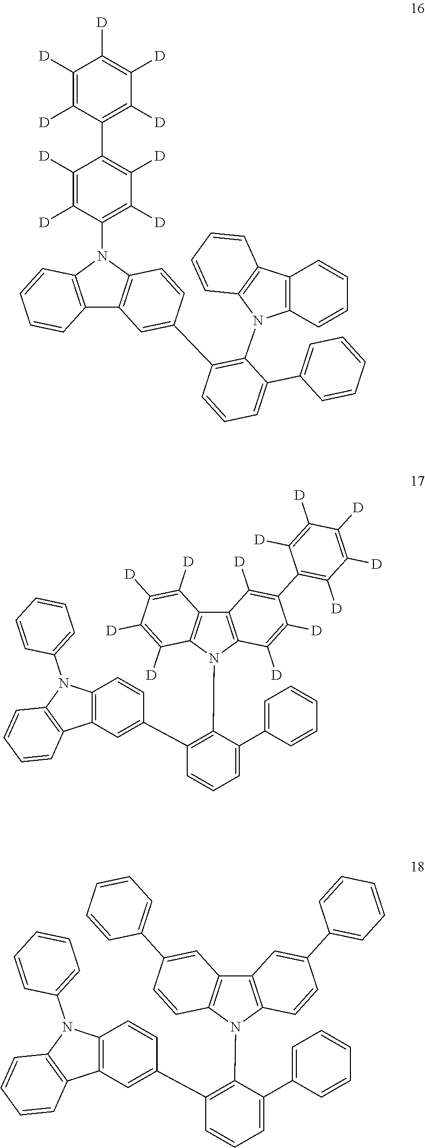 [SMILES: [2H]c1c([2H])c([2H])c(-c2c([2H])c([2H])c(-n3c4ccccc4c4cc(-c5cccc(-c6ccccc6)c5-n5c6ccccc6c6ccccc65)ccc43)c([2H])c2[2H])c([2H])c1[2H] ; [2H]c1c([2H])c([2H])c(-c2c([2H])c([2H])c3c(c2[2H])c2c([2H])c([2H])c([2H])c([2H])c2n3-c2c(-c3ccccc3)cccc2-c2ccc3c(c2)c2ccccc2n3-c2ccccc2)c([2H])c1[2H] ; c1ccc(-c2ccc3c(c2)c2cc(-c4ccccc4)ccc2n3-c2c(-c3ccccc3)cccc2-c2ccc3c(c2)c2ccccc2n3-c2ccccc2)cc1] 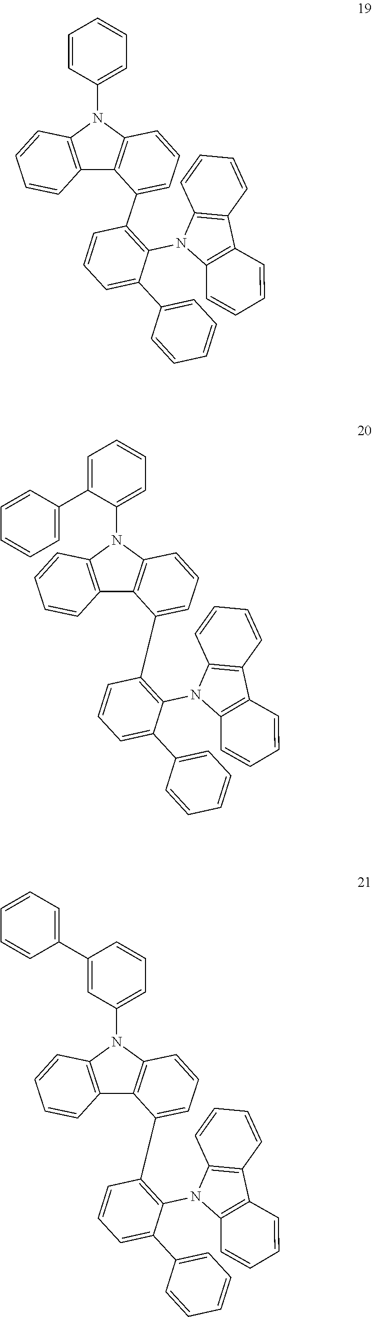 [SMILES: c1ccc(-c2cccc(-c3cccc4c3c3ccccc3n4-c3ccccc3)c2-n2c3ccccc3c3ccccc32)cc1 ; c1ccc(-c2ccccc2-n2c3ccccc3c3c(-c4cccc(-c5ccccc5)c4-n4c5ccccc5c5ccccc54)cccc32)cc1 ; c1ccc(-c2cccc(-n3c4ccccc4c4c(-c5cccc(-c6ccccc6)c5-n5c6ccccc6c6ccccc65)cccc43)c2)cc1] 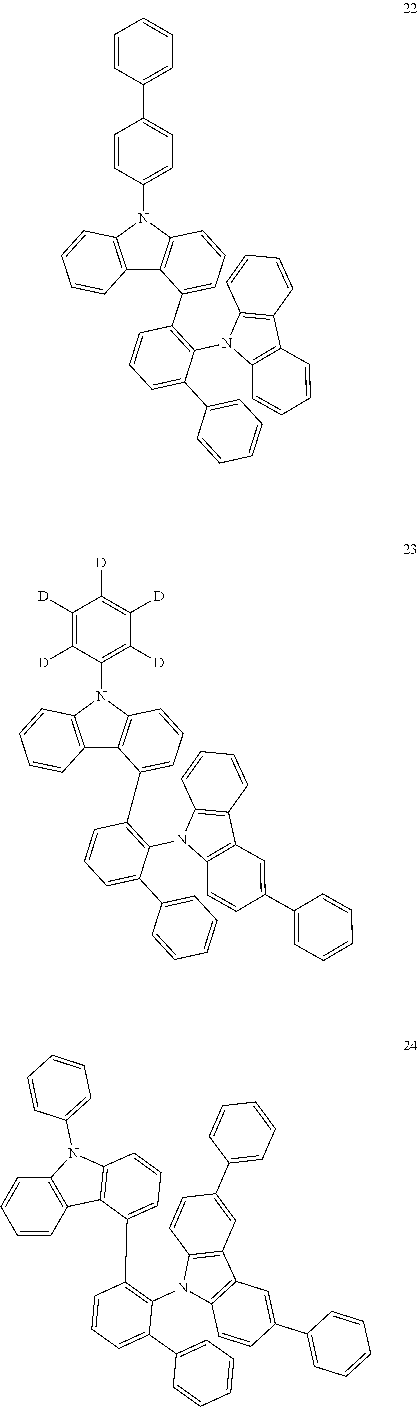 [SMILES: c1ccc(-c2ccc(-n3c4ccccc4c4c(-c5cccc(-c6ccccc6)c5-n5c6ccccc6c6ccccc65)cccc43)cc2)cc1 ; [2H]c1c([2H])c([2H])c(-n2c3ccccc3c3c(-c4cccc(-c5ccccc5)c4-n4c5ccccc5c5cc(-c6ccccc6)ccc54)cccc32)c([2H])c1[2H] ; c1ccc(-c2ccc3c(c2)c2cc(-c4ccccc4)ccc2n3-c2c(-c3ccccc3)cccc2-c2cccc3c2c2ccccc2n3-c2ccccc2)cc1] 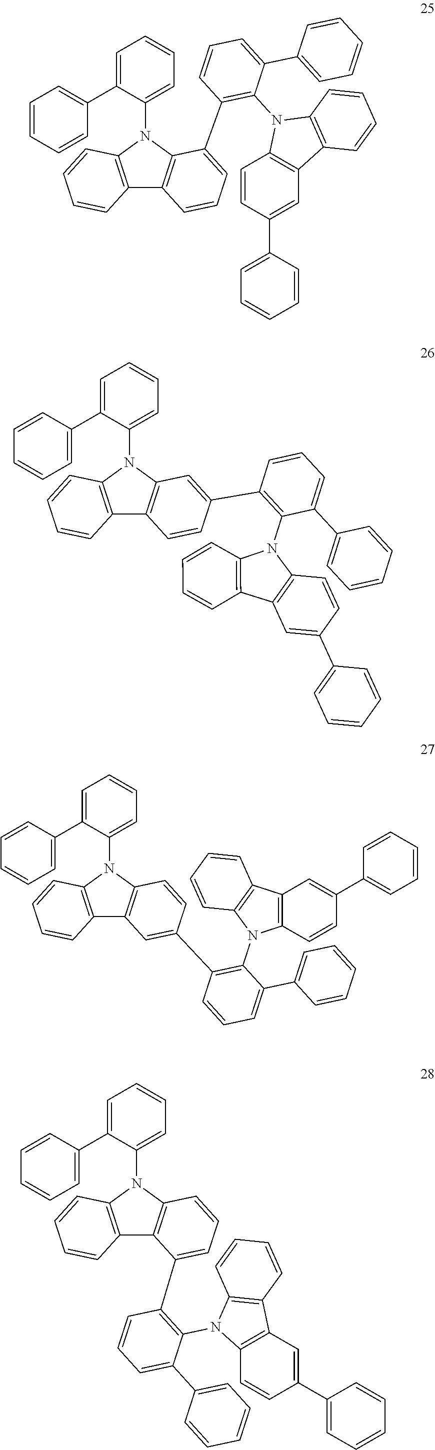 [SMILES: c1ccc(-c2ccc3c(c2)c2ccccc2n3-c2c(-c3ccccc3)cccc2-c2cccc3c4ccccc4n(-c4ccccc4-c4ccccc4)c23)cc1 ; c1ccc(-c2ccc3c(c2)c2ccccc2n3-c2c(-c3ccccc3)cccc2-c2ccc3c4ccccc4n(-c4ccccc4-c4ccccc4)c3c2)cc1 ; c1ccc(-c2ccc3c(c2)c2ccccc2n3-c2c(-c3ccccc3)cccc2-c2ccc3c(c2)c2ccccc2n3-c2ccccc2-c2ccccc2)cc1 ; c1ccc(-c2ccc3c(c2)c2ccccc2n3-c2c(-c3ccccc3)cccc2-c2cccc3c2c2ccccc2n3-c2ccccc2-c2ccccc2)cc1] 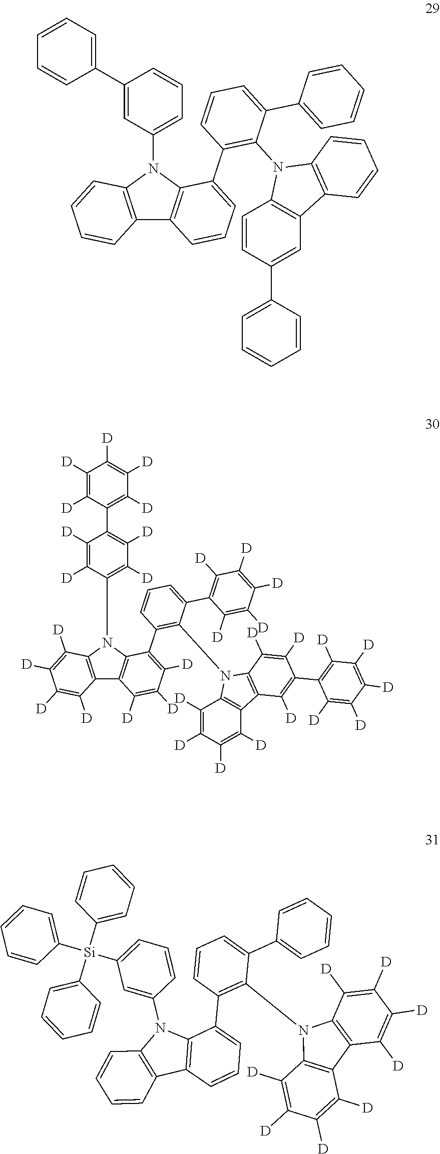 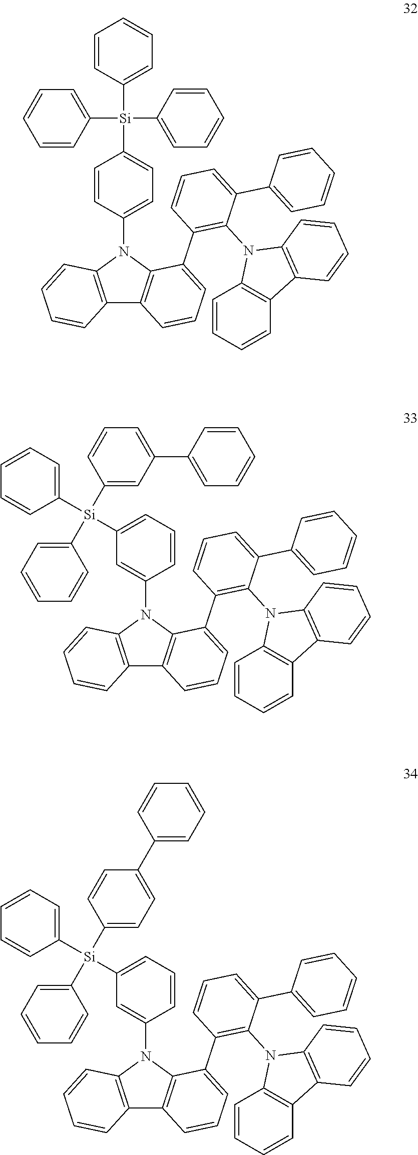 [SMILES: c1ccc(-c2cccc(-c3cccc4c5ccccc5n(-c5ccc([Si](c6ccccc6)(c6ccccc6)c6ccccc6)cc5)c34)c2-n2c3ccccc3c3ccccc32)cc1 ; c1ccc(-c2cccc([Si](c3ccccc3)(c3ccccc3)c3cccc(-n4c5ccccc5c5cccc(-c6cccc(-c7ccccc7)c6-n6c7ccccc7c7ccccc76)c54)c3)c2)cc1 ; c1ccc(-c2ccc([Si](c3ccccc3)(c3ccccc3)c3cccc(-n4c5ccccc5c5cccc(-c6cccc(-c7ccccc7)c6-n6c7ccccc7c7ccccc76)c54)c3)cc2)cc1] 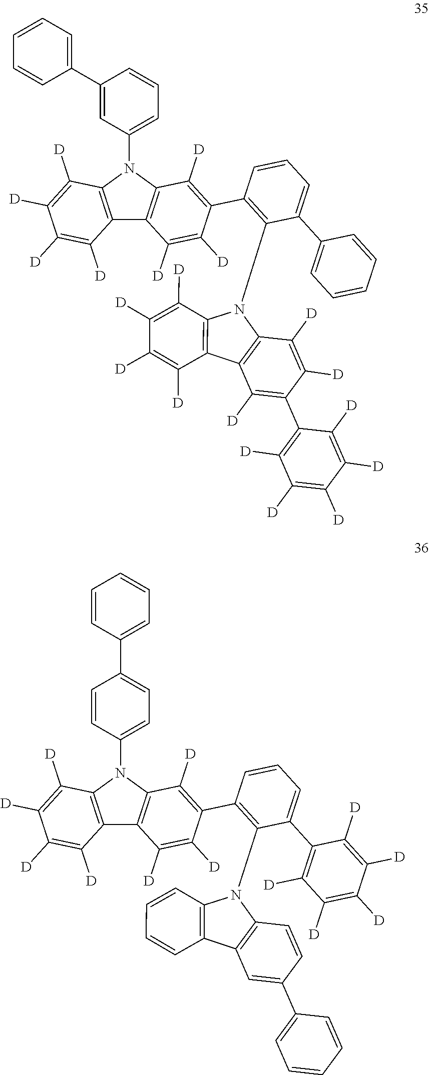 [SMILES: [2H]c1c([2H])c([2H])c(-c2c([2H])c([2H])c3c(c2[2H])c2c([2H])c([2H])c([2H])c([2H])c2n3-c2c(-c3ccccc3)cccc2-c2c([2H])c([2H])c3c4c([2H])c([2H])c([2H])c([2H])c4n(-c4cccc(-c5ccccc5)c4)c3c2[2H])c([2H])c1[2H] ; [2H]c1c([2H])c([2H])c(-c2cccc(-c3c([2H])c([2H])c4c5c([2H])c([2H])c([2H])c([2H])c5n(-c5ccc(-c6ccccc6)cc5)c4c3[2H])c2-n2c3ccccc3c3cc(-c4ccccc4)ccc32)c([2H])c1[2H]] 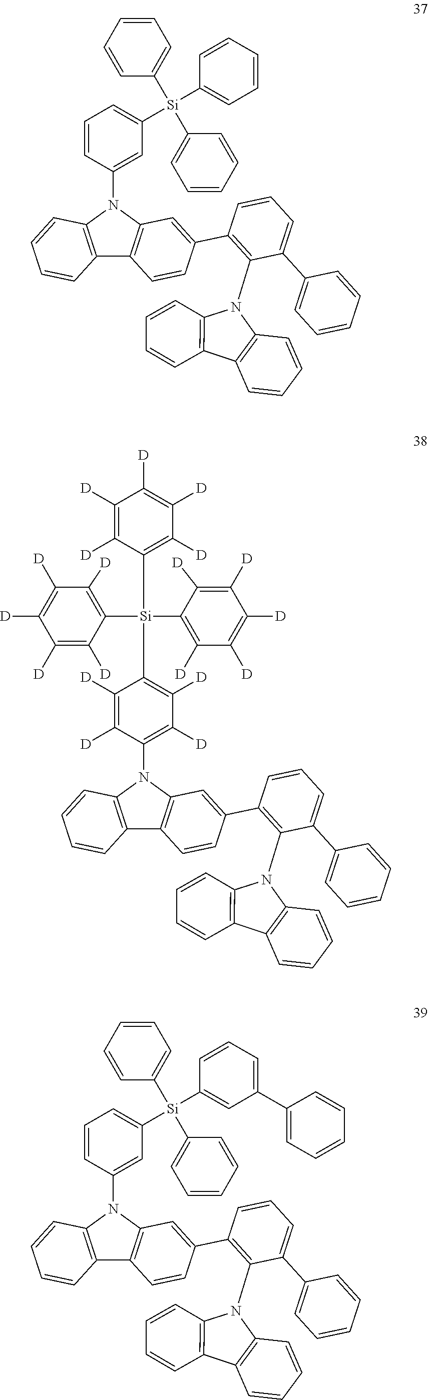 [SMILES: c1ccc(-c2cccc(-c3ccc4c5ccccc5n(-c5cccc([Si](c6ccccc6)(c6ccccc6)c6ccccc6)c5)c4c3)c2-n2c3ccccc3c3ccccc32)cc1 ; [2H]c1c([2H])c([2H])c([Si](c2c([2H])c([2H])c([2H])c([2H])c2[2H])(c2c([2H])c([2H])c([2H])c([2H])c2[2H])c2c([2H])c([2H])c(-n3c4ccccc4c4ccc(-c5cccc(-c6ccccc6)c5-n5c6ccccc6c6ccccc65)cc43)c([2H])c2[2H])c([2H])c1[2H] ; c1ccc(-c2cccc([Si](c3ccccc3)(c3ccccc3)c3cccc(-n4c5ccccc5c5ccc(-c6cccc(-c7ccccc7)c6-n6c7ccccc7c7ccccc76)cc54)c3)c2)cc1] 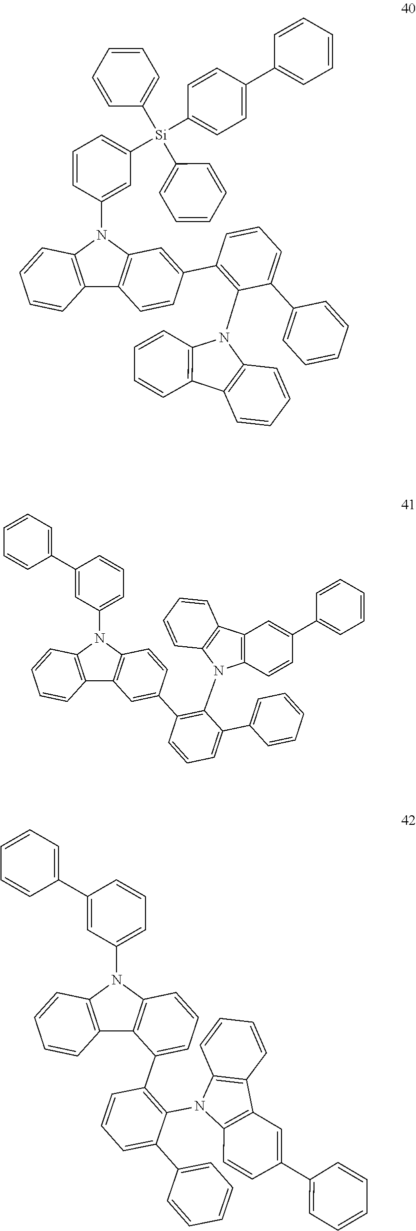 [SMILES: c1ccc(-c2ccc([Si](c3ccccc3)(c3ccccc3)c3cccc(-n4c5ccccc5c5ccc(-c6cccc(-c7ccccc7)c6-n6c7ccccc7c7ccccc76)cc54)c3)cc2)cc1 ; c1ccc(-c2cccc(-n3c4ccccc4c4cc(-c5cccc(-c6ccccc6)c5-n5c6ccccc6c6cc(-c7ccccc7)ccc65)ccc43)c2)cc1 ; c1ccc(-c2cccc(-n3c4ccccc4c4c(-c5cccc(-c6ccccc6)c5-n5c6ccccc6c6cc(-c7ccccc7)ccc65)cccc43)c2)cc1] 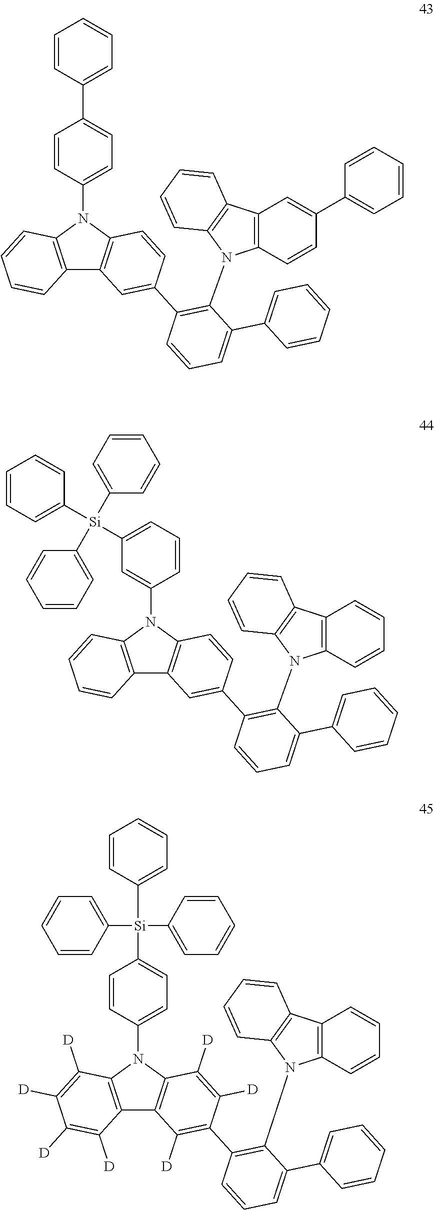 [SMILES: c1ccc(-c2ccc(-n3c4ccccc4c4cc(-c5cccc(-c6ccccc6)c5-n5c6ccccc6c6cc(-c7ccccc7)ccc65)ccc43)cc2)cc1 ; c1ccc(-c2cccc(-c3ccc4c(c3)c3ccccc3n4-c3cccc([Si](c4ccccc4)(c4ccccc4)c4ccccc4)c3)c2-n2c3ccccc3c3ccccc32)cc1 ; [2H]c1c([2H])c([2H])c2c(c1[2H])c1c([2H])c(-c3cccc(-c4ccccc4)c3-n3c4ccccc4c4ccccc43)c([2H])c([2H])c1n2-c1ccc([Si](c2ccccc2)(c2ccccc2)c2ccccc2)cc1] 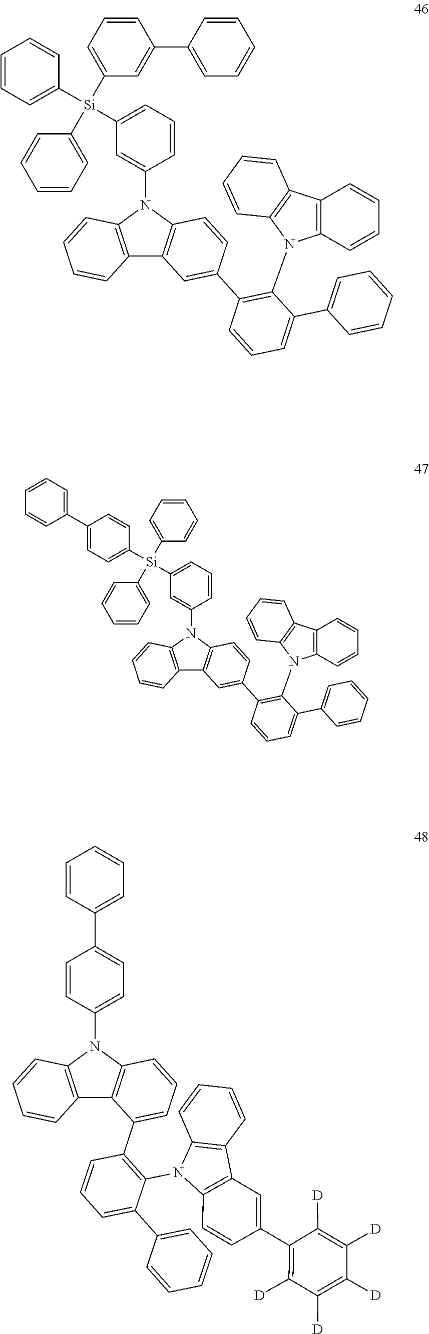 [SMILES: c1ccc(-c2cccc([Si](c3ccccc3)(c3ccccc3)c3cccc(-n4c5ccccc5c5cc(-c6cccc(-c7ccccc7)c6-n6c7ccccc7c7ccccc76)ccc54)c3)c2)cc1 ; c1ccc(-c2ccc([Si](c3ccccc3)(c3ccccc3)c3cccc(-n4c5ccccc5c5cc(-c6cccc(-c7ccccc7)c6-n6c7ccccc7c7ccccc76)ccc54)c3)cc2)cc1 ; [2H]c1c([2H])c([2H])c(-c2ccc3c(c2)c2ccccc2n3-c2c(-c3ccccc3)cccc2-c2cccc3c2c2ccccc2n3-c2ccc(-c3ccccc3)cc2)c([2H])c1[2H]] 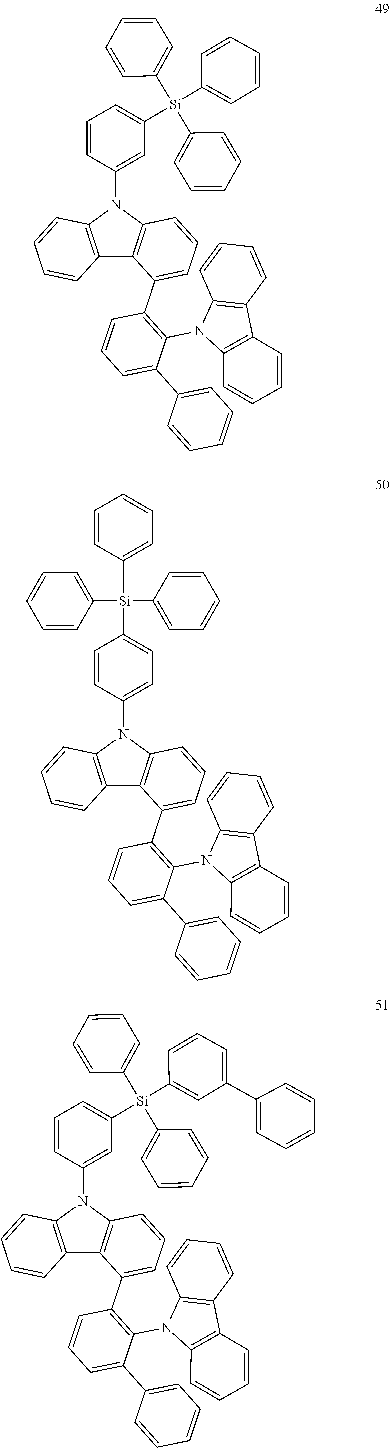 [SMILES: c1ccc(-c2cccc(-c3cccc4c3c3ccccc3n4-c3cccc([Si](c4ccccc4)(c4ccccc4)c4ccccc4)c3)c2-n2c3ccccc3c3ccccc32)cc1 ; c1ccc(-c2cccc(-c3cccc4c3c3ccccc3n4-c3ccc([Si](c4ccccc4)(c4ccccc4)c4ccccc4)cc3)c2-n2c3ccccc3c3ccccc32)cc1 ; c1ccc(-c2cccc([Si](c3ccccc3)(c3ccccc3)c3cccc(-n4c5ccccc5c5c(-c6cccc(-c7ccccc7)c6-n6c7ccccc7c7ccccc76)cccc54)c3)c2)cc1] 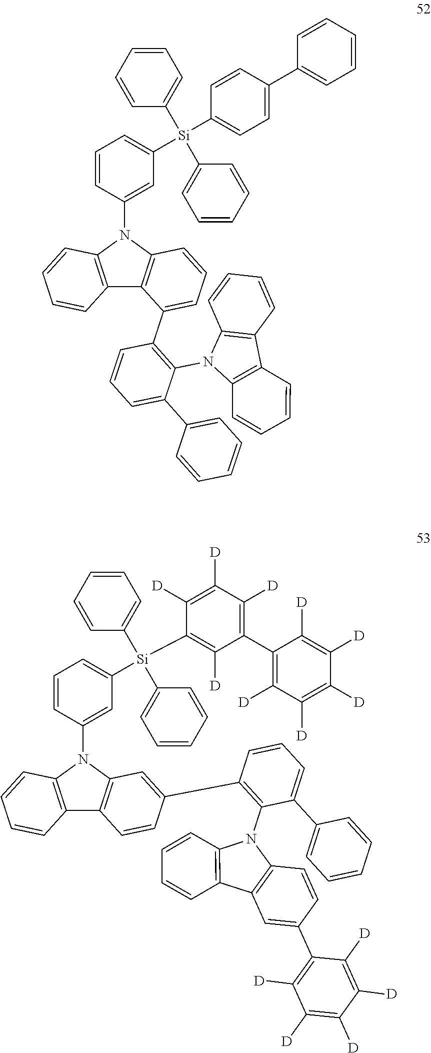 [SMILES: c1ccc(-c2ccc([Si](c3ccccc3)(c3ccccc3)c3cccc(-n4c5ccccc5c5c(-c6cccc(-c7ccccc7)c6-n6c7ccccc7c7ccccc76)cccc54)c3)cc2)cc1 ; [2H]c1c([2H])c([2H])c(-c2ccc3c(c2)c2ccccc2n3-c2c(-c3ccccc3)cccc2-c2ccc3c4ccccc4n(-c4cccc([Si](c5ccccc5)(c5ccccc5)c5c([2H])c([2H])c([2H])c(-c6c([2H])c([2H])c([2H])c([2H])c6[2H])c5[2H])c4)c3c2)c([2H])c1[2H]] 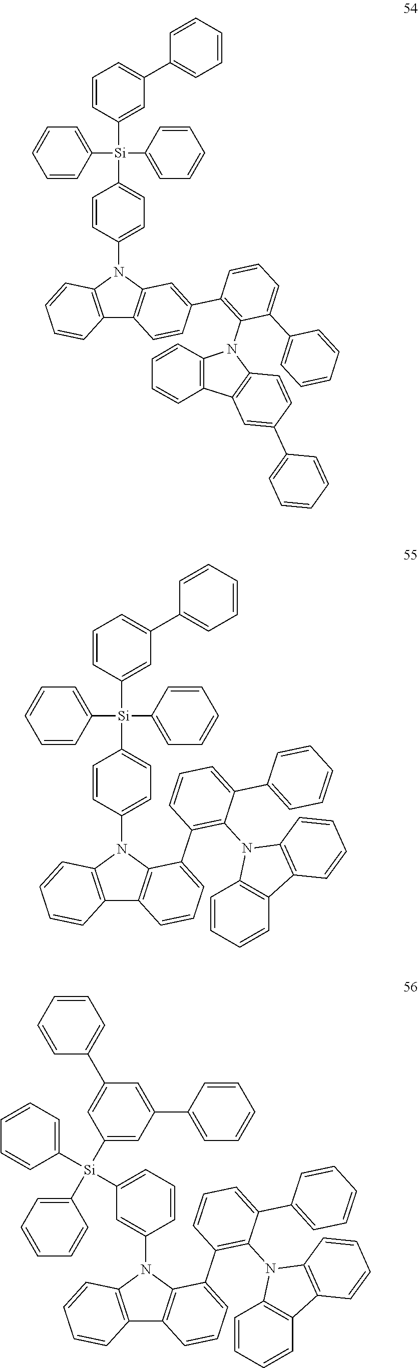 [SMILES: c1ccc(-c2cccc([Si](c3ccccc3)(c3ccccc3)c3ccc(-n4c5ccccc5c5ccc(-c6cccc(-c7ccccc7)c6-n6c7ccccc7c7cc(-c8ccccc8)ccc76)cc54)cc3)c2)cc1 ; c1ccc(-c2cccc([Si](c3ccccc3)(c3ccccc3)c3ccc(-n4c5ccccc5c5cccc(-c6cccc(-c7ccccc7)c6-n6c7ccccc7c7ccccc76)c54)cc3)c2)cc1 ; c1ccc(-c2cc(-c3ccccc3)cc([Si](c3ccccc3)(c3ccccc3)c3cccc(-n4c5ccccc5c5cccc(-c6cccc(-c7ccccc7)c6-n6c7ccccc7c7ccccc76)c54)c3)c2)cc1] 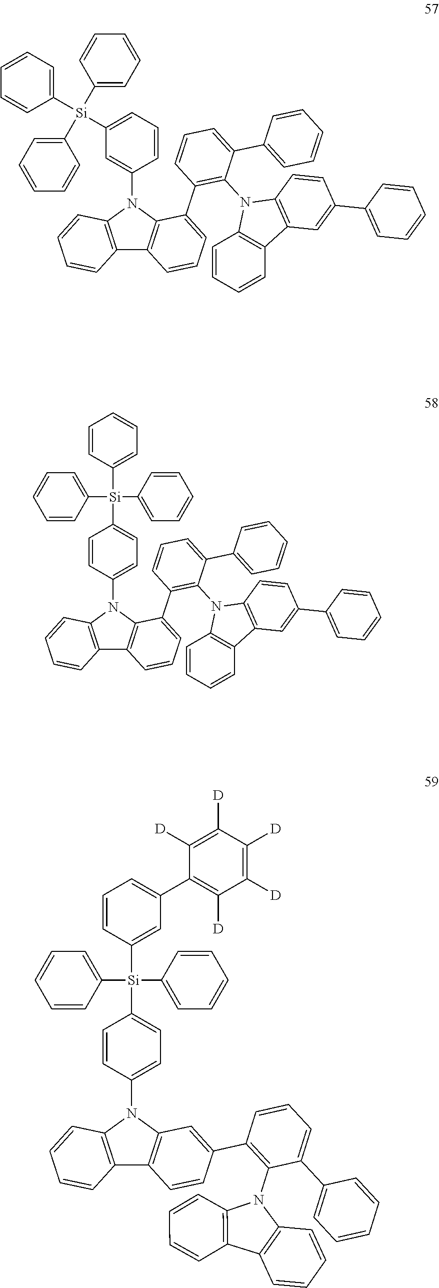 [SMILES: c1ccc(-c2ccc3c(c2)c2ccccc2n3-c2c(-c3ccccc3)cccc2-c2cccc3c4ccccc4n(-c4cccc([Si](c5ccccc5)(c5ccccc5)c5ccccc5)c4)c23)cc1 ; c1ccc(-c2ccc3c(c2)c2ccccc2n3-c2c(-c3ccccc3)cccc2-c2cccc3c4ccccc4n(-c4ccc([Si](c5ccccc5)(c5ccccc5)c5ccccc5)cc4)c23)cc1 ; [2H]c1c([2H])c([2H])c(-c2cccc([Si](c3ccccc3)(c3ccccc3)c3ccc(-n4c5ccccc5c5ccc(-c6cccc(-c7ccccc7)c6-n6c7ccccc7c7ccccc76)cc54)cc3)c2)c([2H])c1[2H]] 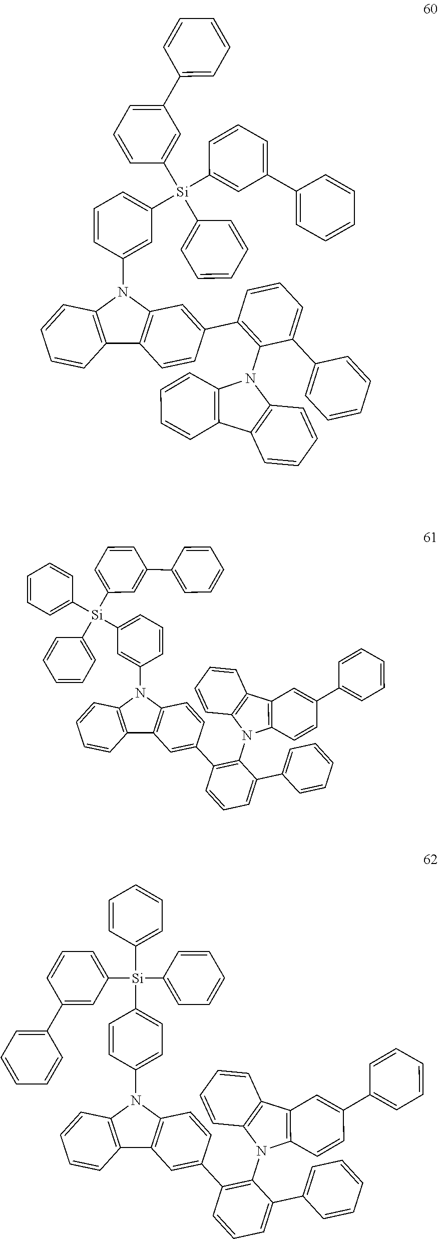 [SMILES: c1ccc(-c2cccc([Si](c3ccccc3)(c3cccc(-c4ccccc4)c3)c3cccc(-n4c5ccccc5c5ccc(-c6cccc(-c7ccccc7)c6-n6c7ccccc7c7ccccc76)cc54)c3)c2)cc1 ; c1ccc(-c2cccc([Si](c3ccccc3)(c3ccccc3)c3cccc(-n4c5ccccc5c5cc(-c6cccc(-c7ccccc7)c6-n6c7ccccc7c7cc(-c8ccccc8)ccc76)ccc54)c3)c2)cc1 ; c1ccc(-c2cccc([Si](c3ccccc3)(c3ccccc3)c3ccc(-n4c5ccccc5c5cc(-c6cccc(-c7ccccc7)c6-n6c7ccccc7c7cc(-c8ccccc8)ccc76)ccc54)cc3)c2)cc1] 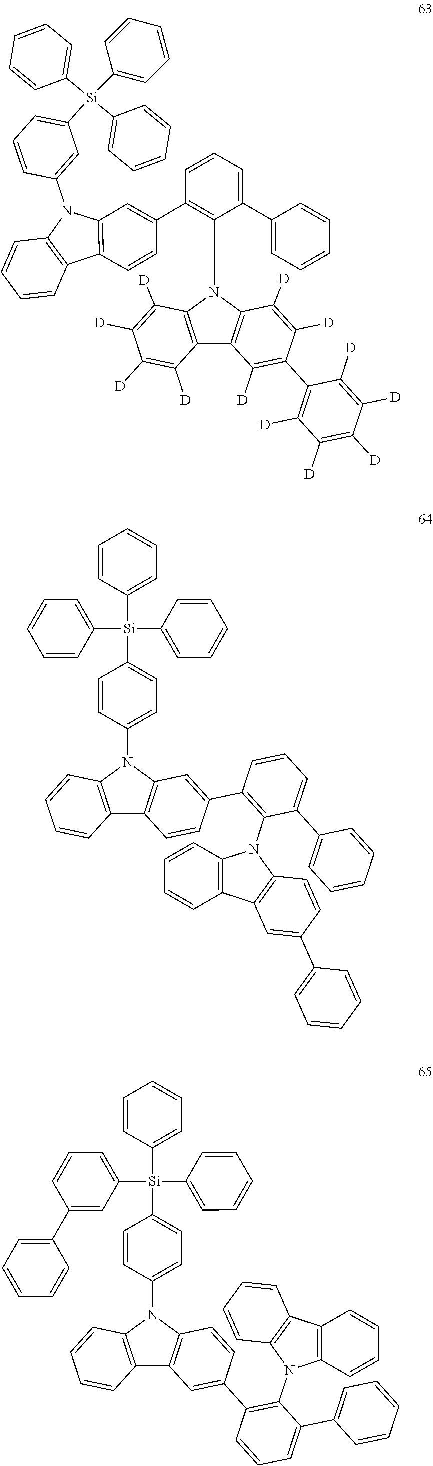 [SMILES: [2H]c1c([2H])c([2H])c(-c2c([2H])c([2H])c3c(c2[2H])c2c([2H])c([2H])c([2H])c([2H])c2n3-c2c(-c3ccccc3)cccc2-c2ccc3c4ccccc4n(-c4cccc([Si](c5ccccc5)(c5ccccc5)c5ccccc5)c4)c3c2)c([2H])c1[2H] ; c1ccc(-c2ccc3c(c2)c2ccccc2n3-c2c(-c3ccccc3)cccc2-c2ccc3c4ccccc4n(-c4ccc([Si](c5ccccc5)(c5ccccc5)c5ccccc5)cc4)c3c2)cc1 ; c1ccc(-c2cccc([Si](c3ccccc3)(c3ccccc3)c3ccc(-n4c5ccccc5c5cc(-c6cccc(-c7ccccc7)c6-n6c7ccccc7c7ccccc76)ccc54)cc3)c2)cc1] 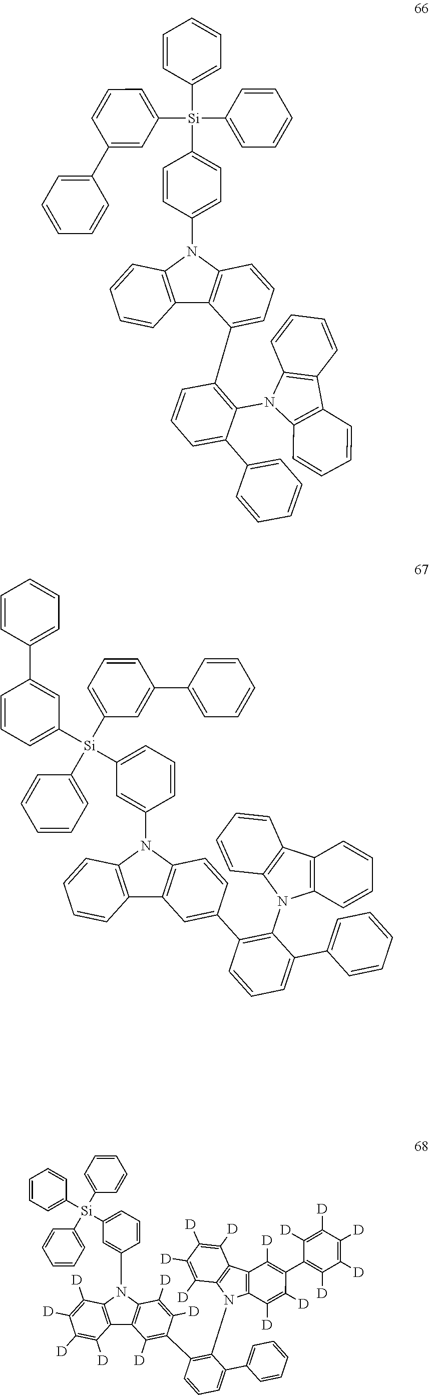 [SMILES: c1ccc(-c2cccc([Si](c3ccccc3)(c3ccccc3)c3ccc(-n4c5ccccc5c5c(-c6cccc(-c7ccccc7)c6-n6c7ccccc7c7ccccc76)cccc54)cc3)c2)cc1 ; c1ccc(-c2cccc([Si](c3ccccc3)(c3cccc(-c4ccccc4)c3)c3cccc(-n4c5ccccc5c5cc(-c6cccc(-c7ccccc7)c6-n6c7ccccc7c7ccccc76)ccc54)c3)c2)cc1 ; [2H]c1c([2H])c([2H])c(-c2c([2H])c([2H])c3c(c2[2H])c2c([2H])c([2H])c([2H])c([2H])c2n3-c2c(-c3ccccc3)cccc2-c2c([2H])c([2H])c3c(c2[2H])c2c([2H])c([2H])c([2H])c([2H])c2n3-c2cccc([Si](c3ccccc3)(c3ccccc3)c3ccccc3)c2)c([2H])c1[2H]] 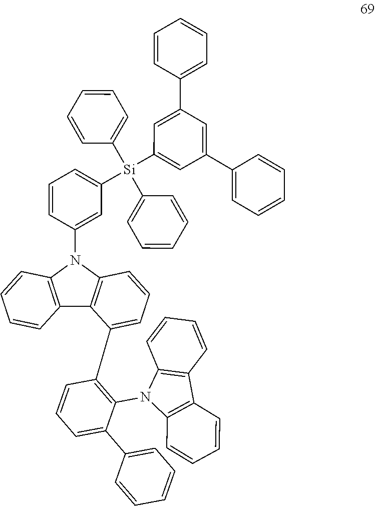 [SMILES: c1ccc(-c2cc(-c3ccccc3)cc([Si](c3ccccc3)(c3ccccc3)c3cccc(-n4c5ccccc5c5c(-c6cccc(-c7ccccc7)c6-n6c7ccccc7c7ccccc76)cccc54)c3)c2)cc1] 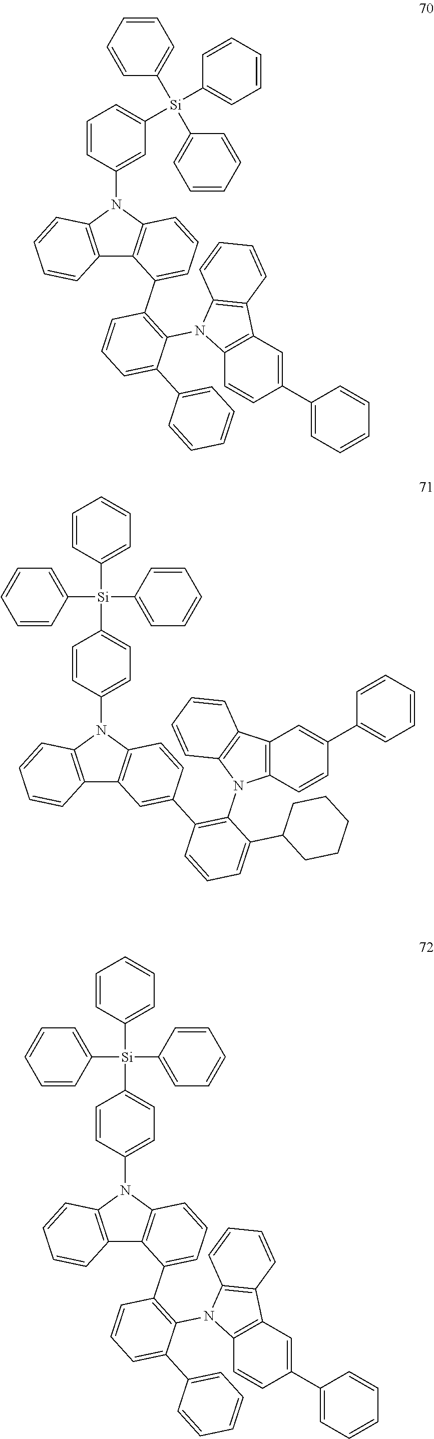 [SMILES: c1ccc(-c2ccc3c(c2)c2ccccc2n3-c2c(-c3ccccc3)cccc2-c2cccc3c2c2ccccc2n3-c2cccc([Si](c3ccccc3)(c3ccccc3)c3ccccc3)c2)cc1 ; c1ccc(-c2ccc3c(c2)c2ccccc2n3-c2c(-c3ccc4c(c3)c3ccccc3n4-c3ccc([Si](c4ccccc4)(c4ccccc4)c4ccccc4)cc3)cccc2C2CCCCC2)cc1 ; c1ccc(-c2ccc3c(c2)c2ccccc2n3-c2c(-c3ccccc3)cccc2-c2cccc3c2c2ccccc2n3-c2ccc([Si](c3ccccc3)(c3ccccc3)c3ccccc3)cc2)cc1] 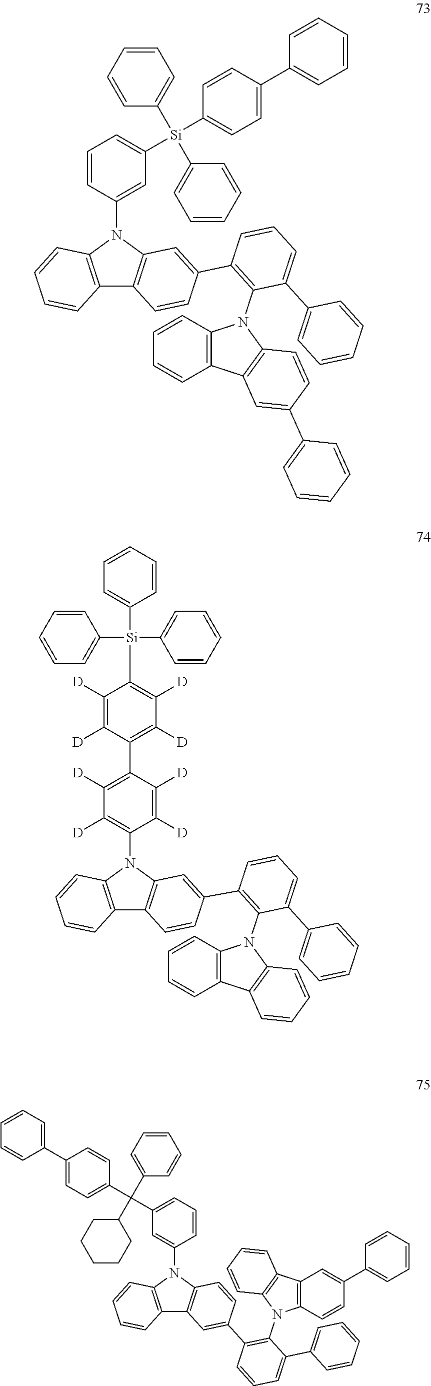 [SMILES: c1ccc(-c2ccc([Si](c3ccccc3)(c3ccccc3)c3cccc(-n4c5ccccc5c5ccc(-c6cccc(-c7ccccc7)c6-n6c7ccccc7c7cc(-c8ccccc8)ccc76)cc54)c3)cc2)cc1 ; [2H]c1c([2H])c(-n2c3ccccc3c3ccc(-c4cccc(-c5ccccc5)c4-n4c5ccccc5c5ccccc54)cc32)c([2H])c([2H])c1-c1c([2H])c([2H])c([Si](c2ccccc2)(c2ccccc2)c2ccccc2)c([2H])c1[2H] ; c1ccc(-c2ccc(C(c3ccccc3)(c3cccc(-n4c5ccccc5c5cc(-c6cccc(-c7ccccc7)c6-n6c7ccccc7c7cc(-c8ccccc8)ccc76)ccc54)c3)C3CCCCC3)cc2)cc1] 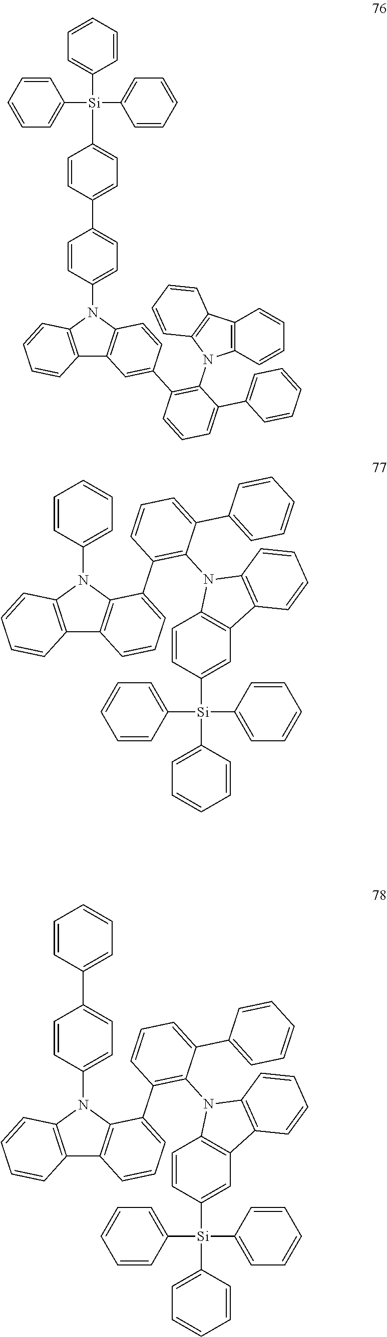 [SMILES: c1ccc(-c2cccc(-c3ccc4c(c3)c3ccccc3n4-c3ccc(-c4ccc([Si](c5ccccc5)(c5ccccc5)c5ccccc5)cc4)cc3)c2-n2c3ccccc3c3ccccc32)cc1 ; c1ccc(-c2cccc(-c3cccc4c5ccccc5n(-c5ccccc5)c34)c2-n2c3ccccc3c3cc([Si](c4ccccc4)(c4ccccc4)c4ccccc4)ccc32)cc1 ; c1ccc(-c2ccc(-n3c4ccccc4c4cccc(-c5cccc(-c6ccccc6)c5-n5c6ccccc6c6cc([Si](c7ccccc7)(c7ccccc7)c7ccccc7)ccc65)c43)cc2)cc1] 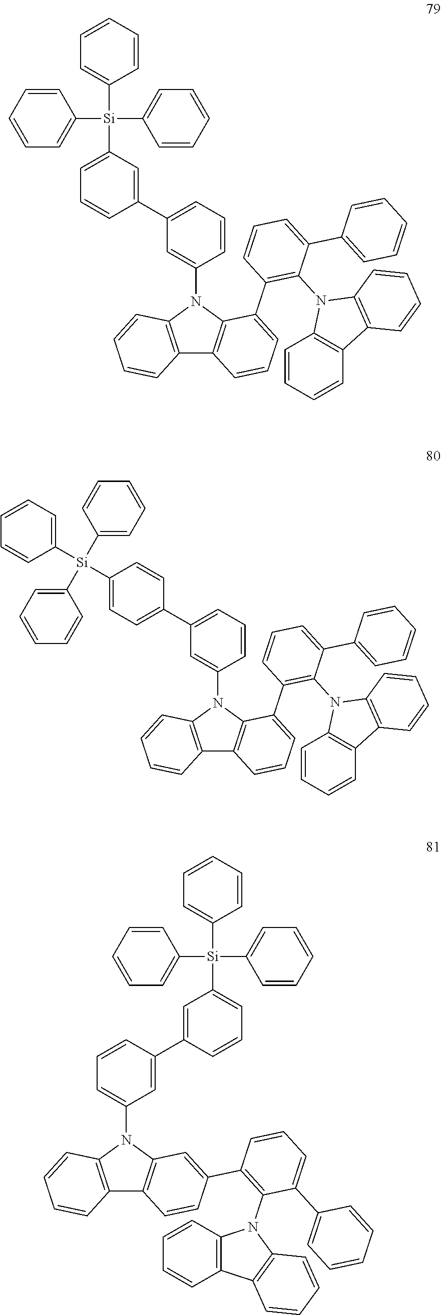 [SMILES: c1ccc(-c2cccc(-c3cccc4c5ccccc5n(-c5cccc(-c6cccc([Si](c7ccccc7)(c7ccccc7)c7ccccc7)c6)c5)c34)c2-n2c3ccccc3c3ccccc32)cc1 ; c1ccc(-c2cccc(-c3cccc4c5ccccc5n(-c5cccc(-c6ccc([Si](c7ccccc7)(c7ccccc7)c7ccccc7)cc6)c5)c34)c2-n2c3ccccc3c3ccccc32)cc1 ; c1ccc(-c2cccc(-c3ccc4c5ccccc5n(-c5cccc(-c6cccc([Si](c7ccccc7)(c7ccccc7)c7ccccc7)c6)c5)c4c3)c2-n2c3ccccc3c3ccccc32)cc1] 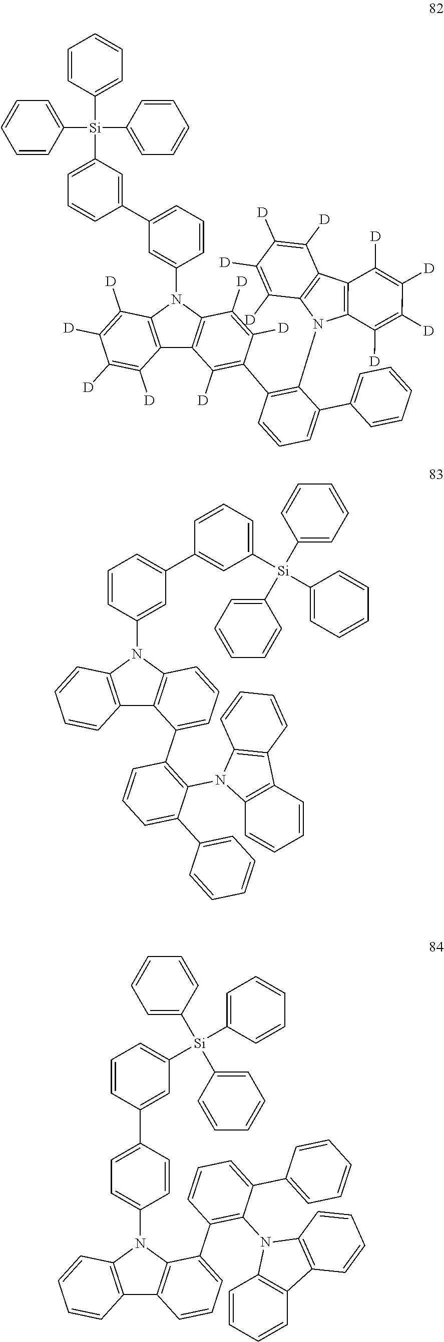 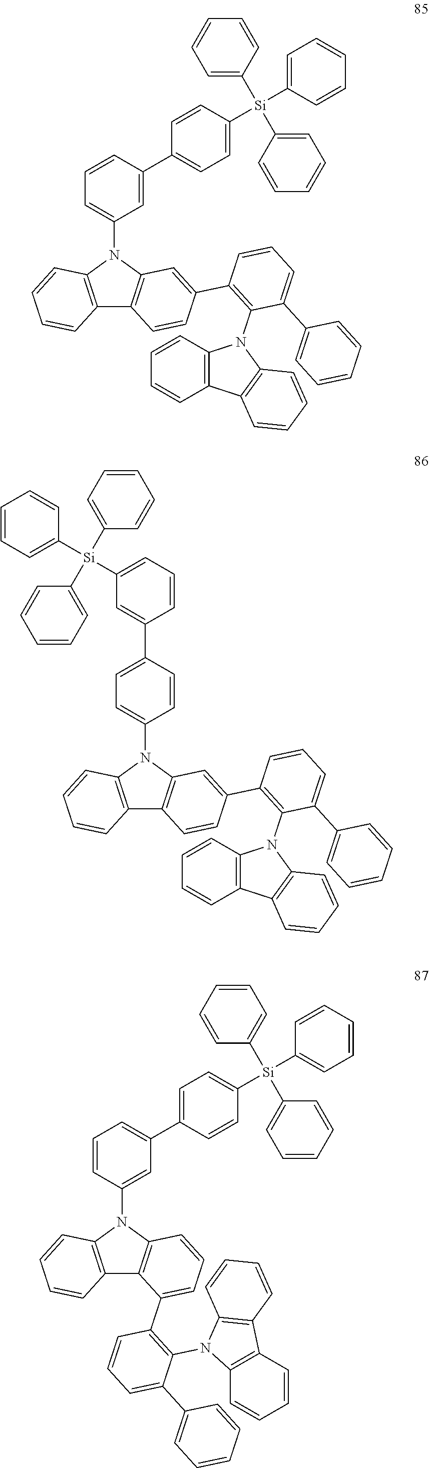 [SMILES: c1ccc(-c2cccc(-c3ccc4c5ccccc5n(-c5cccc(-c6ccc([Si](c7ccccc7)(c7ccccc7)c7ccccc7)cc6)c5)c4c3)c2-n2c3ccccc3c3ccccc32)cc1 ; c1ccc(-c2cccc(-c3ccc4c5ccccc5n(-c5ccc(-c6cccc([Si](c7ccccc7)(c7ccccc7)c7ccccc7)c6)cc5)c4c3)c2-n2c3ccccc3c3ccccc32)cc1 ; c1ccc(-c2cccc(-c3cccc4c3c3ccccc3n4-c3cccc(-c4ccc([Si](c5ccccc5)(c5ccccc5)c5ccccc5)cc4)c3)c2-n2c3ccccc3c3ccccc32)cc1] 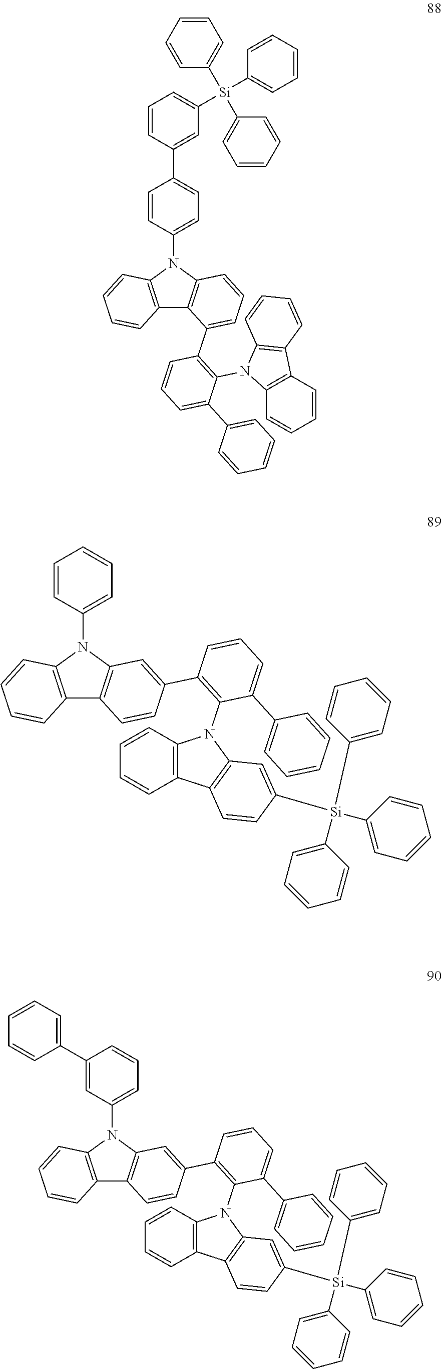 [SMILES: c1ccc(-c2cccc(-c3cccc4c3c3ccccc3n4-c3ccc(-c4cccc([Si](c5ccccc5)(c5ccccc5)c5ccccc5)c4)cc3)c2-n2c3ccccc3c3ccccc32)cc1 ; c1ccc(-c2cccc(-c3ccc4c5ccccc5n(-c5ccccc5)c4c3)c2-n2c3ccccc3c3ccc([Si](c4ccccc4)(c4ccccc4)c4ccccc4)cc32)cc1 ; c1ccc(-c2cccc(-n3c4ccccc4c4ccc(-c5cccc(-c6ccccc6)c5-n5c6ccccc6c6ccc([Si](c7ccccc7)(c7ccccc7)c7ccccc7)cc65)cc43)c2)cc1] 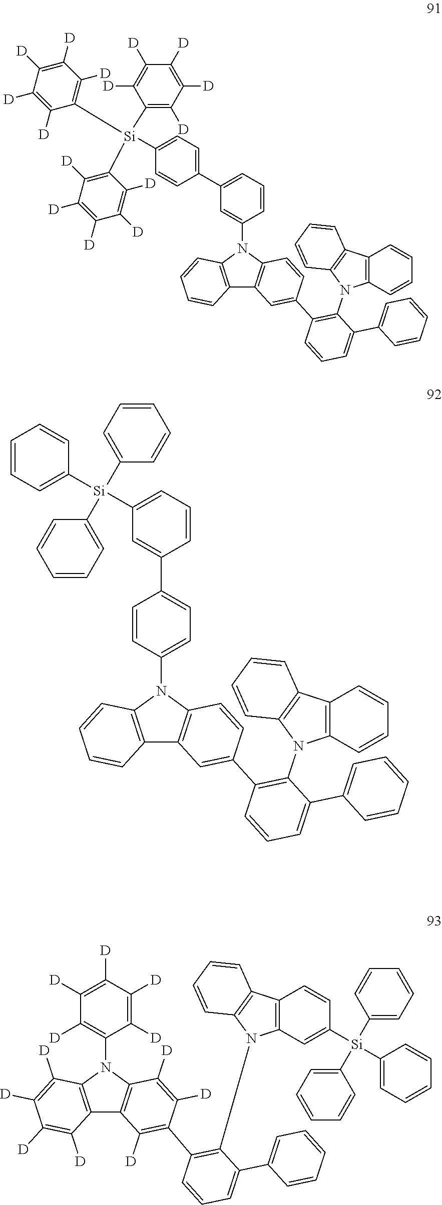 [SMILES: [2H]c1c([2H])c([2H])c([Si](c2ccc(-c3cccc(-n4c5ccccc5c5cc(-c6cccc(-c7ccccc7)c6-n6c7ccccc7c7ccccc76)ccc54)c3)cc2)(c2c([2H])c([2H])c([2H])c([2H])c2[2H])c2c([2H])c([2H])c([2H])c([2H])c2[2H])c([2H])c1[2H] ; c1ccc(-c2cccc(-c3ccc4c(c3)c3ccccc3n4-c3ccc(-c4cccc([Si](c5ccccc5)(c5ccccc5)c5ccccc5)c4)cc3)c2-n2c3ccccc3c3ccccc32)cc1 ; [2H]c1c([2H])c([2H])c(-n2c3c([2H])c([2H])c([2H])c([2H])c3c3c([2H])c(-c4cccc(-c5ccccc5)c4-n4c5ccccc5c5ccc([Si](c6ccccc6)(c6ccccc6)c6ccccc6)cc54)c([2H])c([2H])c32)c([2H])c1[2H]] 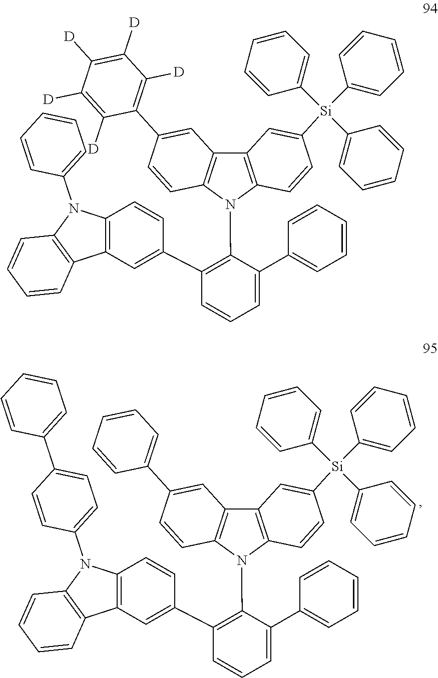 [SMILES: [2H]c1c([2H])c([2H])c(-c2ccc3c(c2)c2cc([Si](c4ccccc4)(c4ccccc4)c4ccccc4)ccc2n3-c2c(-c3ccccc3)cccc2-c2ccc3c(c2)c2ccccc2n3-c2ccccc2)c([2H])c1[2H] ; c1ccc(-c2ccc(-n3c4ccccc4c4cc(-c5cccc(-c6ccccc6)c5-n5c6ccc(-c7ccccc7)cc6c6cc([Si](c7ccccc7)(c7ccccc7)c7ccccc7)ccc65)ccc43)cc2)cc1]
in Compound Group 1, “D” being deuterium.
